(19) United States
(12) Patent Application Publication
(10) Pub. No.: US 2025/0287839 A1
(43) Pub. Date: Sep. 11, 2025

(54) LIGHT-EMITTING ELEMENT, POLYCYCLIC COMPOUND FOR LIGHT-EMITTING ELEMENT, AND DISPLAY DEVICE INCLUDING THE LIGHT-EMITTING ELEMENT

(71) Applicant: Samsung Display Co., Ltd., Yongin-si (KR)

(72) Inventors: Yuuki MIYAZAKI, Yokohama (JP); Keigo HOSHI, Yokohama (JP); Yoshiro SUGITA, Yokohama (JP); Yuma AOKI, Yokohama (JP)

(73) Assignee: Samsung Display Co., Ltd., Yongin-si (KR)

(21) Appl. No.: 19/062,401

(22) Filed: Feb. 25, 2025

(30) Foreign Application Priority Data
Mar. 5, 2024 (KR) 10-2024-0031552

(51) Int. Cl. H10K 85/60; C07F 5/02; C07F 7/08; C09K 11/02; C09K 11/06; H10K 50/12; H10K 85/30

(52) U.S. Cl. CPC H10K 85/6572; C07F 5/027; C07F 7/0812; C09K 11/02; C09K 11/06; H10K 85/346; H10K 85/636; C07B 2200/05; C09K 2211/1007; C09K 2211/1014; C09K 2211/1018; C09K 2211/1022; H10K 50/121; H10K 85/658

(57) ABSTRACT

Embodiments provide a polycyclic compound, a light emitting element that includes the polycyclic compound, and a display device that includes the light emitting element. The light-emitting element includes a first electrode, a second electrode facing the first electrode, and an emission layer disposed between the first electrode and the second electrode and including the polycyclic compound. The polycyclic compound is represented by Formula 1, which is explained in the specification.

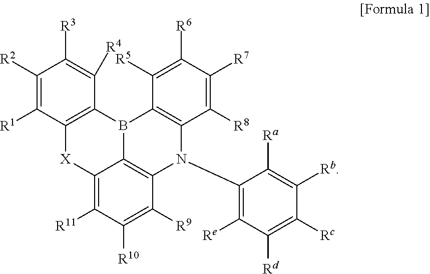

### CROSS-REFERENCE TO RELATED APPLICATION(S)

This application claims priority to and benefits of Korean Patent Application No. 10-2024-0031552 under 35 U.S.C. § 119, filed on Mar. 5, 2024, in the Korean Intellectual Property Office, the entire contents of which are incorporated herein by reference.

### BACKGROUND

### 1. Technical Field

The disclosure relates to a light-emitting element, a polycyclic compound used for a light-emitting element, and an electronic device including the light-emitting element.

### 2. Description of the Related Art

Ongoing development continues for an organic electroluminescence display device as an image display device. Unlike a liquid crystal display device, an organic electroluminescence display device is a so-called self-emissive display device, in which holes and electrons respectively injected from a first electrode and a second electrode recombine in an emission layer so that a light emitting material in the emission layer emits light to achieve display.

In the application of a light-emitting element to a display device, there is a persistent demand for increased emission efficiency and lifespan, and as such, there is ongoing development on materials for a light emitting element that stably achieves such characteristics. For example, developments on a thermally activated delayed fluorescence (TADF) material using a delayed fluorescence phenomenon is being conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved emission efficiency and lifespan.

The disclosure also provides a polycyclic compound having an improved material lifespan.

The disclosure also provides a display device including a light-emitting element having improved emission efficiency and lifespan, thereby having excellent display quality.

According to an embodiment, a light-emitting element may include a first electrode, a second electrode facing the first electrode, and an emission layer disposed between the first electrode and the second electrode and including a first compound represented by Formula 1.

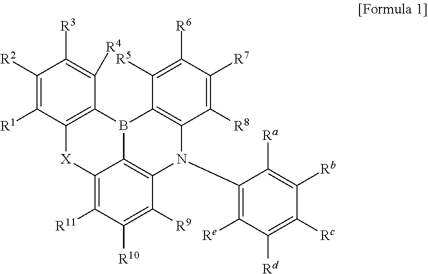

In Formula 1, X may be O, S, or N(R¹²); R¹ to R¹² may each independently be a hydrogen atom, a deuterium atom, a halogen atom, a cyano group, a substituted or unsubstituted amine group, a substituted or unsubstituted oxy group, a substituted or unsubstituted sulfinyl group, a substituted or unsubstituted boron group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or R¹ to R⁴ may be bonded to an adjacent group to form a ring only between R¹ to R⁴, or R⁵ to R⁸ may be bonded to an adjacent group to form a ring only between R⁵ to R⁸; and R^{a} to R^{e} may each independently be a hydrogen atom, a deuterium atom, a halogen atom, a cyano group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30.

In Formula 1, at least one of R^{a} to R^{e} may be a cyano group; and at least one of the remainder of R^{a} to R^{e} may each independently be a substituted or unsubstituted aryl group having a ring-forming carbon number of 6 to 30.

In an embodiment, the emission layer may further include at least one of a second compound represented by Formula HT-1 and a third compound represented by Formula ET-1.

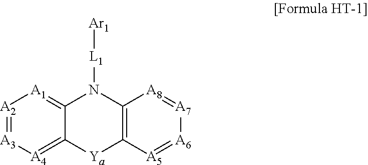

In Formula HT-1, A₁ to A₈ may each independently be N or C(R₅₁); L₁ may be a direct linkage, a substituted or unsubstituted arylene group having a ring-forming carbon number of 6 to 30, or a substituted or unsubstituted heteroarylene group having a ring-forming carbon number of 2 to 30; Yₐ may be a direct linkage, C(R₅₂)(R₅₃), or Si(R₅₄)(R₅₅); Ar₁ may be a substituted or unsubstituted aryl group having a ring-forming carbon number of 6 to 30, or a substituted or unsubstituted heteroaryl group having a ring-forming carbon number of 2 to 30; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 30, or a substituted or unsubstituted heteroaryl group having a ring-forming carbon number of 2 to 60, or bonded to an adjacent group to form a ring.

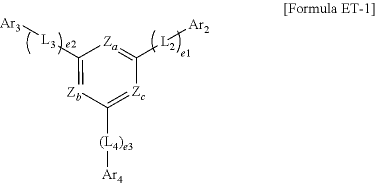

In Formula ET-1, at least one of Zₐ to Z_{c} may be N; the remainder of Zₐ to Z_{c} may each independently be C(R₅₆); R₅₆ may be a hydrogen atom, a deuterium atom, a substituted or unsubstituted alkyl group having a carbon number of 1 to 20, a substituted or unsubstituted aryl group having a ring-forming carbon number of 6 to 60, or a substituted or unsubstituted heteroaryl group having a ring-forming carbon number of 2 to 60; e1 to e3 may each independently be an integer from 0 to 10; Ar₂ to Ar₄ may each independently be a hydrogen atom, a deuterium atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30; and L₂ to L₄ may each independently be a direct linkage, a substituted or unsubstituted arylene group having a ring-forming carbon number of 6 to 30, or a substituted or unsubstituted heteroarylene group having a ring-forming carbon number of 2 to 30.

In an embodiment, the emission layer may further include a fourth compound represented by Formula D-1.

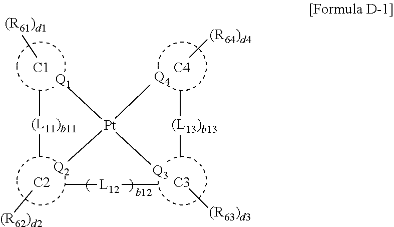

In Formula D-1, Q₁ to Q₄ may each independently be C or N; C1 to C4 may each independently be a substituted or unsubstituted hydrocarbon ring having a ring-forming carbon number of 5 to 30, or a substituted or unsubstituted heterocycle having a ring-forming carbon number of 2 to 30; L₁₁ to L₁₃ may each independently be a direct linkage,

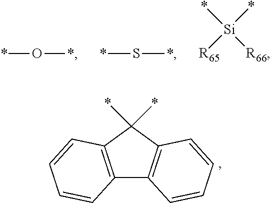

a substituted or unsubstituted alkylene group having a carbon number of 1 to 20, a substituted or unsubstituted arylene group having a ring-forming carbon number of 6 to 30, or a substituted or unsubstituted heteroarylene group having a ring-forming carbon number of 2 to 30; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 60, or a substituted or unsubstituted heteroaryl group having a ring-forming carbon number of 2 to 60; and d1 to d4 may each independently be an integer from 0 to 4.

In an embodiment, among two selected from R^{a} to R^{e}, one thereof may be a cyano group, and the other thereof may be a substituted or unsubstituted phenyl group; and the remainder of R^{a} to R^{e} that are not the cyano group or the substituted or unsubstituted phenyl group may each independently be a hydrogen atom, a deuterium atom, or a substituted or unsubstituted aryl group having a ring-forming carbon number of 6 to 30.

In an embodiment, the first compound represented by Formula 1 may be represented by one of Formula 2-1 to Formula 2-3.

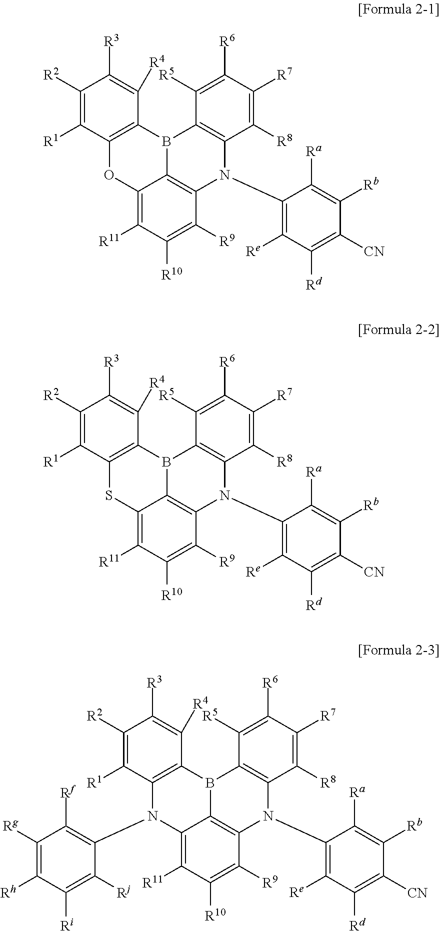

In Formula 2-1 to Formula 2-3, one or two of R^{a}, R^{b}, R^{d}, and R^{e} may each independently be a substituted or unsubstituted phenyl group; the remainder of R^{a}, R^{b}, R^{d}, and R^{e} may each independently be a hydrogen atom or a deuterium atom; and R¹ to R¹¹ may each be the same as defined in Formula 1. In Formula 2-3, R^{f}, R^{g}, R^{h}, Rⁱ, and Rⱼ may each independently be a hydrogen atom, a deuterium atom, a cyano group, an unsubstituted alkyl group having a carbon number of 1 to 20, or a substituted or unsubstituted aryl group having a ring-forming carbon number of 6 to 30.

In an embodiment, the first compound represented by Formula 1 may be represented by one of Formula 3-1 to Formula 3-5.

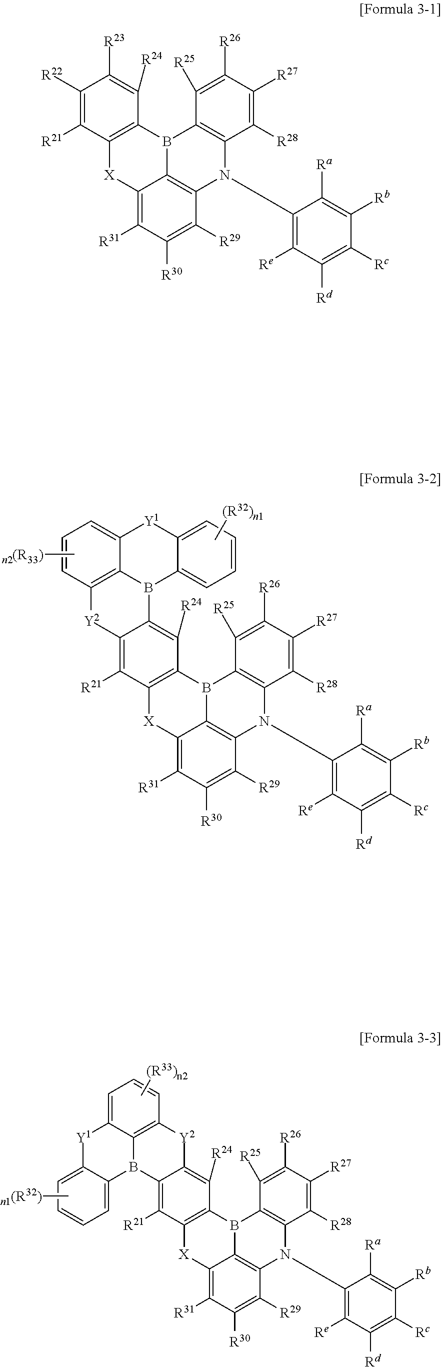

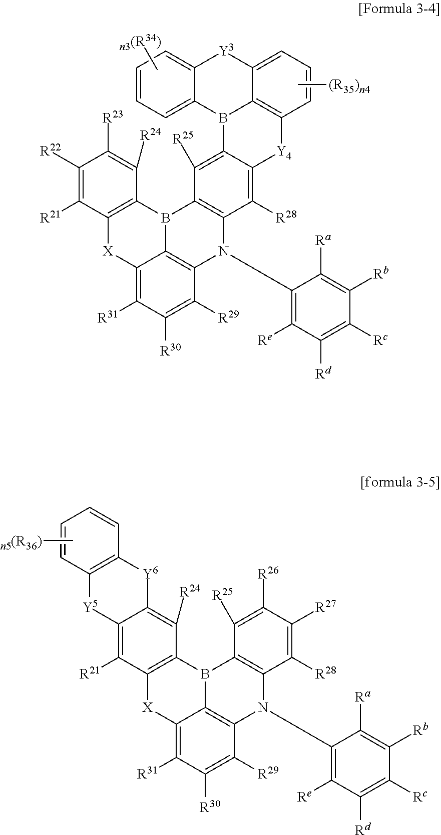

In Formula 3-1 to Formula 3-5, R²¹ to R³⁶ may each independently be a hydrogen atom, a deuterium atom, a substituted or unsubstituted amine group, a substituted or unsubstituted oxy group, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30; and X, R^{a}, R^{b}, R^{c}, R^{d}, and R^{e} may each be the same as defined in Formula 1. In Formula 3-2 to Formula 3-5, n1, n3, and n5 may each independently be an integer from 0 to 4; n2 and n4 may each independently be an integer from 0 to 3; Y¹ to Y⁴ may each independently be O, S, or N(R³⁷); Y⁵ and Y⁶ may each independently be O, S, N(R³⁸), or B(R³⁹); and R³⁷ to R³⁹ may each independently be a substituted or unsubstituted aryl group having a ring-forming carbon number of 6 to 30.

In an embodiment, at least one hydrogen atom in the first compound represented by Formula 1 may be substituted with a deuterium atom.

In an embodiment, the emission layer may emit delayed fluorescence.

In an embodiment, the emission layer may emit blue light.

In an embodiment, the first compound may be selected from Compound Group 1, which is explained below.

According to an embodiment, a polycyclic compound may be represented by Formula 1, which is explained herein.

In an embodiment, among two selected from R^{a} to R^{e}, one thereof may be a cyano group, and the other thereof may be a substituted or unsubstituted phenyl group; and the remainder of R^{a} to R^{e} that are not the cyano group or the substituted or unsubstituted phenyl group may each independently be a hydrogen atom, a deuterium atom, or a substituted or unsubstituted aryl group having a ring-forming carbon number of 6 to 30.

In an embodiment, X may be N(R¹²); and R¹² may be a substituted or unsubstituted aryl group having a ring-forming carbon number of 6 to 30.

In an embodiment, the polycyclic compound represented by Formula 1 may be represented by one of Formula 2-1 to Formula 2-3, which are explained herein.

In an embodiment, the polycyclic compound represented by Formula 2-3 may be represented by Formula 2-3-1, which is explained below.

In an embodiment, the polycyclic compound represented by Formula 1 may be represented by one of Formula 3-1 to Formula 3-5, which are explained herein.

In an embodiment, the polycyclic compound represented by Formula 1 may be a compound selected from Compound Group 1, which is explained below.

According to an embodiment, an electronic device includes a display device, and the display device may include a circuit layer disposed on a base layer, and a display element layer disposed on the circuit layer and including a light-emitting element, wherein the light-emitting element may include a first electrode, a second electrode facing the first electrode, and an emission layer disposed between the first electrode and the second electrode and including a polycyclic compound represented by Formula 1, which is explained herein.

In an embodiment, the light-emitting element may emit blue light.

In an embodiment, the display device may further include a light control layer including a quantum dot.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a block diagram of an electronic device according to an embodiment.

FIG. 2 illustrates schematic diagrams of electronic devices according to embodiments.

FIG. 3 is a schematic plan view of a display device according to an embodiment;

FIG. 4 is a schematic cross-sectional view of a section taken along a line I-I′ in FIG. 1;

FIG. 5 is a schematic cross-sectional view of a light-emitting element according to an embodiment;

FIG. 6 is a schematic cross-sectional view of a light-emitting element according to an embodiment;

FIG. 7 is a schematic cross-sectional view of a light-emitting element according to an embodiment;

FIG. 8 is a schematic cross-sectional view of a light-emitting element according to an embodiment;

FIG. 9 is a schematic cross-sectional view of a light-emitting element according to an embodiment;

FIG. 10 is a schematic cross-sectional view of a display device according to an embodiment;

FIG. 11 is a schematic cross-sectional view of a display device according to an embodiment;

FIG. 12 is a schematic cross-sectional view of a display device according to an embodiment;

FIG. 13 is a schematic cross-sectional view of a display device according to an embodiment; and

FIG. 14 is a schematic diagram of an inside of a vehicle in which a display device according to an embodiment is disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring, or a substituted or unsubstituted heterocycle. The hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. Although the number of carbon atoms is not particularly limited, it may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15.

Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

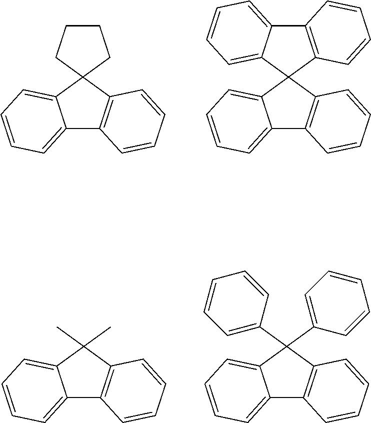

In the specification, a heterocyclic group may be any functional group or substituent derived from a ring that includes at least one of B, O, N, P, Si, S, and Se as a heteroatom. A heterocyclic group may be aliphatic heterocyclic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group.

Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

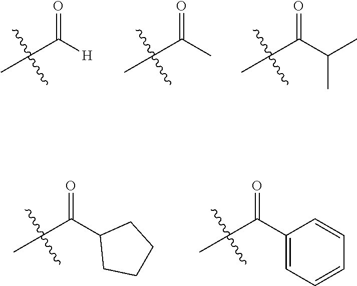

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. The alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a t-butylmethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group described above.

In the specification, a direct linkage may be a single bond.

In the specification, the symbols “ [symbol] ” and “ [symbol] ” each represent a bond to a neighboring atom in a corresponding formula or moiety.

Hereinafter, embodiments will be described with reference to the accompanying drawings.

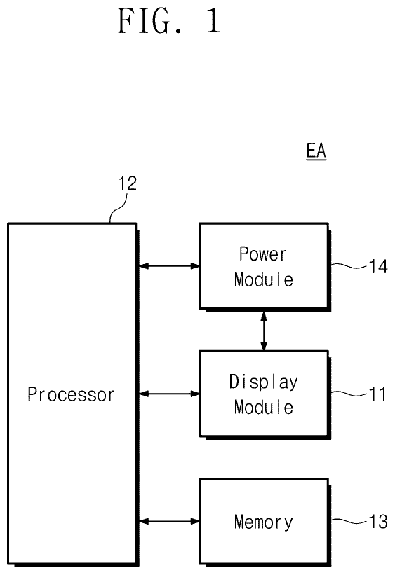

FIG. 1 is a block diagram of an electronic device according to an embodiment. Referring to FIG. 1, an electronic device EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data required for the operation of the processor 12 or the display module 11. When the processor 12 executes an application stored in the memory 13, an image data signal and/or an input control signal may be transmitted to the display module 11, and the display module 11 may process the provided signal and output image information through a display screen.

The power module 14 may include a power supply module such as a power adapter or a battery device, and a power conversion module that converts power supplied by the power supply module and generates power required for an operation of the electronic device EA.

At least one of the components of the electronic device EA described above may be included in a display device according to an embodiment. Some individual modules of the electronic device EA may be included in the display device, and other modules may be provided separately from the display device. For example, the display device may include the display module 11, while the processor 12, the memory 13, and the power module 14 may not be provided in the display device but may be provided in another portion of the electronic device EA.

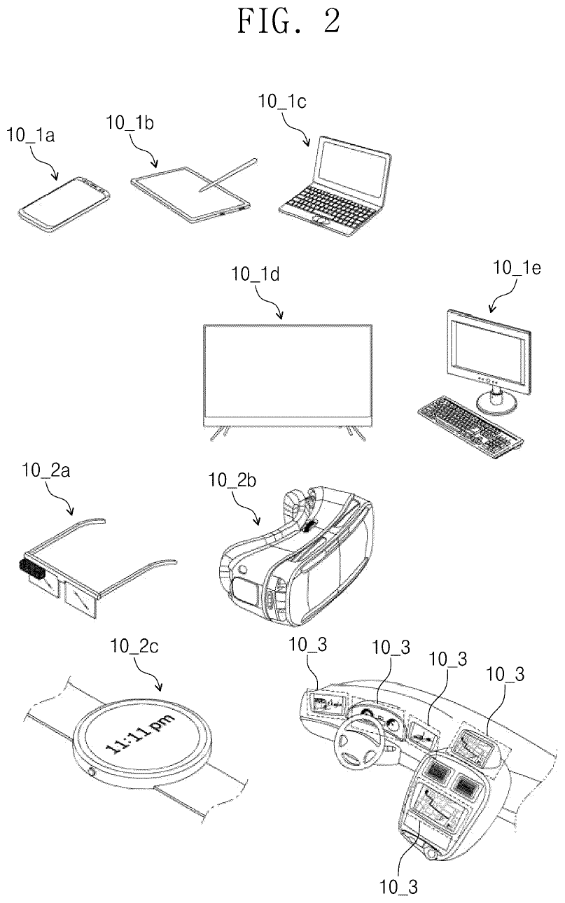

FIG. 2 illustrates schematic diagrams of electronic devices EA (see FIG. 1) according to embodiments.

Referring to FIG. 2, the display device according to an embodiment may be applied to various electronic devices, which may include electronic devices that display images, for example, a smartphone 10_1a, a tablet computer (PC) 10_1b, a laptop computer 10_1c, television (TV) set 10_1d, and a monitor for a desk computer 10_1e. The display device according to an embodiment may be applied to wearable electronic devices that include a display module, for example, smart glasses 10_2a, a head mounted display 10_2b, and a smart watch 10_2c. The display device according to an embodiment may be applied to electronic devices for a vehicle 10_3 that include a display module, for example, a vehicle instrument panel, a center fascia, a center information display (CID) disposed on a dashboard, and a mirror display.

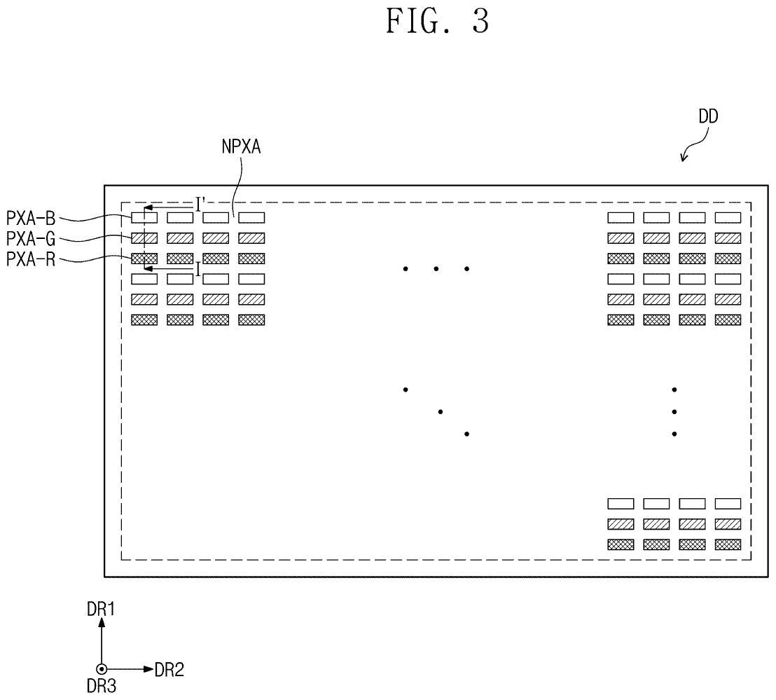

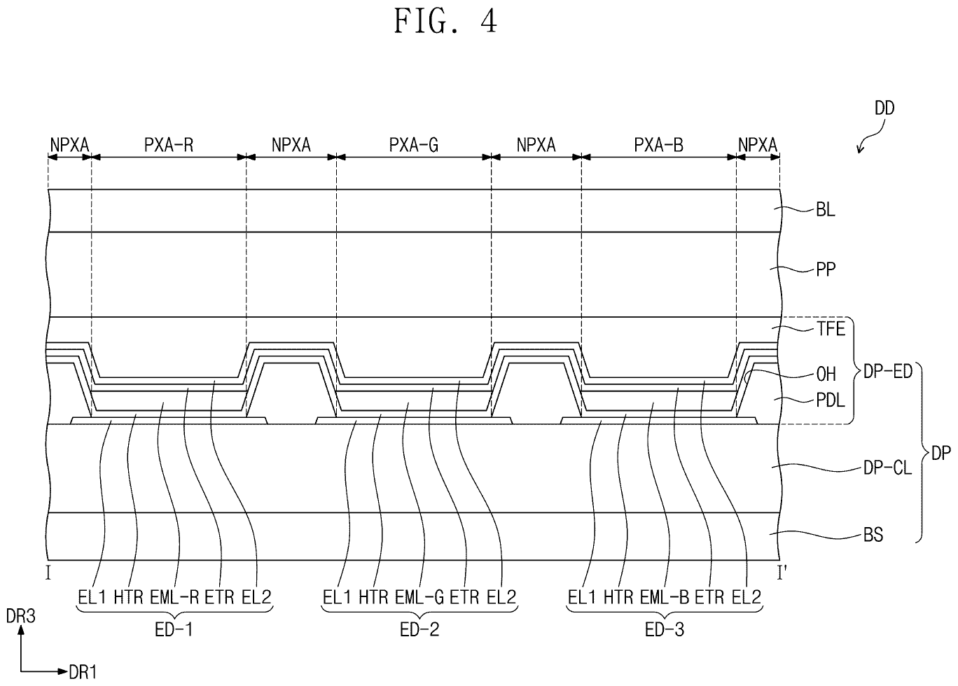

FIG. 3 is a schematic plan view of a display device DD according to an embodiment. FIG. 4 is a schematic cross-sectional view of a display device DD according to the embodiment. FIG. 4 is a schematic cross-sectional view of a portion of the display device DD taken along a virtual line I-I′ in FIG. 3. The display device DD according to an embodiment may be included in an electronic device EA as described above. The display device DD may be a part that provides an image in the electronic device EA.

The display device DD may include a display panel DP and an optical layer PP disposed on the display panel DP. The display panel DP includes light emitting elements ED-1, ED-2, and ED-3. The display device DD may include multiple of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawing, the optical layer PP may be omitted from the display device DD.

A base substrate BL may be disposed on the optical layer PP. The base substrate BL may provide a base surface on which the optical layer PP disposed. The base substrate BL may be a glass substrate, a metal substrate, a plastic substrate, etc. However, the embodiments are not limited thereto, and the base substrate BL may be an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer.

The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

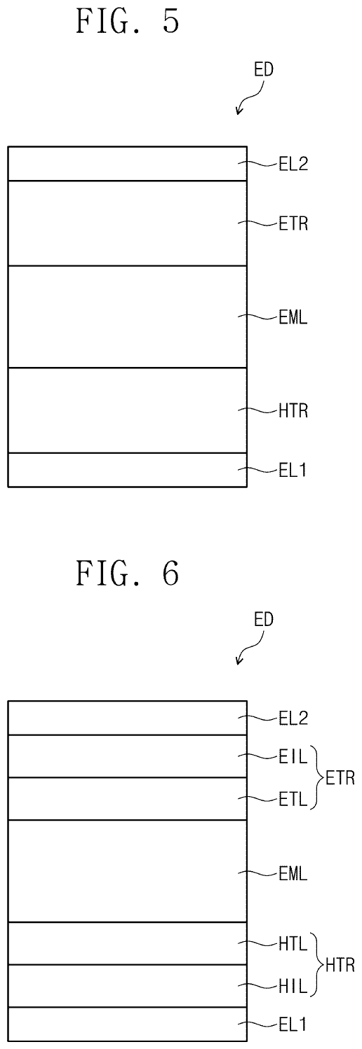

The light emitting elements ED-1, ED-2, and ED-3 may each have a structure of a light emitting element ED of an embodiment according to any one of FIGS. 5 to 9, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 4 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the entire light emitting elements ED-1, ED-2, and ED-3. However, embodiments are not limited thereto.

Although not shown in FIG. 4, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may be provided by being patterned through an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-based compound, an epoxy-based compound, or the like. The encapsulation-organic film may include a photopolymerizable organic material, but embodiments are not particularly limited thereto.

The encapsulation layer TFE may be disposed on the second electrode EL2 and may be disposed to fill the opening OH.

Referring to FIGS. 3 and 4, the display device DD may include a non-light emitting region NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 3 and 4, three light emitting regions PXA-R, PXA-G, and PXA-B, which respectively emit red light, green light, and blue light, are illustrated as an example. For example, the display device DD according to an embodiment may include the red light emitting region PXA-R, the green light emitting region PXA-G, and the blue light emitting region PXA-B which are distinct from each other.

In the display device DD according to an embodiment, the light emitting elements ED-1, ED-2 and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit a light beam in a wavelength range that is different from the remainder. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 3, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this order along a first directional axis DR1.

FIGS. 3 and 4 illustrate that the light emitting regions PXA-R, PXA-G, and PXA-B all have a similar area, but embodiments are not limited thereto. In an embodiment, the light emitting regions PXA-R, PXA-G, and PXA-B may be different in shape or size from each other according to a wavelength range of emitted light. The areas of the light emitting regions PXA-R, PXA-G, and PXA-B may be areas in a plan view that are defined by the first directional axis DR1 and the second directional axis DR2. The third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 3, and the order in which the red light emitting region PXA-R, the green light emitting region PXA-G, and the blue light emitting region PXA-B are arranged may be provided in various combinations according to the display quality characteristics that are required in the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 5 to FIG. 9 are each a schematic cross-sectional view of a light emitting element ED according to an embodiment. A light-emitting element ED according to an embodiment may include a first electrode EL1, a second electrode EL2 facing the first electrode EL1, and an emission layer EML disposed between the first electrode EL1 and the second electrode EL2. The light-emitting element ED according to an embodiment may include a polycyclic compound according to an embodiment, which will be described later, in at least one functional layer.

The light emitting element ED may include a hole transport region HTR or an electron transport region ETR between the first electrode EL1 and the emission layer EML and between the emission layer EML and the second electrode EL2. For example, the light emitting element ED may include a first electrode EL1, a hole transport region HTR, an emission layer EML, an electron transport region ETR, and a second electrode EL2 that are stacked in that order.

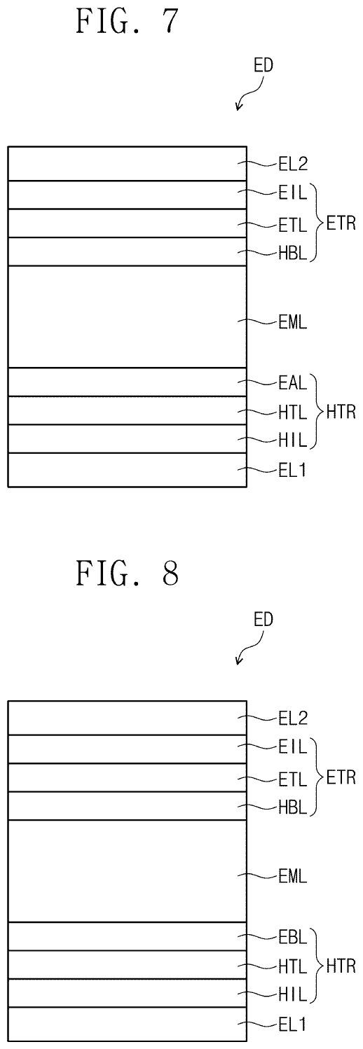

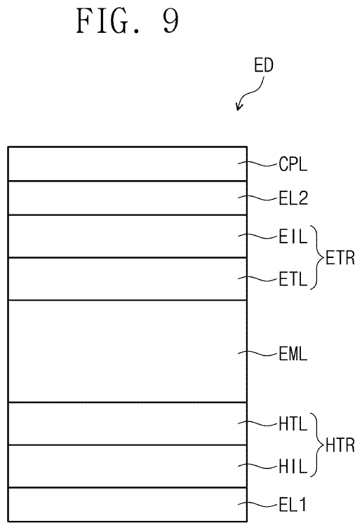

In comparison to FIG. 5, FIG. 6 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 5, FIG. 7 is a schematic cross-sectional view of a light emitting element ED according to an embodiment, in which a hole transport region HTR includes a hole injection layer HIL, a hole transport layer HTL, and an auxiliary emission layer EAL, and an electron transport region ETR includes an electron injection layer EIL, an electron transport layer ETL, and a hole blocking layer HBL. FIG. 8 is, in comparison to FIG. 5, a schematic cross-sectional view of a light emitting element ED according to an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. In comparison to FIG. 6, FIG. 9 is a schematic cross-sectional view of a light emitting element ED according an embodiment including a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, Inₓ Sn, and Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof or a mixture thereof (e.g., a mixture of Ag and Mg). In another embodiment, the first electrode EL1 may have a multilayered structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an auxiliary emission layer EAL, and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure formed of a hole injection material and a hole transport material. In an embodiment, the hole transport region HTR may have a single-layered structure including different materials, or may have a structure in which a hole injection layer HIL/hole transport layer HTL, a hole injection layer HIL/hole transport layer HTL/auxiliary emission layer EAL, a hole injection layer HIL/auxiliary emission layer EAL, a hole transport layer HTL/auxiliary emission layer EAL, a hole injection layer HIL/hole transport layer HTL/auxiliary emission layer EAL, or a hole injection layer HIL/hole transport layer HTL/electron blocking layer EBL are stacked in its respectively stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

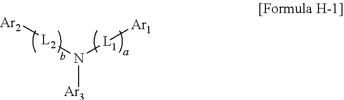

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ and multiple L₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, the compound represented by Formula H-1 may be a monoamine compound. In another embodiment, the compound represented by Formula H-2 may be a diamine compound in which at least one of Ar₁ to Ar₃ includes an amine group as a substituent.

In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ or Ar₂ including a substituted or unsubstituted fluorene group.

The compound represented by Formula H-1 may be a compound selected from Compound Group H. However, the compounds listed in Compound Group H are only examples, and a compound represented by Formula H-1 is not limited to Compound Group H:

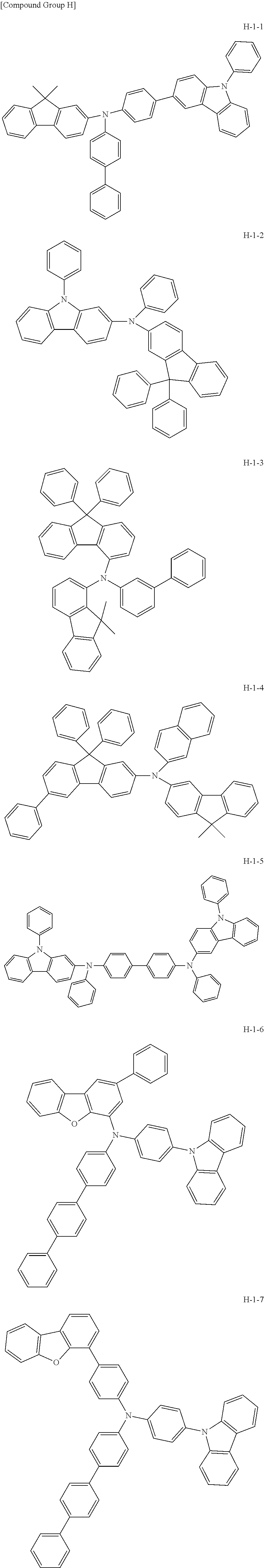

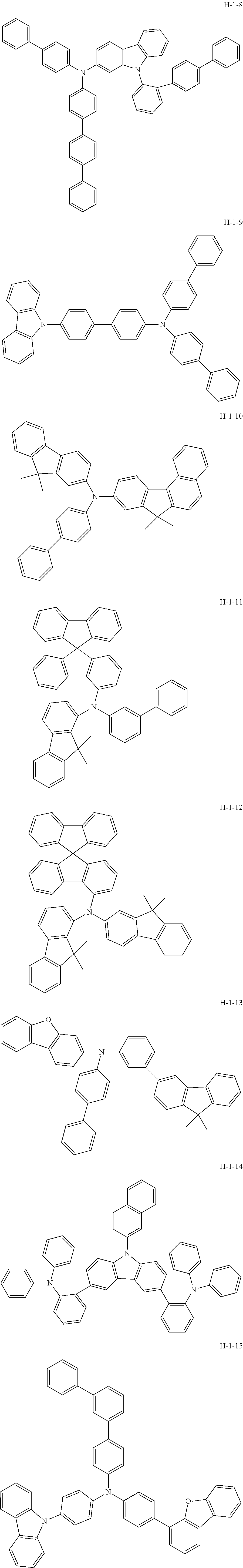

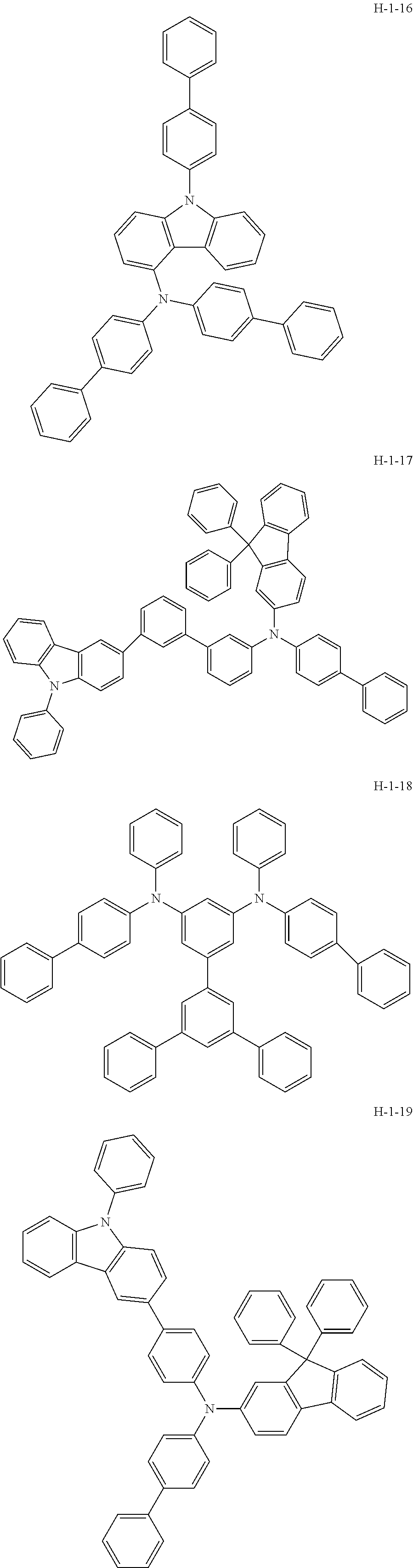 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an auxiliary emission layer EAL and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes the hole injection layer HIL, a hole injection layer HIL may have, for example, a thickness in a range of about 30 Å to about 1,000 Å. When the hole transport region HTR includes the hole transport layer HTL, the hole transport layer HTL may have a thickness in a range of about 250 Å to about 1,000 Å. For example, when the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP₉), etc., but embodiments are not limited thereto.

As described above, the hole transport region HTR may further include at least one of a buffer layer (not shown) or an electron blocking layer EBL in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be included in the buffer layer (not shown). The electron blocking layer EBL may prevent the injection of electrons from an electron transport region ETR to the hole transport region HTR.

As described above, the hole transport region HTR may further include at least one of an auxiliary emission layer EAL and an electron blocking layer EBL, in addition to the hole injection layer HIL and the hole transport layer HTL. The auxiliary emission layer EAL may compensate for a resonance distance according to a wavelength of light emitted from the emission layer EML and may increase a light emission efficiency by controlling the hole charge balance. In an embodiment, the auxiliary emission layer EAL may prevent electron injection into the hole transport region HTR. A material that may be included in the hole transport region HTR may be used as a material to be included in the auxiliary emission layer EAL. The electron blocking layer EBL may prevent the injection of electrons from an electron transport region ETR to the hole transport region HTR.

In the light-emitting element ED according to an embodiment, an emission layer EML may contain a polycyclic compound. The emission layer EML may include the polycyclic compound according to an embodiment as a dopant. The polycyclic compound according to an embodiment may be a dopant material of the emission layer EML. In the specification, the polycyclic compound may be referred to as a first compound.

The polycyclic compound according to an embodiment may include, as a core structure, a fused ring with five rings including one hetero atom, one nitrogen atom (N), and one boron atom (B) as a ring-forming atom. In embodiments, the polycyclic compound may include, as a core structure, a fused ring with seven rings or a fused ring with nine rings, in which two rings including two hetero atoms as ring-forming atoms or four rings including four hetero atoms as ring-forming atoms are respectively fused to the core structure of the fused ring of five rings

In the polycyclic compound according to an embodiment a first benzene ring may be connected to a nitrogen atom of the core structure, and at least one first substituent or at least one second substituent may be bonded to the first benzene ring. The first substituent may be a cyano group, and the second substituent may be a substituted or unsubstituted aryl group. The polycyclic compound according to an embodiment may exhibit a molecular type, in which the first benzene ring is connected to a nitrogen atom constituting the core structure and at least one cyano group and at least one aryl group are connected to the first benzene ring, thereby protecting the core structure. In an embodiment, in the polycyclic compound, solvation and association with a solvent or a host material may be suppressed due to the first substituent and the second substituent, and thus high efficiency and excellent element lifespan may be achieved during driving an element.

In an embodiment, the light-emitting element ED may include the polycyclic compound. The polycyclic compound may be represented by Formula 1.

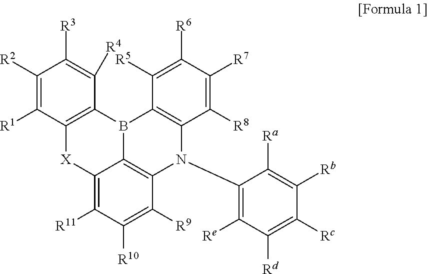

In Formula 1, X may be O, S, or N(R¹²); and R¹ to R¹² may each independently be a hydrogen atom, a deuterium atom, a halogen atom, a cyano group, a substituted or unsubstituted amine group, a substituted or unsubstituted oxy group, a substituted or unsubstituted sulfinyl group, a substituted or unsubstituted boron group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or R¹ to R⁴ may be bonded to an adjacent group to form a ring only between R¹ to R⁴, or R⁵ to R⁸ may be bonded to an adjacent group to form a ring R⁵ to R⁸. In an embodiment, R¹ to R¹¹ may each independently be a hydrogen atom, a deuterium atom, a halogen atom, a cyano group, a substituted or unsubstituted aryl amine group, a substituted or unsubstituted aryl oxy group, a substituted or unsubstituted aryl sulfinyl group, a substituted or unsubstituted aryl boron group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30; and R¹² may be a substituted or unsubstituted aryl group having a ring-forming carbon number of 6 to 30. For example, R¹ to R¹¹ may each independently be a hydrogen atom, a deuterium atom, or a group selected from Substituent Group 1, and R¹² may be a substituted or unsubstituted phenyl group, a substituted or unsubstituted biphenyl group, or a substituted or unsubstituted terphenyl group, but embodiments are not limited thereto.

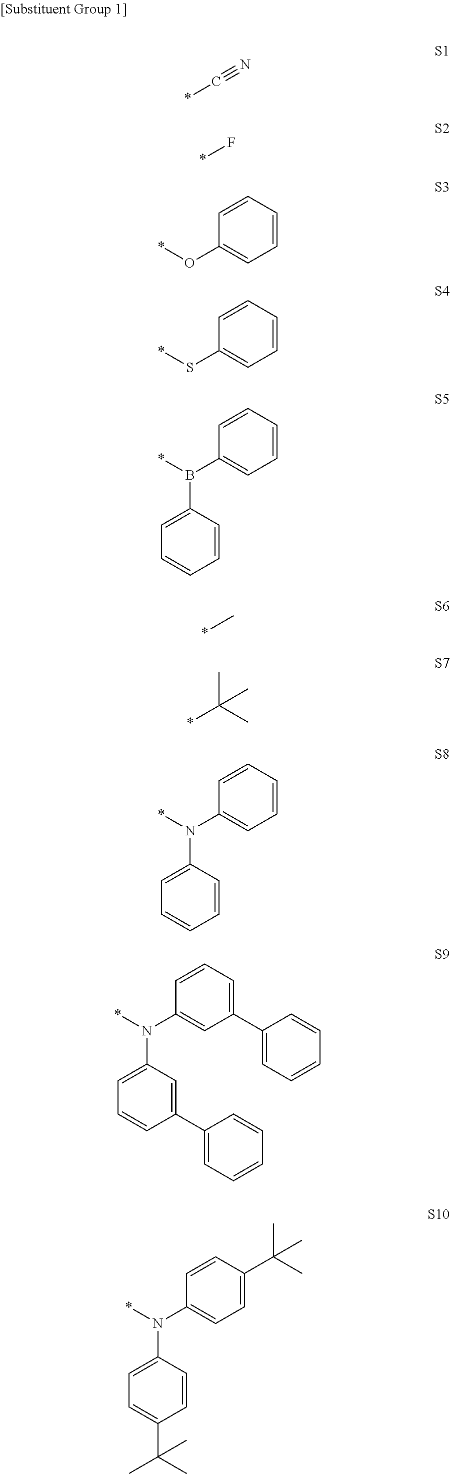

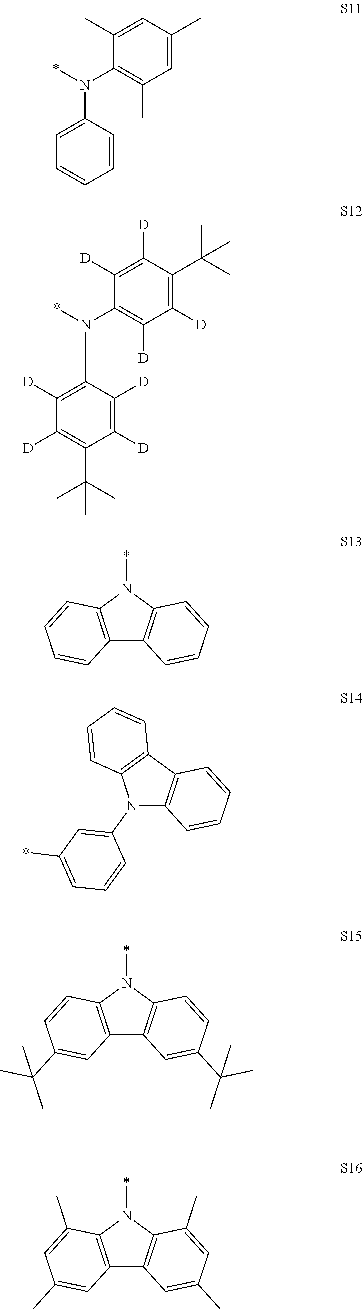

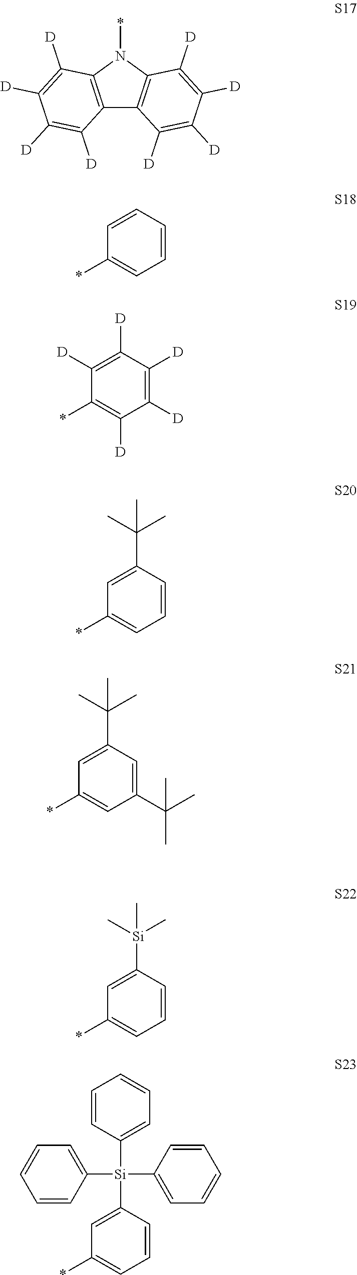

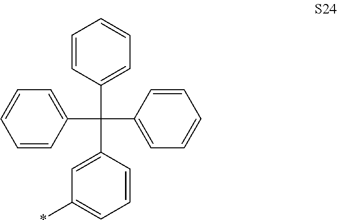 [SMILES: *c1cccc(C(c2ccccc2)(c2ccccc2)c2ccccc2)c1]

As described above, in Formula 1, R¹ to R⁴ may be bonded to an adjacent group to form a ring only between R¹ to R⁴, or R⁵ to R⁸ may be bonded to an adjacent group to form a ring only between R⁵ to R⁸. For example, a consecutive pair among R¹ to R⁴ may be combined with each other to form a ring, and a consecutive pair among R⁵ to R⁸ may be combined with each other to form a ring. For example, R¹ and R², R² and R³, or R³ and R⁴ may each be combined with each other to form a ring, or R⁵ and R⁶, R⁶ and R⁷, or R⁷ and R⁸ may each be combined with each other to form a ring. For example, R² and R³ may be combined with each other to form a substituted or unsubstituted heterocycle, and R⁶ and R⁷ may be combined with each other to form a substituted or unsubstituted heterocycle.

In Formula 1, a benzene ring connected to R^{a} to R^{e} may correspond to the above-described first benzene ring. In Formula 1, R^{a} to R^{e} may each independently be a hydrogen atom, a deuterium atom, a halogen atom, a cyano group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. In an embodiment, among R^{a} to R^{e}, at least one may be the first substituent, and at least one of the remainder of R^{a} to R^{e} except for the first substituent may be the second substituent. For example, in Formula 1, at least one of R^{a} to R^{e} may be a cyano group, and at least one of the remainder of R^{a} to R^{e} may be a substituted or unsubstituted aryl group having a ring-forming carbon number of 6 to 30. For example, one of R^{a} to R^{e} may be a cyano group, and another of R^{a} to R^{e} except for the cyano group may be a substituted or unsubstituted aryl group having a ring-forming carbon number of 6 to 30.

In an embodiment, in Formula 1, among two selected from R^{a} to R^{e}, one thereof may be a cyano group, and the other thereof may be a substituted or unsubstituted phenyl group, and the remainder of R^{a} to R^{e} except for the cyano group and the substituted or unsubstituted phenyl group among R^{a} to R^{e} may each independently be a hydrogen atom, a deuterium atom, or a substituted or unsubstituted aryl group having a ring-forming carbon number of 6 to 30.

For example, in Formula 1, among R^{a} to R^{e}, R^{a} may be a cyano group, one of R^{b}, R^{c}, R^{d}, and R^{e} may be a substituted or unsubstituted phenyl group, and the remainder of R^{b}, R^{c}, R^{d}, and R^{e} except for the substituted or unsubstituted phenyl group may each independently be a hydrogen atom, or a deuterium atom. For example, in Formula 1, among R^{a} to R^{e}, R^{b} may be a cyano group, one of R^{a}, R^{c}, R^{d}, and R^{e} may be a substituted or unsubstituted phenyl group, and the remainder of R^{a}, R^{c}, R^{d}, and R^{e} except for the substituted or unsubstituted phenyl group may each independently be a hydrogen atom, or a deuterium atom. For example, in Formula 1, among R^{a} to R^{e}, R^{c} may be a cyano group, one of R^{a}, R^{b}, R^{d}, and R^{e} may be a substituted or unsubstituted phenyl group, and the remainder of R^{a}, R^{b}, R^{d}, and R^{e} except for the substituted or unsubstituted phenyl group may each independently be a hydrogen atom, or a deuterium atom. For example, in Formula 1, among R^{a} to R^{e}, R^{c} may be a cyano group, two selected from R^{a}, R^{b}, R^{d}, and R^{e} may each independently be a substituted or unsubstituted phenyl group, and the remainder of R^{a}, R^{b}, R^{d}, and R^{e} except for the substituted or unsubstituted phenyl groups may each independently be a hydrogen atom or a deuterium atom.

In an embodiment, in the polycyclic compound represented by Formula 1, at least one hydrogen atom may be substituted with a deuterium atom. For example, in the polycyclic compound represented by Formula 1, a hydrogen atom among R¹ to R¹² and R^{a} to R^{e}, or a hydrogen atom in a substituent thereof may be substituted with a deuterium atom.

In an embodiment, the polycyclic compound represented by Formula 1 may include a cyano group bonded to the first benzene ring at a para position with respect to a nitrogen atom constituting a core structure. Therefore, the polycyclic compound represented by Formula 1 may be represented by one of Formula 2-1 to Formula 2-3. Formula 2-1 to Formula 2-3 each represents a case where in Formula 1, R^{c} is a cyano group.

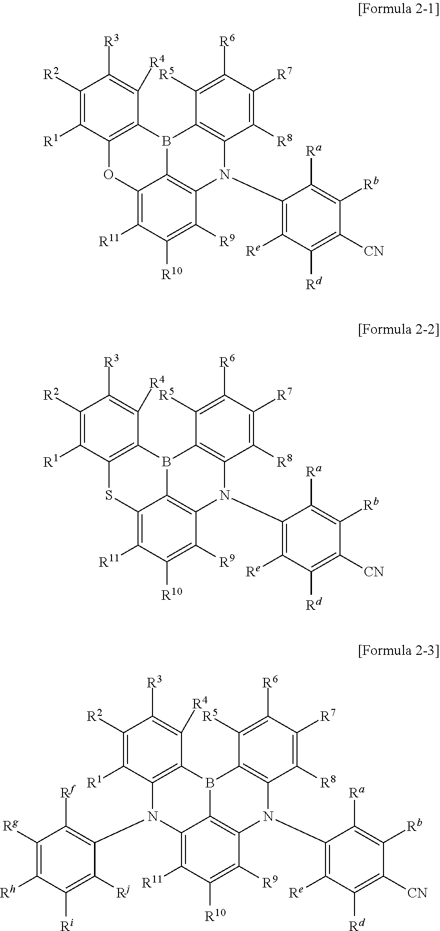

In Formula 2-1 to Formula 2-3, one or two of R^{a}, R^{b}, R^{d}, and R^{e} may each independently be a substituted or unsubstituted phenyl group, and the remainder of R^{a}, R^{b}, R^{d}, and R^{e} may each independently be a hydrogen atom or a deuterium atom. For example, R^{a} or R^{b} may be a substituted or unsubstituted phenyl group, and the remainder of R^{a} and R^{b} that is not the substituted or unsubstituted phenyl group, and R^{d} and R^{e} may each independently be a hydrogen atom or a deuterium atom. In an embodiment, R^{a} and R^{e} may each independently be substituted or unsubstituted phenyl groups, R^{b} and R^{d} may each independently be a hydrogen atom or a deuterium atom.

In Formula 2-1 to Formula 2-3, R¹ to R¹¹ may be the same as described in Formula 1.

In Formula 2-3, R^{f}, R^{g}, R^{h}, Rⁱ, and Rⱼ may each independently be a hydrogen atom, a deuterium atom, a cyano group, an unsubstituted alkyl group having a carbon number of 1 to 20, or a substituted or unsubstituted aryl group having a ring-forming carbon number of 6 to 30. For example, R^{f}, R^{g}, R^{h}, Rⁱ, and Rⱼ may each independently be a hydrogen atom, a deuterium atom, an unsubstituted t-butyl group, or a substituted or unsubstituted phenyl group.

In an embodiment, the polycyclic compound represented by Formula 2-3 may be represented by Formula 2-3-1. The polycyclic compound represented by Formula 2-3-1 may represent a case where R^{a} and R^{f} are each independently a substituted or unsubstituted phenyl group in Formula 2-3.

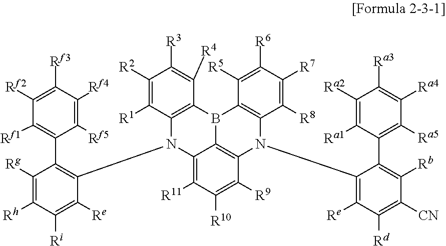

In Formula 2-3-1, R^{a1} to R^{a5} and R^{f1} to R^{f5} may each independently be a hydrogen atom, a deuterium atom, or a substituted or unsubstituted alkyl group having a carbon number of 1 to 10. For example, R^{a1} to R^{a5} and R^{f1} to R^{f5} may each independently be a hydrogen atom, a deuterium atom, or an unsubstituted t-butyl group, but embodiments are not limited thereto.

In Formula 2-3-1, one of R^{b}, R^{d}, and R^{e} may be a substituted or unsubstituted phenyl group, and the remainder of R^{b}, R^{d}, and R^{e} may each independently be a hydrogen atom or a deuterium atom. In Formula 2-3-1, R^{g}, Rⁱ, and Rⱼ may each independently be a hydrogen atom, a deuterium atom, an unsubstituted alkyl group having a carbon number of 1 to 20, or a substituted or unsubstituted aryl group having a ring-forming carbon number of 6 to 30; and R^{h} may be a hydrogen atom, a deuterium atom, or a cyano group.

In Formula 2-3-1, R¹ to R¹¹ may be the same as described in Formula 1.

In an embodiment, the polycyclic compound represented by Formula 1 may be represented by one of Formula 3-1 to Formula 3-5. Formula 3-1 to Formula 3-5 each represent a case where R¹ to R¹¹ are further defined in Formula 1.

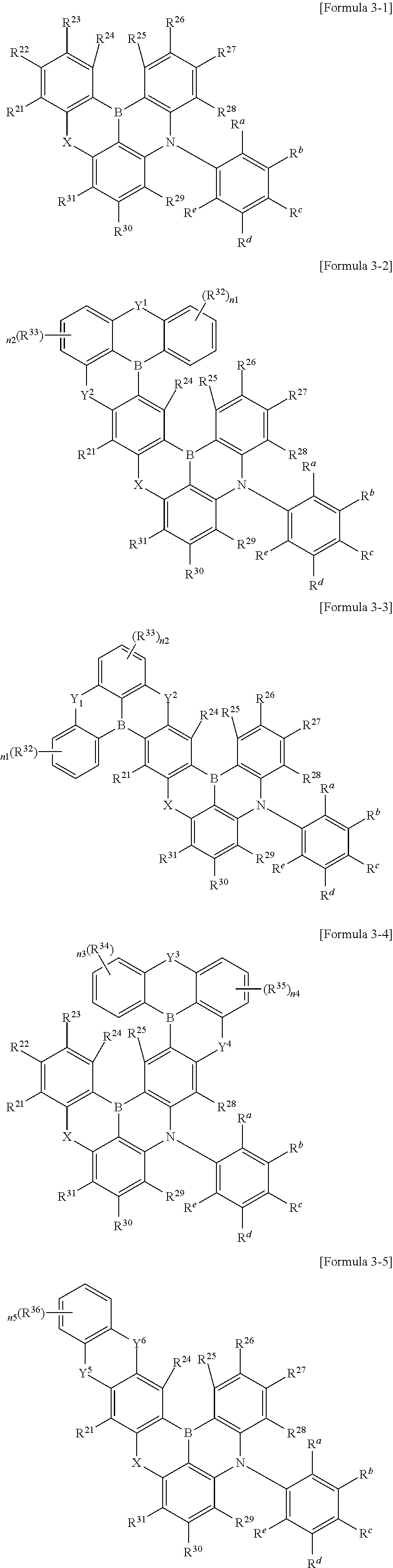

In Formula 3-1 to Formula 3-5,R²¹ to R³⁶ may each independently be a hydrogen atom, a deuterium atom, a substituted or unsubstituted amine group, a substituted or unsubstituted oxy group, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. For example, R²¹ to R³¹ may each independently be a hydrogen atom, a deuterium atom, a halogen atom, a cyano group, a substituted or unsubstituted aryl amine group, a substituted or unsubstituted aryl oxy group, a substituted or unsubstituted aryl sulfinyl group, a substituted or unsubstituted aryl boron group, an unsubstituted alkyl group having a carbon number of 1 to 20, a substituted or unsubstituted heteroaryl group having a ring-forming carbon number of 6 to 30, or a substituted or unsubstituted heteroaryl group having a ring-forming carbon number of 2 to 30. For example, R²¹ to R³¹ may each independently be a hydrogen atom, a deuterium atom, or may be a group selected from Substituent Group 1. For example, R³² to R³⁶ may each independently be a hydrogen atom, a deuterium atom, a substituted or unsubstituted phenyl group, but are not limited thereto.

In Formula 3-1 to Formula 3-5, X, R^{a}, R^{b}, R^{c}, R^{d}, and R^{e} may each be the same as described in Formula 1.

In Formula 3-2 to Formula 3-5, n1, n3, and n5 may each independently be an integer from 0 to 4. If n1, n3, and n5 are each 0, the polycyclic compound according to an embodiment may be unsubstituted with each of R³², R³⁴, and R³⁶. In Formula 3-2 to Formula 3-5, cases where n1, n3, and n5 are each 4 and R³², R³⁴, and R³⁶ are all hydrogen atoms may be the same as the cases where n1, n3, and n5 are each 0 in Formula 3-2 to Formula 3-5. If n1, n3 and n5 are each 2 or more, multiple R³², multiple R³⁴, and multiple R³⁶, may be the same or at least one thereof may be different.

In Formula 3-2 to Formula 3-5, n2 and n4 may each independently be an integer from 0 to 3. If n2 and n4 are each 0, the polycyclic compound according to an embodiment may be unsubstituted with each of R³³ and R³⁵. In Formula 3-2 to Formula 3-5, cases where n2 and n4 are each 3 and R³³ and R³⁵ are all hydrogen atoms in Formula 3-2 to Formula 3-5 may be the same as the cases where n2 and n4 are each 0 in Formula 3-2 to Formula 3-5. If b2 and b4 are each 2 or more, multiple R³³ and multiple R³⁵, may be all the same or at least one thereof may be different.

In Formula 3-2 to Formula 3-5, Y¹ to Y⁴ may each independently be O, S, or N(R³⁷); and Y⁵ and Y⁶ may each independently be O, S, N(R³⁸), or B(R³⁹). For example, in Formula 3-2, Y¹ may be O or N(R³⁷), and Y² may be O, S, or N(R³⁷). In Formula 3-3, Y¹ and Y² may each be O, but embodiments are not limited thereto. In Formula 3-4, Y³ may be N(R³⁷), and Y⁴ may be O, S, or N(R³⁷). In Formula 3-5, Y⁵ may be O or S, and Y⁶ may be N(R³⁸) or B(R³⁹).

In Formula 3-2 to Formula 3-5, R³⁷ to R³⁹ may each independently be a substituted of unsubstituted aryl group having a ring-forming carbon number of 6 to 30. For example, R³⁷ to R³⁹ may each independently be a substituted or unsubstituted phenyl group, a substituted or unsubstituted biphenyl group, or a substituted or unsubstituted terphenyl group.

In the polycyclic compound according to an embodiment, a first benzene ring may be connected to a nitrogen atom constituting a core structure, and at least one cyano group or at least one aryl group may be additionally connected to the first benzene ring, thereby contributing to achieving improvements in high efficiency and long lifetime of the light-emitting element ED.

In the polycyclic compound according to an embodiment, at least one cyano group bonded to the first benzene ring serves as an electron withdrawing group to reduce electron-donating ability of the polycyclic compound according to an embodiment and alleviate a polarization of the core structure, and thus an electrostatic interaction thereof with a molecule having high polarity may be suppressed. In the polycyclic compound according to an embodiment, since the at least one cyano group is located relatively outside of the core structure, conjugation with the core structure may not occur. Therefore, in the polycyclic compound according to an embodiment, significant changes in an emission color and expansion of a full width at half maximum may be suppressed and suitable properties for being used as a blue light-emitting material may be provided due to introduction of the cyano group.

In the polycyclic compound according to an embodiment, at least one aryl group may be connected to the first benzene ring. Since being located relatively outside of the core structure, the aryl group serves as a robust substituent without conjugation with the core structure, and thus association between a surrounding molecule and the core structure may be suppressed. In the polycyclic compound according to an embodiment, since the aryl group connected to the first benzene ring is a robust substituent, structural relaxation due to mobility of the substituent during light emission is not significant, and thus the polycyclic compound may exhibit high color purity. Therefore, the light-emitting element ED including the polycyclic compound in the emission layer EML may emit a deep blue color, and at the same time, element lifespan may be improved in addition to an increase in emission efficiency.

In an embodiment, the polycyclic compound may be selected from Compound Group 1. In an embodiment, the light-emitting element ED may include at least one compound selected from Compound Group 1. In an embodiment, the emission layer EML may include at least one compound selected from Compound Group 1.

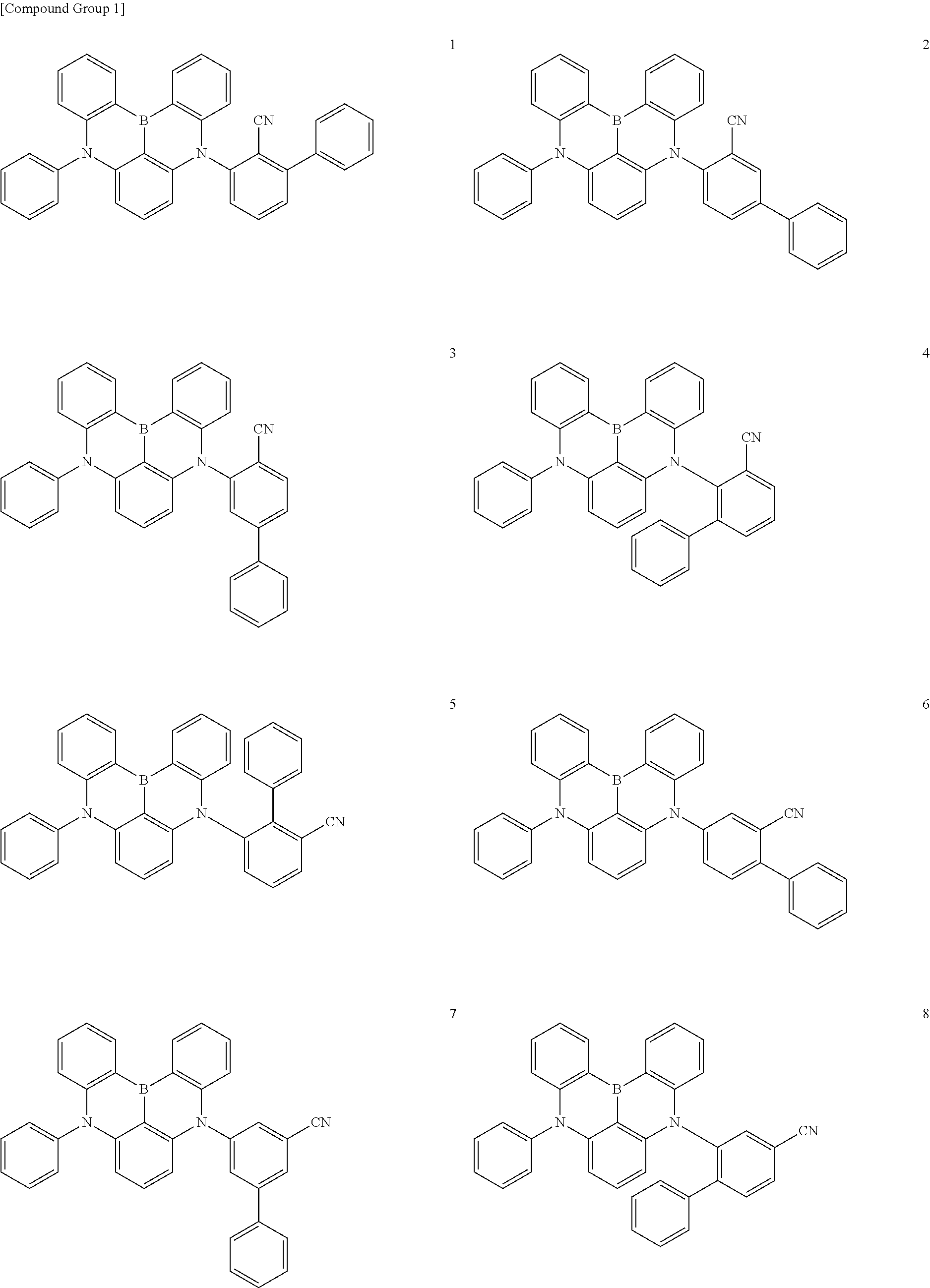

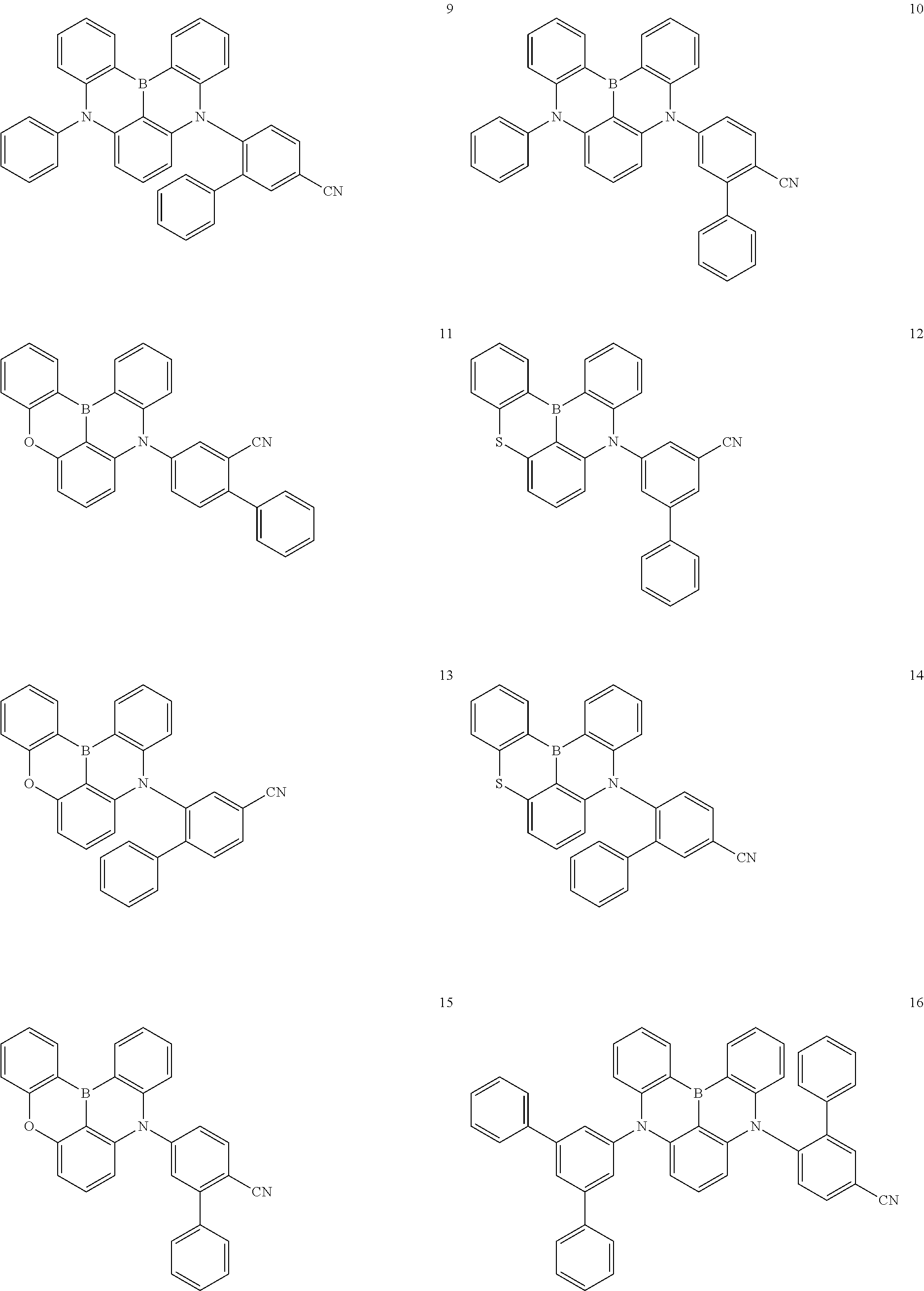

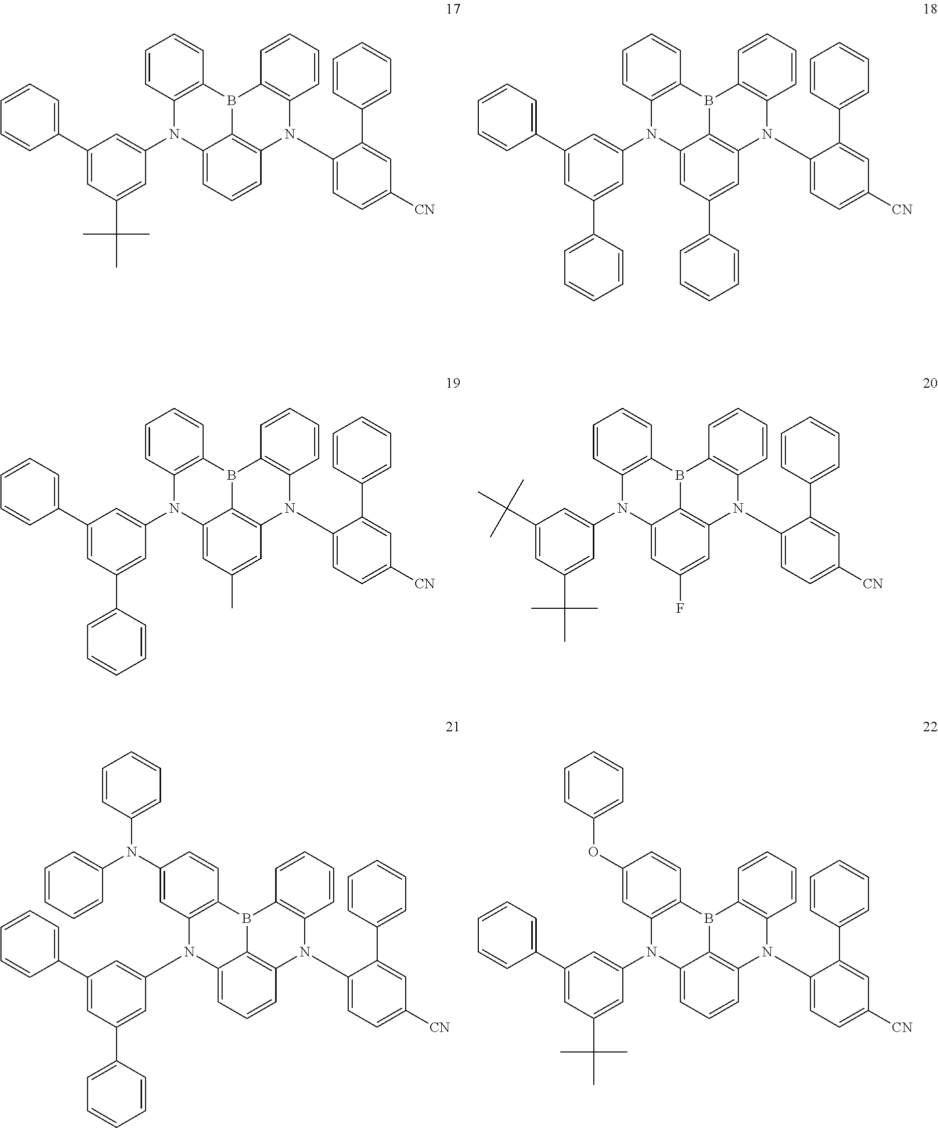

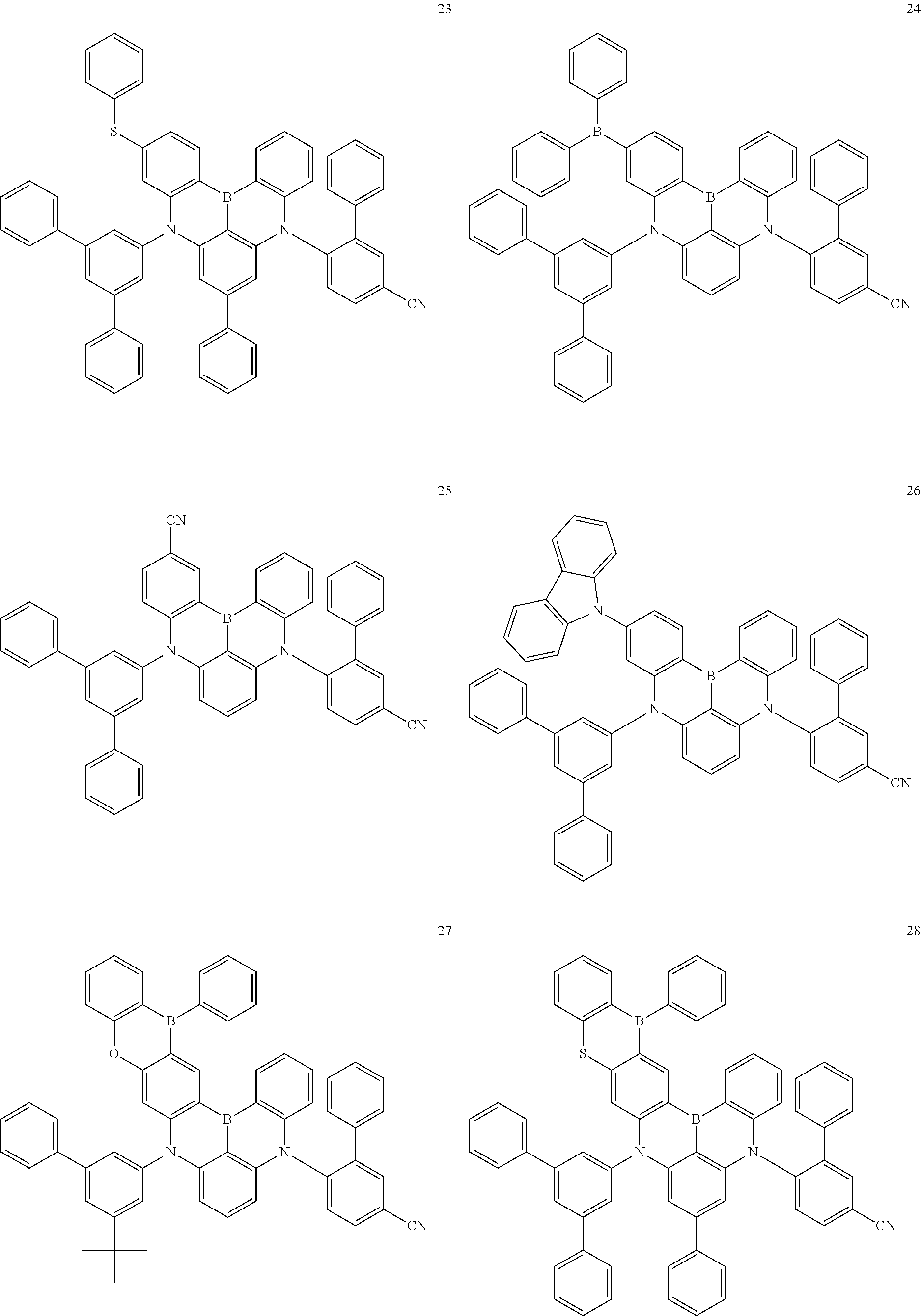

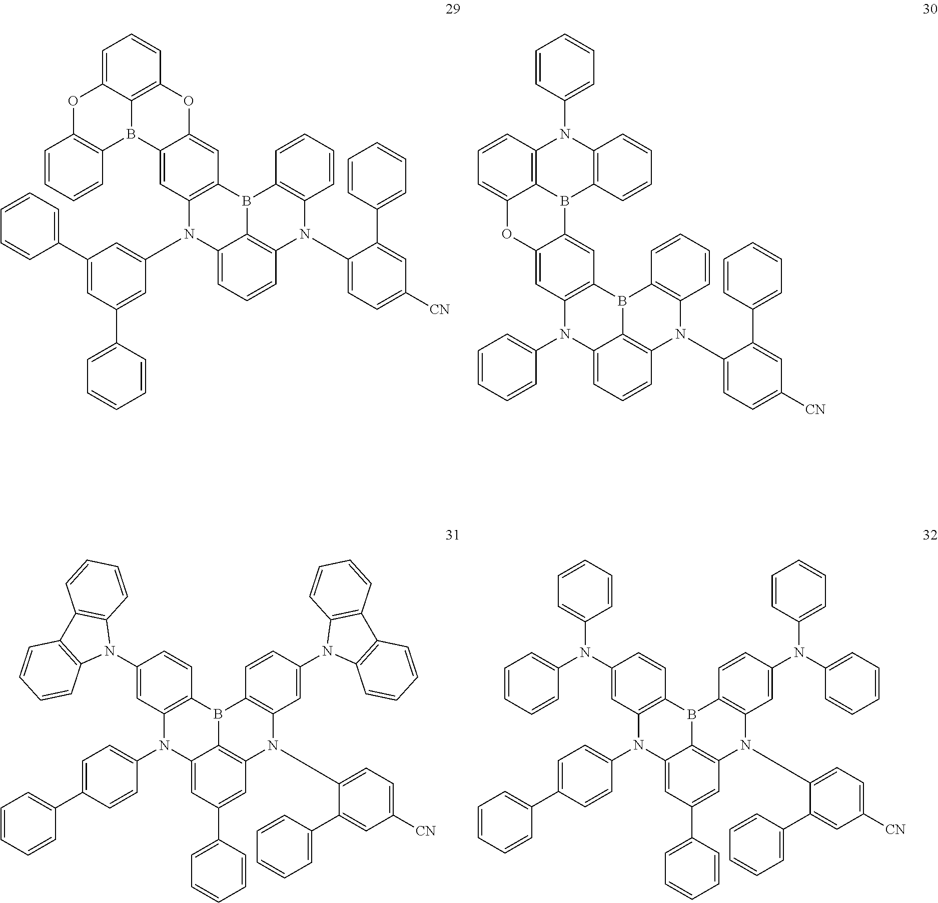 [SMILES: N#Cc1ccc(N2c3ccccc3B3c4cc5c(cc4N(c4cc(-c6ccccc6)cc(-c6ccccc6)c4)c4cccc2c43)B2c3ccccc3Oc3cccc(c32)O5)c(-c2ccccc2)c1 ; N#Cc1ccc(N2c3ccccc3B3c4cc5c(cc4N(c4ccccc4)c4cccc2c43)Oc2cccc3c2B5c2ccccc2N3c2ccccc2)c(-c2ccccc2)c1 ; N#Cc1ccc(N2c3cc(-n4c5ccccc5c5ccccc54)ccc3B3c4ccc(-n5c6ccccc6c6ccccc65)cc4N(c4ccc(-c5ccccc5)cc4)c4cc(-c5ccccc5)cc2c43)c(-c2ccccc2)c1 ; N#Cc1ccc(N2c3cc(N(c4ccccc4)c4ccccc4)ccc3B3c4ccc(N(c5ccccc5)c5ccccc5)cc4N(c4ccc(-c5ccccc5)cc4)c4cc(-c5ccccc5)cc2c43)c(-c2ccccc2)c1]

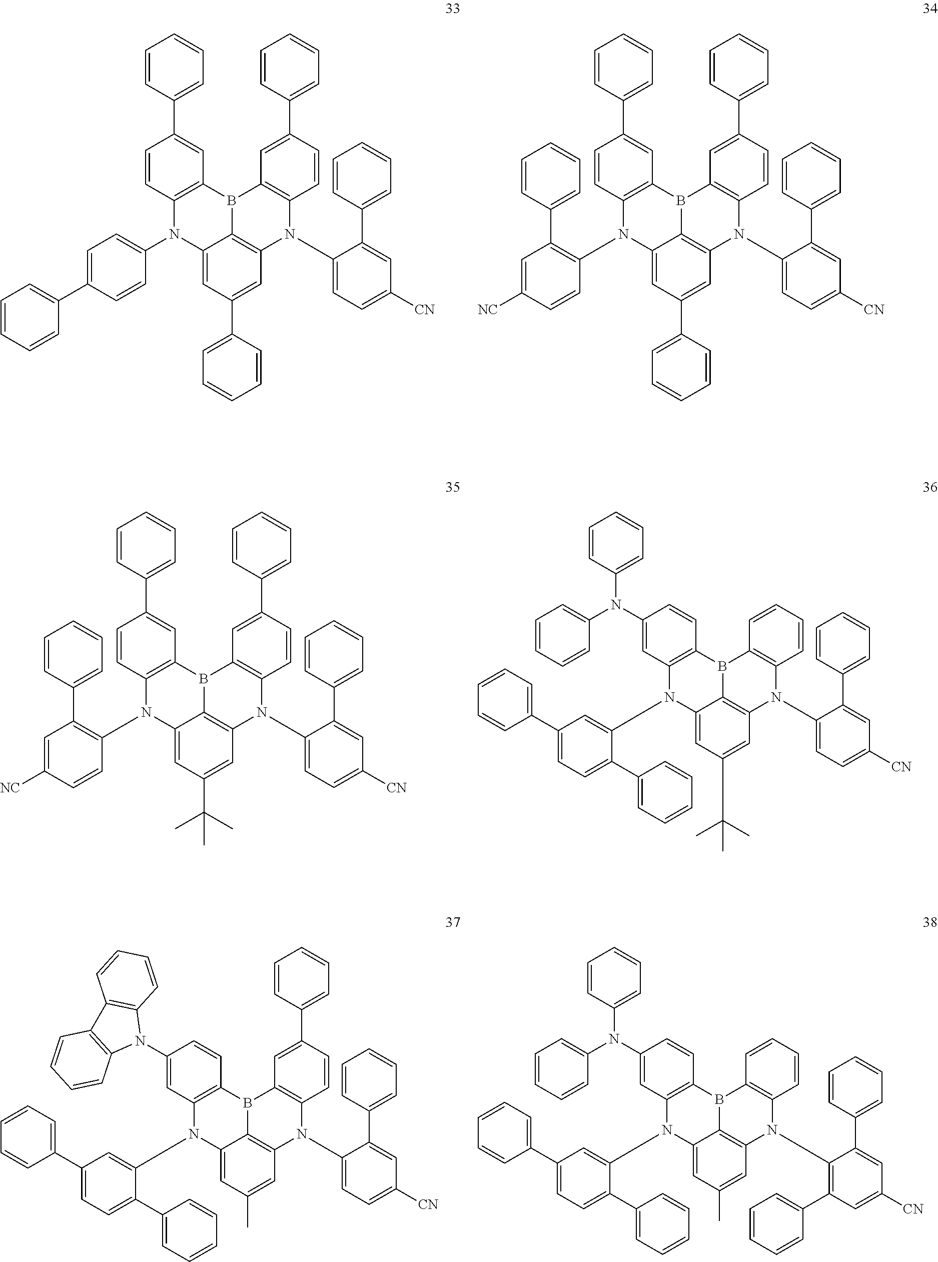

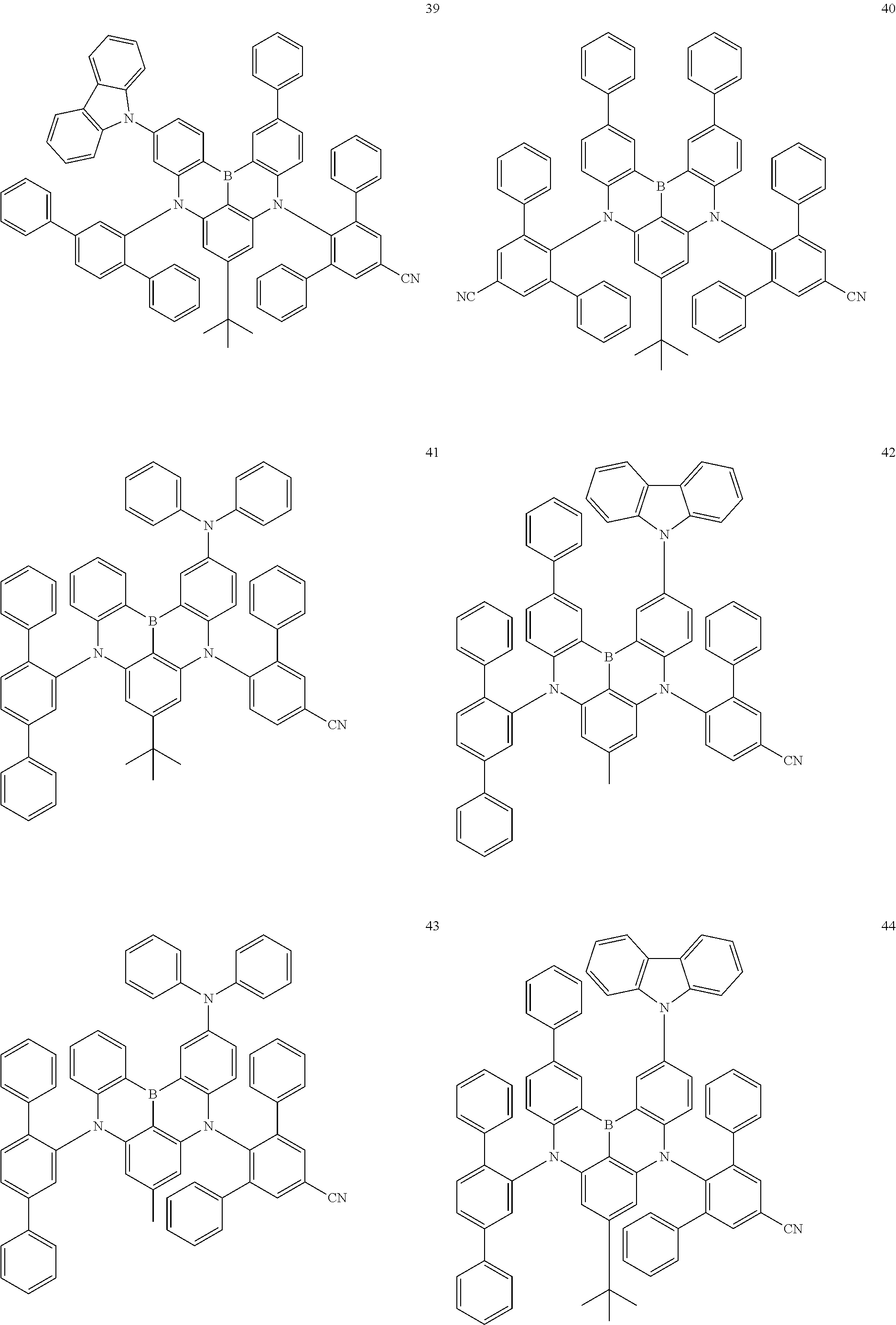

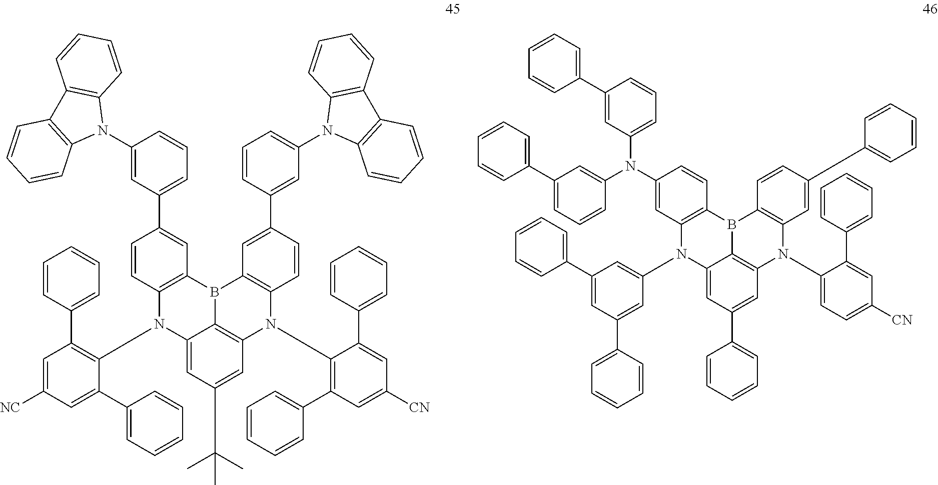 [SMILES: CC(C)(C)c1cc2c3c(c1)N(c1c(-c4ccccc4)cc(C#N)cc1-c1ccccc1)c1ccc(-c4cccc(-n5c6ccccc6c6ccccc65)c4)cc1B3c1cc(-c3cccc(-n4c5ccccc5c5ccccc54)c3)ccc1N2c1c(-c2ccccc2)cc(C#N)cc1-c1ccccc1 ; N#Cc1ccc(N2c3cc(-c4ccccc4)ccc3B3c4ccc(N(c5cccc(-c6ccccc6)c5)c5cccc(-c6ccccc6)c5)cc4N(c4cc(-c5ccccc5)cc(-c5ccccc5)c4)c4cc(-c5ccccc5)cc2c43)c(-c2ccccc2)c1]

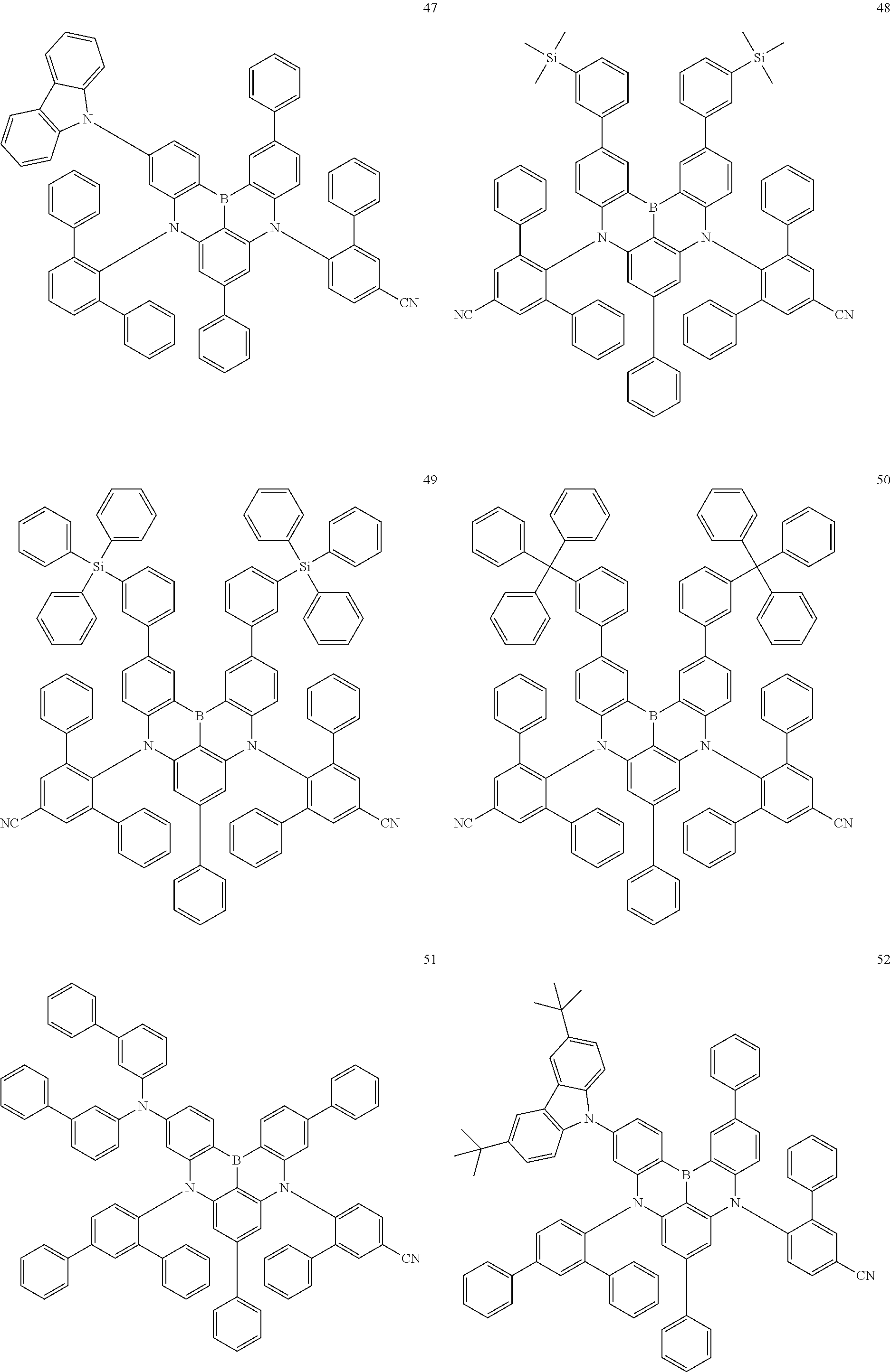

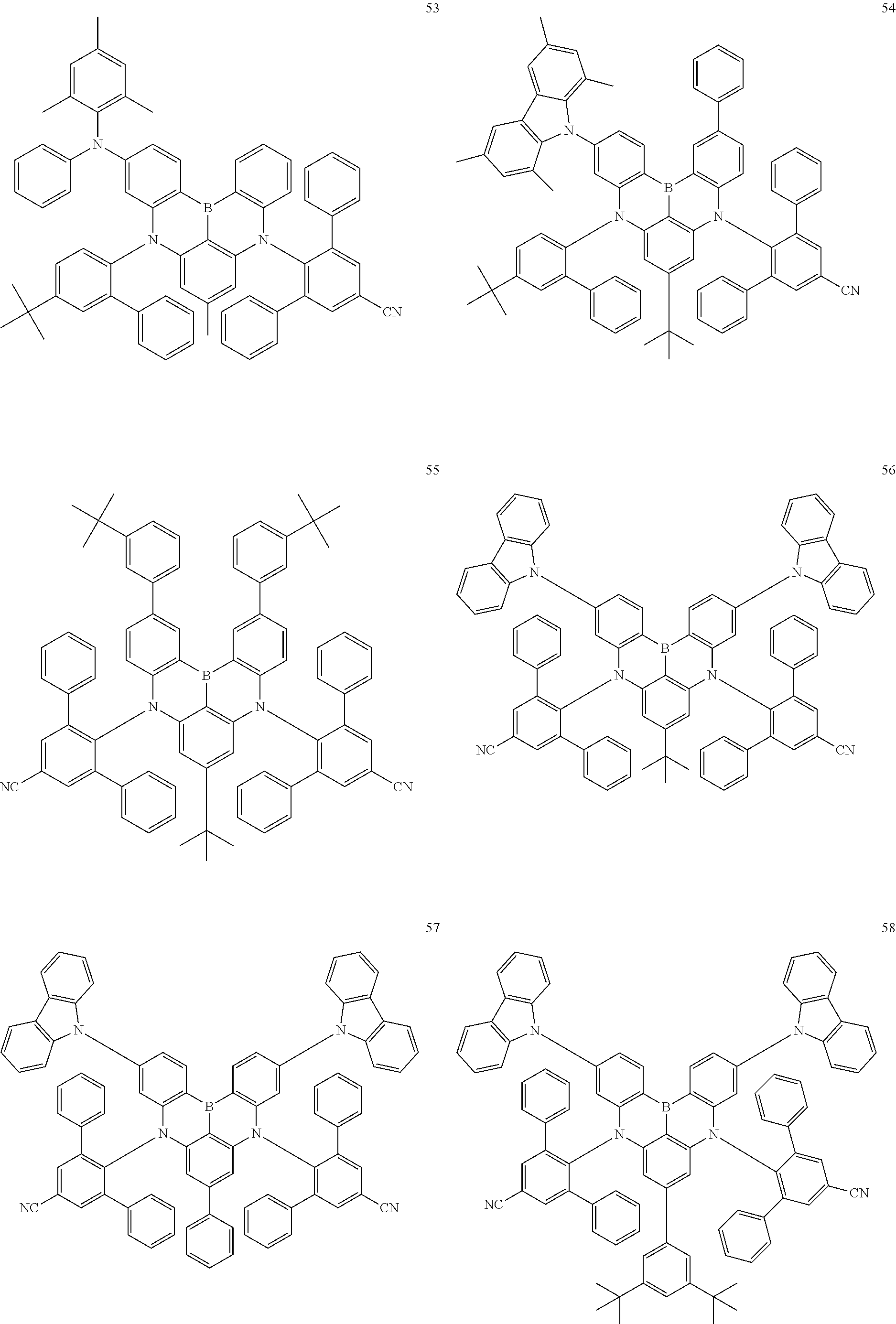

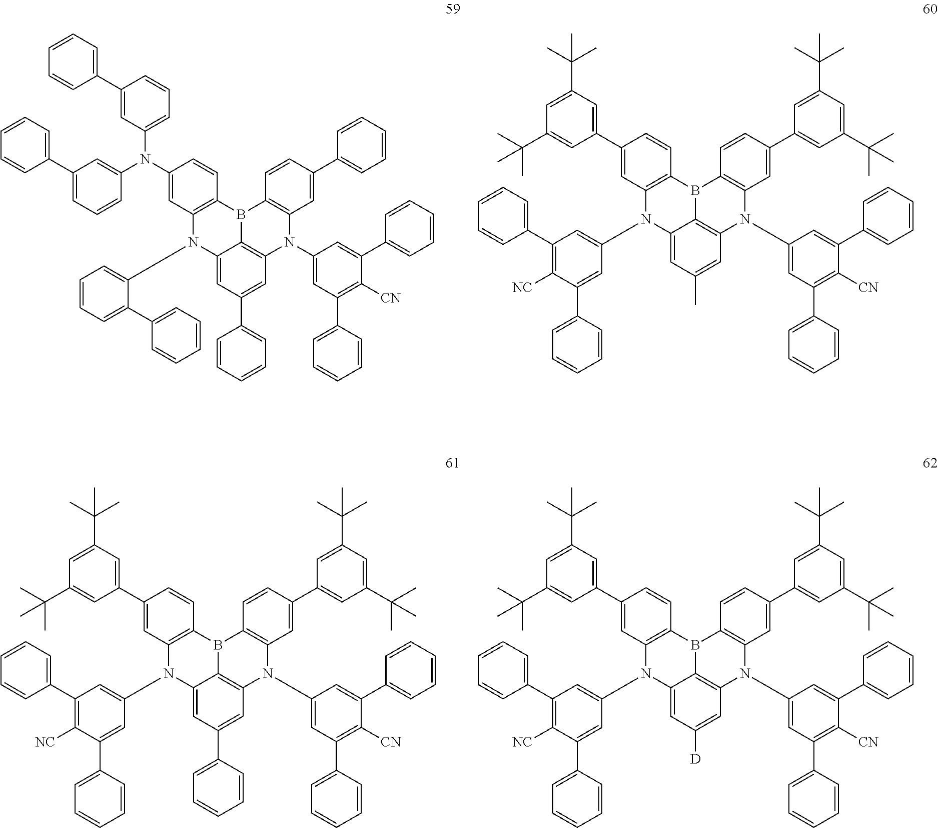

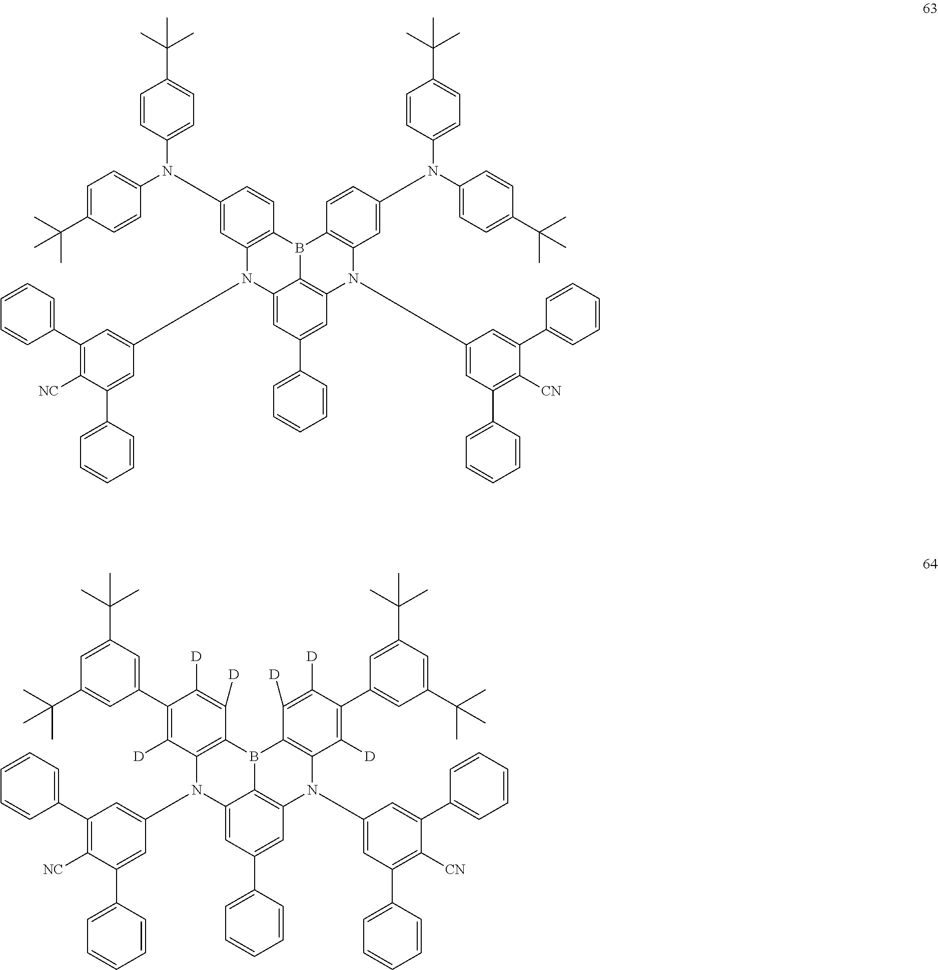 [SMILES: CC(C)(C)c1ccc(N(c2ccc(C(C)(C)C)cc2)c2ccc3c(c2)N(c2cc(-c4ccccc4)c(C#N)c(-c4ccccc4)c2)c2cc(-c4ccccc4)cc4c2B3c2ccc(N(c3ccc(C(C)(C)C)cc3)c3ccc(C(C)(C)C)cc3)cc2N4c2cc(-c3ccccc3)c(C#N)c(-c3ccccc3)c2)cc1 ; [2H]c1c([2H])c(-c2cc(C(C)(C)C)cc(C(C)(C)C)c2)c([2H])c2c1B1c3c(cc(-c4ccccc4)cc3N(c3cc(-c4ccccc4)c(C#N)c(-c4ccccc4)c3)c3c([2H])c(-c4cc(C(C)(C)C)cc(C(C)(C)C)c4)c([2H])c([2H])c31)N2c1cc(-c2ccccc2)c(C#N)c(-c2ccccc2)c1]

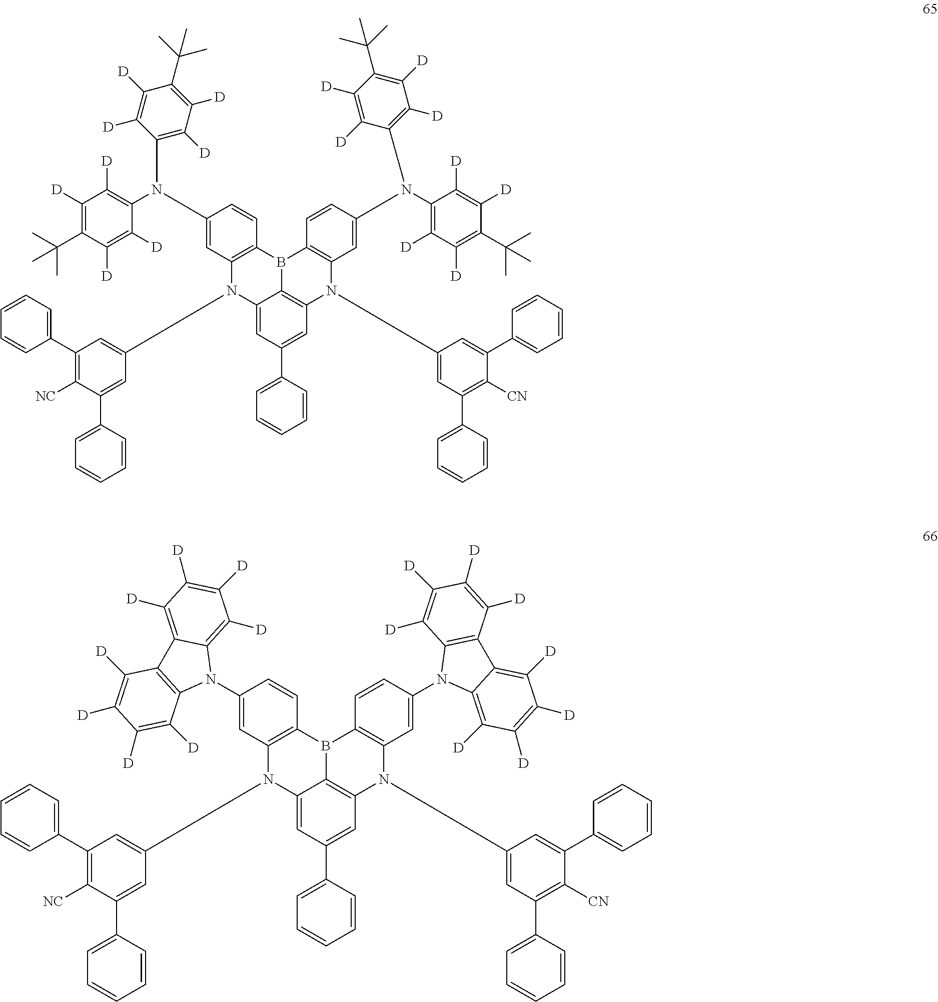

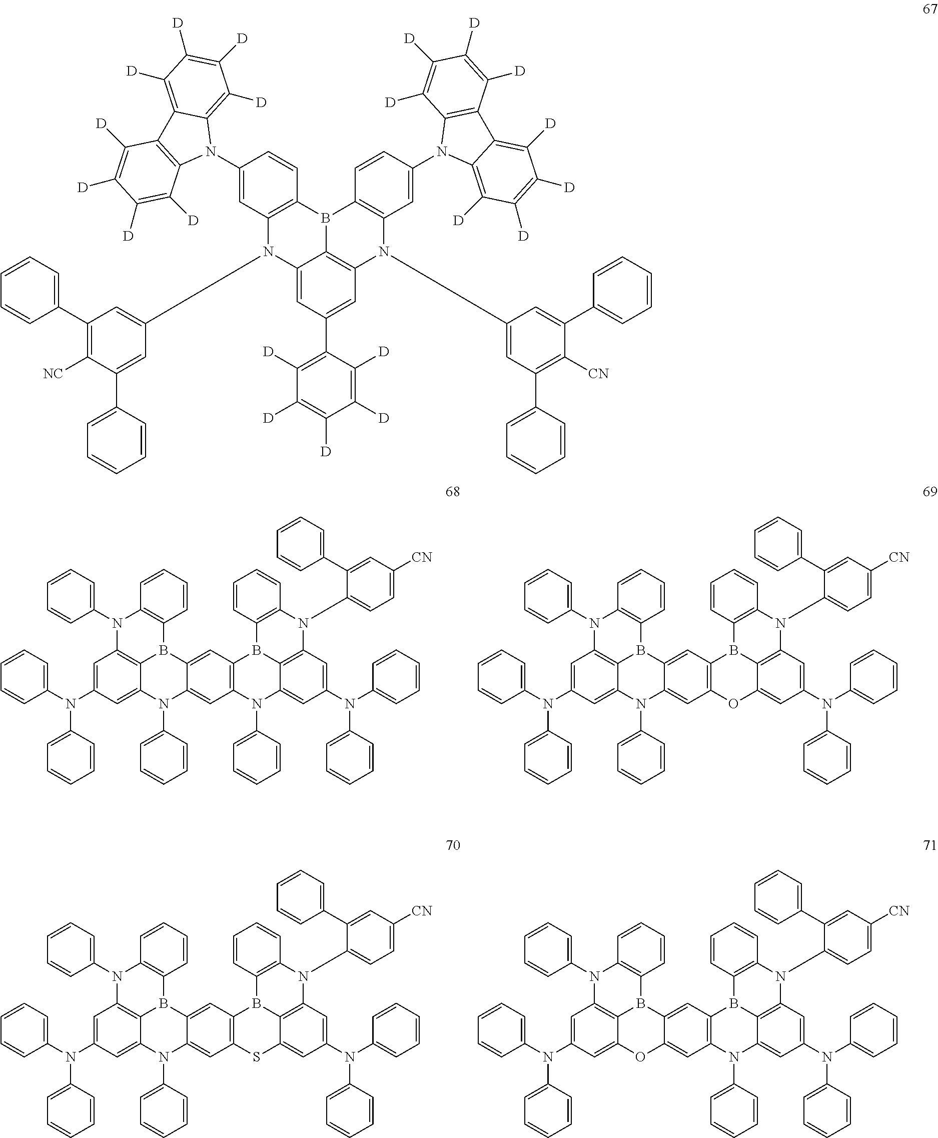

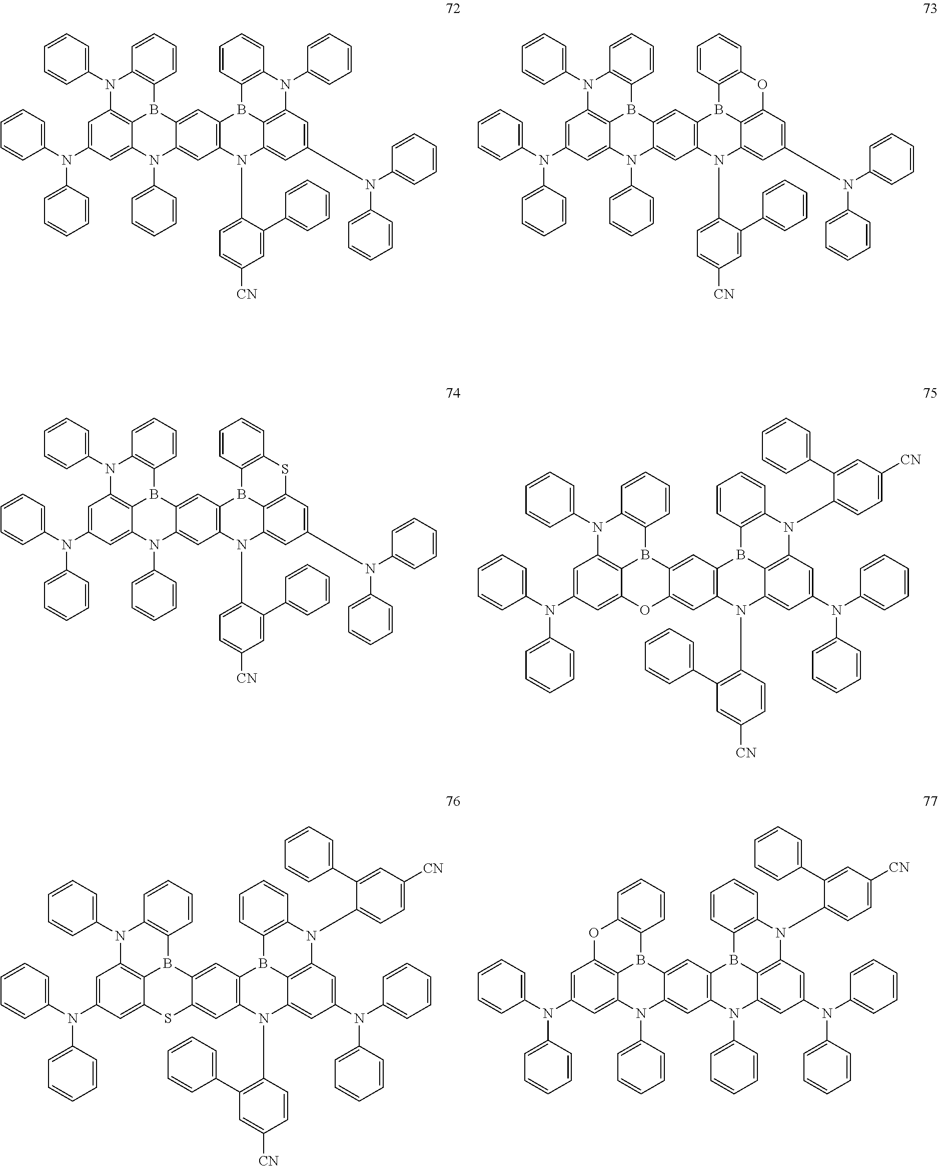

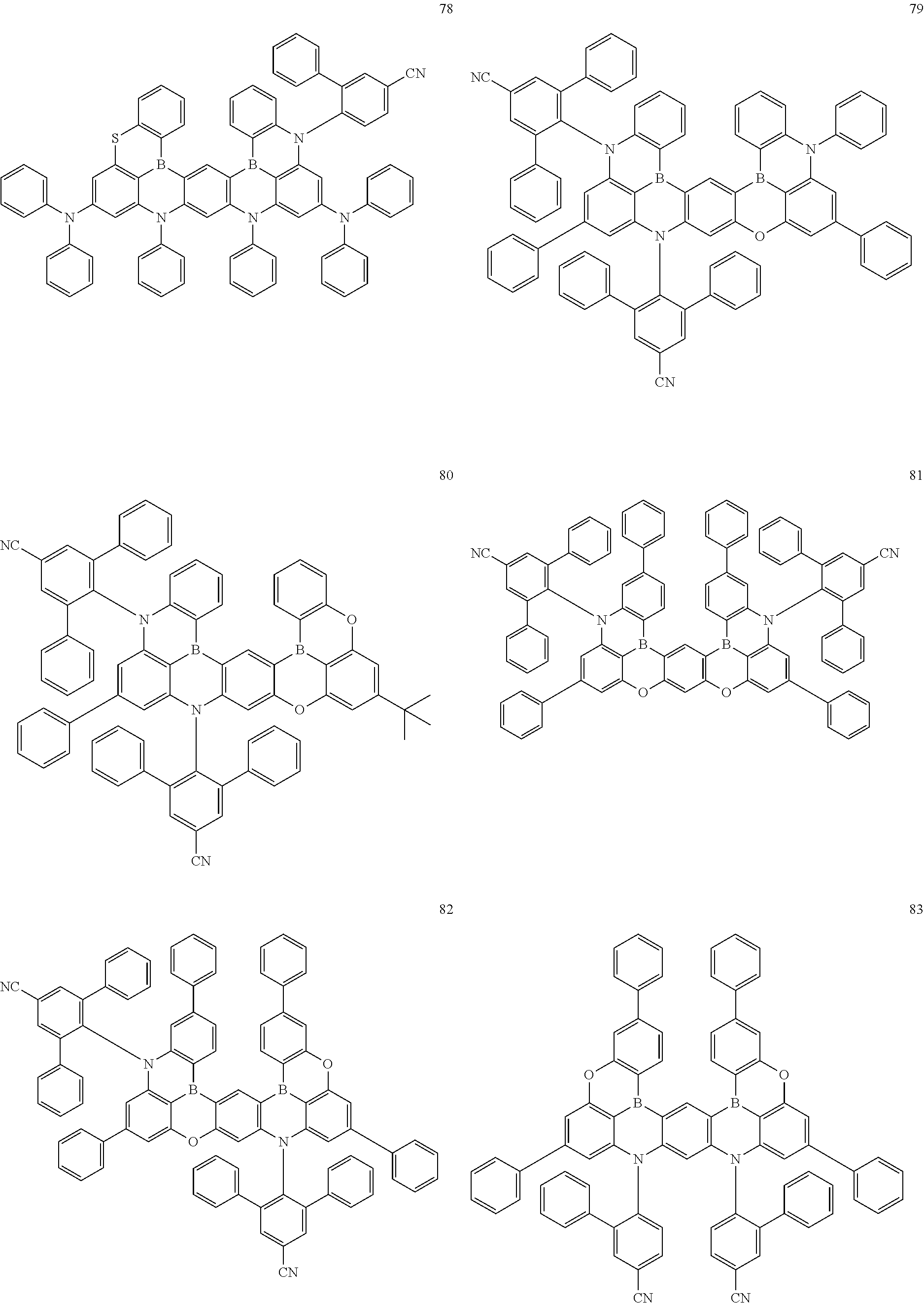

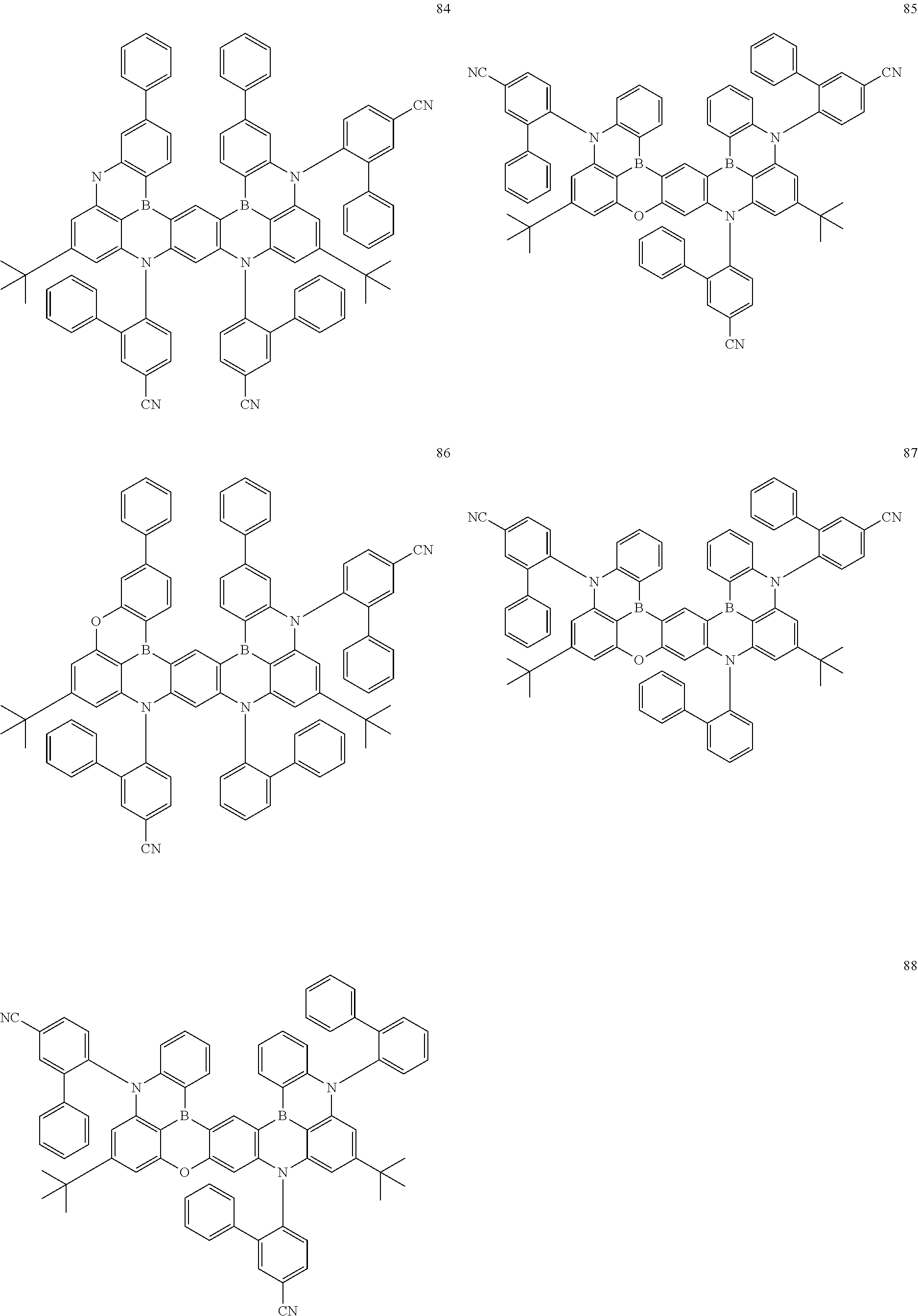

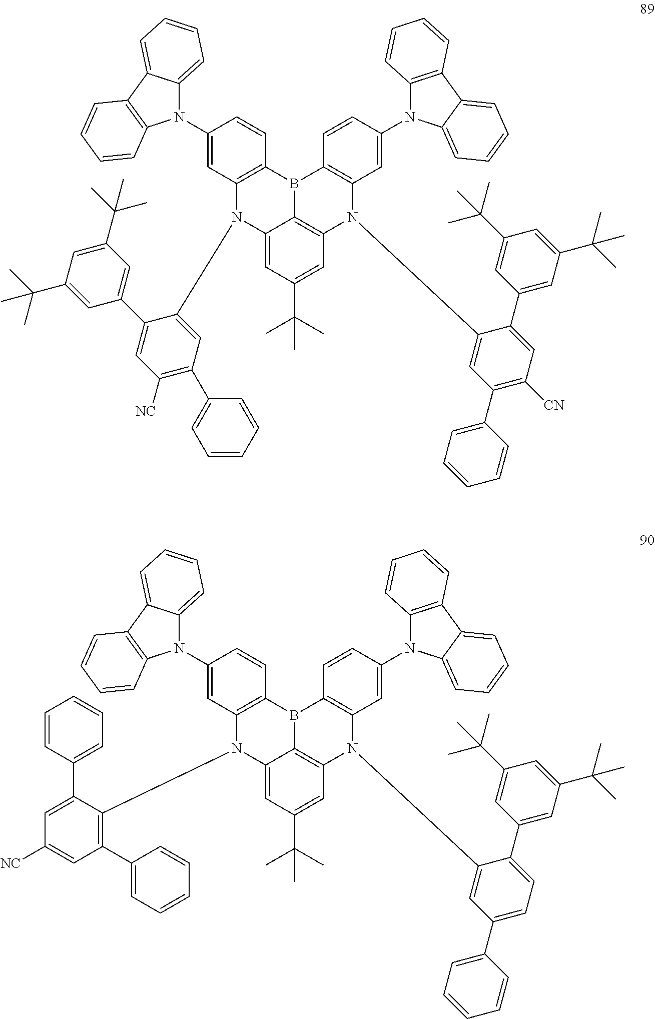 [SMILES: CC(C)(C)c1cc(-c2cc(C#N)c(-c3ccccc3)cc2N2c3cc(-n4c5ccccc5c5ccccc54)ccc3B3c4ccc(-n5c6ccccc6c6ccccc65)cc4N(c4cc(-c5ccccc5)c(C#N)cc4-c4cc(C(C)(C)C)cc(C(C)(C)C)c4)c4cc(C(C)(C)C)cc2c43)cc(C(C)(C)C)c1 ; CC(C)(C)c1cc(-c2ccc(-c3ccccc3)cc2N2c3cc(-n4c5ccccc5c5ccccc54)ccc3B3c4ccc(-n5c6ccccc6c6ccccc65)cc4N(c4c(-c5ccccc5)cc(C#N)cc4-c4ccccc4)c4cc(C(C)(C)C)cc2c43)cc(C(C)(C)C)c1]

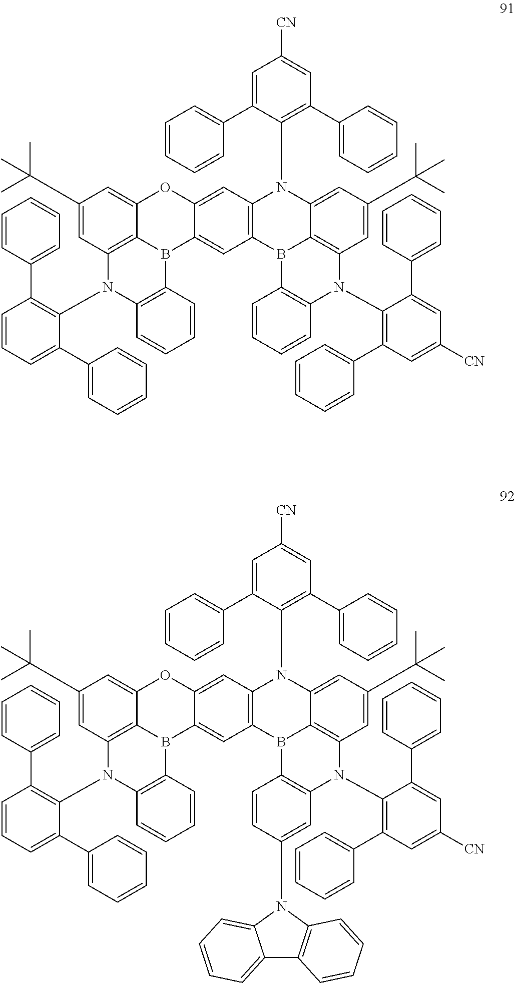 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccccc1N2c1c(-c2ccccc2)cc(C#N)cc1-c1ccccc1 ; CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccc(-n3c4ccccc4c4ccccc43)cc1N2c1c(-c2ccccc2)cc(C#N)cc1-c1ccccc1]

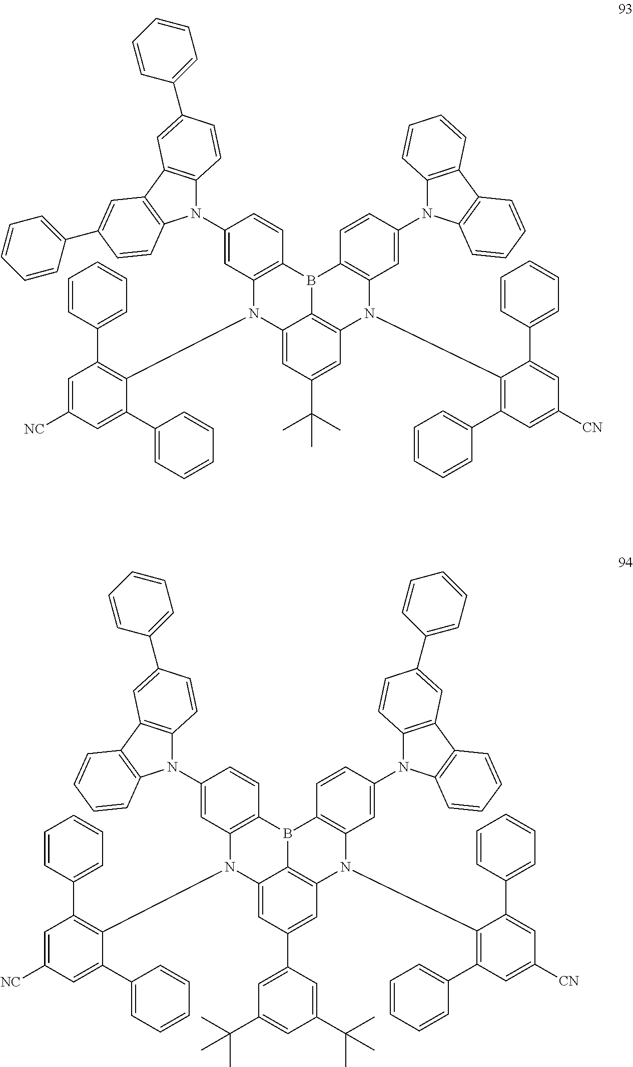 [SMILES: CC(C)(C)c1cc2c3c(c1)N(c1c(-c4ccccc4)cc(C#N)cc1-c1ccccc1)c1cc(-n4c5ccc(-c6ccccc6)cc5c5cc(-c6ccccc6)ccc54)ccc1B3c1ccc(-n3c4ccccc4c4ccccc43)cc1N2c1c(-c2ccccc2)cc(C#N)cc1-c1ccccc1 ; CC(C)(C)c1cc(-c2cc3c4c(c2)N(c2c(-c5ccccc5)cc(C#N)cc2-c2ccccc2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cc(C#N)cc2-c2ccccc2)cc(C(C)(C)C)c1]

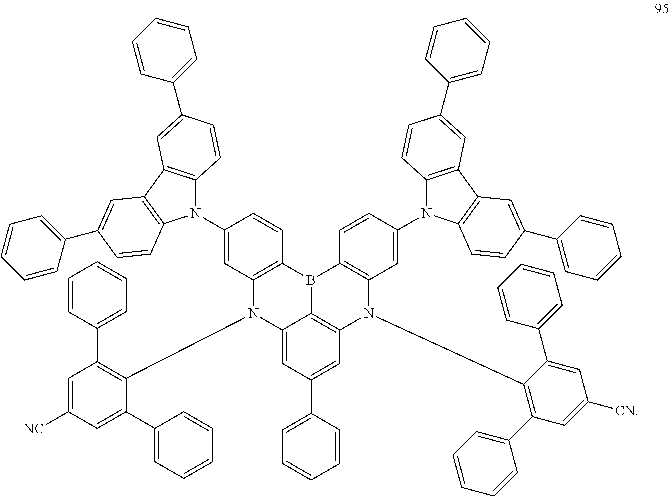 [SMILES: N#Cc1cc(-c2ccccc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4N(c4c(-c5ccccc5)cc(C#N)cc4-c4ccccc4)c4cc(-c5ccccc5)cc2c43)c(-c2ccccc2)c1]

In the light-emitting element ED according to an embodiment, the emission layer EML may be a delayed fluorescence emission layer including a host and a dopant. For example, the emission layer EML may emit a thermally activated delayed fluorescence (TADF). The polycyclic compound may be a delayed fluorescence dopant. For example, the polycyclic compound may be a thermally activated delayed fluorescence dopant.

The emission layer EML may include the polycyclic compound according to an embodiment as a dopant. The polycyclic compound may emit blue light. For example, the polycyclic compound may be a light emitting material that has a peak emission wavelength in a range of about 430 nm to about 490 nm. For example, the polycyclic compound may be a light emitting material that has a peak emission wavelength in a range of about 450 nm to about 470 nm.

In an embodiment, the emission layer EML may include the polycyclic compound according to an embodiment, and may further include at least one of a second compound, a third compound, and a fourth compound. In an embodiment, the emission layer EML may further include a second compound represented by Formula 2. In an embodiment, the second compound may be used as a hole transporting host material in the emission layer EML.

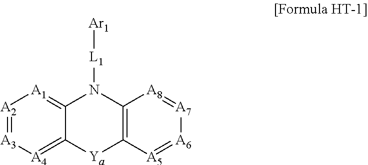

In Formula HT-1, A₁ to A₈ may each independently be N or C(R₅₁). For example, A₁ to A₈ may each independently be C(R₅₁). For another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

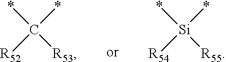

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

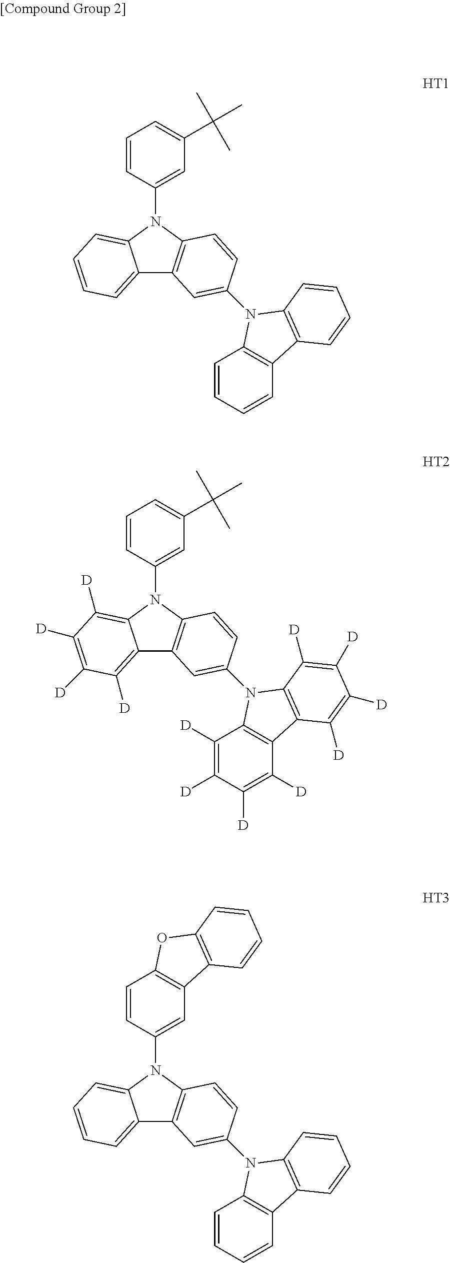 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

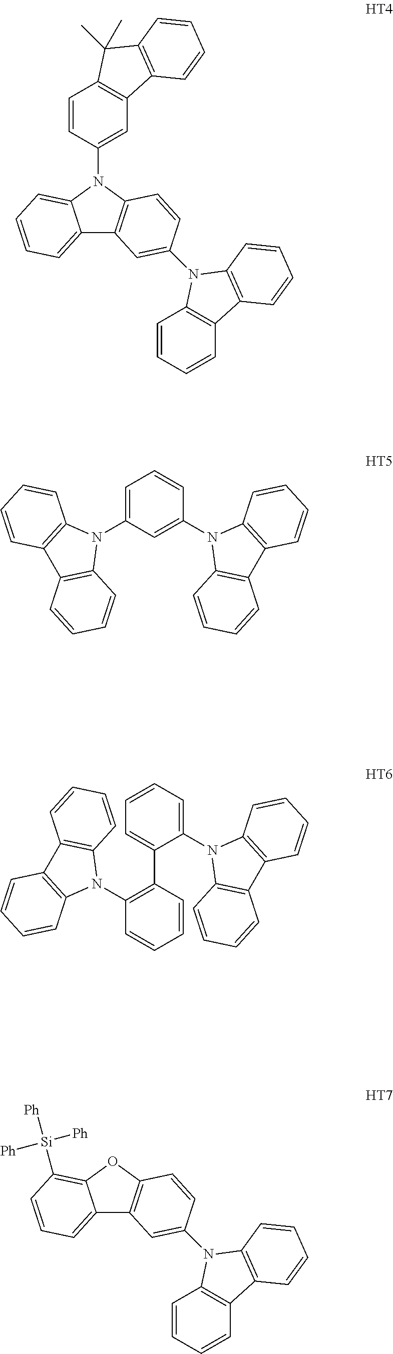 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

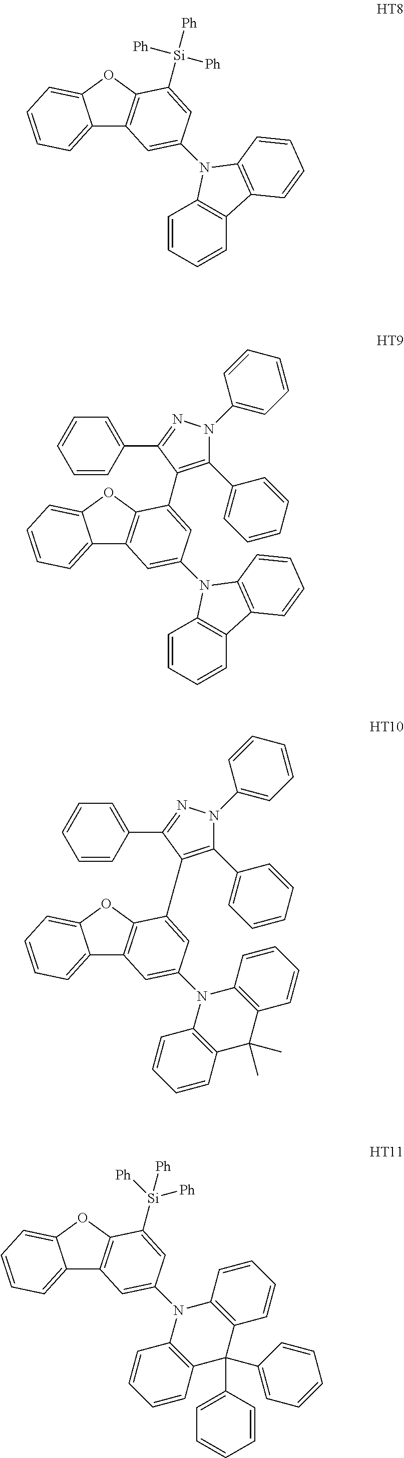 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

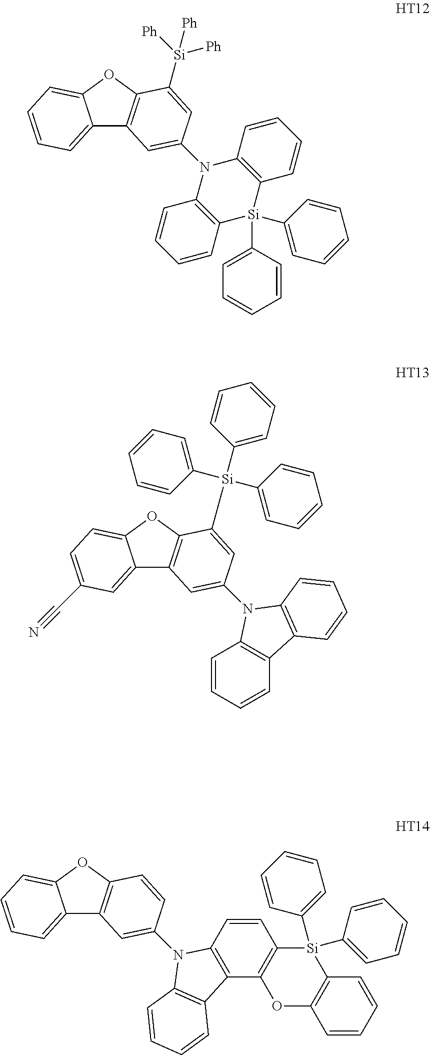 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

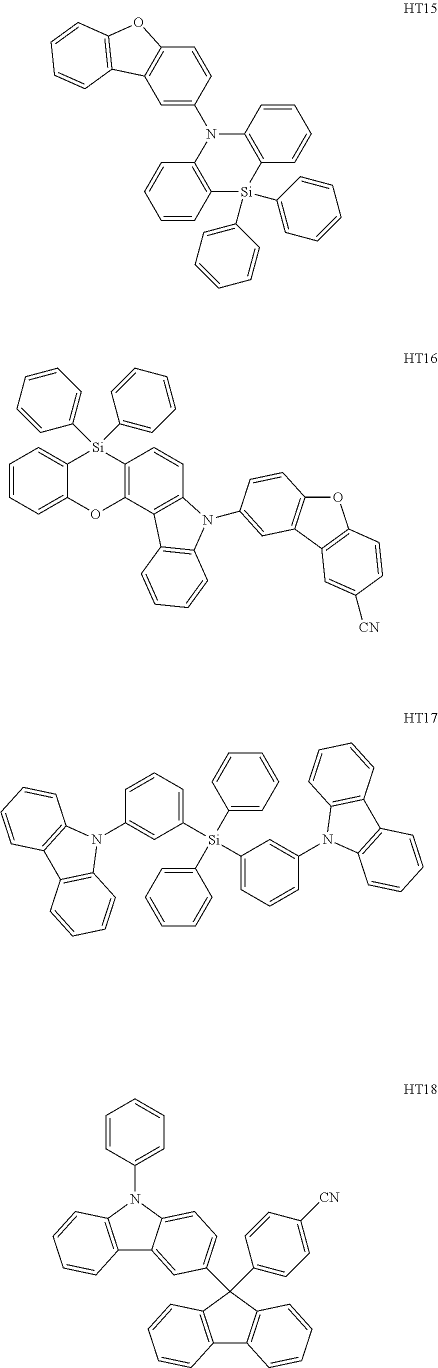 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

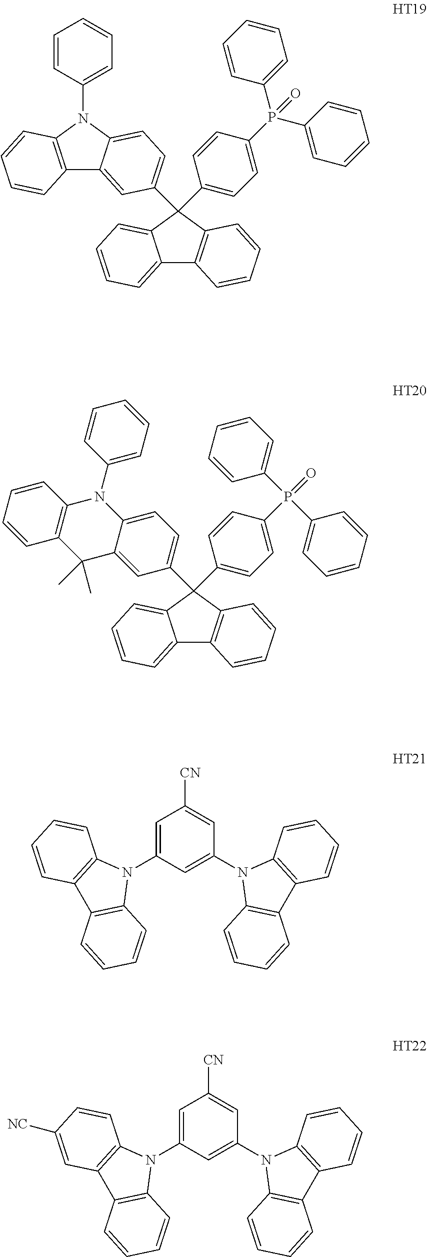 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

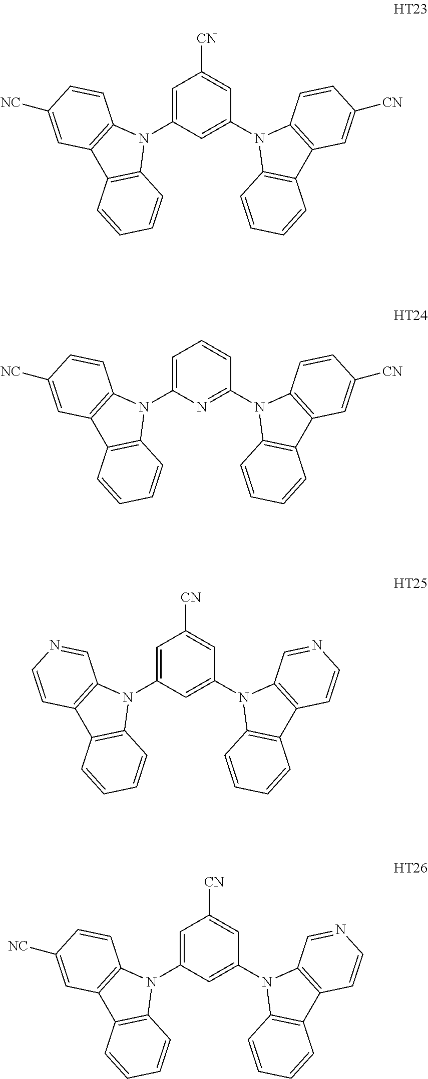 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

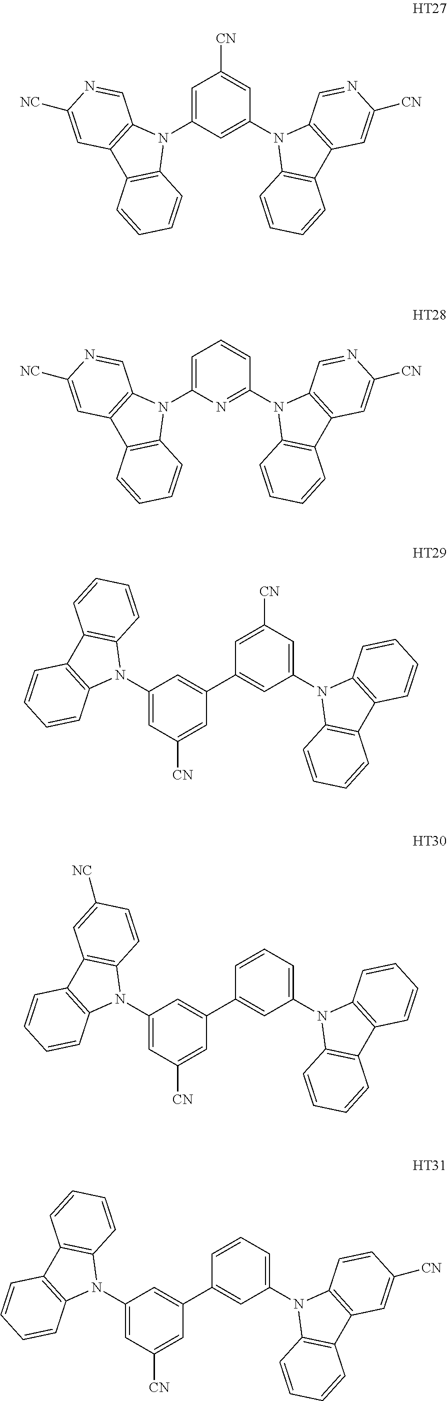 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

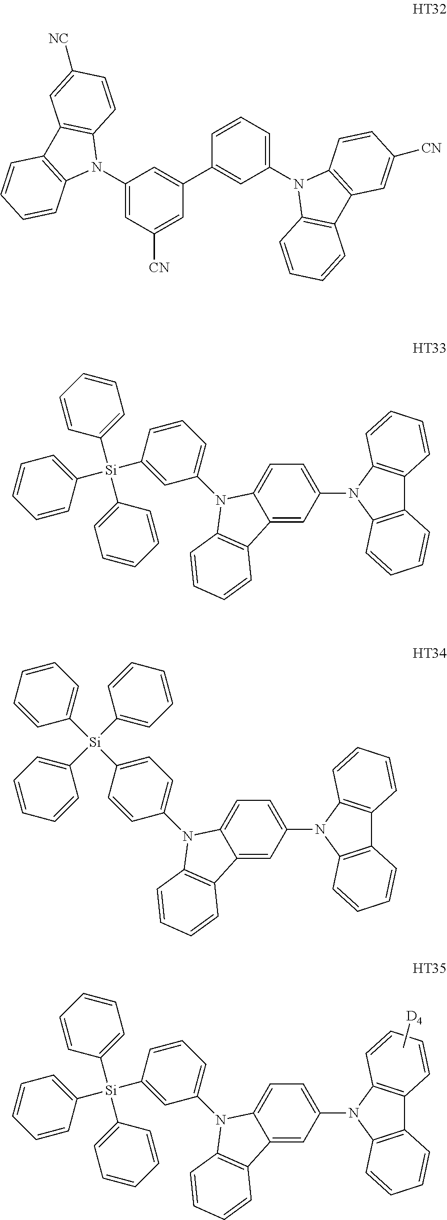

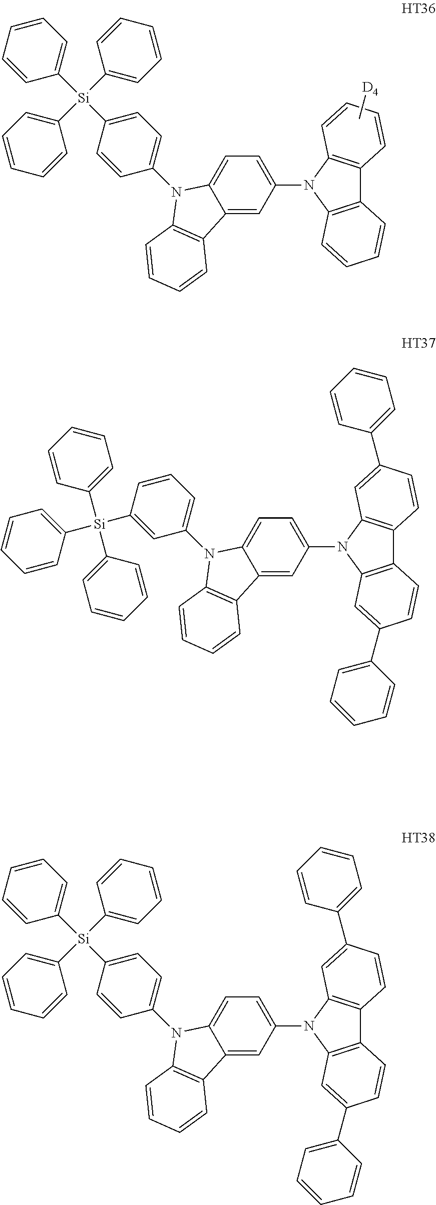

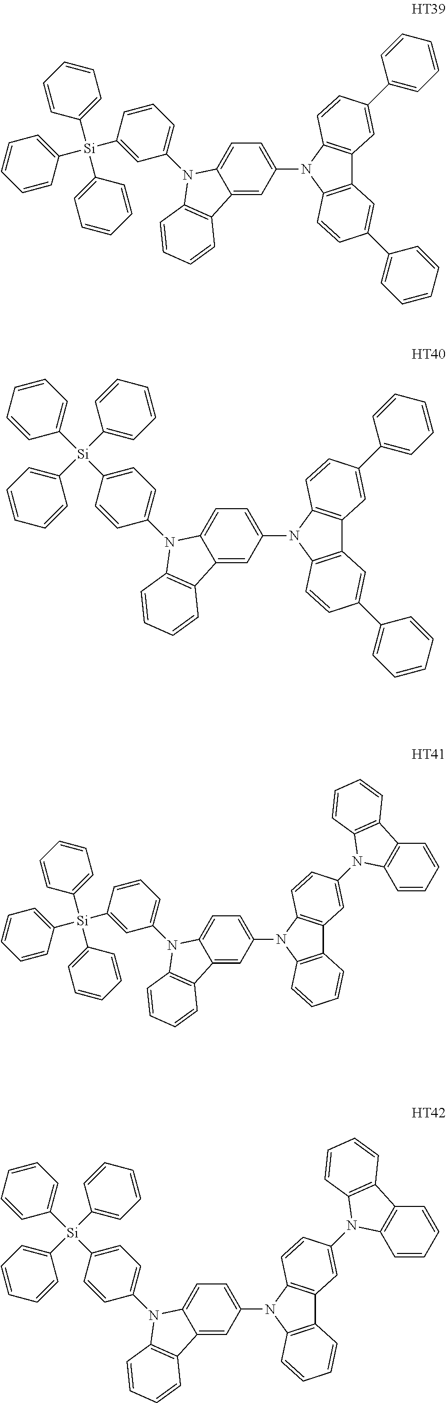 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

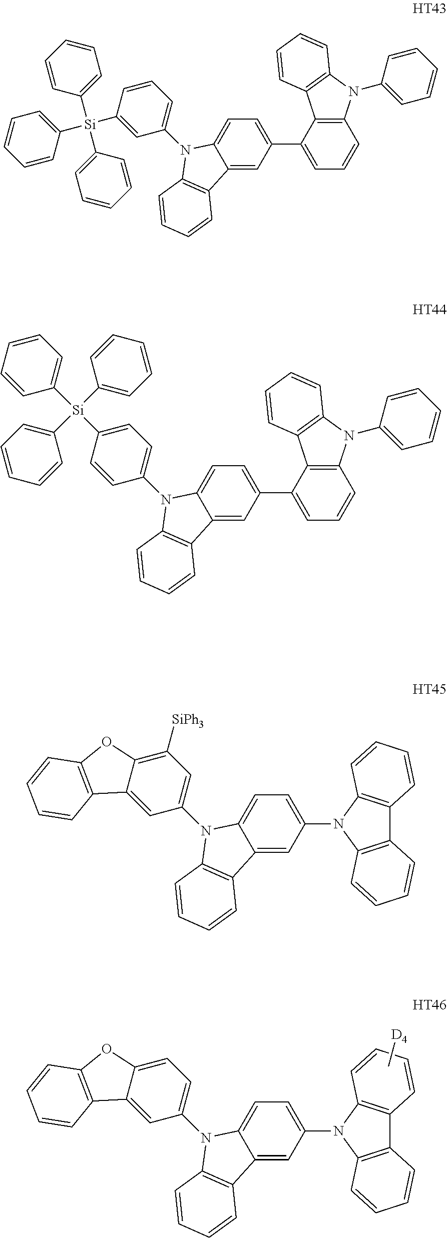

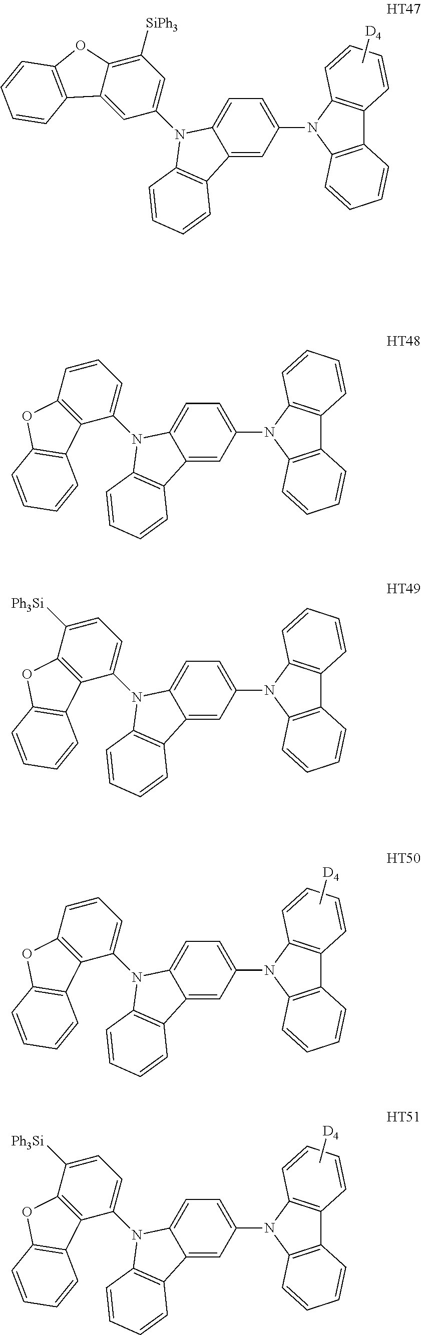

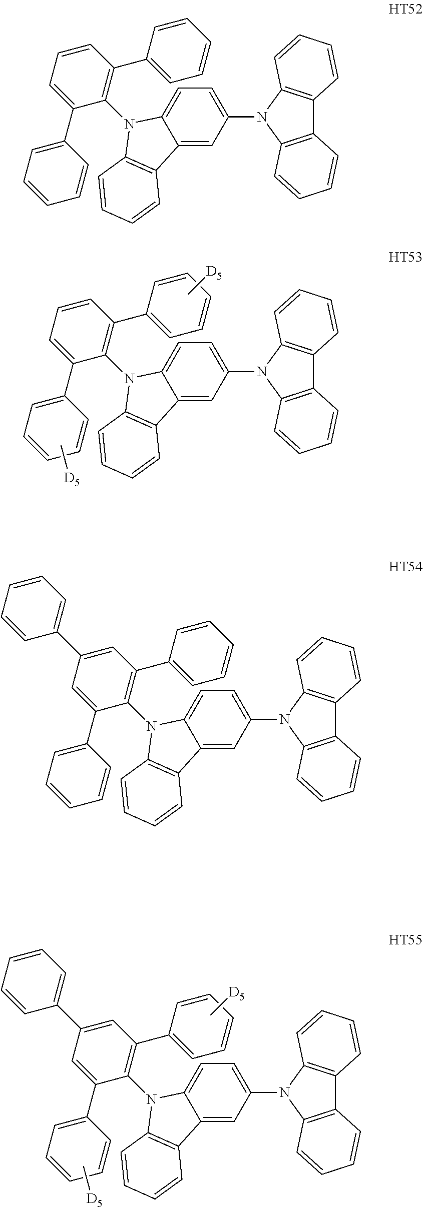

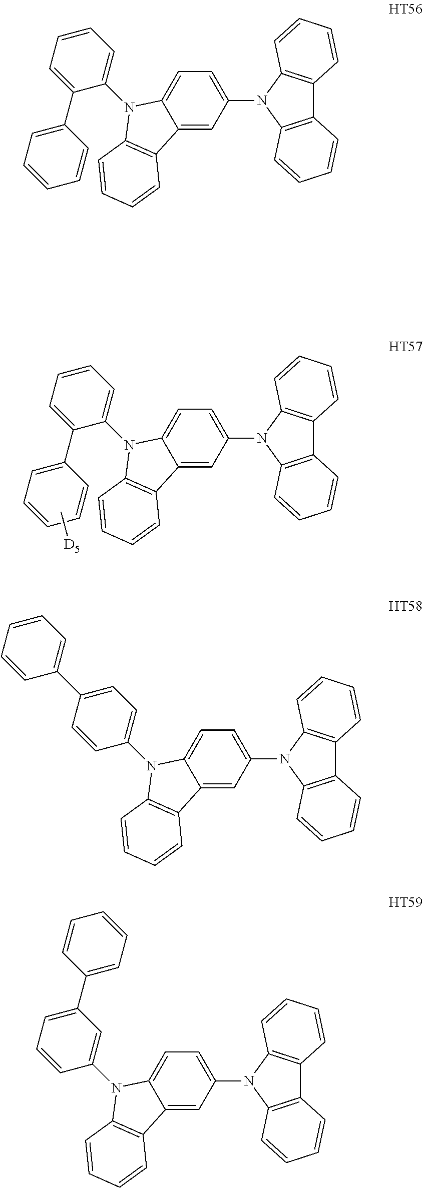

In Compound Group 2, “D” represents a deuterium atom, and “Ph” represents a substituted or unsubstituted phenyl group. For example, in Compound Group 2, “Ph” may represent an unsubstituted phenyl group.

In an embodiment, the emission layer EML may further include a third compound represented by Formula ET-1. In an embodiment, the third compound may be used as an electron transport host material for the emission layer EML.

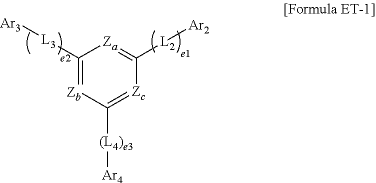

In Formula ET-1, at least one of Zₐ to Z_{c} may each be N, and the remainder of Zₐ to Z_{c} may each independently be C(R₅₆). For example, one of Zₐ to Z_{c} may be N, and the remainder of Zₐ to Z_{c} may each independently be C(R₅₆). Thus, the third compound represented by Formula ET-1 may include a pyridine moiety. In another embodiment, two of Zₐ to Z_{c} may each be N, and the remainder of Zₐ to Z_{c} may be C(R₅₆). Thus, the third compound represented by Formula ET-1 may include a pyrimidine moiety. In another embodiment, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, e1 to e3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When e1 to e3 are each 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

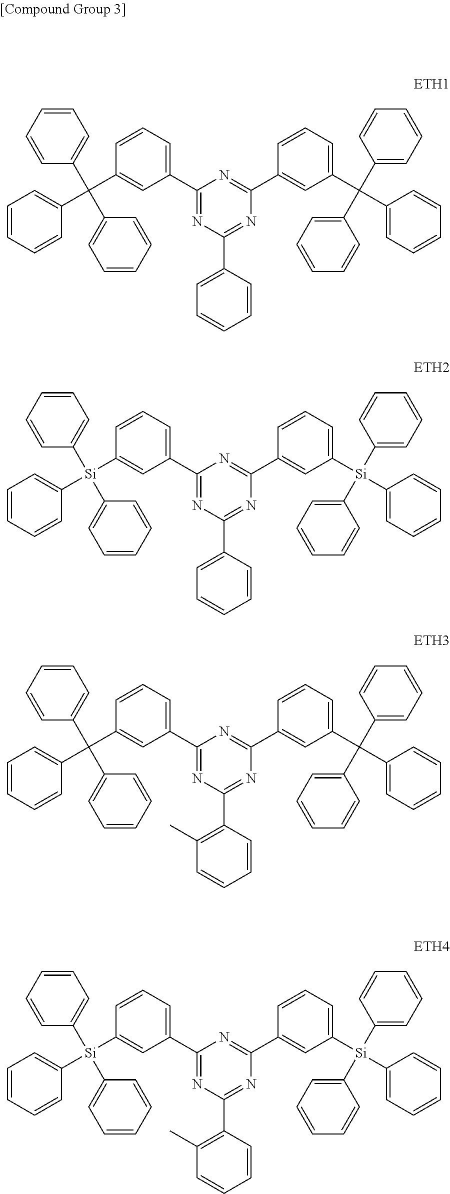 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

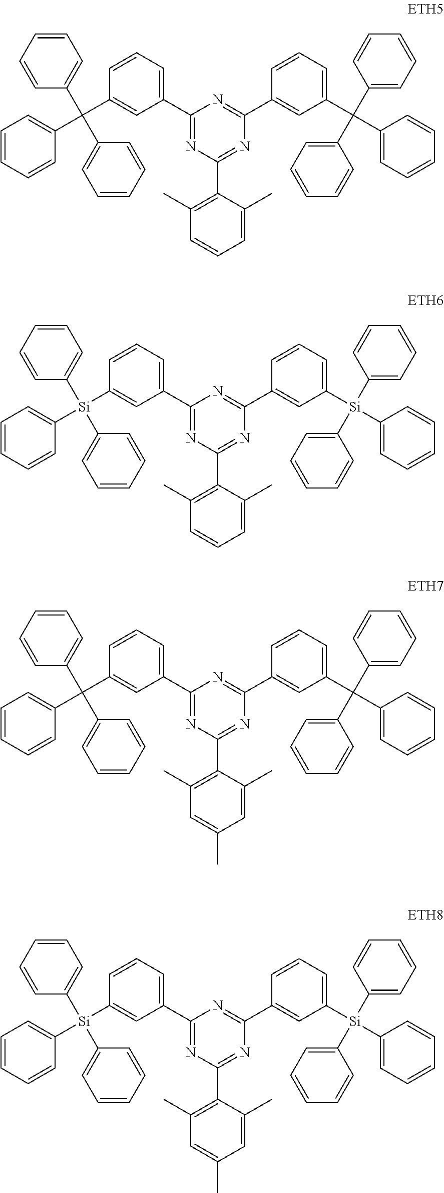 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

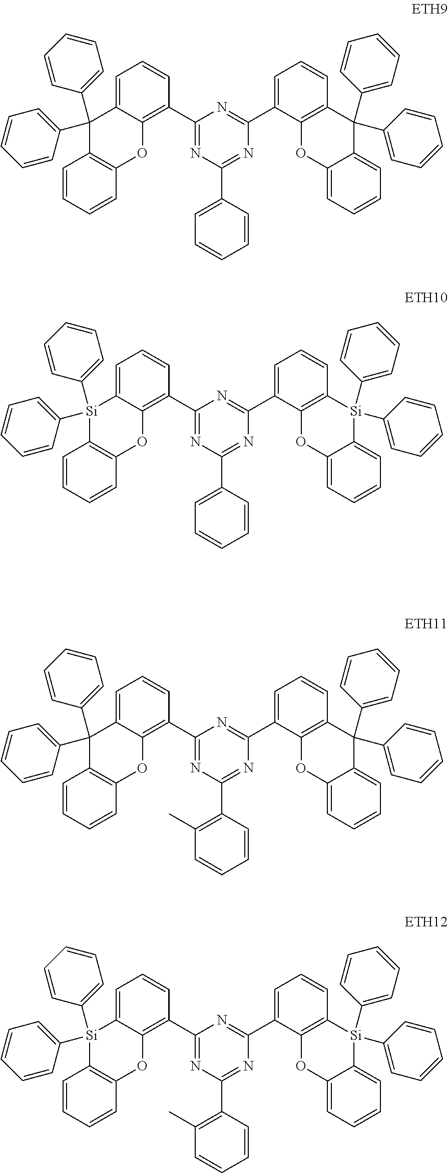 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

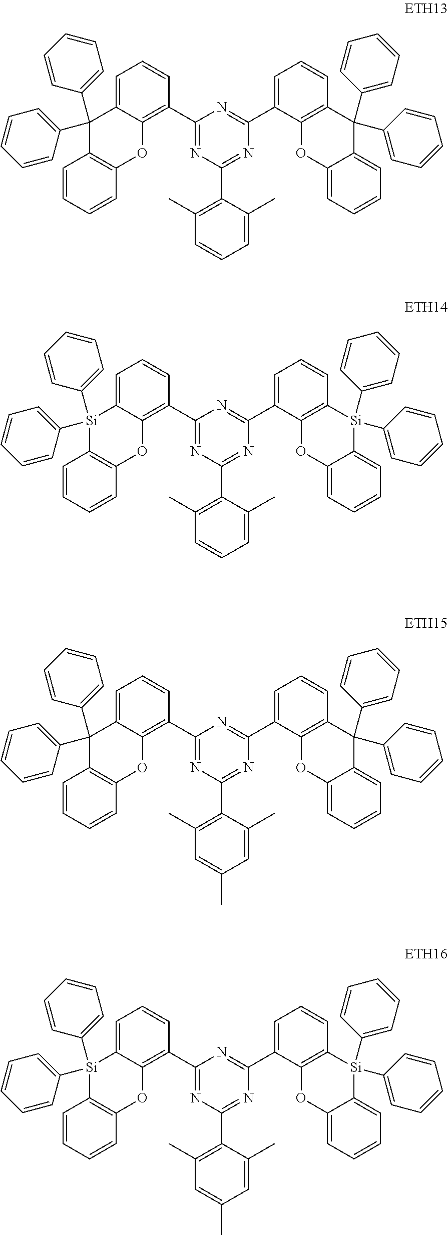 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

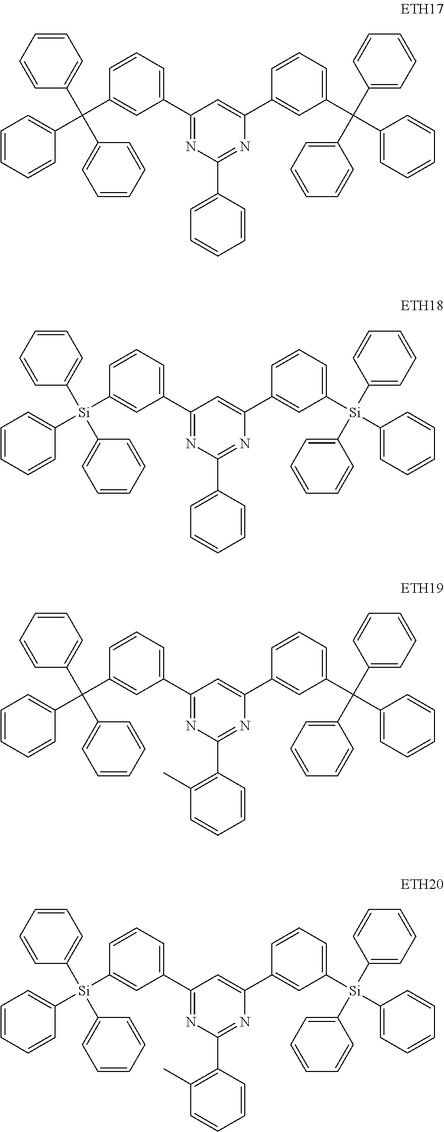 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

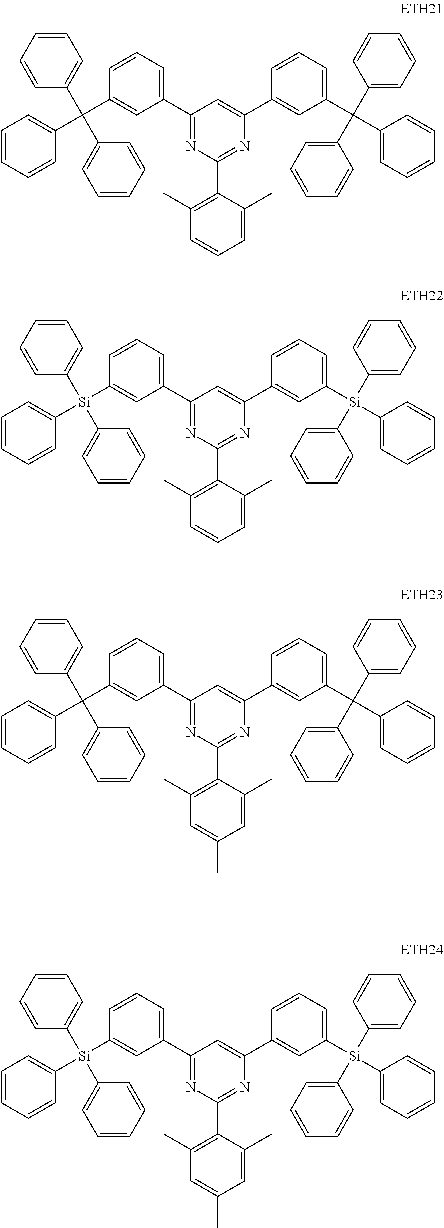 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

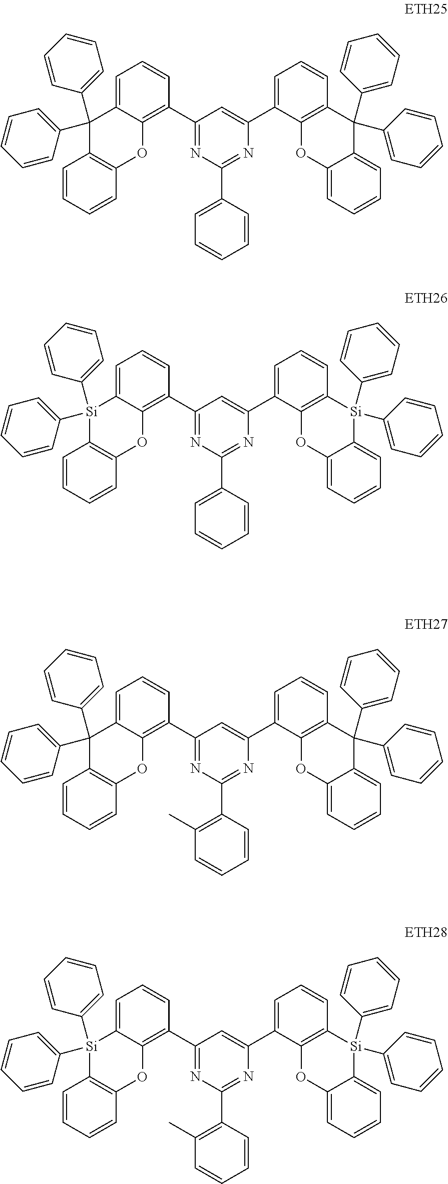 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

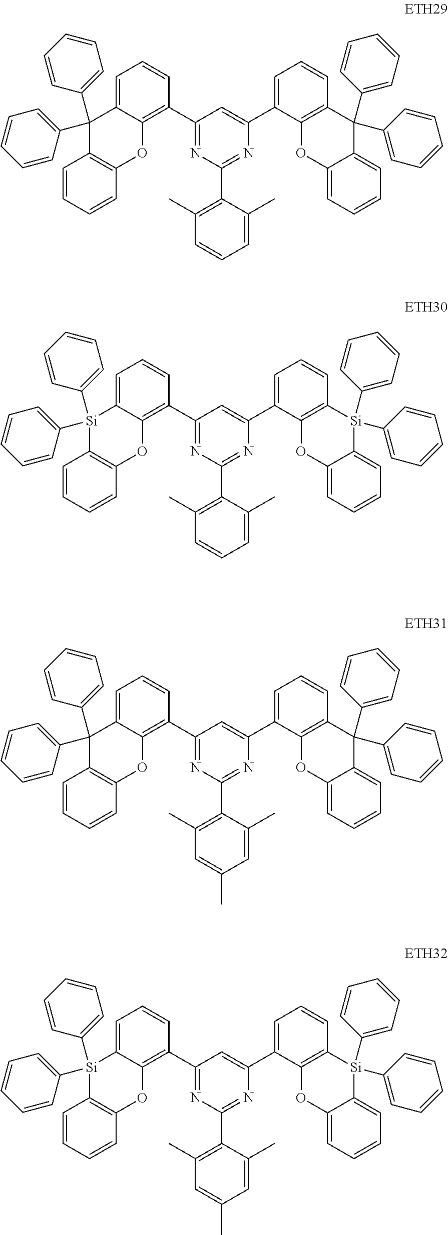 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

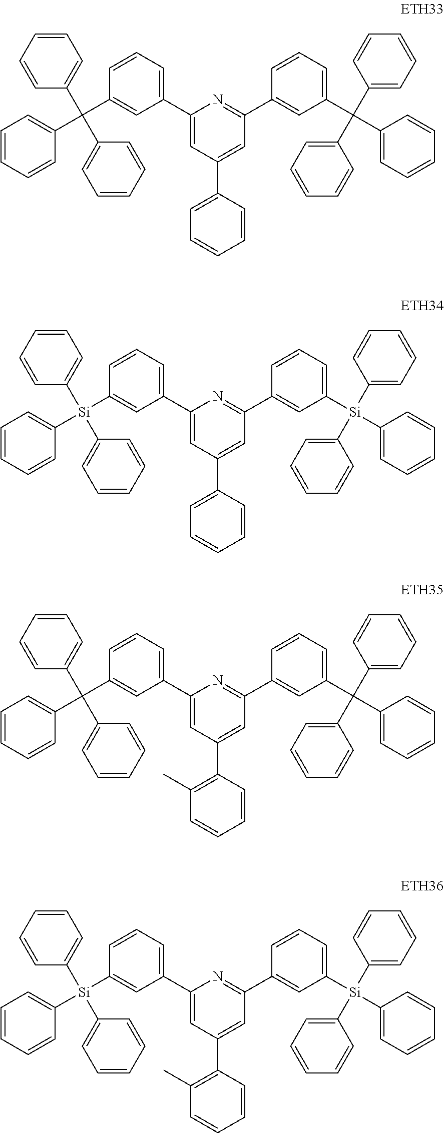 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

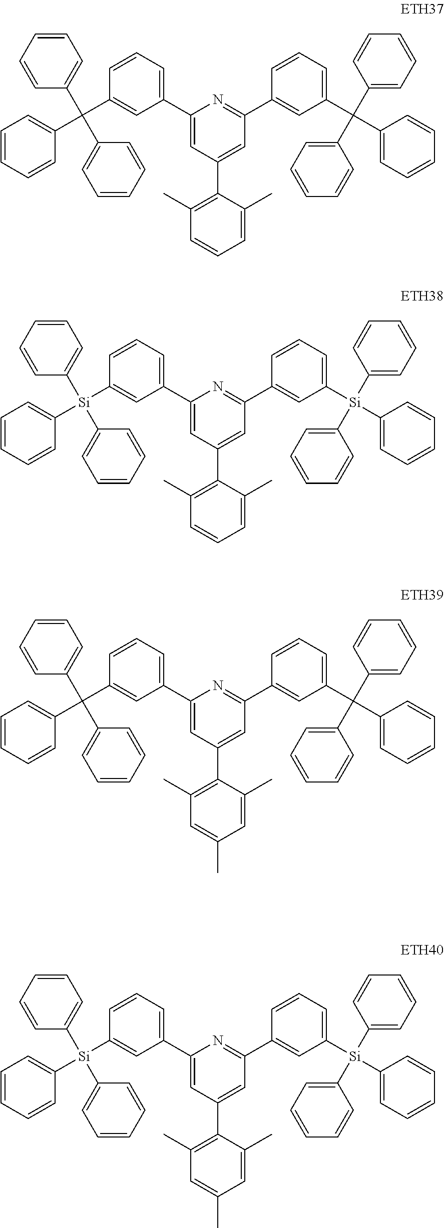 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

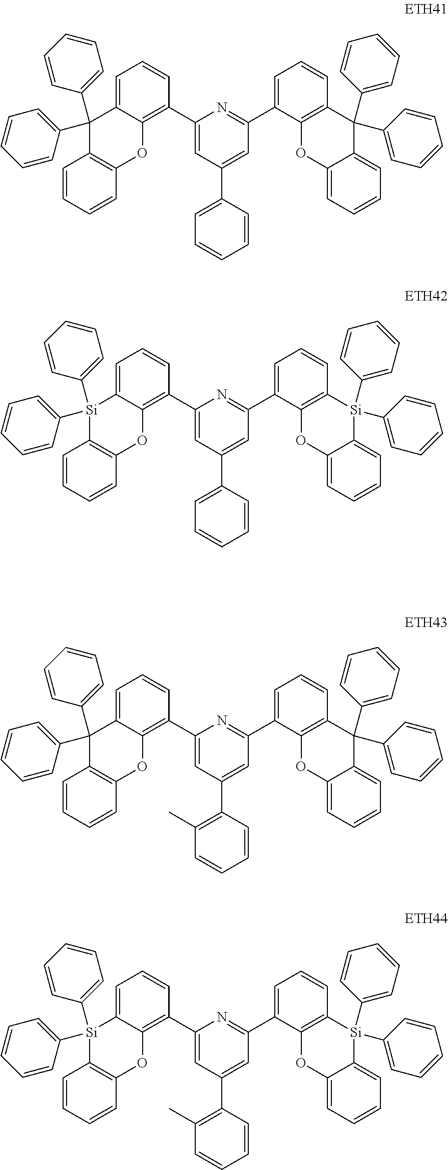 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

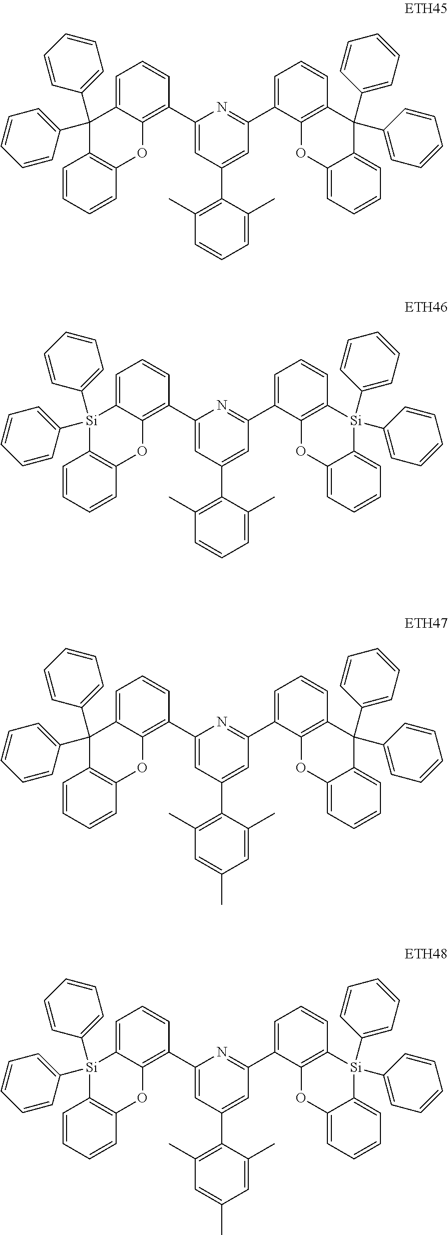 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

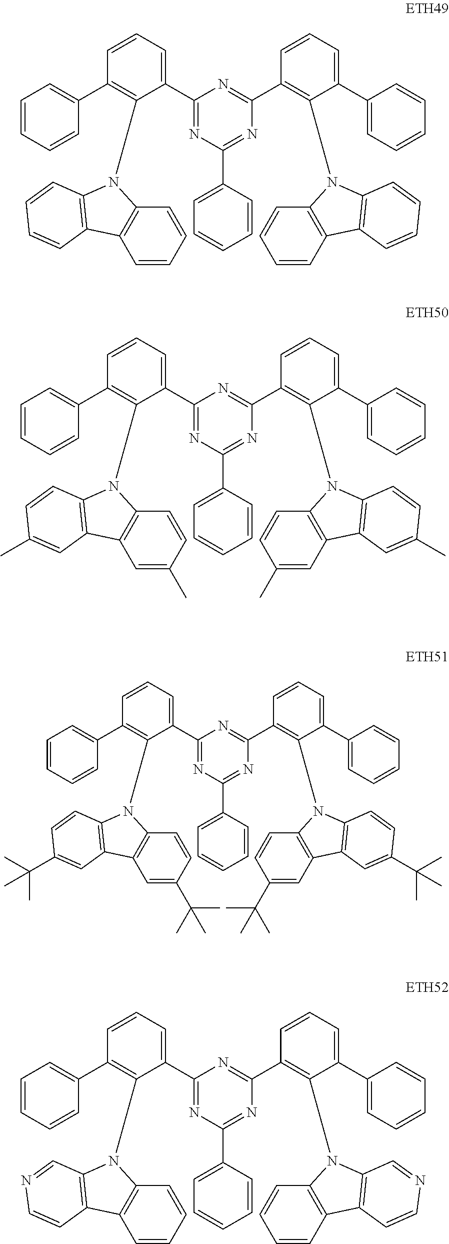

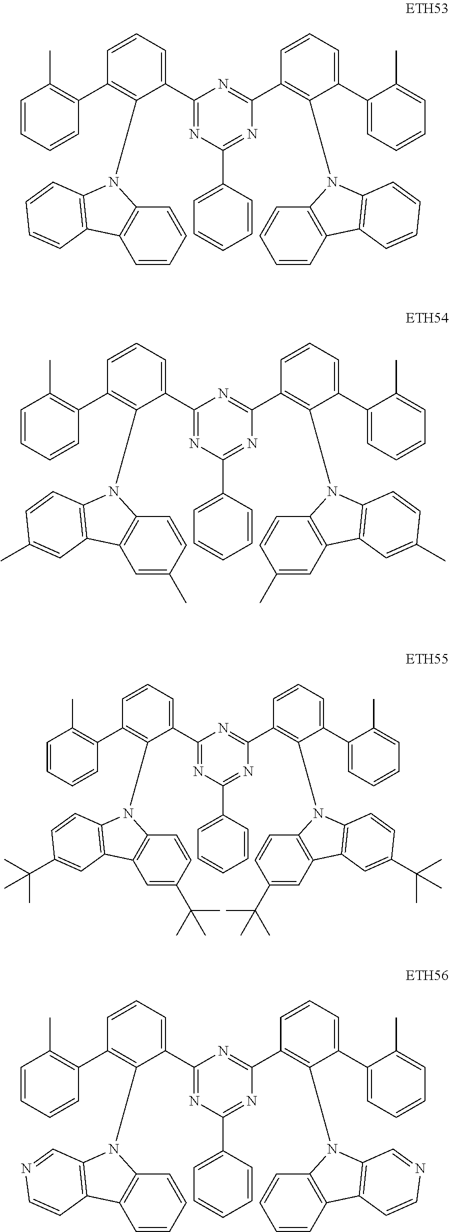

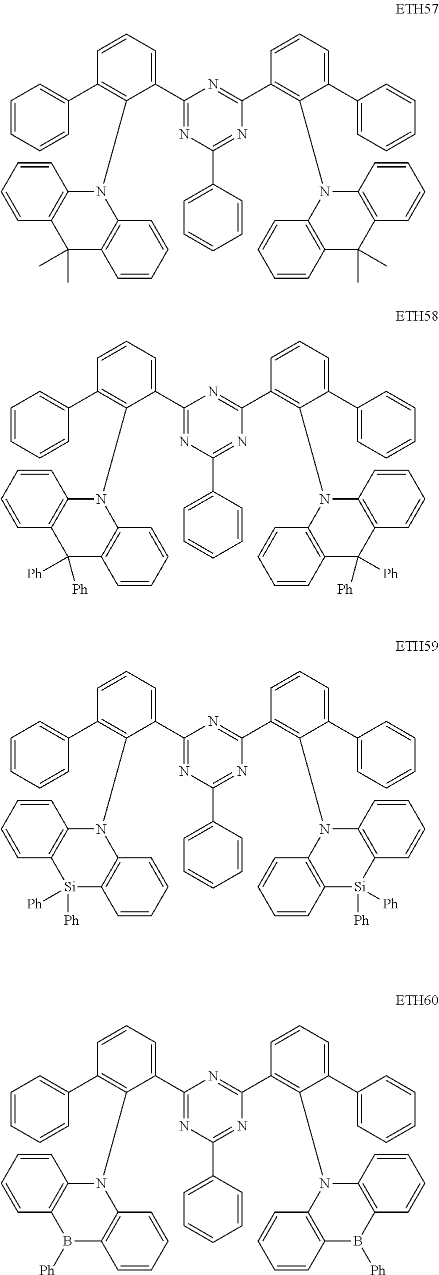

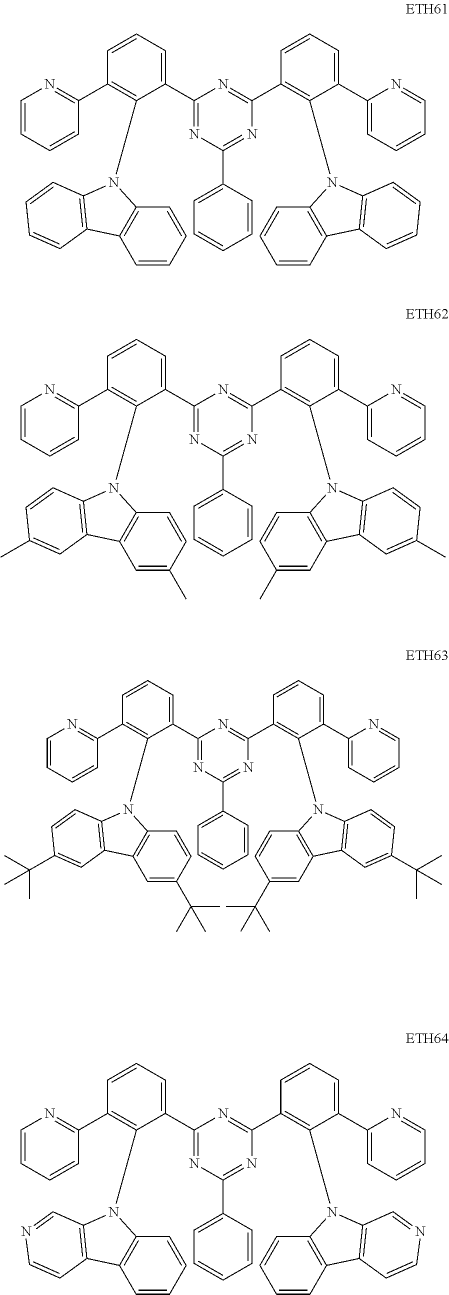

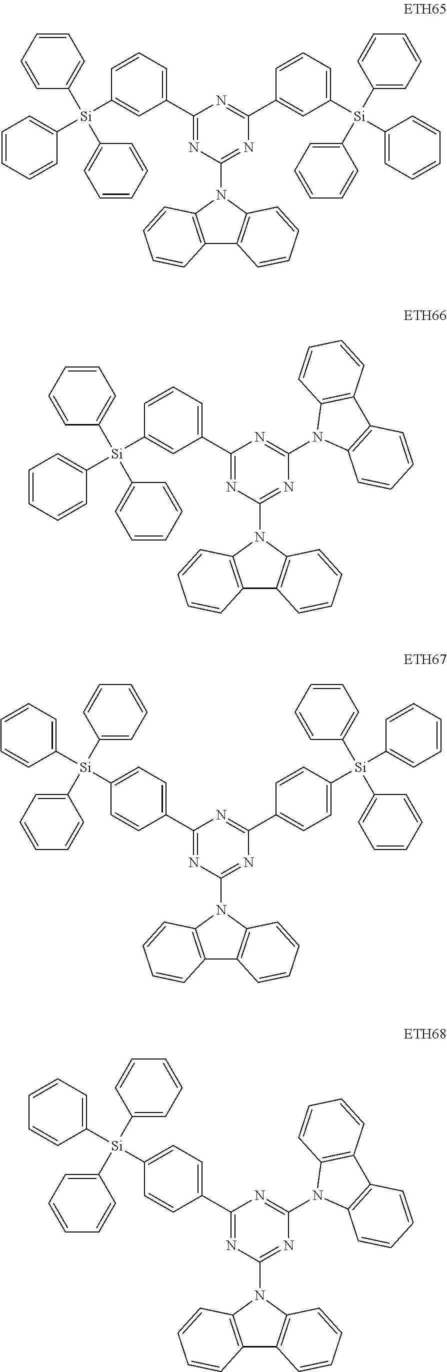 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

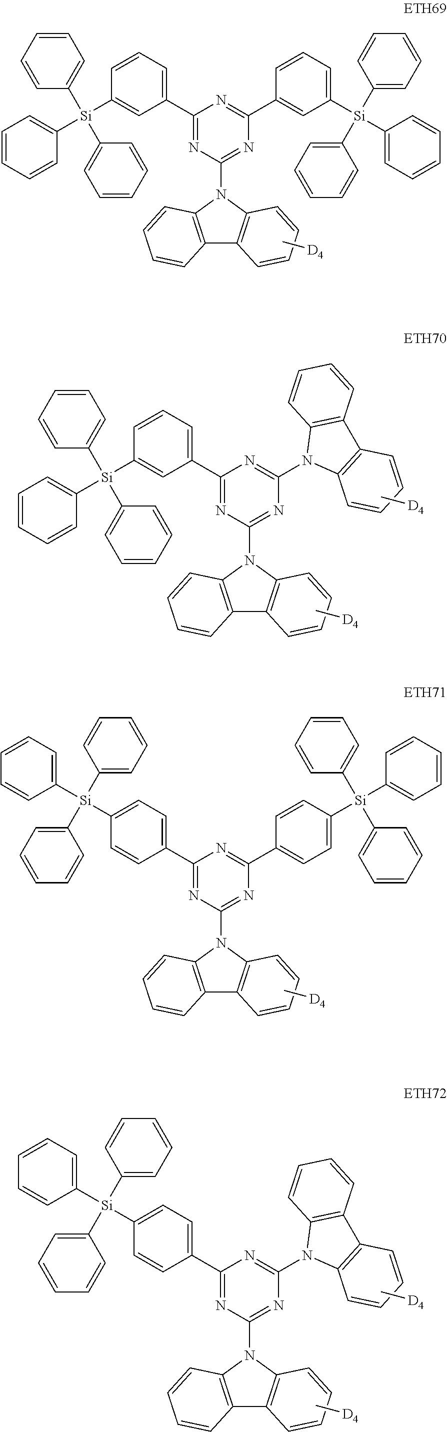

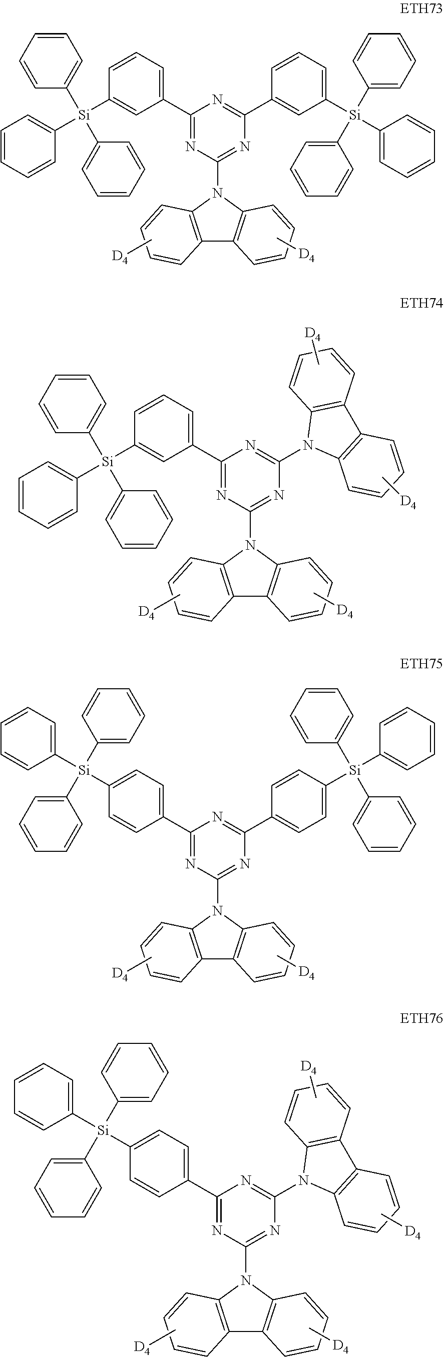

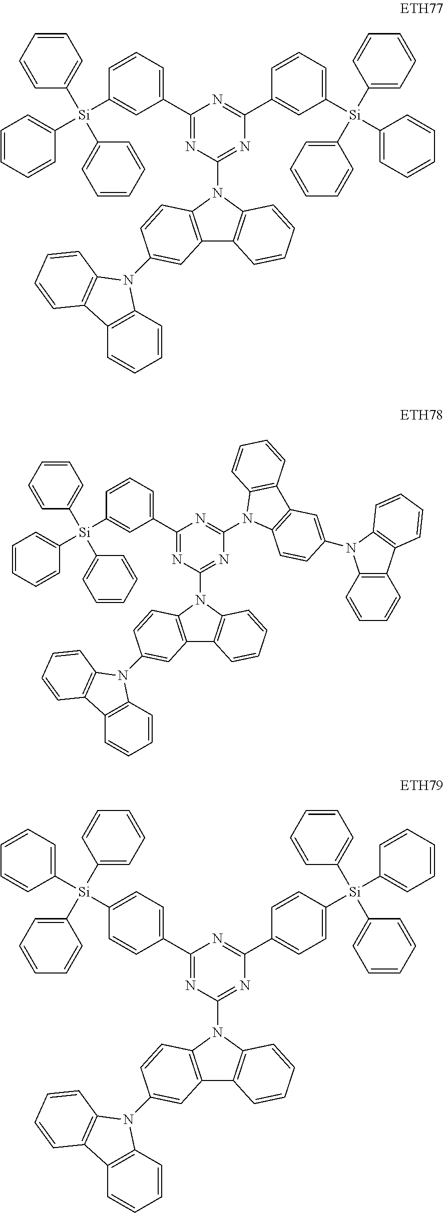 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

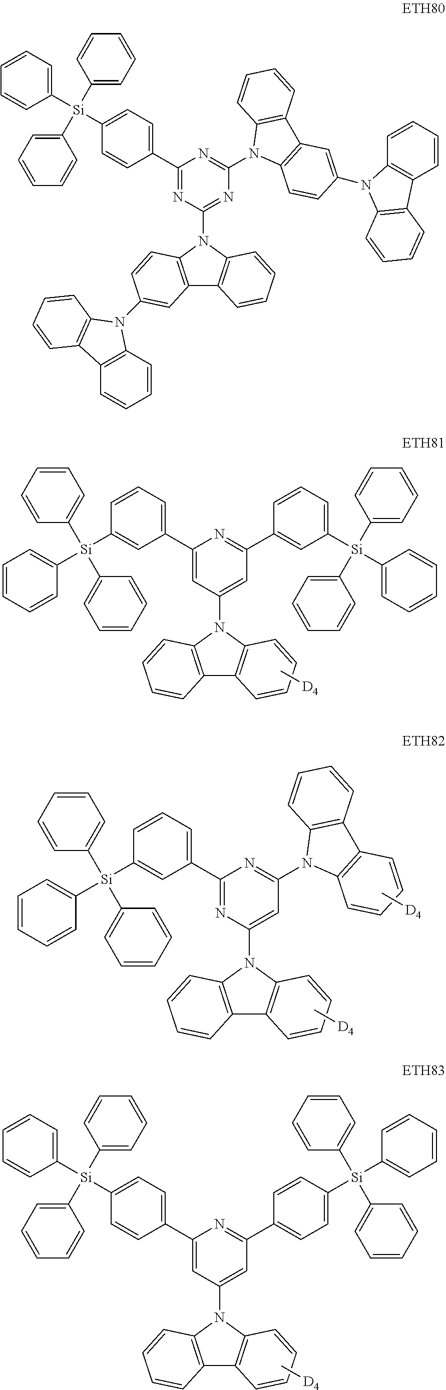

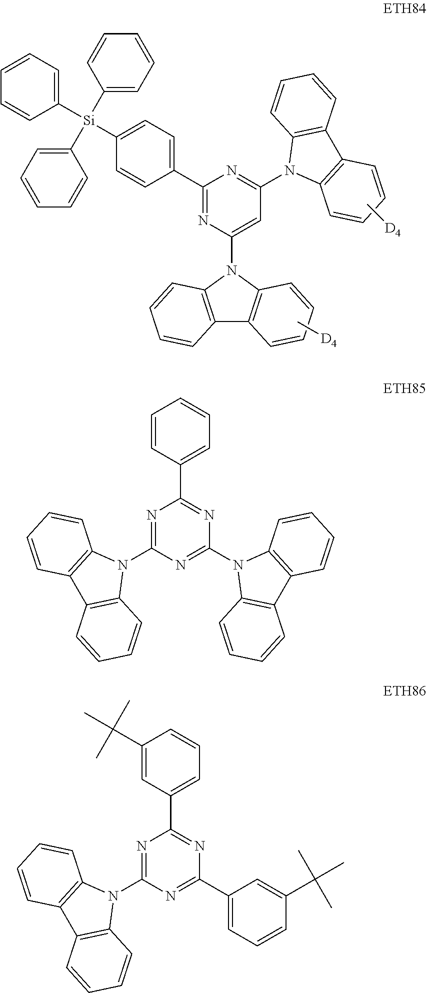

In Compound Group 3, “D” represents a deuterium atom and “Ph” represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of an exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy (T1) of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level less than or equal to about 3.0 eV, which is an energy gap between the hole transporting host and the electron transporting host.

In an embodiment, the emission layer EML may include a fourth compound in addition to the first compound, the second compound, and the third compound as described above. The fourth compound may be used as a phosphorescent sensitizer in an emission layer EML. The energy may be transferred from the fourth compound to the first compound, thereby emitting light.

In an embodiment, the emission layer EML may further include, as a fourth compound, an organometallic complex that includes platinum (Pt) as a central metal atom and ligands linked to the central metal atom. In an embodiment, the emission layer EML may include a fourth compound represented by Formula D-1:

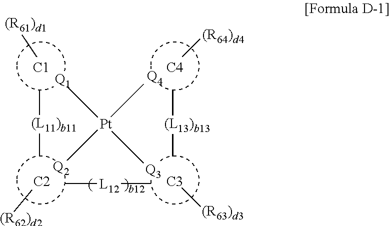

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, Lia to L₁₃ may each independently be a direct linkage,

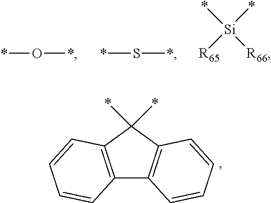

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b13 is 0, C3 and C4 may not be directly bonded to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group, or a substituted or unsubstituted t-butyl group.

In an embodiment, in Formula D-1, d1 to d4 may each independently be an integer from 0 to 4. In Formula D-1, if d1 to d4 are each 0, the fourth compound may not be substituted with R₆₁ to R₆₄, respectively. A case where d1 to d4 are each 4 and multiple R₆₁ to R₆₄ are each hydrogen atoms may be the same as the case where d1 to d4 are each 0. When d1 to d4 are each 2 or more, multiple R₆₁ to R₆₄ may each be the same or at least one thereof may be different from the others.

In an embodiment, in Formula D-1, C1 to C4 may each independently be a substituted or unsubstituted hydrocarbon ring or a substituted or unsubstituted heterocycle that is represented by one of Formula C-1 to Formula C-4:

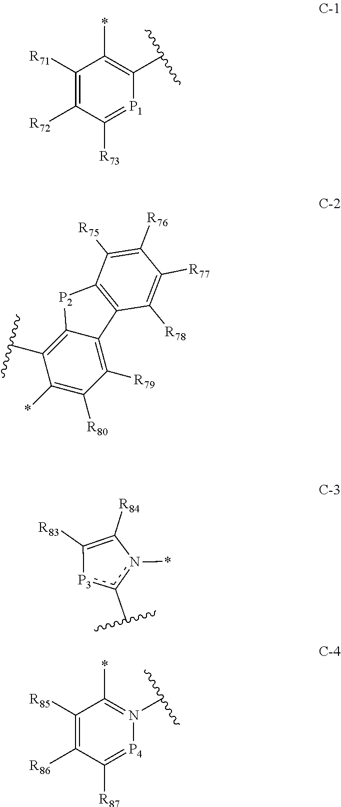

In Formula C-1 to Formula C-4, P₁ may be [symbol] or C(R₇₄), P₂ may be [symbol] or N(R₈₁), P₃ may be [symbol] or N(R₈₂), and P₄ may be [symbol] or C(R₈₈). In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4, “ [symbol] ” represents a bond to Pt that is a central metal atom, and “ [symbol] ” represents a bond to a neighboring cyclic group (C1 to C4) or to a linking moiety (L₁₁ to L₁₃).

In an embodiment, the emission layer EML may include the first compound, which is a polycyclic compound, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting element ED may serve as a sensitizer that transfers energy from the host to the first compound, which is a light emitting dopant. For example, the fourth compound serving as an auxiliary dopant may accelerate energy transfer to the first compound, which is a light emitting dopant, thereby increasing an emission ratio of the first compound. Therefore, the emission layer EML may have improved luminous efficiency. When the energy transfer to the first compound is increased, excitons formed in the emission layer EML may not accumulate in the emission layer EML and may rapidly emit light, resulting in less deterioration of a light emitting element ED. Therefore, the service life of the light emitting element ED according to an embodiment may increase.

In an embodiment, the light emitting element ED may include the first compound, the second compound, the third compound, and the fourth compound, and the emission layer EML may include a combination of two host materials and two dopant materials. In the light emitting element ED, the emission layer EML may include the second compound and the third compound, which are two different hosts, the first compound that emits a delayed fluorescence, and the fourth compound including an organometallic complex, thereby exhibiting excellent luminous efficiency characteristics.

In an embodiment, the fourth compound represented by Formula D-1 may be selected from Compound Group 4. In an embodiment, in light emitting element ED, the fourth compound may include at least one compound selected from Compound Group 4.

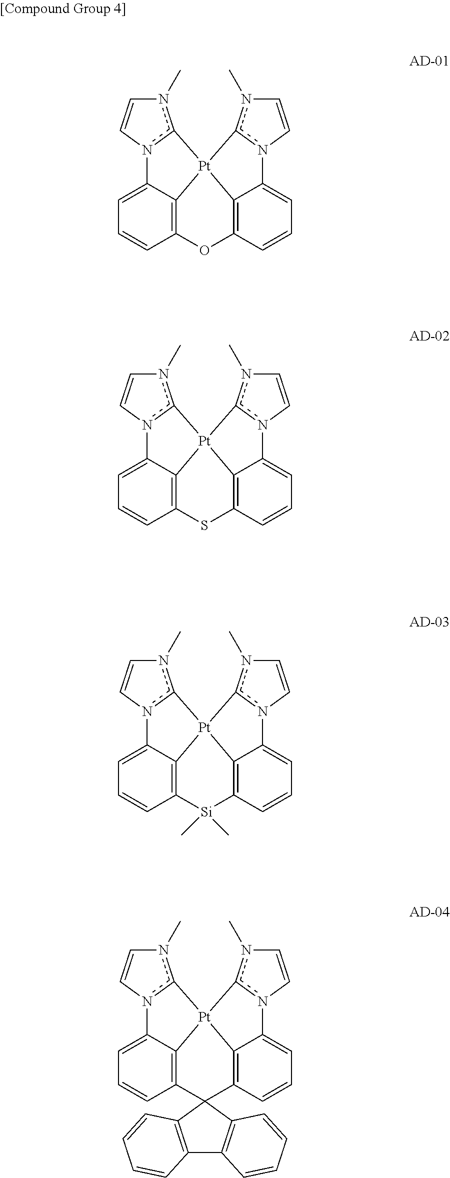

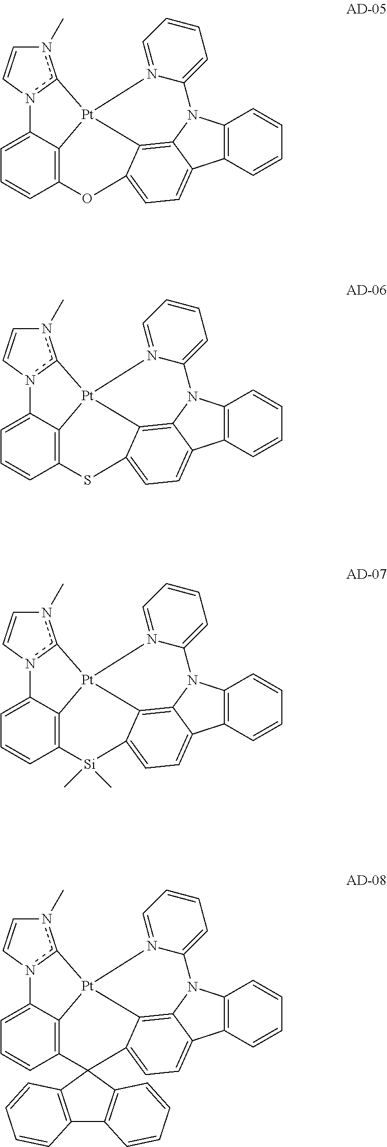

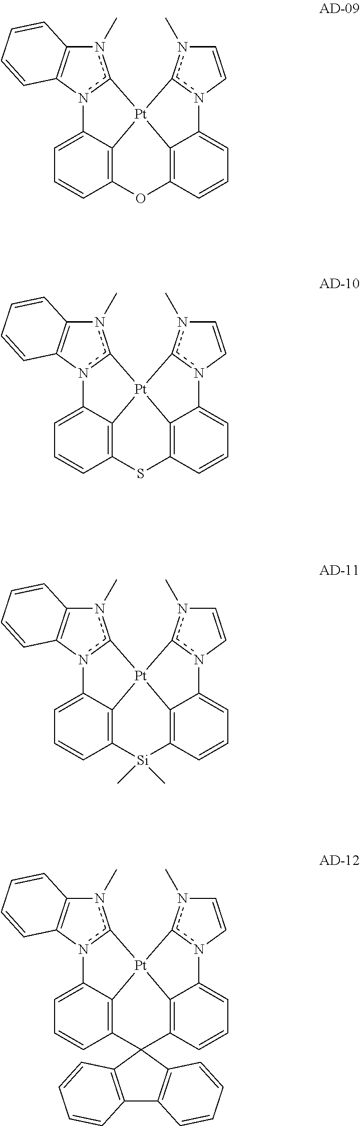

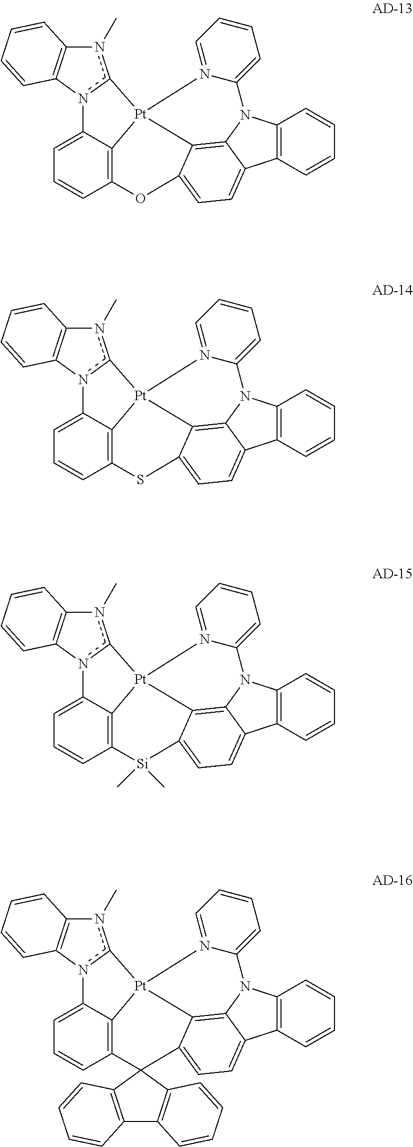

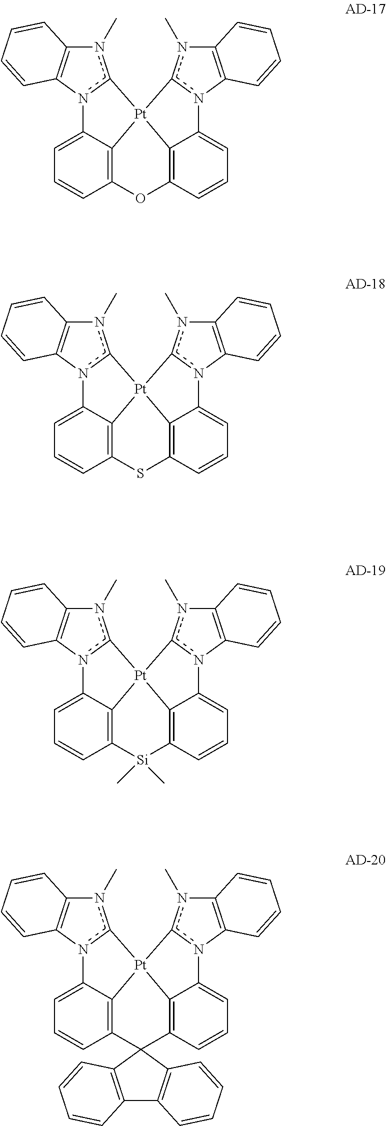

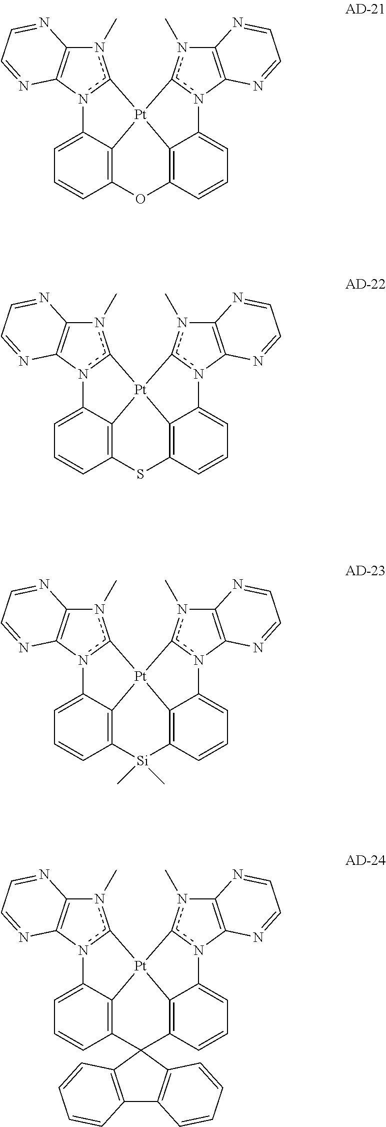

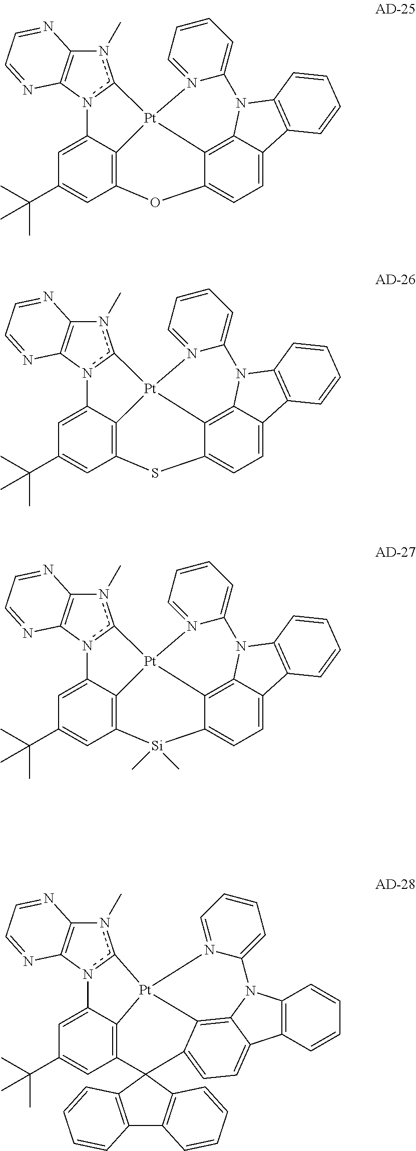

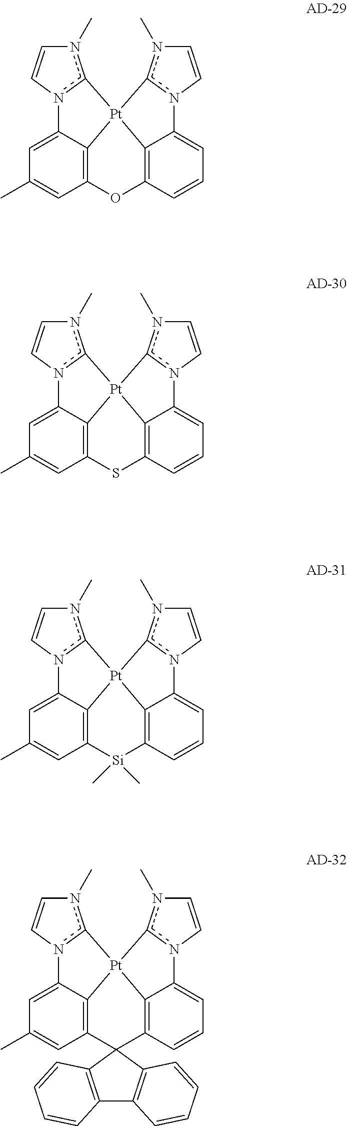

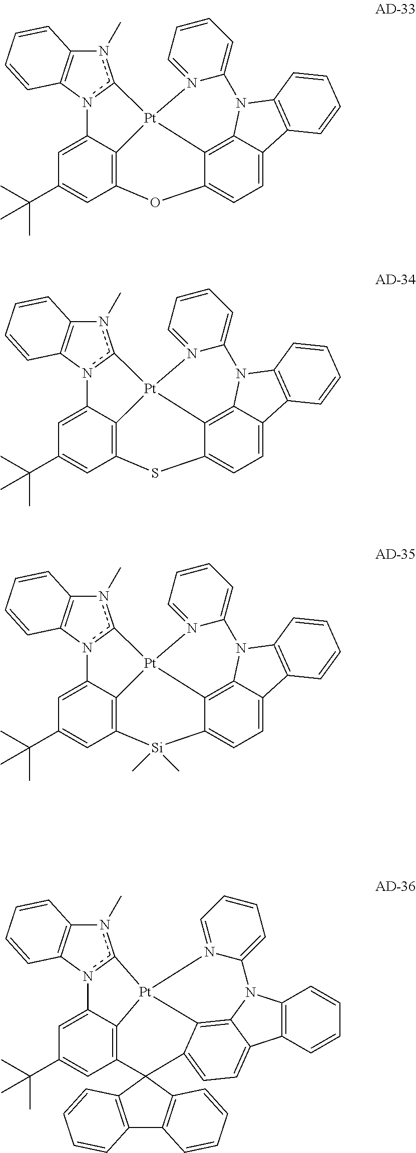

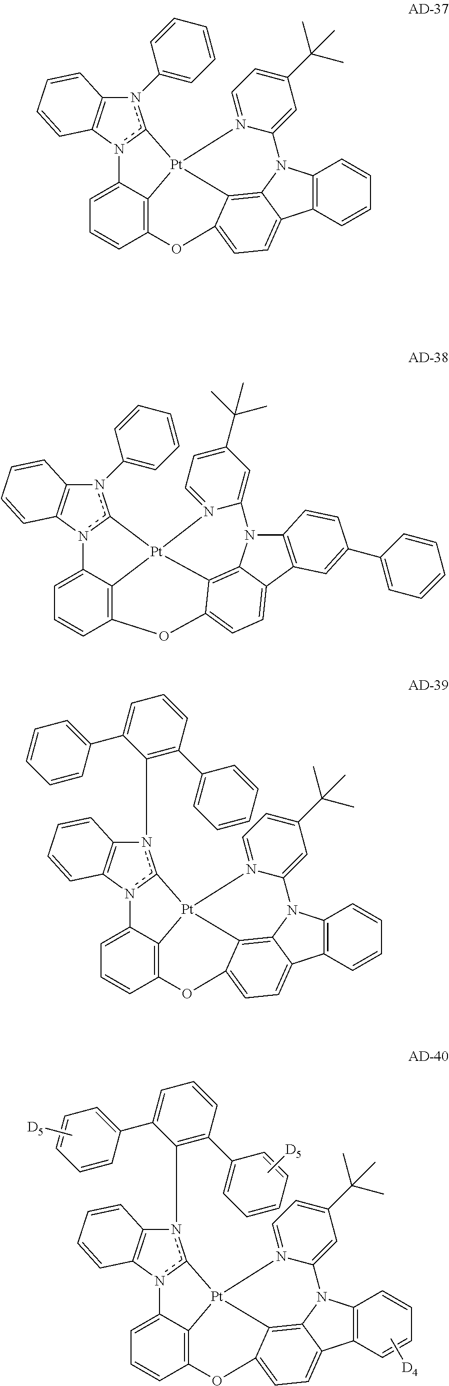

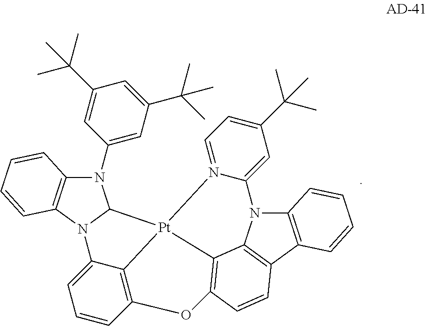

In Compound Group 4, “D” represents a deuterium atom.

In an embodiment, in the light emitting element ED, when the emission layer EML includes the first compound, the second compound, and the third compound, an amount of the first compound may be in a range of about 0.1 wt % to about 5 wt %, based on a total weight of the first compound, the second compound, and the third compound. However, embodiments are not limited thereto. When an amount of the first compound satisfies the range described above, energy transfer from the second compound and the third compound to the first compound may increase, and thus luminous efficiency and device service life may increase.

In the emission layer EML, a combined amount of the second compound and the third compound may be the remainder of the total weight of the first compound, the second compound, and the third compound, excluding the amount of the first compound. For example, a combined amount of the second compound and the third compound in the emission layer EML may be in a range of about 65 wt % to about 95 wt % based on a total weight of the first compound, the second compound, and the third compound.

Within the combined amount of the second compound and the third compound, a weight ratio of the second compound to the third compound may be in a range of about 3:7 to about 7:3.

When the amounts of the second compound and the third compound satisfy the above-described ranges and ratios, charge balance characteristics in the emission layer EML may be improved, and thus luminous efficiency and device service life may increase. When the amounts of the second compound and the third compound deviate from the above-described ranges and ratios, charge balance in the emission layer EML may not be achieved, and thus luminous efficiency may be reduced and the device may readily deteriorate.

When the emission layer EML includes the fourth compound, an amount of the fourth compound in the emission layer EML may be in a range of about 4 wt % to about 30 wt %, based on a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that an emission ratio may be improved, and thus luminous efficiency of the emission layer EML may be improved. When the first compound, the second compound, the third compound, and the fourth compound included in the emission layer EML satisfy the above-described ranges and ratios, excellent luminous efficiency and long service life may be achieved.

The emission layer EML may be provided on the hole transport region HTR. The emission layer EML may have a thickness in a range of, for example, about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

In each light-emitting element ED as shown in each of FIG. 5 to FIG. 9, the emission layer EML may further include the above-described polycyclic compound according to an embodiment as a dopant. In an embodiment, in the light-emitting element ED as shown in each of FIG. 5 to FIG. 9, the emission layer EML may include a first compound, which is the polycyclic compound and may further include at least one of a second compound represented by Formula HT-1 and a third compound represented by Formula ET-1. In an embodiment, in the light-emitting element ED as shown in each of FIG. 5 to FIG. 9, the emission layer EML may include the first compound which is the polycyclic compound, the second compound represented by Formula HT-1, the third compound represented by Formula ET-1, and the fourth compound represented by Formula D-1.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In each light emitting element ED according to embodiments illustrated in FIGS. 5 to 9, the emission layer EML may further include a host and dopant of the related art in addition to the above-described host and dopant, and for example the emission layer EML may include a compound represented by Formula E-1. The compound represented by Formula E-1 may be used as a fluorescent host material.

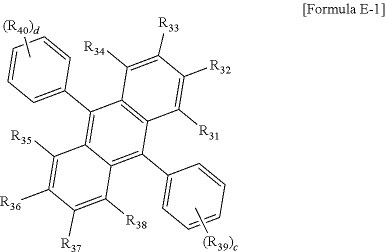

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

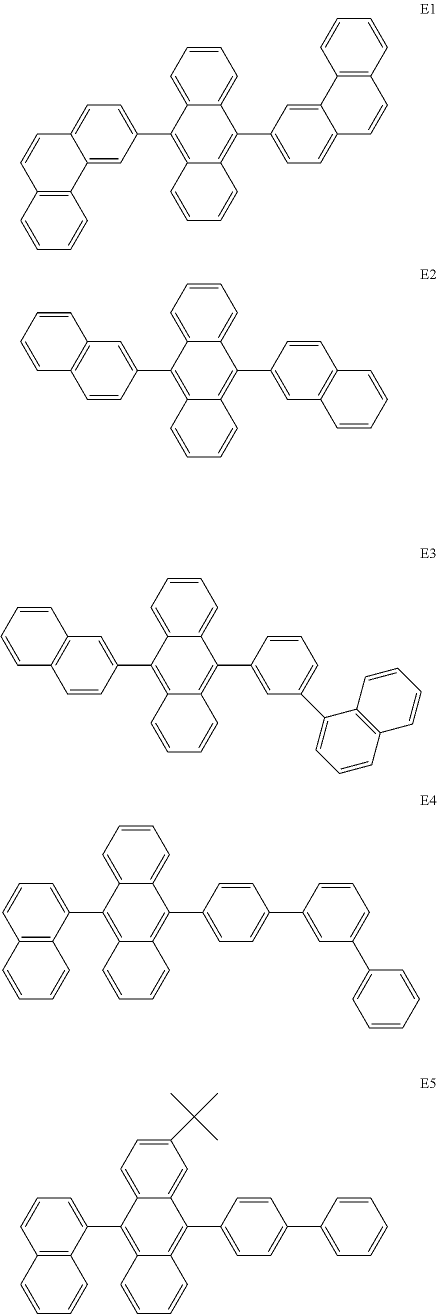

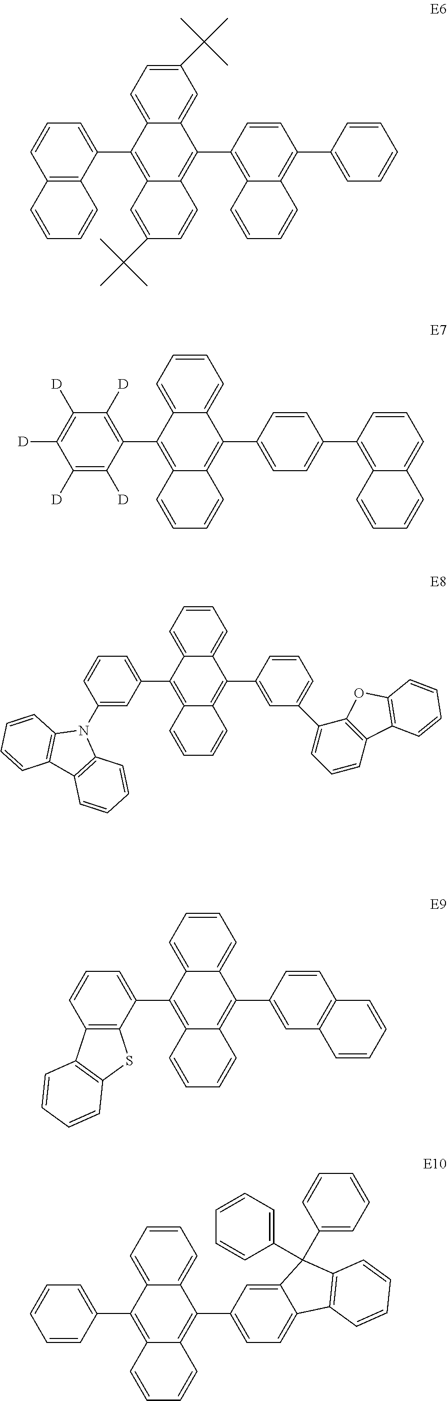

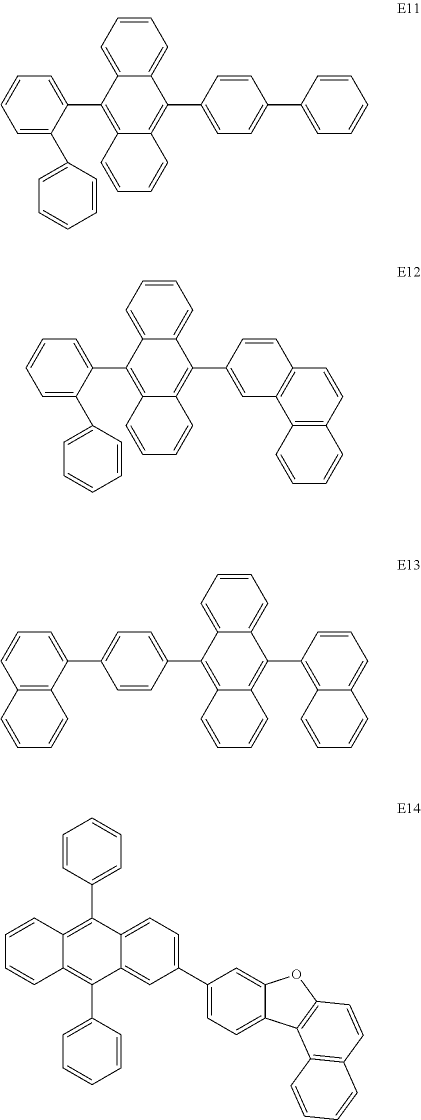

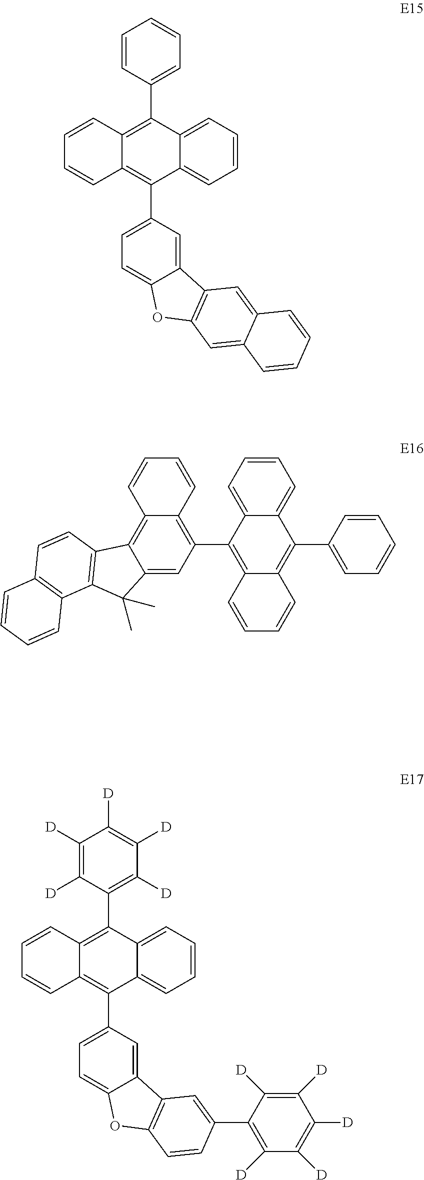

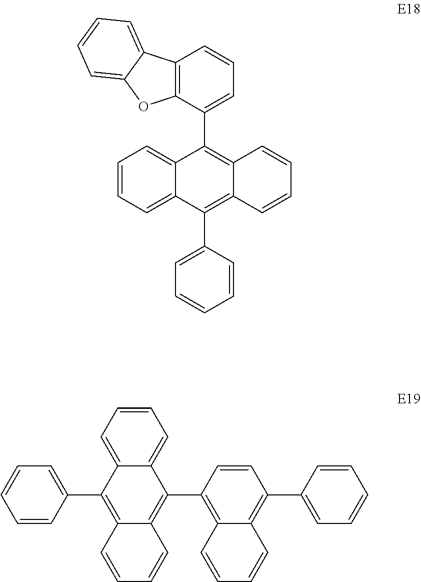

In an embodiment, the emission layer EML may include a compound represented by Formula E-2a or Formula E-2b. The compound represented by Formula E-2a or Formula E-2b may be used as a host material for a phosphorescent light-emitting element.

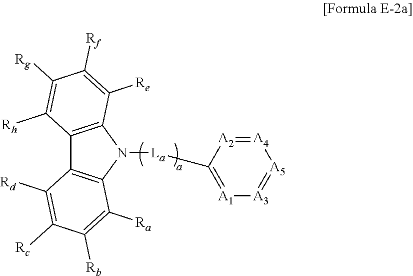

In Formula E-2a, a may be an integer from 0 to 10, and L₄ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₈ may each independently be N or C(Rᵢ). In Formula E-2a, R^{a} to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R^{a} to Rᵢ may be bonded to an adjacent group to form a hydrocarbon ring or a heterocycle containing N, O, S, etc., as a ring-forming atom.

In Formula E-2a, two or three of A₁ to A₈ may be N, and the remainder of A₁ to A₅ may each independently be C(Rᵢ).

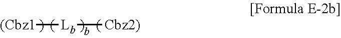

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} is a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} may each independently be a substituted or unsubstituted arylene group having 6 to 30 ring-forming carbon atoms, or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 below are only examples, and the compound represented by Formula E-2a or Formula E-2b is not limited to Compound Group E-2.

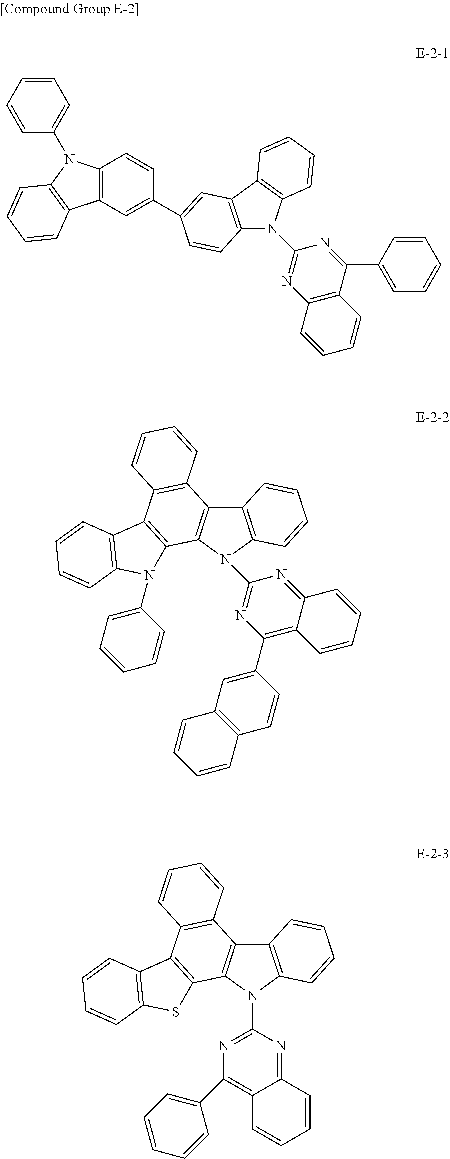 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

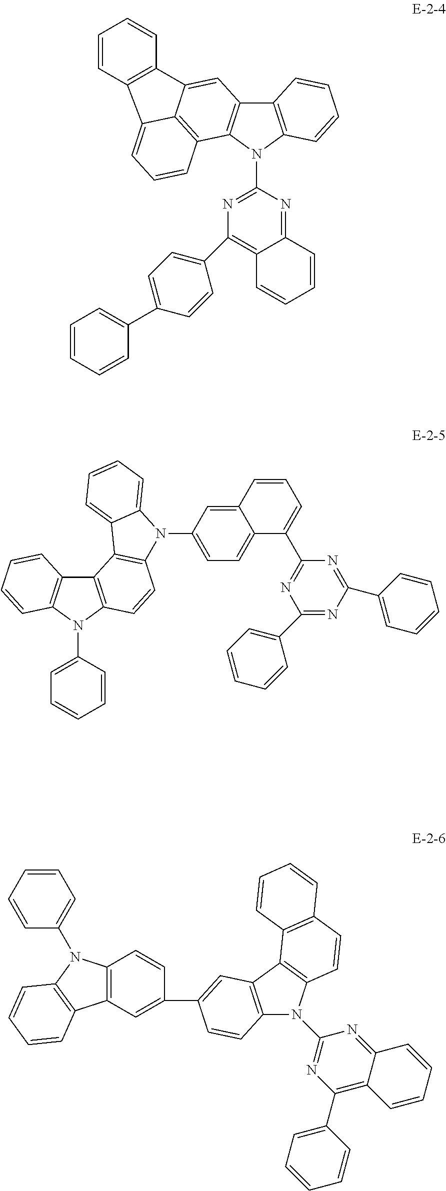 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

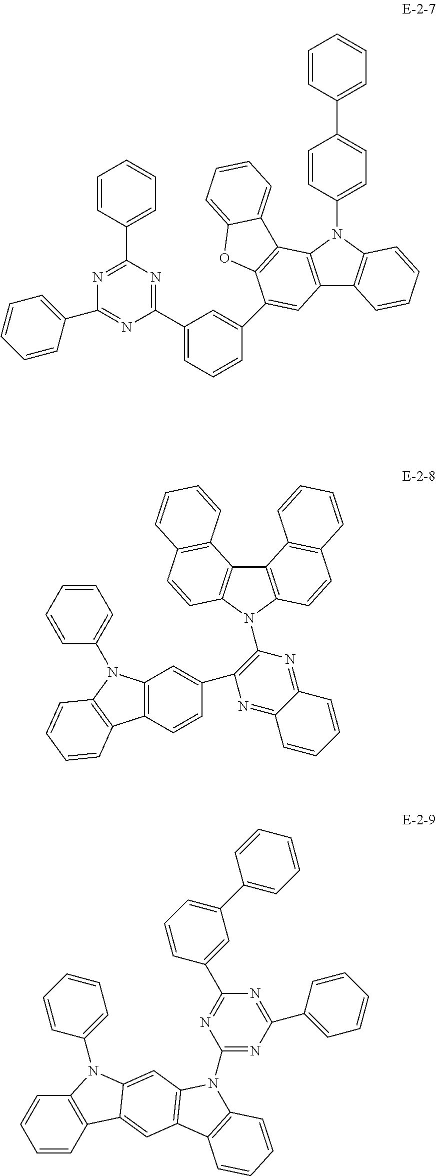 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

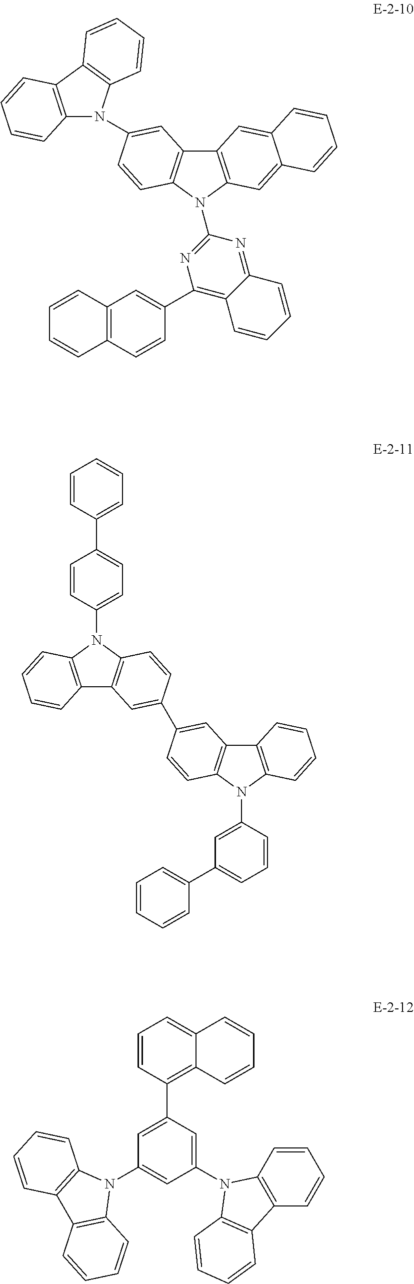 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

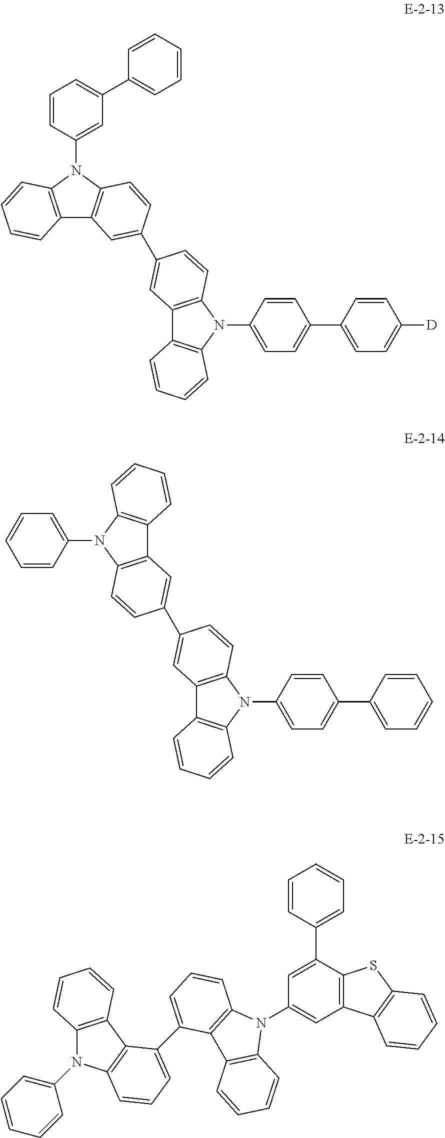 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

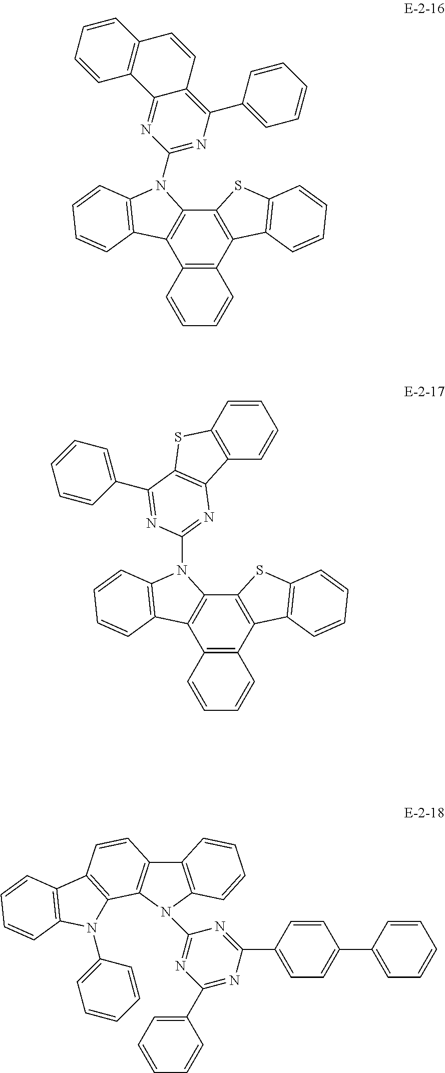 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

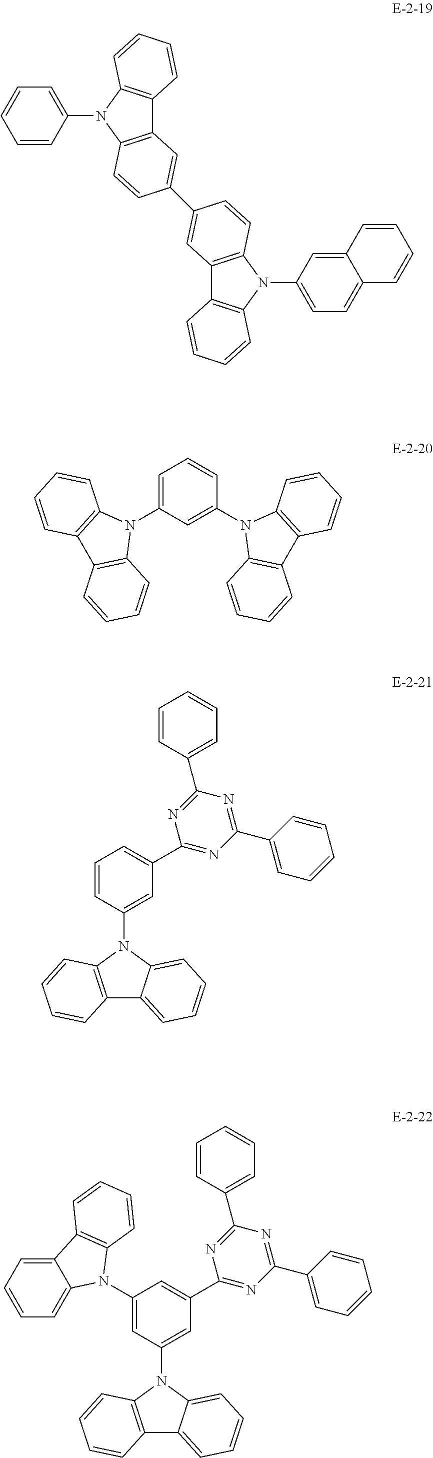 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

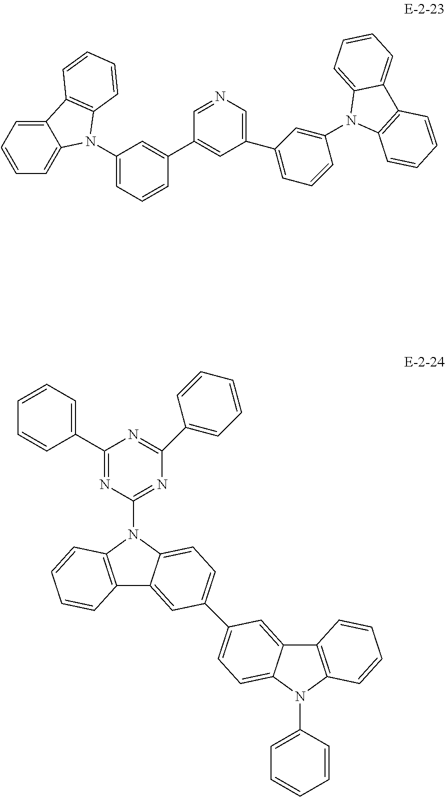 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In an embodiment, the emission layer EML may include the compound represented by Formula M-a. The compound represented by Formula M-a may be used as a phosphorescent dopant material.

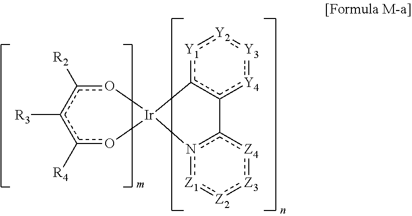

In Formula M-a, Y₁ to Y₄ and Z₁ to Z₄ may each independently be C(R₁) or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

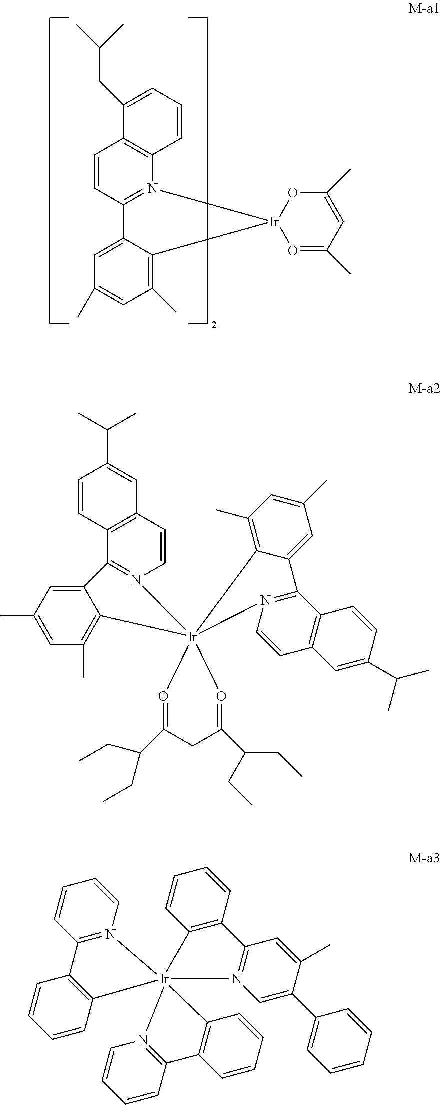

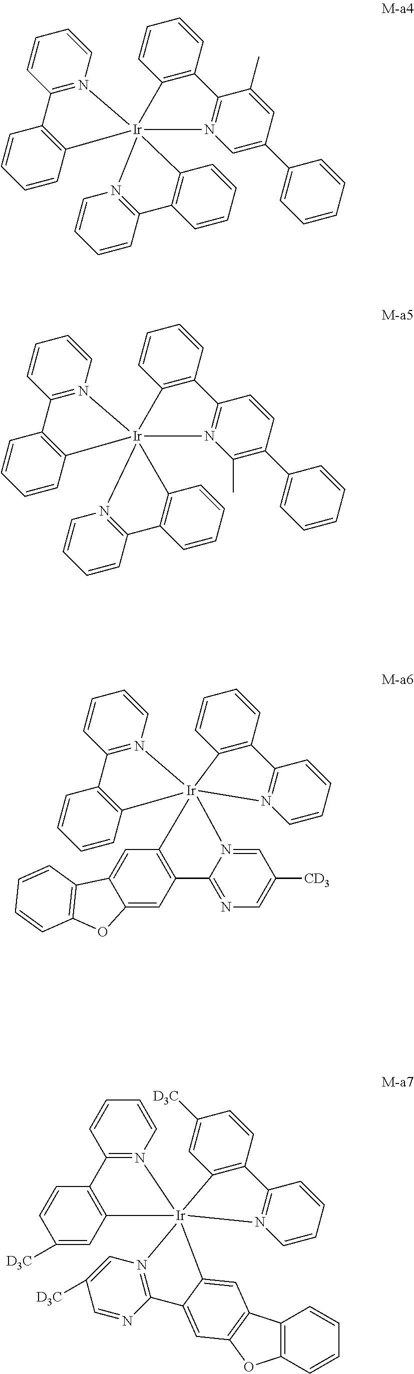

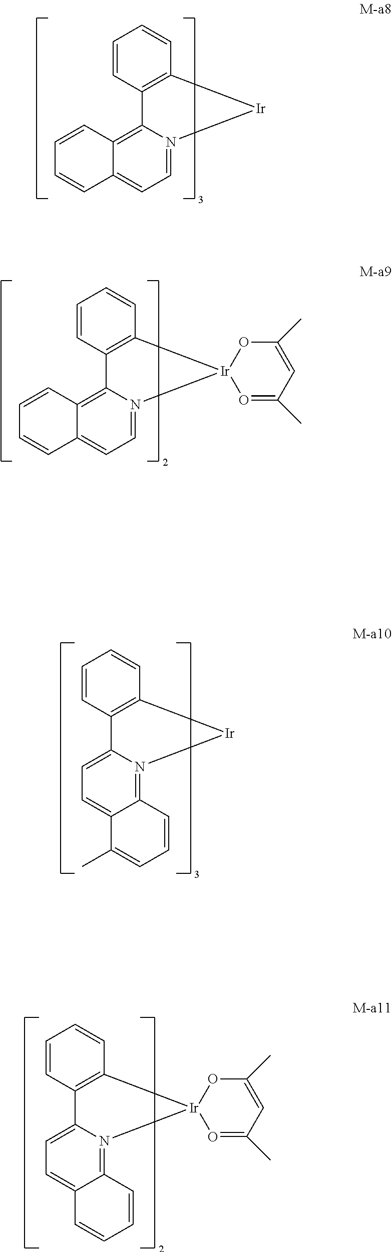

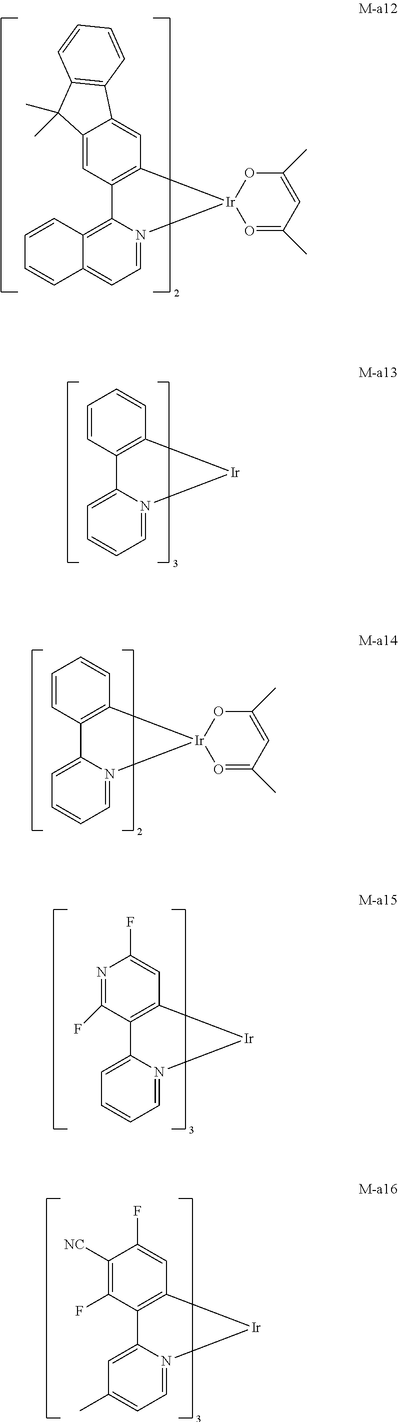

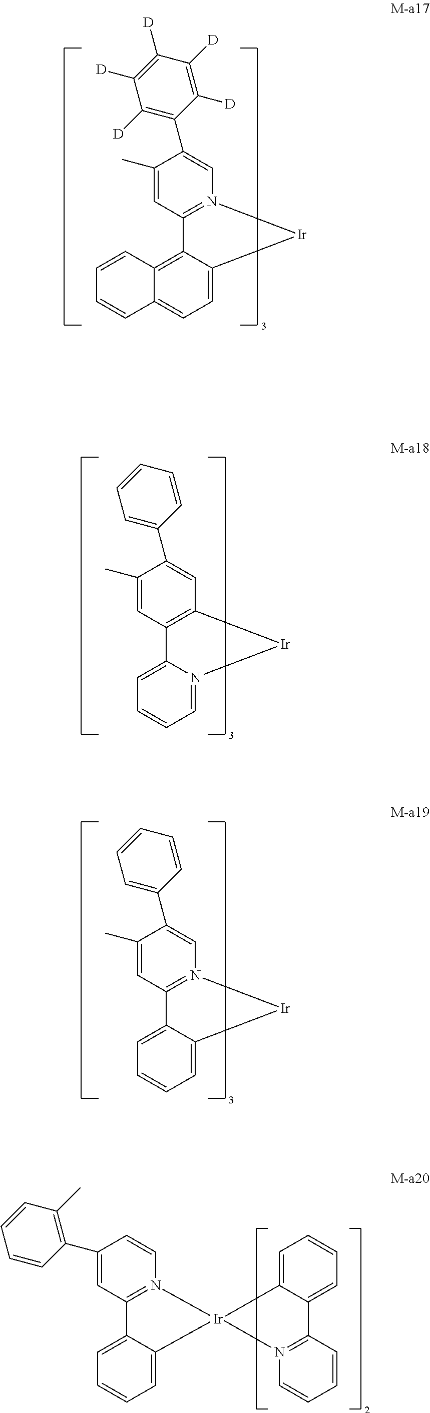

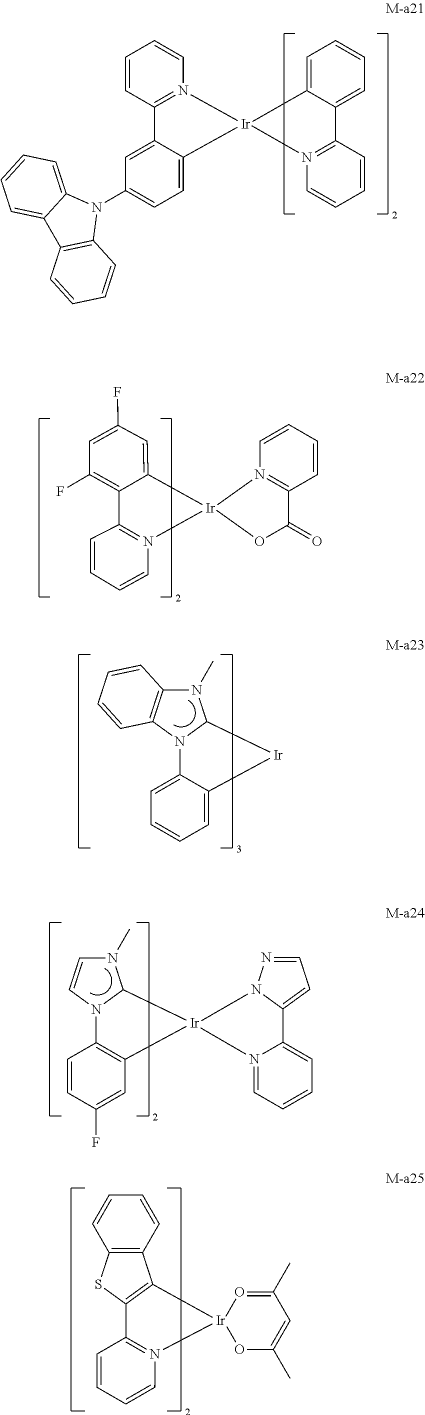

In an embodiment, the emission layer EML may include a compound represented by any one of Formula F-a to Formula F-c. The compound represented by Formula F-a to Formula F-c may be used as a fluorescent dopant material.

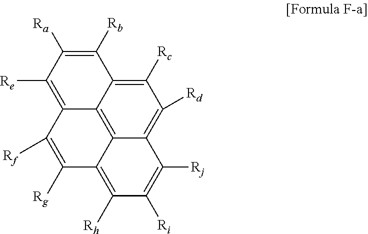

In Formula F-a, two of R^{a} to Rⱼ may each independently be substituted with a group [symbol] represented by [symbol] . The remainder of R^{a} to Rⱼ, that are not substituted with a group represented by [symbol] , may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by [symbol] , Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ and Ar₂ may be a heteroaryl group containing O or S as a ring-forming atom.

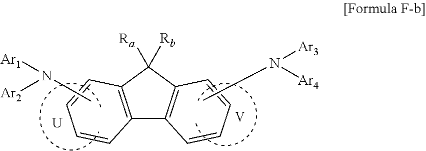

In Formula F-b, R^{a} and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core in Formula F-b may be a cyclic compound having four rings. When U and V is each 0, a fused ring in Formula F-b may be a cyclic compound having three rings. When U and V is each 1, a fused ring having a fluorene core in Formula F-b may be a cyclic compound having five rings.

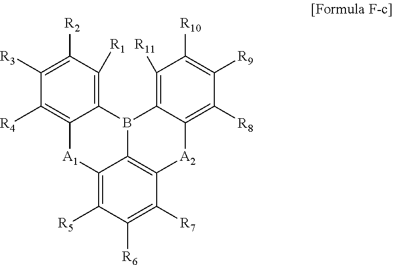

In Formula F-c, A₁ and A₂ may each independently be O, S, Se, or N(Rₘ), and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to substituents of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), gold (Au), titanium (T1), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, the emission layer EML may include a quantum dot material. The quantum dot may include a Group II-VI compound, a Group II-VI compound, a Group I-III-VI compound, a Group II-V compound, a Group III-II-V compound, a Group IV-VI compound, a Group IV element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof.

Examples of a Group III-VI compound may include: a binary compound such as In₂S₃ or In₂Se₃; a ternary compound such as InGaS₃ or InGaSe₃, and any combination thereof.

Examples of a Group I-III-VI compound may include a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP, etc.

Examples of a Group IV-VI compound may include a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof.

Examples of a Group IV element may include Si, Ge, and a mixture thereof. Examples of a Group IV compound may include a binary compound such as SiC, SiGe, and a mixture thereof.

Each element included in a compound such as a binary compound, a ternary compound, or a quaternary compound may be present in a particle at a uniform concentration distribution or at a non-uniform concentration distribution. For example, a formula may indicate elements that are included in a compound, but an elemental ratio in the compound may vary. For example, AgInGaS₂ may mean AgInₓGa₁₋ₓS₂ (wherein x is a real number between 0 to 1).

In an embodiment, the quantum dot may have a single structure or a core-shell structure in which the concentration of each element included in the quantum dot is uniform. For example, a material included in the core may be different from a material included in the shell.

The shell of the quantum dot may serve as a protection layer to prevent the chemical deformation of the core to maintain semiconductor properties, and/or may serve as a charging layer to impart electrophoresis properties to the quantum dot. The shell may be single-layered or multilayered. An interface between the core and the shell may have a concentration gradient in which the concentration of an element present in the shell becomes lower towards the core.

A shell of the quantum dots may include a metal oxide, a non-metal oxide, a semiconductor compound, or any combination thereof. Examples of a metal oxide and a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of a light emitting wavelength spectrum less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. The color purity or color reproducibility may be improved in any of the above ranges. Light emitted through a quantum dot may be emitted in all directions so that a wide viewing angle may be improved.

The form of the quantum dot may be a form used in the related art, but embodiments are not limited thereto. For example, a quantum dot may have a spherical form, a pyramidal form, a multi-arm form, or a cubic form, or a quantum dot may be in the form of nanoparticles, nanotubes, nanowires, nanofibers, nanoplate particles, etc.

As a size of a quantum dot is adjusted or an elemental ratio in the quantum dot compound is adjusted, it is possible to control the energy band gap, and thus light in various wavelength ranges may be obtained in the quantum dot emission layer. Therefore, utilizing the quantum dot as described above (using different sizes of quantum dots or different elemental ratios in the quantum dot compound) the light emitting element, may emit light in various wavelengths. The adjustment of the size of the quantum dot or the elemental ratio in the quantum dot compound may be selected to emit red, green, and/or blue light. In an embodiment, the quantum dots may be configured to emit white light by combining various colors of light.

In the light emitting elements ED according to embodiments as shown in each of FIGS. 5 to 9, the electron transport region ETR may be provided on the emission layer EML. The electron transport region ETR may include at least one of a hole blocking layer HBL, an electron transport layer ETL, or an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material and an electron transport material. The electron transport region ETR may have a single-layered structure including different materials.

In embodiments, the electron transport region ETR may have a structure in which an electron transport layer ETL/electron injection layer EIL, a hole blocking layer HBL/electron transport layer ETL/electron injection layer EIL are stacked in order from the emission layer EML, but embodiments are not limited thereto. The electron transport region ETR may have a thickness in a range, for example, of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the electron transport region ETR may include a compound represented by Formula ET-2:

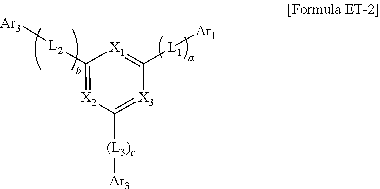

In Formula ET-2, at least one of X₁ to X₃ is N, and the remainder of X₁ to X₃ may each independently be C(R^{a}). R^{a} may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiples of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include a compound selected from Compound Group 3.

In an embodiment, the electron transport region ETR may include at least one

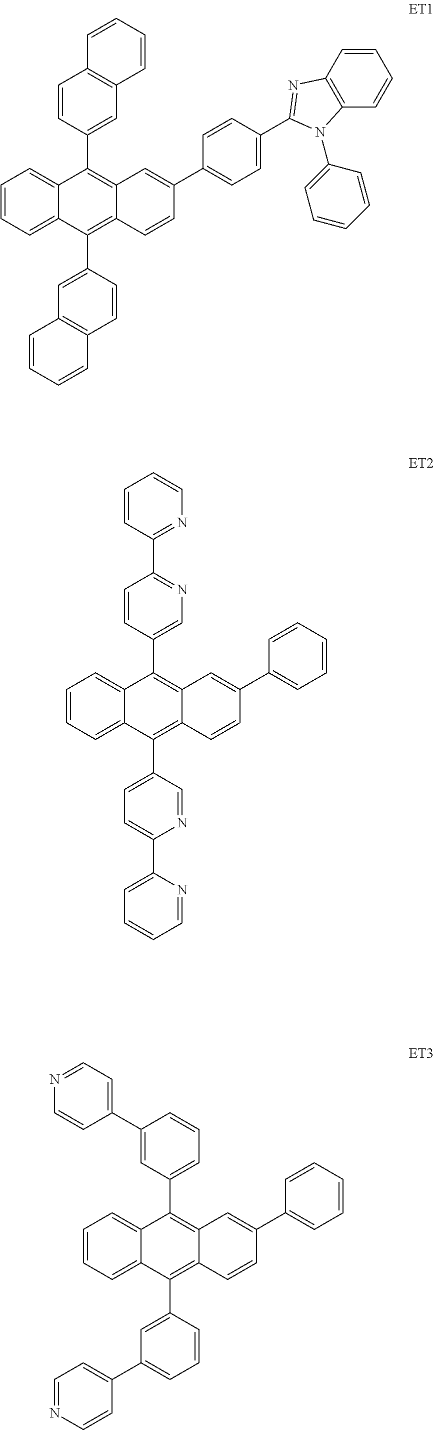 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

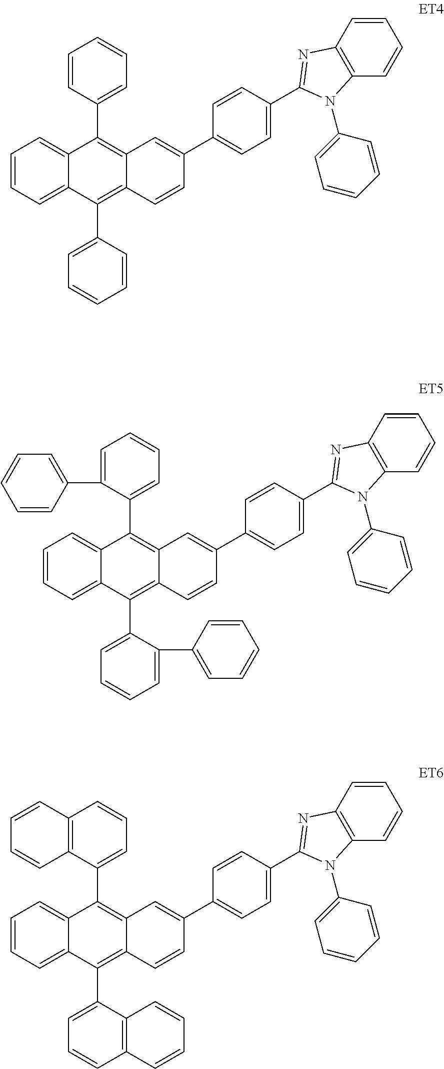 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

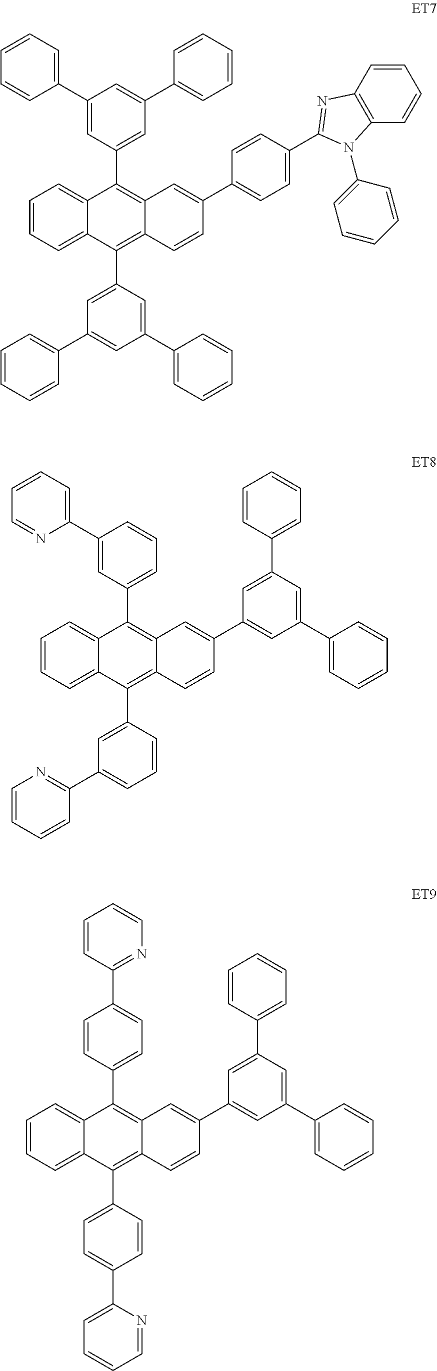 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

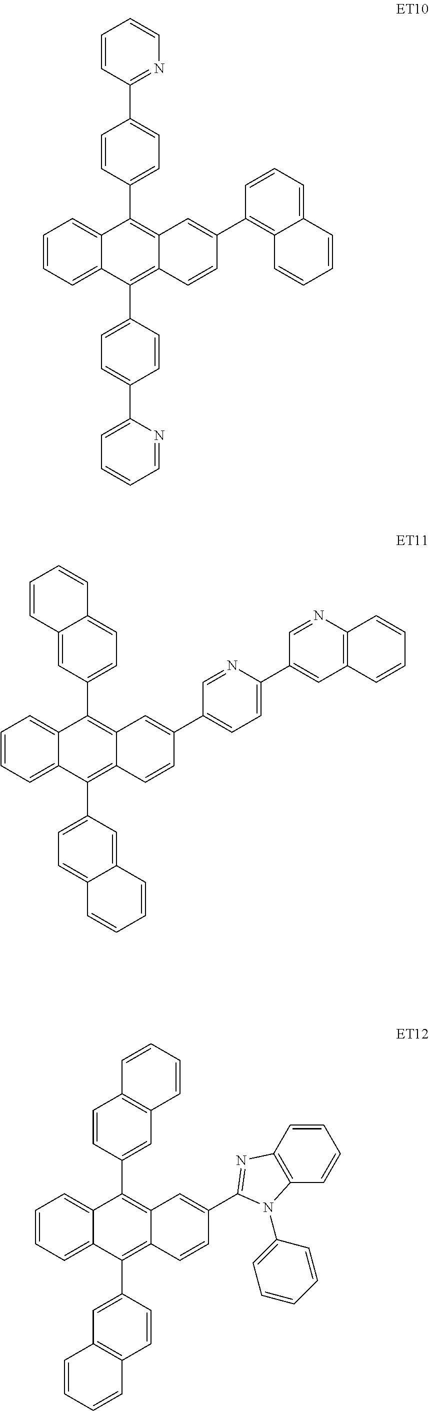 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

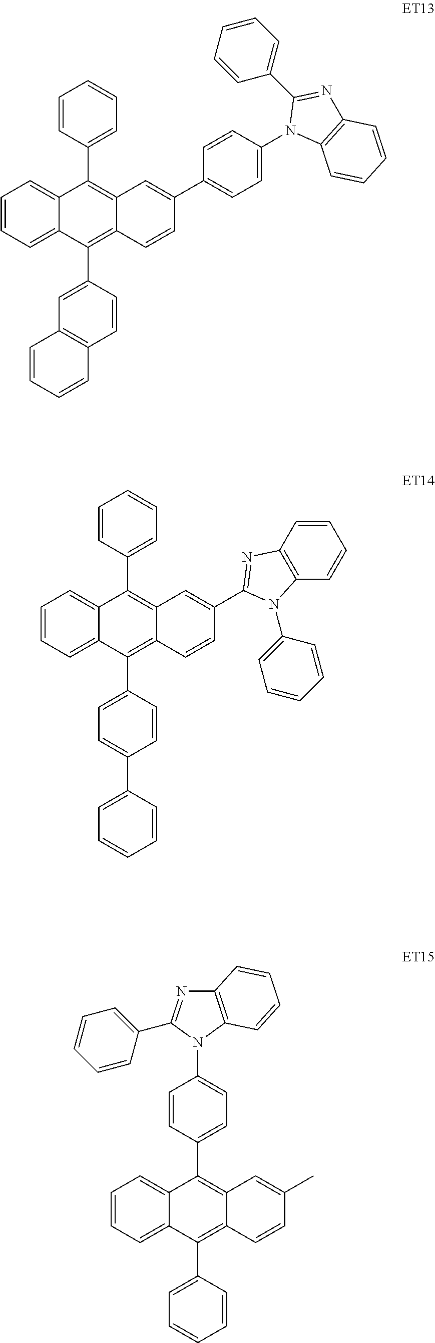 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

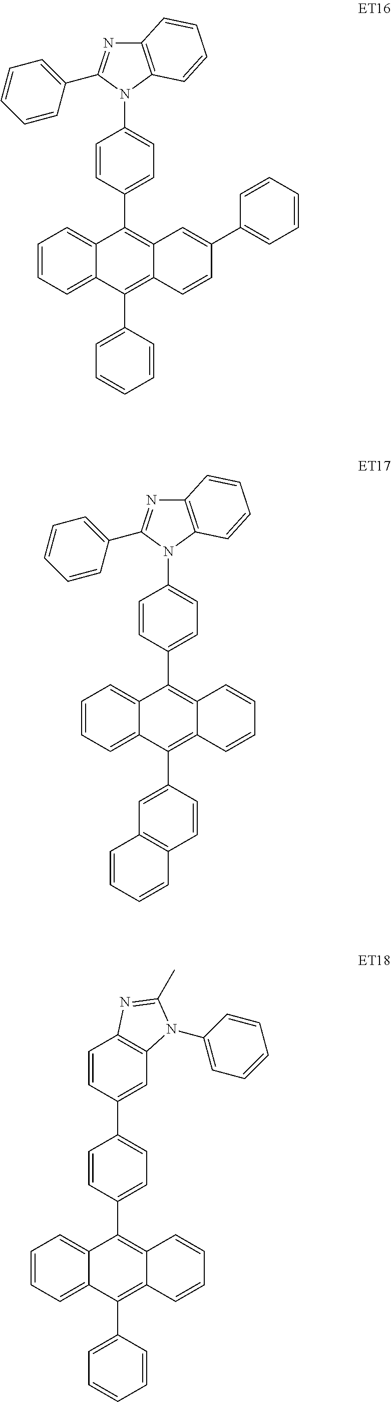 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

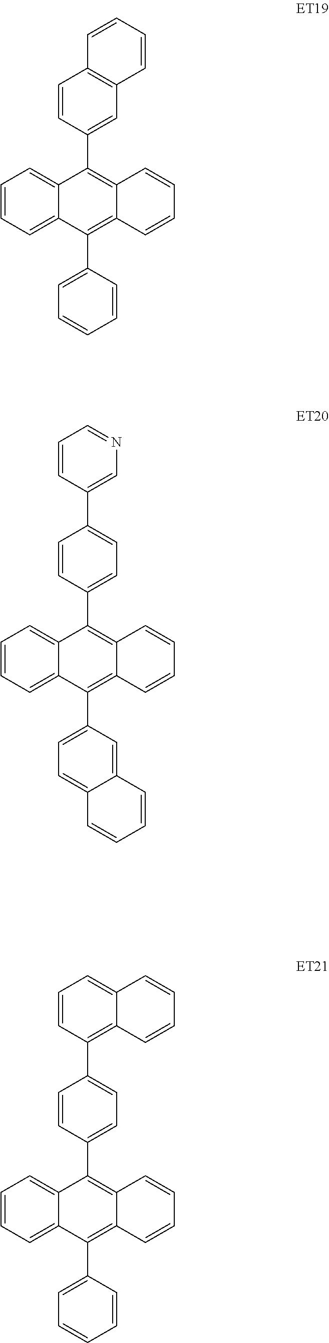

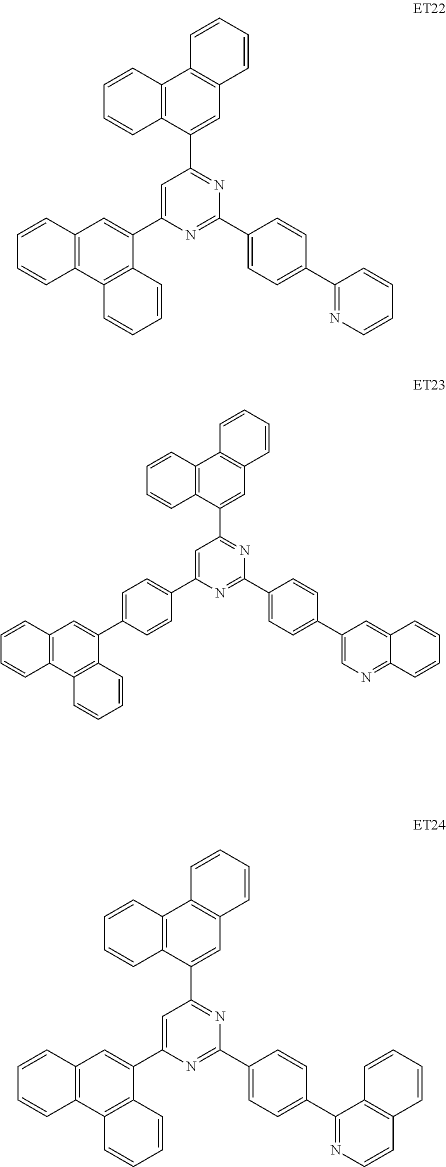 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

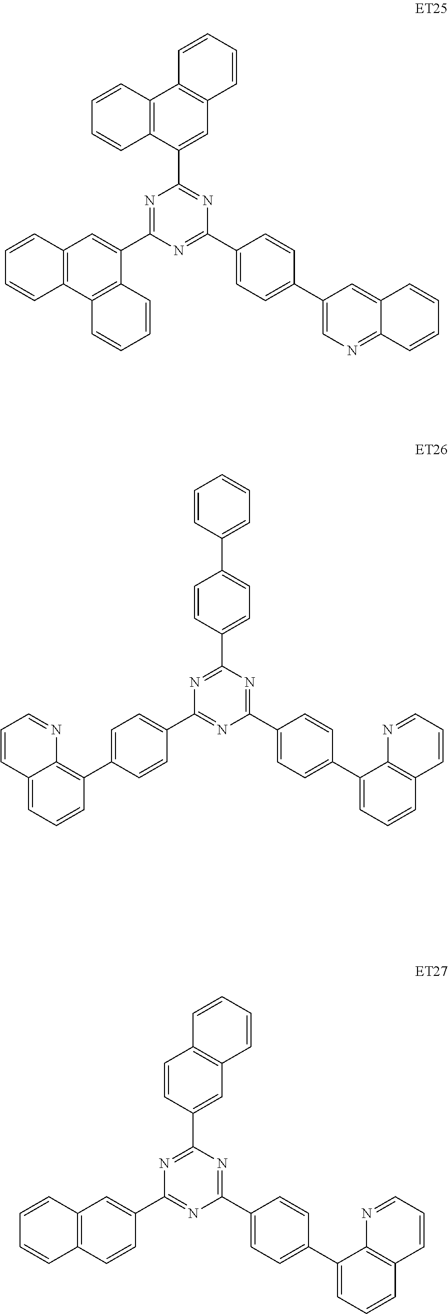 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

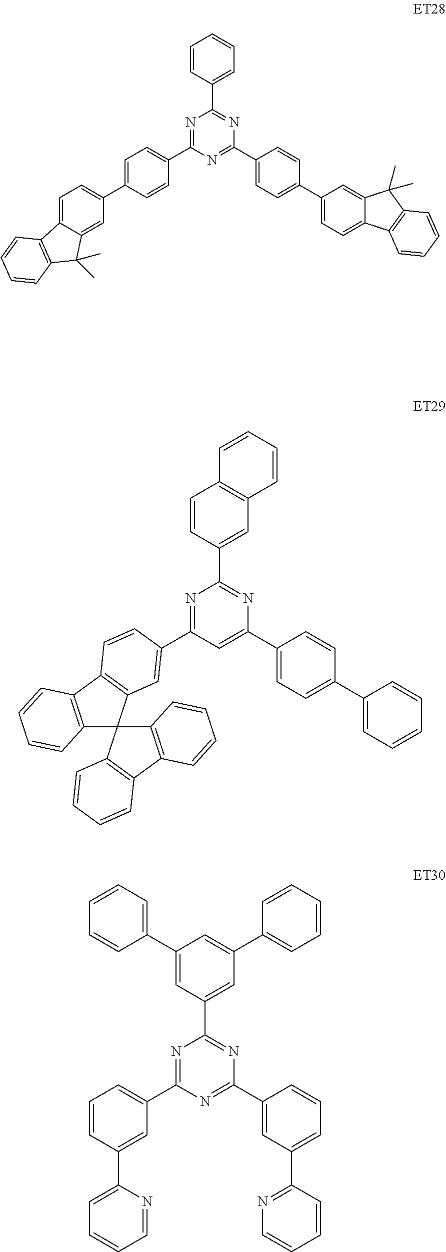 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

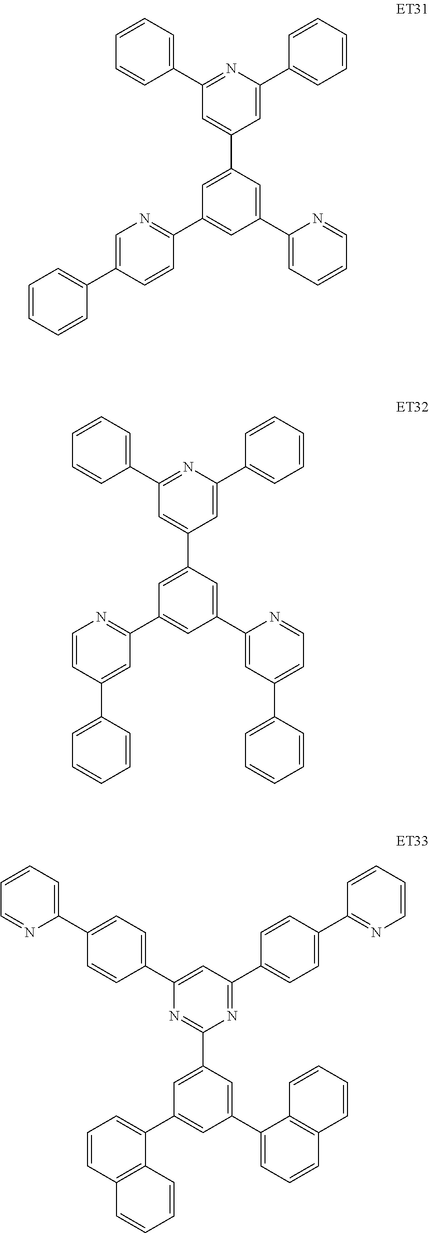 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

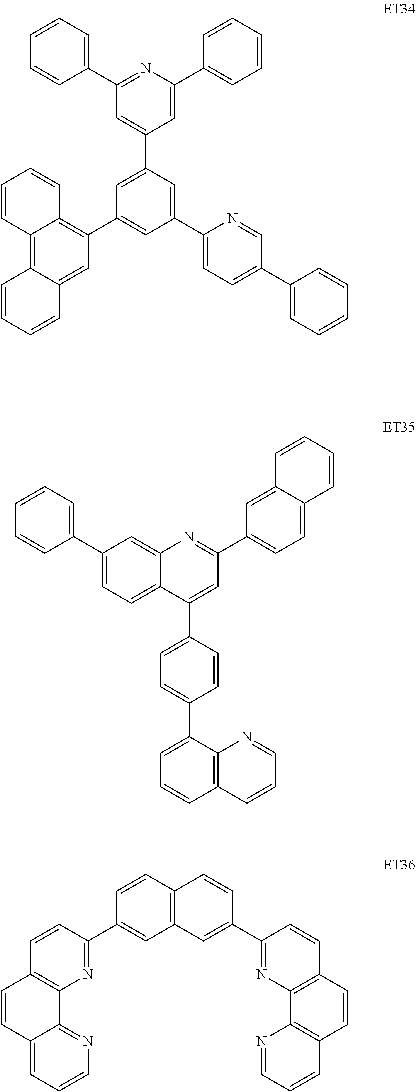 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI, a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may be formed using a metal oxide such as Li₂O or BaO, or 8-hydroxyl-lithium quinolate (Lig), etc., but embodiments are not limited thereto. In another embodiment, the electron transport region ETR may also include a mixture material of an electron transport material and an insulating organometallic salt. The organometallic salt may be a material having an energy band gap greater than or equal to about 4 eV. For example, the organometallic salt may include, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the hole transport region in at least one of the electron injection layer EIL, the electron transport layer ETL, or the hole blocking layer HBL.

When the electron transport region ETR includes an electron transport layer ETL, the electron transport layer ETL may have a thickness in a range of about 100 Å to about 1,000 Å. For example, the thickness of the electron transport layer ETL may be in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the thickness of the EIL may be in a range of about 3 Å to about 90 Å. If the thickness of the electron injection layer EIL satisfies any of the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is connected to an auxiliary electrode, resistance of the second electrode EL2 may be decreased.

In an embodiment, in the light emitting element ED, a capping layer CPL may further be disposed on the second electrode EL2. The capping layer CPL may have a multilayered structure or a single-layered structure.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

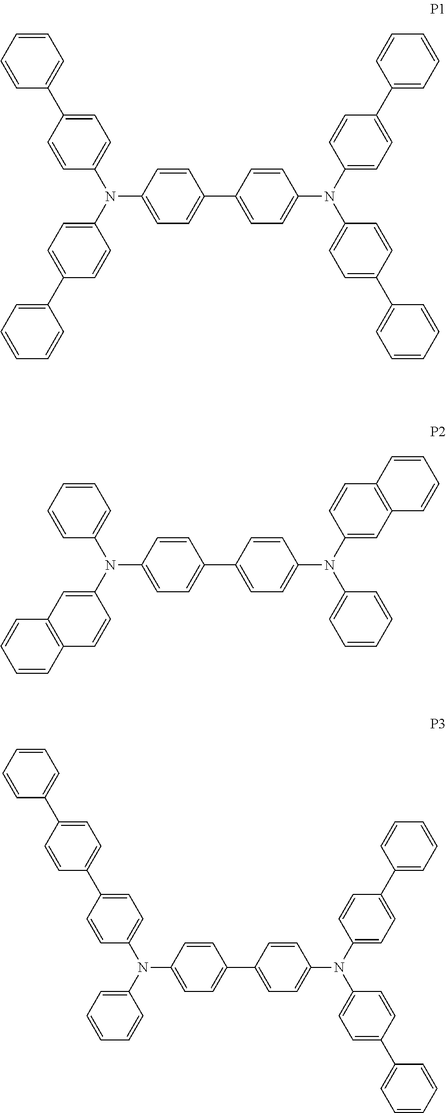 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

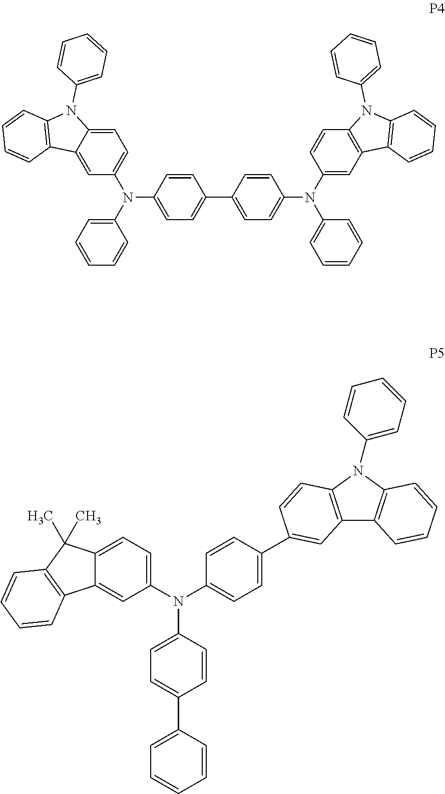 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be greater than or equal to 1.6. The refractive index of the capping layer CPL may be greater than or equal to about 1.6 with respect to light in a wavelength range of about 550 nm to about 660 nm.

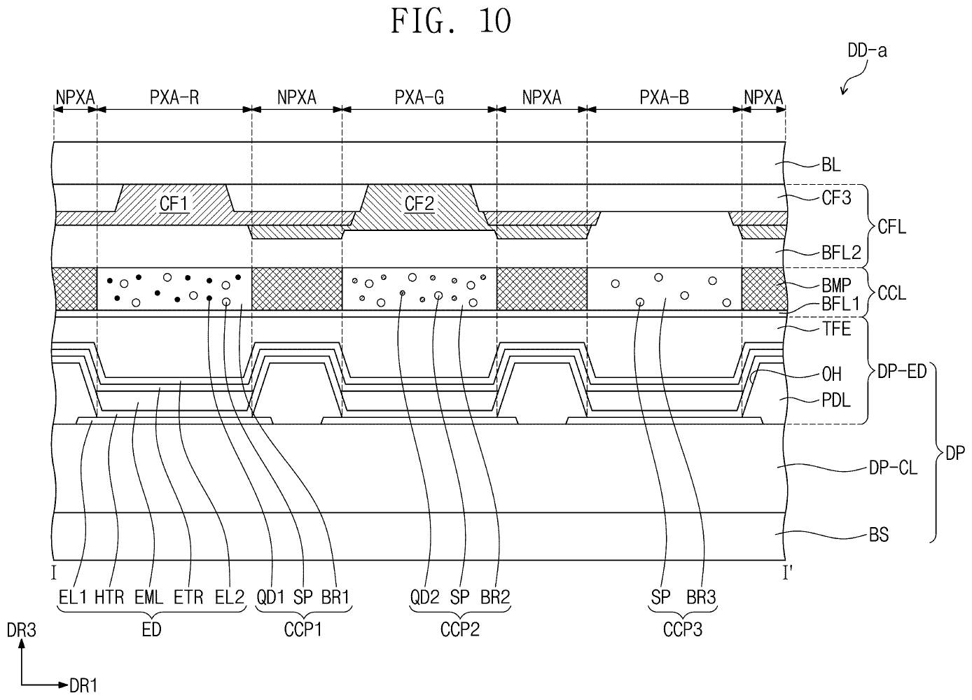

Each of FIGS. 10 to 13 are each a schematic cross-sectional view of a display device according to an embodiment. Hereinafter, in describing the display devices according to embodiments as shown in FIGS. 10 to 13, the duplicated features that have been described above with respect to FIGS. 3 to 9 are not described again, but differing features will be described.

Referring to FIG. 10, the display device DD-a according to an embodiment may include a display panel DP including a display device layer DP-ED, a light control layer CCL disposed on the display panel DP, and a color filter layer CFL. In an embodiment shown in FIG. 10, the display panel DP may include a base layer BS, a circuit layer DP-CL provided on the base layer BS, and the display device layer DP-ED, and the display device layer DP-ED may include a light emitting element ED.

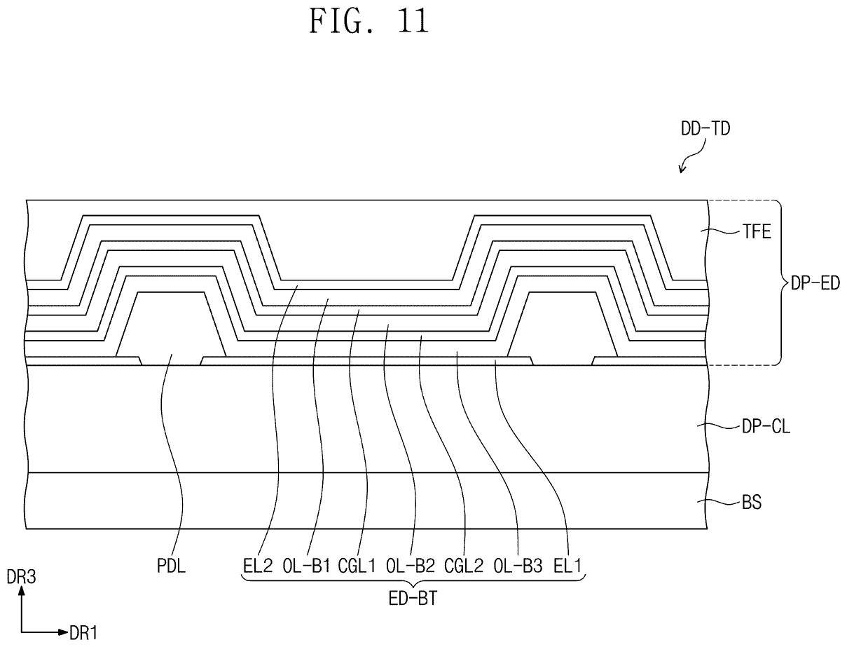

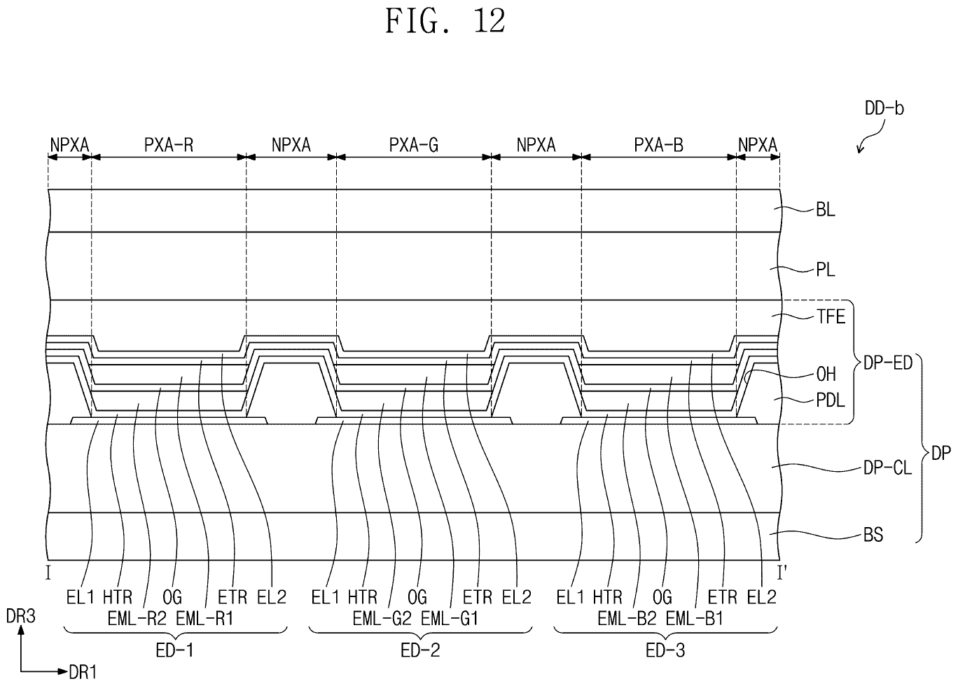

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 11 may be a same structure of the light emitting elements according to one of FIGS. 5 to 9 as described above. The light-emitting element ED illustrated in FIG. 10 may include the polycyclic compound according to an embodiment. Therefore, the light-emitting element ED may exhibit characteristics of high efficiency and long lifespan.

Referring to FIG. 10, the emission layer EML may be disposed in an opening OH defined in a pixel defining film PDL. For example, the emission layer EML which is separated by the pixel defining film PDL and provided to correspond to each of the light emitting regions PXA-R, PXA-G, and PXA-B may emit light in a same wavelength range. In the display device DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may emit light by converting a wavelength thereof. For example, the light control layer CCL may be a layer that includes the quantum dot or a layer that includes the phosphor.

The light control layer CCL may include multiple light control parts CCP1, CCP2 and CCP3. The light control parts CCP1, CCP2, and CCP3 may be spaced apart from each other.

Referring to FIG. 10, divided patterns BMP may be disposed between the light control parts CCP1, CCP2 and CCP3 which are spaced apart from each other, but embodiments are not limited thereto. In FIG. 10, it is shown that the divided patterns BMP do not overlap the light control parts CCP1, CCP2 and CCP3, but the edges of the light control parts CCP1, CCP2 and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may provide blue light that transmits the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include one of TiO₂, ZnO, Al₂O₃, SiO₂, and hollow sphere silica, or may be a mixture of at least two materials selected from TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may be medium in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resins. In an embodiment, the first base resin BR1, the second base resin BR2, and the third base resin BR3 may be the same as or different from each other.

The barrier layers BFL1 and BFL2 may each independently include at least one inorganic layer. For example, the barrier layers BFL1 and BFL2 may include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may be formed of a single layer or multiple layers.

In the display device DD-a according to an embodiment, the color filter layer CFL may be disposed on the light control layer CCL. For example, the color filter layer CFL may be disposed (e.g., directly disposed) on the light control layer CCL. In an embodiment, the barrier layer BFL2 may be omitted.

The color filter layer CFL may include filters CF1, CF2, and CF3. The first to third filters CF1, CF2, and CF3 can be arranged to so that they respectively correspond to a red light-emitting region PXA-R, a green light-emitting region PXA-G, and a blue light-emitting region PXA-B.

The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may be a yellow filter. The first filter CF1 and the second filter CF2 may not be provided as separate filters and may be provided as one filter.

Although not shown in the drawings, the color filter layer CFL may further include a light shielding part (not shown). The light shielding part may be a black matrix. The light shielding part (not shown) may include an organic light shielding material or an inorganic light shielding material containing a black pigment or dye. The light shielding part (not shown) may prevent light leakage, and may separate boundaries between the adjacent filters CF1, CF2, and CF3.

A base substrate BL may be disposed on the color filter layer CFL. The base substrate BL may provide a base surface in which the color filter layer CFL, the light control layer CCL, and the like are disposed. The base substrate BL may be a glass substrate, a metal substrate, a plastic substrate, etc. However, embodiments are not limited thereto, and the base substrate BL may be an inorganic layer, an organic layer, or a composite material layer. Although not shown in the drawings, in an embodiment, the base substrate BL may be omitted.

FIG. 11 is a schematic cross-sectional view of a portion of a display device according to an embodiment. In the display device DD-TD according to an embodiment, the light emitting element ED-BT may include light emitting structures OL-B1, OL-B2, and OL-B3. At least one of the emission structures OL-B1, OL-B2, and OL-B3 may include the polycyclic compound according to an embodiment. Therefore, the light-emitting element ED-BT may exhibit characteristics of high efficiency and long lifespan.

The light emitting element ED-BT may include a first electrode EL1 and a second electrode EL2 that face each other, and the light emitting structures OL-B1, OL-B2, and OL-B3 stacked in a thickness direction between the first electrode EL1 and the second electrode EL2. The light emitting structures OL-B1, OL-B2, and OL-B3 each may each include a hole transport region HTR (FIG. 10), an emission layer EML (FIG. 10), and an electron transport region ETR (FIG. 10 which may be disposed in that order between the first electrode EL1 and the second electrode EL2.

For example, the light emitting element ED-BT included in the display device DD-TD may be a light emitting element having a tandem structure and that includes multiple emission layers.

In an embodiment shown in FIG. 11, light emitted from the light emitting structures OL-B1, OL-B2, and OL-B3 may each be blue light. However, embodiments are not limited thereto, and the light emitted from the light emitting structures OL-B1, OL-B2, and OL-B3 may each have wavelength ranges that are different from each other. For example, the light emitting element ED-BT that includes the light emitting structures OL-B1, OL-B2, and OL-B3 which emit light having wavelength ranges different from each other may each emit white light.

Charge generation layers CGL1 and CGL2 may each be disposed between two adjacent light emitting structures among the light emitting structures OL-B1, OL-B2, and OL-B3. The charge generation layers CGL1 and CGL2 may each independently include a p-type charge generation layer and/or an n-type charge generation layer.

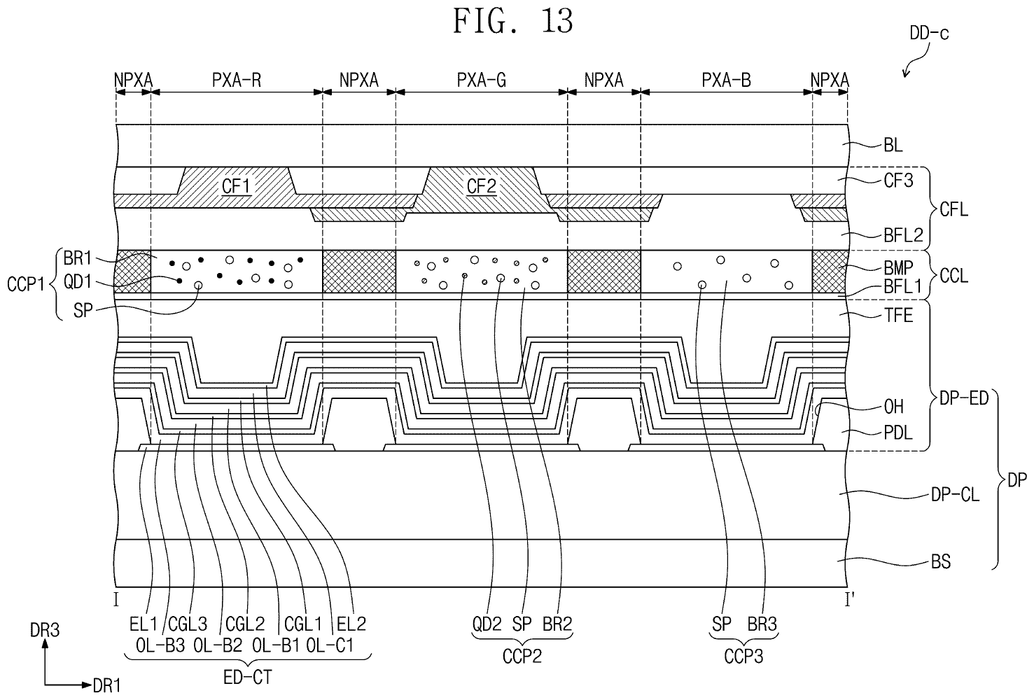

Referring to FIG. 12, the display device DD-b according to an embodiment may include light emitting elements ED-1, ED-2, and ED-3 in which two emission layers are stacked. At least one among the light-emitting elements ED-1, ED-2, and ED-3 may include the polycyclic compound according to an embodiment. Therefore, the light-emitting element ED-BT may exhibit characteristics of high efficiency and long lifespan.

In comparison to the display device DD illustrated in FIG. 4, the embodiment illustrated in FIG. 12 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region which may be stacked in that order. The emission auxiliary part OG may be provided as a common layer for the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R₁, the first green emission layer EML-G1, and the first blue emission layer EML-B1 may each be disposed between the emission auxiliary part OG and the electron transport region ETR. The second red emission layer EML-R₂, the second green emission layer EML-G2, and the second blue emission layer EML-B2 may be disposed between the hole transport region HTR and the emission auxiliary part OG.

For example, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2 which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 which are stacked in that order.

An optical auxiliary layer PL may be disposed on the display device layer DP-ED. The optical auxiliary layer PL may include a polarizing layer. The optical auxiliary layer PL may be disposed on the display panel DP and control reflected light in the display panel DP from an external light. Although not shown in the drawings, the optical auxiliary layer PL in the display device DD-b may be omitted.

At least one emission layer included in a display device DD-b shown in FIG. 12 may include the polycyclic compound according to an embodiment as described above. For example, at least one of the first blue emission layer EML-B1 or the second blue emission layer EML-B2 may include the polycyclic compound according to an embodiment.

In contrast to FIGS. 11 and 12, FIG. 13 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 may be stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The charge generation layers CGL1, CGL2, and CGL3 disposed between adjacent light emitting structures OL-B1, OL-B2, OL-B3, and OL-C1 may each independently include a p-type charge generation layer and/or an n-type charge generation layer.

In an embodiment, at least one of the light emitting structures OL-B1, OL-B2, OL-B3, and OL-C1 included in the display device DD-c may include the polycyclic compound according an embodiment as described above. For example, in an embodiment, at least one of the first to third light emitting structures OL-B1, OL-B2, and OL-B3 may each include the polycyclic compound according to an embodiment as described above.

The light emitting element ED represented by Formula 1 described above according to an embodiment includes the polycyclic compound according to an embodiment in at least one functional layer disposed between the first electrode EL1 and the second electrode EL2, and may thus exhibit excellent light emitting efficiency and improved lifespan. For example, the polycyclic compound according to an embodiment may be included in the emission layer EML of the light emitting element ED, and the light emitting element may exhibit long lifespan.

In an embodiment, the electronic device may include a display device that includes multiple light emitting elements, and a control part which controls the display device. The electronic device may be a device that is activated according to an electrical signal. The electronic device may include display devices according to various embodiments. Examples of an electronic device may include large-sized, medium-sized, and small-sized electronic apparatuses such as a television set, a monitor, a billboard, a personal computer, a laptop computer, a personal digital terminal, a display device for a vehicle, a game console, a portable electronic device, smart watch, and a camera.

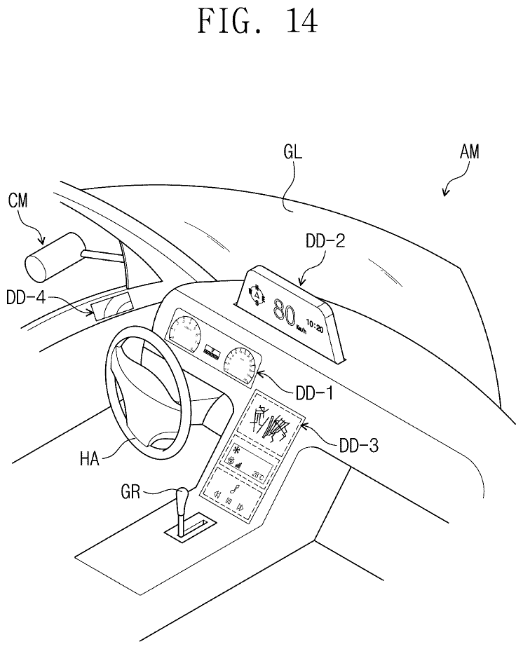

FIG. 14 is a schematic diagram of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c as described above with reference to FIGS. 3, 4, and 10 to 13.

FIG. 14 shows a vehicle AM, but this is only an example, and the first to fourth display devices DD-1, DD-2, DD-3, and DD-4 may be disposed in various transportation means such as a bicycle, a motorcycle, a train, a ship, and an airplane. In an embodiment, at least one of the first to fourth display devices DD-1, DD-2, DD-3, and DD-4 may have a structure according to one of display devices DD, DD-TD, DD-a, DD-b, and DD-c may be employed in a personal computer, a laptop computer, a personal digital terminal, a game console, a portable electronic device, a television, a monitor, a billboard, or the like. Herein, these are merely provided as examples, and the display devices may be included in other electronic devices.

At least one of the first to fourth display devices DD-1, DD-2, DD-3, and DD-4 may each independently include the light emitting element ED according to an embodiment as described with reference to any of FIGS. 5 to 9. The light emitting element ED may include a polycyclic compound according to an embodiment. At least one of the first to fourth display devices DD-1, DD-2, DD-3, or DD-4 includes the light emitting element ED containing the polycyclic compound according to an embodiment, and may thus have increased display lifetime.

Referring to FIG. 14, the vehicle AM may include a steering wheel HA and a gear GR for driving the vehicle AM. The vehicle AM may include a front window GL disposed so as to face the driver.

The first display device DD-1 may be disposed in a first region that overlaps the steering wheel HA. For example, the first display device DD-1 may be a digital cluster which displays first information of the vehicle AM. The first information may include a first scale which indicates a driving speed of the vehicle AM, a second scale which indicates an engine speed (for example, revolutions per minute (RPM)), an image that represents a fuel gauge, etc. A first scale and a second scale may each be represented as a digital image.

The second display device DD-2 may be disposed in a second region facing the driver's seat that overlaps the front window GL. The driver's seat may be a seat in which the steering wheel HA is disposed. For example, the second display device DD-2 may be a head up display (HUD) which displays second information of the vehicle AM. The second display device DD-2 may be optically transparent. The second information may include digital numbers which indicate a driving speed, and may further include information such as the current time. Although not shown in the drawings, the second information of the second display device DD-2 may be displayed by being projected on the front window GL.

The third display device DD-3 may be disposed in a third region that is adjacent to the gearshift GR. For example, the third display device DD-3 may be disposed between the driver's seat and the passenger seat and may be a center information display (CID) for a vehicle for displaying third information. The passenger seat may be a seat spaced apart from the driver's seat with the gearshift GR disposed therebetween. The third information may include information about traffic conditions (e.g., navigation information), about music or radio that is playing, about a video (or an image) that is displayed, about temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror which displays fourth information. The fourth display device DD-4 may display an image outside the vehicle AM taken by a camera module CM that is disposed outside the vehicle AM. The fourth information may include an external image of the vehicle AM.

The first to fourth information are only examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include a same information.

Hereinafter, a polycyclic compound according to an embodiment and a light-emitting element according to an embodiment will be described in detail with reference to the Examples and the Comparative Examples. The examples shown below are only provided to facilitate understanding the disclosure, and the scope thereof is not limited thereto.

### EXAMPLES

### 1. Synthesis of Polycyclic Compounds According to Embodiments

A synthetic method of a polycyclic compound according to an embodiment will be described in detail by describing synthesis methods for Compounds 31, 33, 35, 40, 46, 56, and 91. In the following descriptions, the synthesis method of the polycyclic compound is provided as an example, but the synthesis method of the compound according to an embodiment is not limited to the Examples.

### (1) Synthesis of Compound 31

Compound 31 may be synthesized by, for example, Reaction Scheme 1.

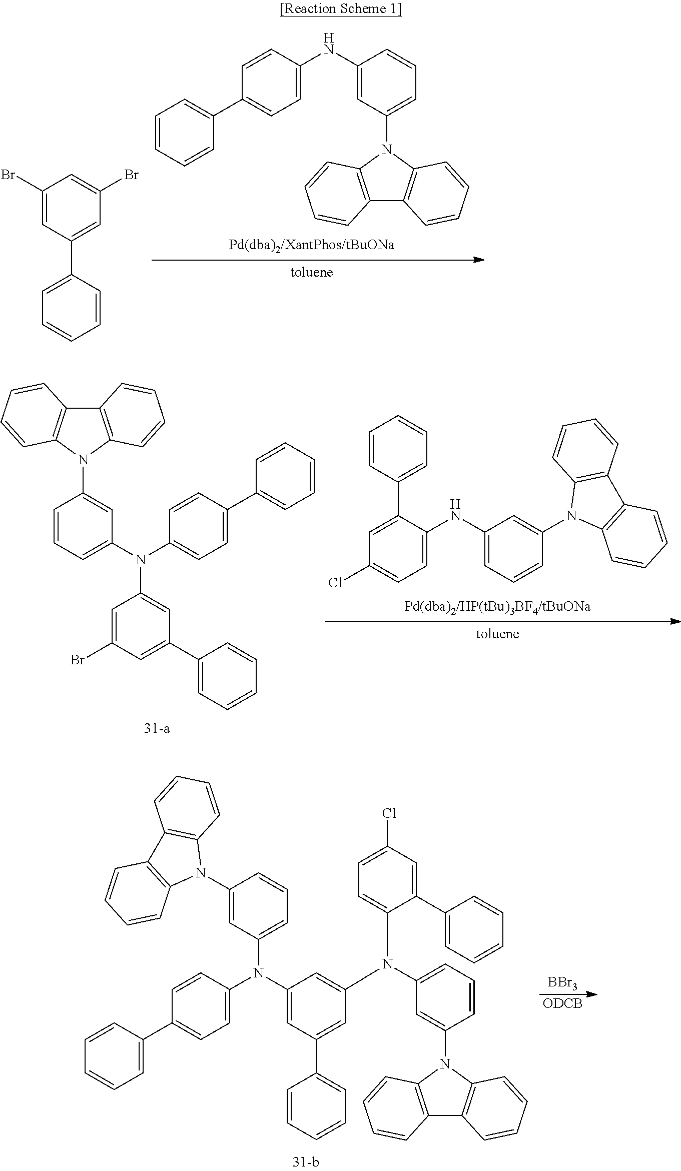

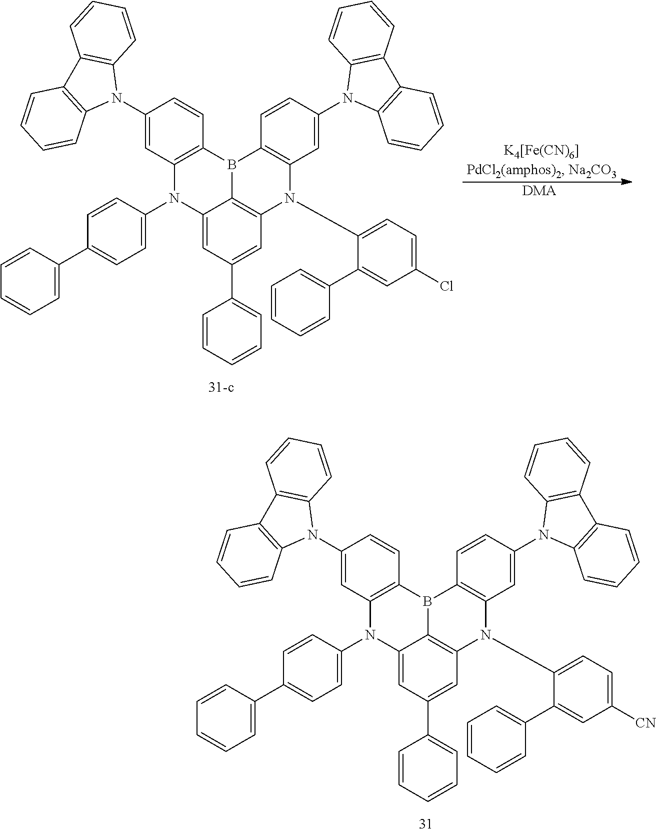

### 1) Synthesis of Intermediate 31-a

3,5-dibromo-1,1′-biphenyl 15 g, N-(3-(9H-carbazol-9-yl)phenyl)-[1,1′-biphenyl]-4-amine 24 g, bis(dibenzylideneacetone)palladium(0) (Pd(dba)₂) 1.3 g, Xantphos 2.7 g, sodium t-butoxide(tBuONa) 6.0 g, and toluene 240 mL were added in a 500 mL of two-neck flask, and the mixture was heated and stirred at 120° C. for 3 hours. The obtained reaction solution was filtered through Celite, concentrated, and purified by column chromatography (eluent: dichloromethane/hexane=1/4) to obtain 26 g of white solid (yield of 83%). By FAB-MS measurement of the obtained product, m/z=642 was observed, and thus it was identified that the white solid was Intermediate 31-a.

### 2) Synthesis of Intermediate 31-b

Intermediate 31-a of 25 g, N-(3-(9H-carbazol-9-yl)phenyl)-5-chloro-[1,1′-biphenyl]-2-amine of 21 g, bis(dibenzylideneacetone)palladium(0) of 1.1 g, HP(tBu)₃BF₄ of 1.1 g, sodium t-butoxide of 4.9 g, and toluene 200 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=3/1) to obtain 24 g of white solid (yield of 62%). By FAB-MS measurement of the obtained product, m/z=1006 was observed, and thus it was identified that the white solid was Intermediate 31-b.

### 3) Synthesis of Intermediate 31-c

Intermediate 31-b 24 g was added to a 1 L three-neck flask, o-dichlorobenzene (ODCB) 240 mL was added under an argon (Ar) atmosphere, borontribromide 36 mL was slowly added, and the mixture was stirred at 180° C. overnight. While ice-bathing in the obtained reaction solution, N,N-diisopropylethylamine 200 mL was added, and water was added to extract an organic layer with toluene. The obtained organic layer was concentrated and purified by column chromatography (eluent: dichloromethane/hexane=3/1) to obtain 0.73 g of yellow solid (yield of 3%). By FAB-MS measurement of the obtained yellow solid, m/z=1013 was observed, and thus it was identified that the yellow solid was Intermediate 31-c.

### 4) Synthesis of Compound 31

Intermediate 31-c of 0.72 g, K₄[Fe(CN)₆] of 0.52 g, bis(di-tert-butyl(4-dimethylaminophenyl)phosphine)dichloropalladium(II) (PdCl₂(amphos)₂) 0.025 g, sodium carbonate 0.30 g, and dimethylacetoamide (DMA) 7 mL were added in a 20 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 0.52 g of yellow solid (yield of 73%). By FAB-MS measurement of the obtained product, m/z=1004 was observed, and thus it was identified that the yellow solid was Compound 31.

### (2) Synthesis of Compound 33

Compound 33 may be synthesized by, for example, Reaction Scheme 2.

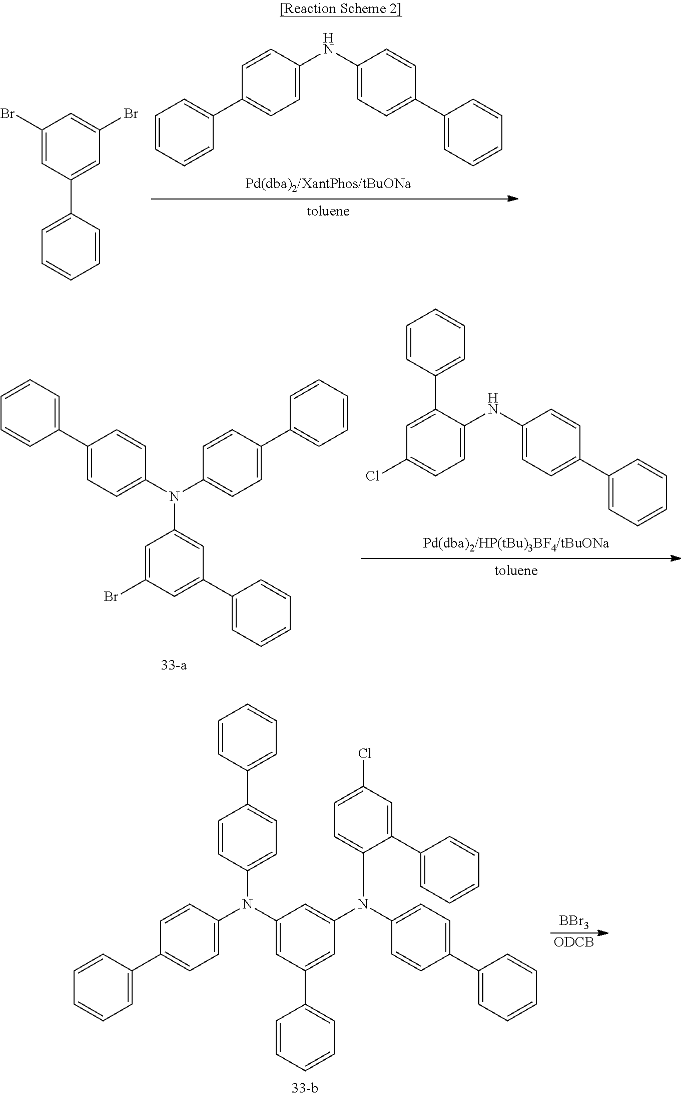

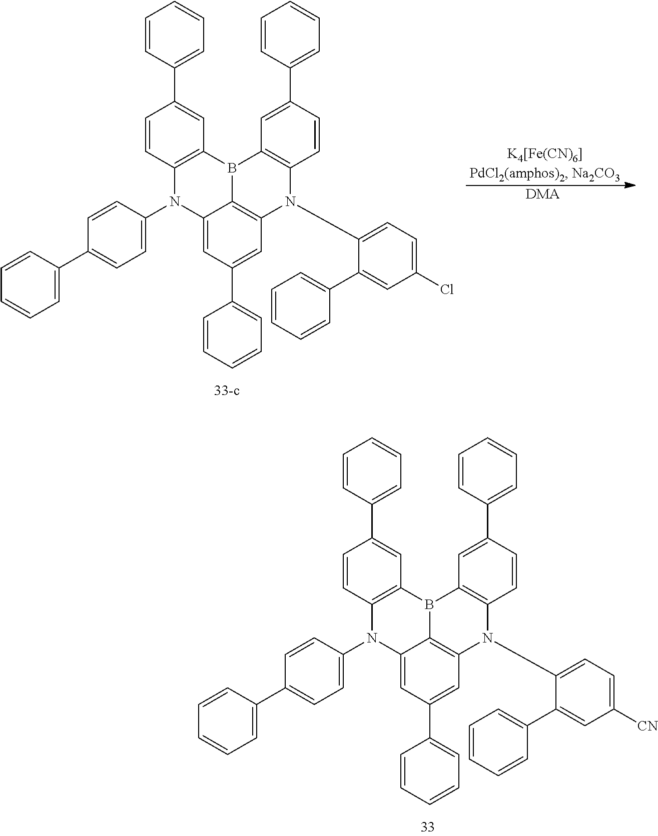

### 1) Synthesis of Intermediate 33-a

3,5-dibromo-1,1′-biphenyl 15 g, di([1,1′-biphenyl]-4-yl)amine 19 g, bis(dibenzylideneacetone)palladium(0) 1.3 g, Xantphos 2.7 g, sodium t-butoxide 6.0 g, and toluene 240 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=1/4) to obtain 21 g of white solid (yield of 79%). By FAB-MS measurement of the obtained product, m/z=553 was observed, and thus it was identified that the white solid was Intermediate 33-a.

### 2) Synthesis of Intermediate 33-b

Intermediate 33-a 21 g, N-([1,1′-biphenyl]-4-yl)-5-chloro-[1,1′-biphenyl]-2-amine 16 g, bis(dibenzylideneacetone)palladium(0) 1.0 g, HP(tBu)₃BF₄1.1 g, sodium t-butoxide 4.7 g, and toluene 200 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=3/1) to obtain 24 g of white solid (yield of 76%). By FAB-MS measurement of the obtained product, m/z=827 was observed, and thus it was identified that the white solid was Intermediate 33-b.

### 3) Synthesis of Intermediate 33-c

Intermediate 33-b 24 g was added to a 1 L three-neck flask, o-dichlorobenzene 240 mL was added under an argon (Ar) atmosphere, borontribromide 44 mL was slowly added, and the mixture was stirred at 180° C. overnight. While ice-bathing in the obtained reaction solution, N,N-diisopropylethylamine 240 mL was added, and water was added to extract an organic layer with toluene. The obtained organic layer was concentrated and purified by column chromatography (eluent: dichloromethane/hexane=3/1) to obtain 1.9 g of yellow solid (yield of 8%). By FAB-MS measurement of the obtained yellow solid, m/z=835 was observed, and thus it was identified that the yellow solid was Intermediate 33-c.

### 4) Synthesis of Compound 33

Intermediate 33-c 1.9 g, K₄[Fe(CN)₆]1.7 g, bis(di-tert-butyl(4-dimethylaminophenyl)phosphine)dichloropalladium(II) 0.082 g, sodium carbonate (Na₂CO₃) 0.98 g, and dimethylacetoamide 20 mL were added in a 50 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 1.3 g of yellow solid (yield of 67%). By FAB-MS measurement of the obtained product, m/z=826 was observed, and thus it was identified that the yellow solid was Compound 33.

### (3) Synthesis of Compound 35

Compound 35 may be synthesized by, for example, Reaction Scheme 3.

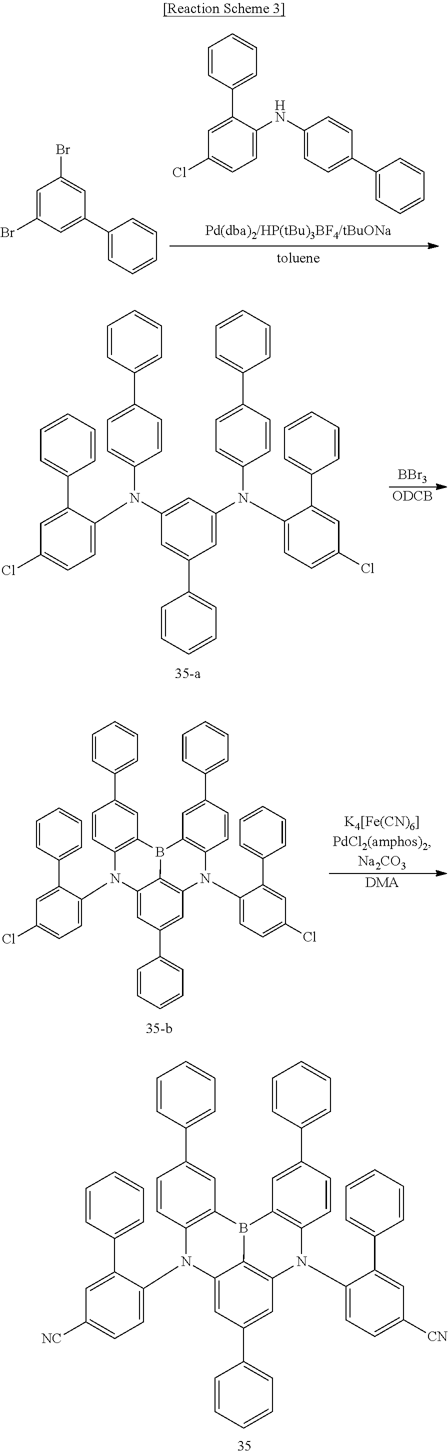

### 1) Synthesis of Intermediate 35-a

3,5-dibromo-1,1′-biphenyl 10 g, N-([1,1′-biphenyl]-4-yl)-5-chloro-[1,1′-biphenyl]-2-amine 23 g, bis(dibenzylideneacetone)palladium(0) 1.5 g, HP(tBu)₃BF₄ 1.5 g, sodium t-butoxide 8.0 g, and toluene 160 mL were added in a 300 mL two-neck flask, and the mixture was heated and stirred at 120° C. for 3 hours. The obtained reaction solution was filtered through Celite, concentrated, and purified by column chromatography (eluent: dichloromethane/hexane=3/1) to obtain 25 g of white solid (yield of 89%). By FAB-MS measurement of the obtained product, m/z=862 was observed, and thus it was identified that the white solid was Intermediate 35-a.

### 2) Synthesis of Intermediate 35-b

Intermediate 35-a 24 g was added in a 1 L three-neck flask, o-dichlorobenzene 280 mL was added under an argon (Ar) atmosphere, borontribromide 42 mL was slowly added, and the mixture was stirred at 180° C. overnight. While ice-bathing in the obtained reaction solution, N,N-diisopropylethylamine 232 mL was added, and water was added to extract an organic layer with toluene. The obtained organic layer was concentrated and purified by column chromatography (eluent: dichloromethane/hexane=3/1) to obtain 1.5 g of yellow solid (yield of 6%). By FAB-MS measurement of the obtained yellow solid, m/z=870 was observed, and thus it was identified that the yellow solid was Intermediate 35-b.

### 3) Synthesis of Compound 35

Intermediate 33-b of 1.5 g, K₄[Fe(CN)₆]2.5 g, bis(di-tert-butyl(4-dimethylaminophenyl)phosphine)dichloropalladium(II) 0.12 g, sodium carbonate 2.8 g, and dimethylacetoamide 20 mL were added in a 50 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 0.84 g of yellow solid (yield of 59%). By FAB-MS measurement of the obtained product, m/z=851 was observed, and thus it was identified that the yellow solid was Compound 35.

### (4) Synthesis of Compound 40

Compound 40 may be synthesized by, for example, Reaction Scheme 4.

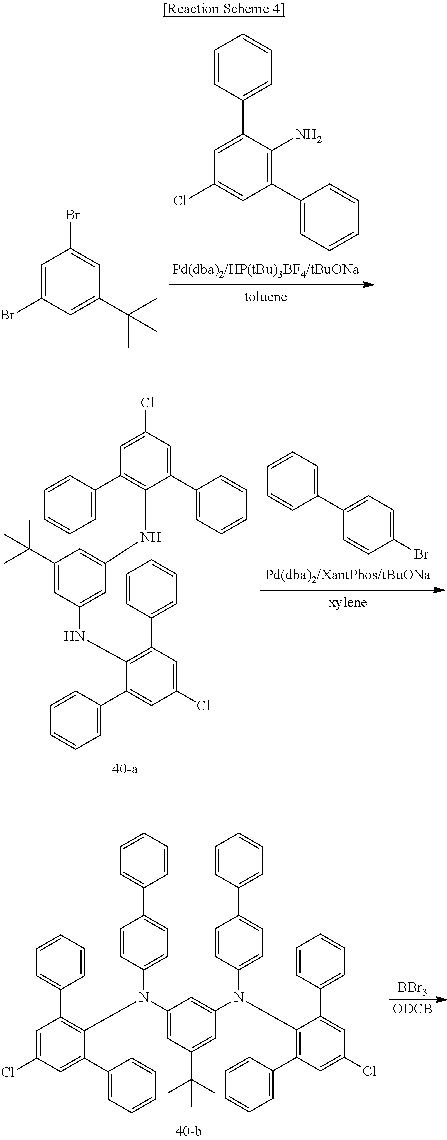

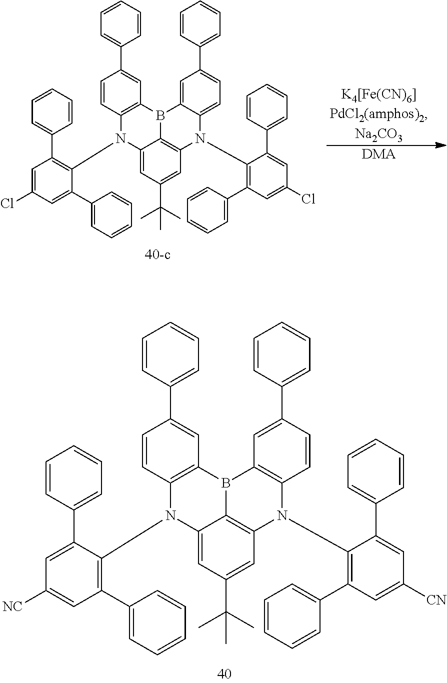

### 1) Synthesis of Intermediate 40-a

1,3-dibromo-5-tert-butylbenzene 10 g, 5′-chloro-[1,1′:3′,1″-terphenyl]-2′-amine 19 g, bis(dibenzylideneacetone)palladium(0) 1.6 g, HP(tBu)₃BF₄ 1.6 g, sodium t-butoxide 8.6 g, and toluene 170 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=1/4) to obtain 21 g of white solid (yield of 91%). By FAB-MS measurement of the obtained product, m/z=690 was observed, and thus it was identified that the white solid was Intermediate 40-a.

### 2) Synthesis of Intermediate 40-b

Intermediate 40-a 20 g, 4-bromo-1,1′-biphenyl 20 g, bis(dibenzylideneacetone)palladium(0) 2.0 g, Xantphos 4.0 g, sodium t-butoxide 17 g, and xylene 30 mL were added in a 500 mL two-neck flask, and the mixture was heated and stirred at 140° C. for 96 hours. The obtained reaction solution was filtered through Celite, concentrated, and purified by column chromatography (eluent: dichloromethane/hexane=3/1) to obtain 19 g of white solid (yield of 65%). By FAB-MS measurement of the obtained product, m/z=994 was observed, and thus it was identified that the white solid was Intermediate 40-b.

### 3) Synthesis of Intermediate 40-c

Intermediate 40-b 19 g was added to a 1 L three-neck flask, o-dichlorobenzene (ODCB) 190 mL was added under an argon (Ar) atmosphere, borontribromide (BBr₃) 29 mL was slowly added, and the mixture was stirred at 180° C. overnight. While ice-bathing in the obtained reaction solution. N,N-diisopropylethylamine 160 mL was added, and water was added to extract an organic layer with toluene. The obtained organic layer was concentrated and purified by column chromatography (eluent: dichloromethane/hexane=3/1) to obtain 0.57 g of yellow solid (yield of 3%). By FAB-MS measurement of the obtained yellow solid, m/z=1002 was observed, and thus it was identified that the yellow solid was Intermediate 40-c.

### 4) Synthesis of Compound 40

Intermediate 40-c of 0.57 g, K₄[Fe(CN)₆]0.84 g, bis(di-tert-butyl(4-dimethylaminophenyl)phosphine)dichloropalladium(II) 0.040 g, sodium carbonate 0.97 g, and dimethylacetoamide 6 mL were added in a 20 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 0.33 g of yellow solid (yield of 59%). By FAB-MS measurement of the obtained product, m/z=983 was observed, and thus it was identified that the yellow solid was Compound 40.

### (5) Synthesis of Compound 46

Compound 46 may be synthesized by, for example, Reaction Scheme 5.

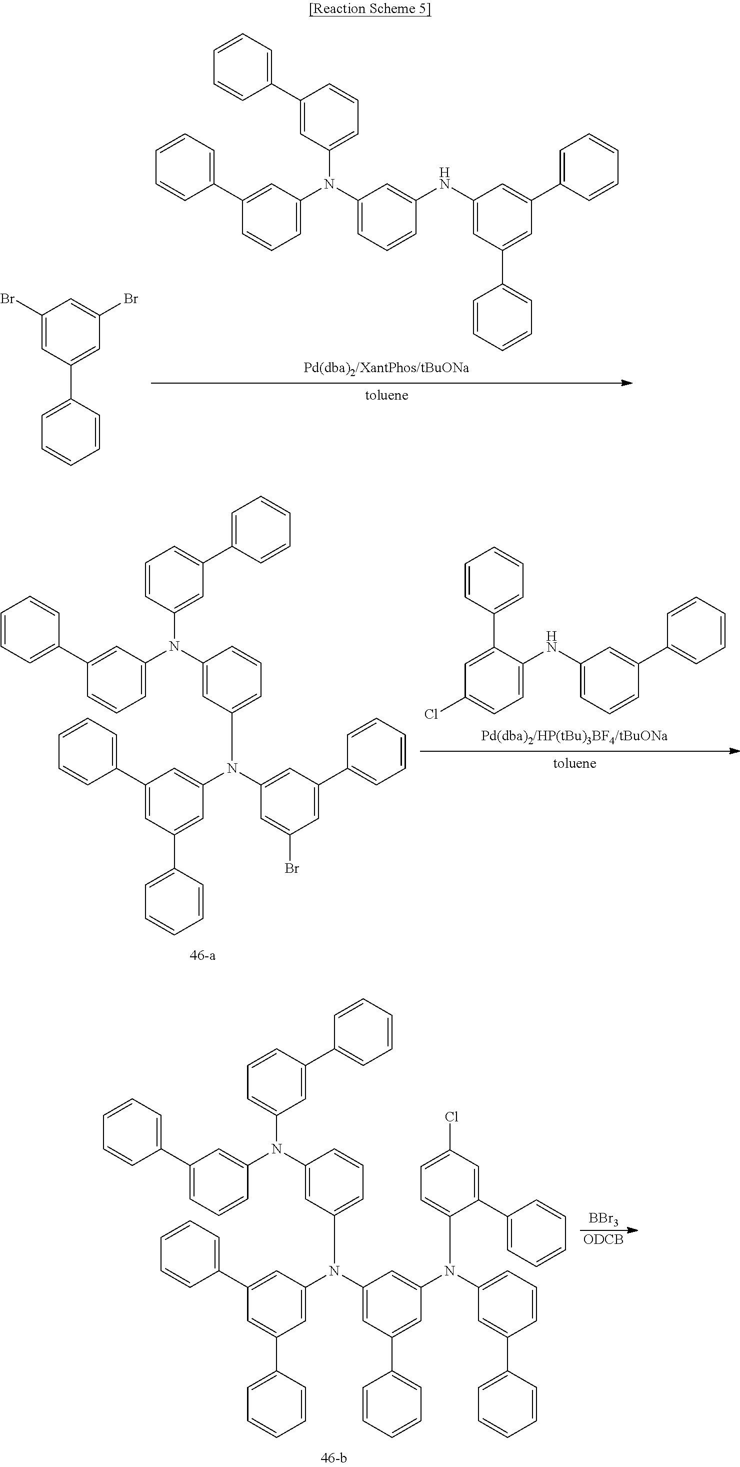

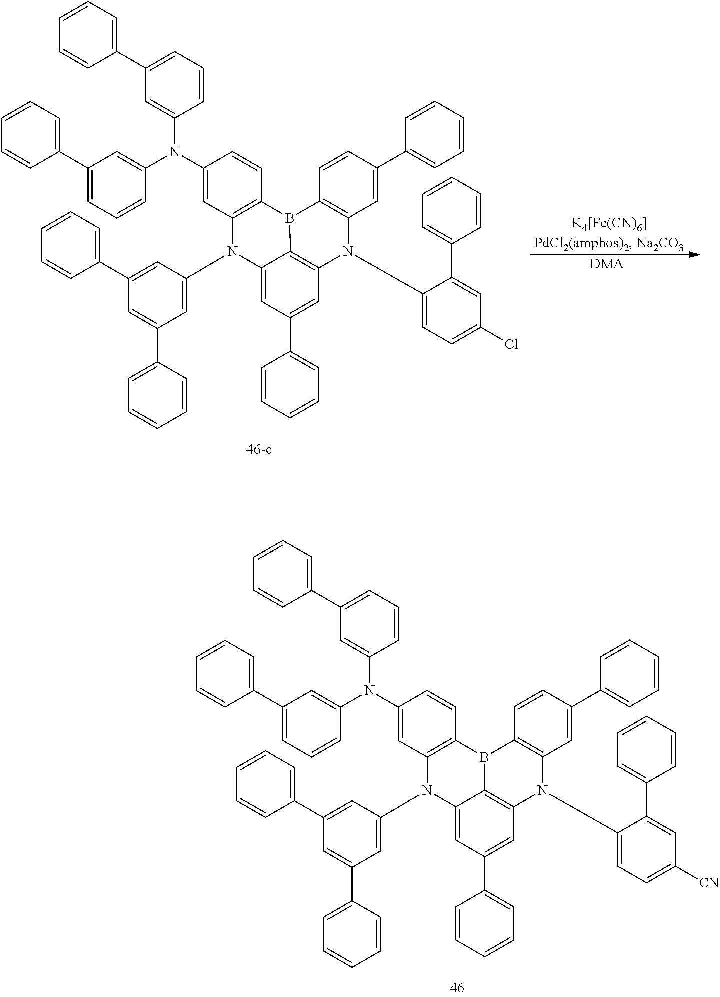

### 1) Synthesis of Intermediate 46-a

3,5-dibromo-1,1′-biphenyl 15 g, N¹,N¹-di([1,1′-biphenyl]-3-yl)-N³-([1,1′:3′,1″-terphenyl]-5′-yl)benzene-1,3-diamine 37 g, bis(dibenzylideneacetone)palladium(0) 1.3 g, Xantphos 2.7 g, sodium t-butoxide 6.0 g, and toluene 240 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=1/4) to obtain 35 g of white solid (yield of 83%). By FAB-MS measurement of the obtained product, m/z=872 was observed, and thus it was identified that the white solid was Intermediate 46-a.

### 2) Synthesis of Intermediate 46-b

Intermediate 46-a 25 g, N-([1,1′-biphenyl]-4-yl)-5-chloro-[1,1′-biphenyl]-2-amine 12 g, bis(dibenzylideneacetone)palladium(0) 0.79 g, HP(tBu)₃BF₄0.80 g, sodium t-butoxide 3.6 g, and toluene 150 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=3/l) to obtain 20 g of white solid (yield of 62%). By FAB-MS measurement of the obtained product, m/z=1147 was observed, and thus it was identified that the white solid was Intermediate 46-b.

### 3) Synthesis of Intermediate 46-c

Intermediate 46-b 20 g was added to a 1 L three-neck flask, o-dichlorobenzene 170 mL was added under an argon (Ar) atmosphere, borontribromide 26 mL was slowly added, and the mixture was stirred at 180° C. overnight. While ice-bathing in the obtained reaction solution, N,N-diisopropylethylamine 150 mL was added, and water was added to extract an organic layer with toluene. The obtained organic layer was concentrated and purified by column chromatography (eluent: dichloromethane/hexane=3/1) to obtain 1.6 g of yellow solid (yield of 8%). By FAB-MS measurement of the obtained yellow solid, m/z=1155 was observed, and thus it was identified that the yellow solid was Intermediate 46-c.

### 4) Synthesis of Compound 46

Intermediate 46-c 0.72 g, K₄[Fe(CN)₆]1.7 g, K₄[Fe(CN)₆]0.46 g, bis(di-tert-butyl(4-dimethylaminophenyl)phosphine)dichloropalladium(II) 0.025 g, sodium carbonate 0.26 g, and dimethylacetoamide 7 mL were added in a 50 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 0.45 g of yellow solid (yield of 63%). By FAB-MS measurement of the obtained product, m/z=1145 was observed, and thus it was identified that the yellow solid was Compound 46.

### (6) Synthesis of Compound 56

Compound 56 may be synthesized by, for example, Reaction Scheme 6.

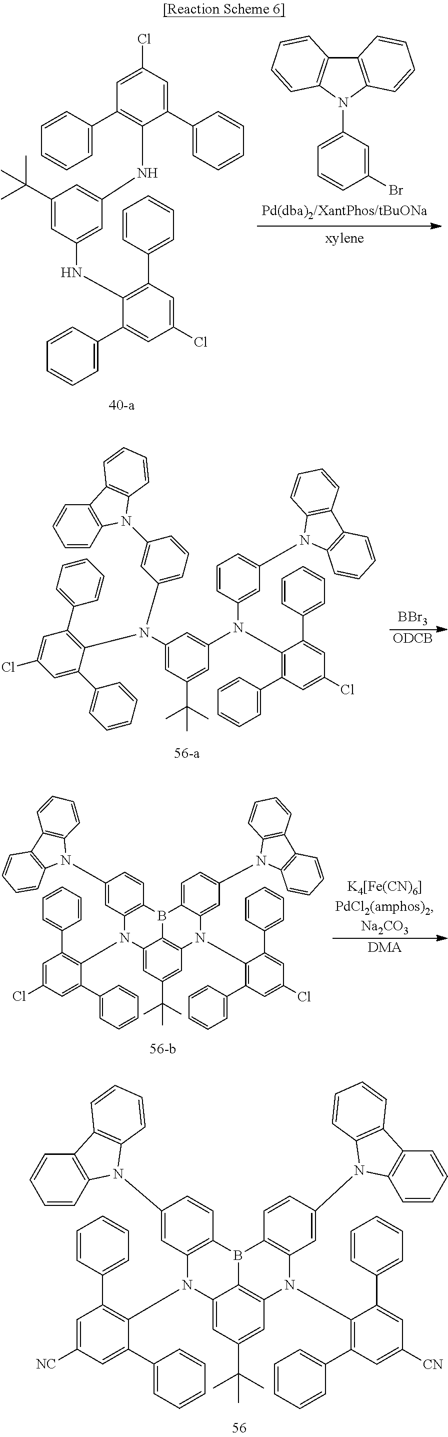

### 1) Synthesis of Intermediate 56-a

Intermediate 40-a 15 g, 9-(3-bromophenyl)-9H-carbazole 21 g, bis(dibenzylideneacetone)palladium(0) 1.5 g, Xantphos 3.0 g, sodium t-butoxide 13 g, and xylene 20 mL were added in a 500 mL two-neck flask, and the mixture was heated and stirred at 120° C. for 3 hours. The obtained reaction solution was filtered through Celite, concentrated, and purified by column chromatography (eluent: dichloromethane/hexane=3/1) to obtain 14 g of white solid (yield of 54%). By FAB-MS measurement of the obtained product, m/z=1172 was observed, and thus it was identified that the white solid was Intermediate 56-a.

### 2) Synthesis of Intermediate 56-b

Intermediate 56-a 14 g was added to a 1 L three-neck flask, o-dichlorobenzene 120 mL was added under an argon (Ar) atmosphere, borontribromide 18 mL was slowly added, and the mixture was stirred at 180° C. overnight. While ice-bathing in the obtained reaction solution, N,N-diisopropylethylamine 100 mL was added, and water was added to extract an organic layer with toluene. The obtained organic layer was concentrated and purified by column chromatography (eluent: dichloromethane/hexane=3/1) to obtain 0.42 g of yellow solid (yield of 3%). By FAB-MS measurement of the obtained yellow solid, m/z=1180 was observed, and thus it was identified that the yellow solid was Intermediate 56-b.

### 3) Synthesis of Compound 56

Intermediate 56-b of 0.42 g, K₄[Fe(CN)₆]0.52 g, bis(di-tert-butyl(4-dimethylaminophenyl)phosphine)dichloropalladium(II) 0.025 g, sodium carbonate 0.60 g, and dimethylacetoamide 4 mL were added in a 20 mL two-neck flask, and the mixture was heated and stirred at 140° C. for 5 hours. The obtained reaction solution was filtered through Celite, concentrated, and purified by column chromatography (eluent: dichloromethane/hexane=1/1) to obtain 0.30 g of yellow solid (yield of 72%). By FAB-MS measurement of the obtained product, m/z=1161 was observed, and thus it was identified that the yellow solid was Compound 56.

### (7) Synthesis of Compound 91

Compound 91 may be synthesized by, for example, Reaction Scheme 7 below.

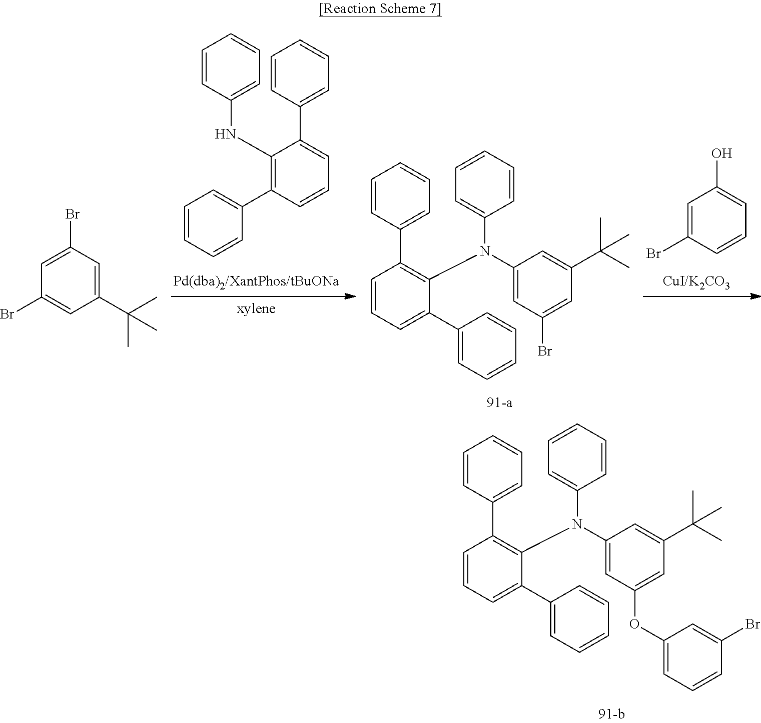

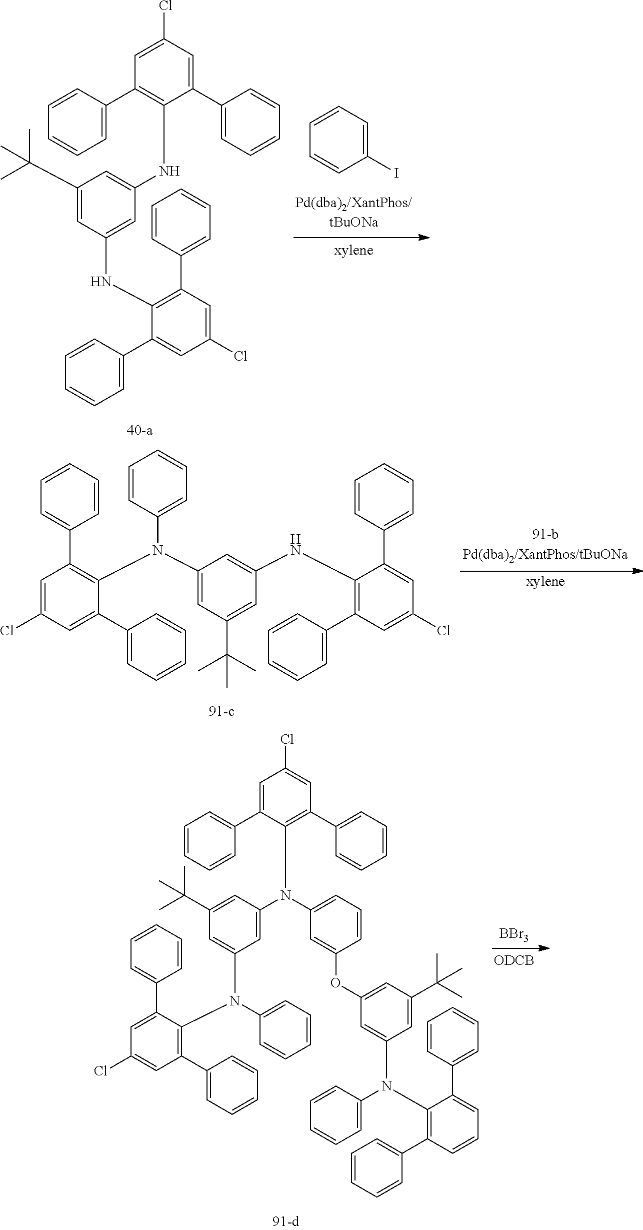

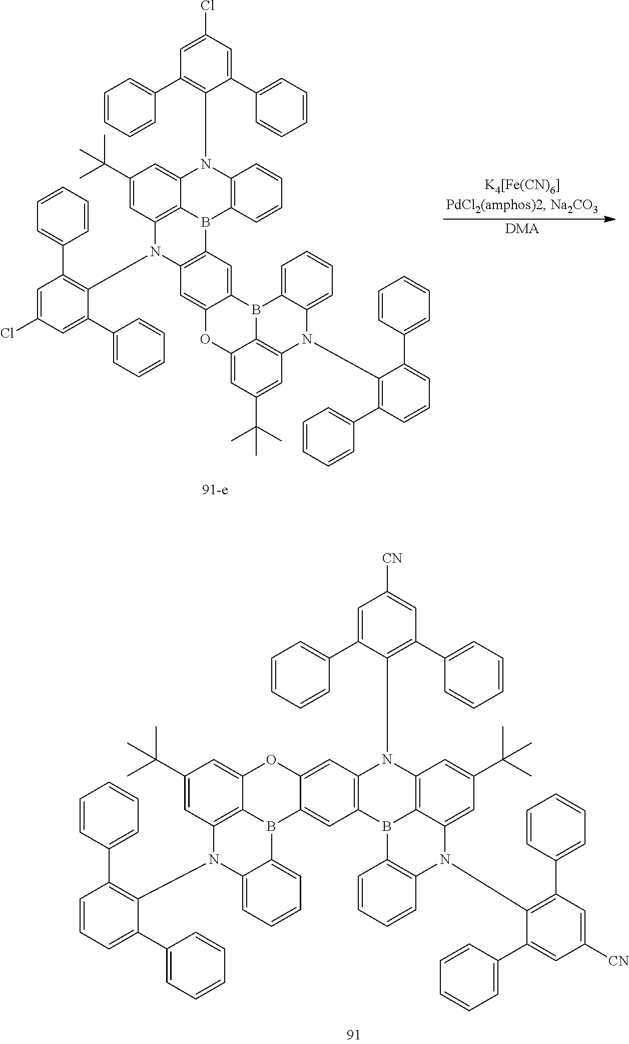

### 1) Synthesis of Intermediate 91-a

1,3-dibromo-5-tert-butylbenzene 40 g, N-phenyl-[1,1′:3′,1″-terphenyl]-2′-amine 130 g, bis(dibenzylideneacetone)palladium(0) 9.5 g, Xantphos 19 g, sodium t-butoxide 79 g, and xylene 140 mL were added in a 500 mL two-neck flask, and the mixture was heated and stirred at 140° C. for 96 hours. The obtained reaction solution was filtered through Celite, concentrated, and purified by column chromatography (eluent: dichloromethane/hexane=3/1) to obtain 47 g of white solid (yield of 65%). By FAB-MS measurement of the obtained product, m/z=533 was observed, and thus it was identified that the white solid was Intermediate 91-a.

### 2) Synthesis of Intermediate 91-b

Intermediate 91-a 47 g, 3-bromophenol 200 g, potassium carbonate (K₂CO₃) 73 g, and CuI(I) 34 g were added in a 100 mL two-neck flask, and the mixture was heated and stirred at 190° C. for 96 hours. The obtained reaction solution was filtered through Celite, concentrated, and purified by column chromatography (eluent: dichloromethane/hexane=3/1) to obtain 9.4 g of white solid (yield of 17%). By FAB-MS measurement of the obtained product, m/z=625 was observed, and thus it was identified that the white solid was Intermediate 91-b.

### 3) Synthesis of Intermediate 91-c

Intermediate 40-a 15 g, iodobenzene 15 g, bis(dibenzylideneacetone)palladium(0) 1.5 g, Xantphos 3.0 g, sodium t-butoxide 5.4 g, and xylene 22 mL were added in a 200 mL two-neck flask, and the mixture was heated and stirred at 140° C. for 96 hours. The obtained reaction solution was filtered through Celite, concentrated, and purified by column chromatography (eluent: dichloromethane/hexane=3/1) to obtain 7.0 g of white solid (yield of 42%). By FAB-MS measurement of the obtained product, m/z=766 was observed, and thus it was identified that the white solid was Intermediate 91-c.

### 4) Synthesis of Intermediate 91-d

Intermediate 91-b 9.4 g, Intermediate 91-c 7.0 g, bis(dibenzylideneacetone)palladium(0) 0.32 g, Xantphos 0.64 g, sodium t-butoxide 5.3 g, and xylene 10 mL were added in a 200 mL two-neck flask, and the mixture was heated and stirred at 140° C. for 96 hours. The obtained reaction solution was filtered through Celite, concentrated, and purified by column chromatography (eluent: dichloromethane/hexane=3/1) to obtain 7.3 g of white solid (yield of 61%). By FAB-MS measurement of the obtained product, m/z=1310 was observed, and thus it was identified that the white solid was Intermediate 91-d.

### 5) Synthesis of Intermediate 91-e

Intermediate 91-d 7.3 g was added to a 500 mL three-neck flask, o-dichlorobenzene 60 mL was added under an argon (Ar) atmosphere, borontribromide 17 mL was slowly added, and the mixture was stirred at 180° C. overnight. While ice-bathing in the obtained reaction solution, N,N-diisopropylethylamine 90 mL was added, and water was added to extract an organic layer with toluene. The obtained organic layer was concentrated and purified by column chromatography (eluent: dichloromethane/hexane=3/1) to obtain 0.15 g of yellow solid (yield of 2%). By FAB-MS measurement of the obtained yellow solid, m/z=1325 was observed, and thus it was identified that the yellow solid was Intermediate 91-e.

### 6) Synthesis of Compound 91

Intermediate 91-e of 0.12 g, K₄[Fe(CN)₆]0.17 g, bis(di-tert-butyl(4-dimethylaminophenyl)phosphine)dichloropalladium(II) 0.0080 g, sodium carbonate 0.19 g, and dimethylacetoamide 1 mL were added in a 20 mL two-neck flask, and the mixture was heated and stirred at 140° C. for 5 hours. The obtained reaction solution was filtered through Celite, concentrated, and purified by column chromatography (eluent: dichloromethane/hexane=l/l) to obtain 0.12 g of yellow solid (yield of 78%). By FAB-MS measurement of the obtained product, m/z=1306 was observed, and thus it was identified that the yellow solid was Compound 91.

### 2. Fluorescence Luminescence Characteristics Evaluation of Compound

Fluorescence luminescence characteristics of the polycyclic compounds according to an embodiment and Comparative Example compounds were evaluated and the results were listed in Table 1. A maximum photoluminescence wavelength (PLλₘₐₓ), a photoluminescence quantum yield (PLQY), and a full width at half maximum (FWHM) of an emission spectrum were evaluated and the results were listed in Table 1.

The maximum photoluminescence wavelength of example compounds and comparative example compounds were measured using the F-7000 spectrofluorometer made by Hitachi High-Tech Corporation under an inert gas atmosphere. The photoluminescence quantum yield was measured using Quantaurus QY made by Hamamatsu Photonics K.K. The full width at half maximum (FWHM) of the emission spectrum was measured using the U-3900 spectrofluorometer made by Hitachi High-Tech Corporation. Luminescence characteristics evaluation of the compounds listed in Table 1 were performed in a toluene solution state of the Example and the Comparative Example Compounds.

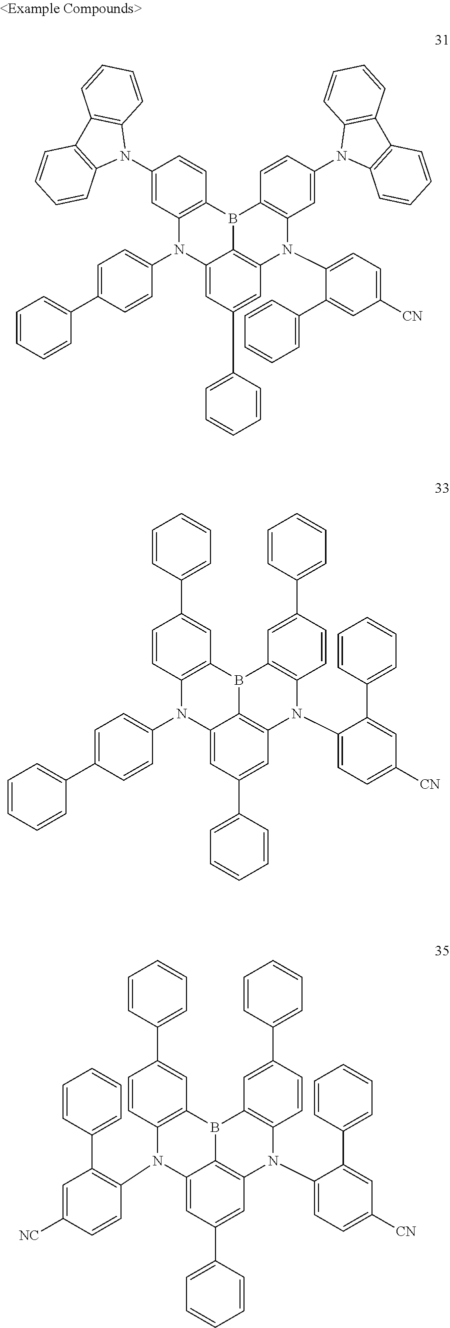 [SMILES: N#Cc1ccc(N2c3cc(-n4c5ccccc5c5ccccc54)ccc3B3c4ccc(-n5c6ccccc6c6ccccc65)cc4N(c4ccc(-c5ccccc5)cc4)c4cc(-c5ccccc5)cc2c43)c(-c2ccccc2)c1 ; N#Cc1ccc(N2c3ccc(-c4ccccc4)cc3B3c4cc(-c5ccccc5)ccc4N(c4ccc(-c5ccccc5)cc4)c4cc(-c5ccccc5)cc2c43)c(-c2ccccc2)c1 ; N#Cc1ccc(N2c3ccc(-c4ccccc4)cc3B3c4cc(-c5ccccc5)ccc4N(c4ccc(C#N)cc4-c4ccccc4)c4cc(-c5ccccc5)cc2c43)c(-c2ccccc2)c1]

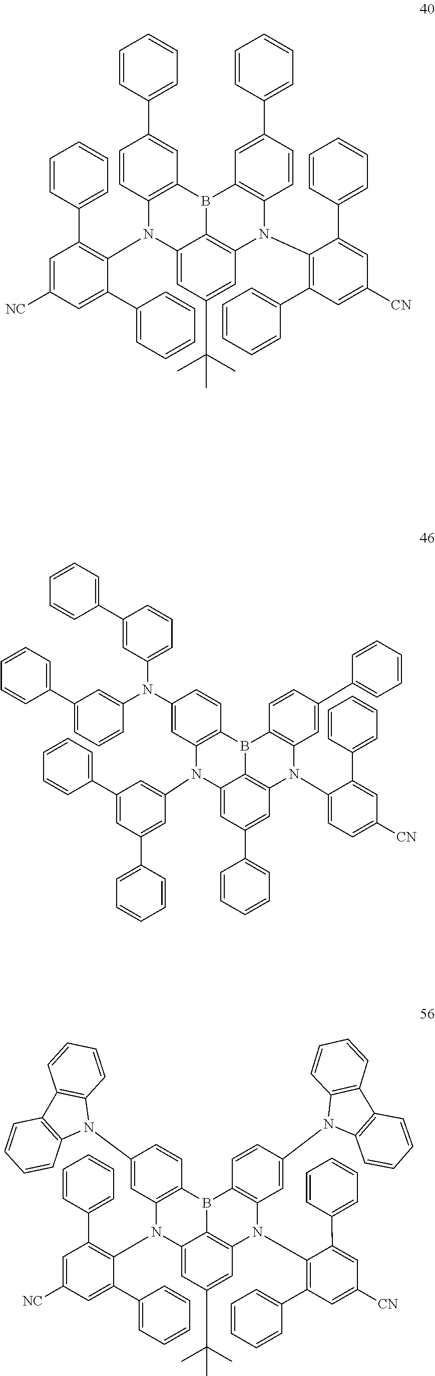 [SMILES: CC(C)(C)c1cc2c3c(c1)N(c1c(-c4ccccc4)cc(C#N)cc1-c1ccccc1)c1ccc(-c4ccccc4)cc1B3c1cc(-c3ccccc3)ccc1N2c1c(-c2ccccc2)cc(C#N)cc1-c1ccccc1 ; N#Cc1ccc(N2c3cc(-c4ccccc4)ccc3B3c4ccc(N(c5cccc(-c6ccccc6)c5)c5cccc(-c6ccccc6)c5)cc4N(c4cc(-c5ccccc5)cc(-c5ccccc5)c4)c4cc(-c5ccccc5)cc2c43)c(-c2ccccc2)c1 ; CC(C)(C)c1cc2c3c(c1)N(c1c(-c4ccccc4)cc(C#N)cc1-c1ccccc1)c1cc(-n4c5ccccc5c5ccccc54)ccc1B3c1ccc(-n3c4ccccc4c4ccccc43)cc1N2c1c(-c2ccccc2)cc(C#N)cc1-c1ccccc1]

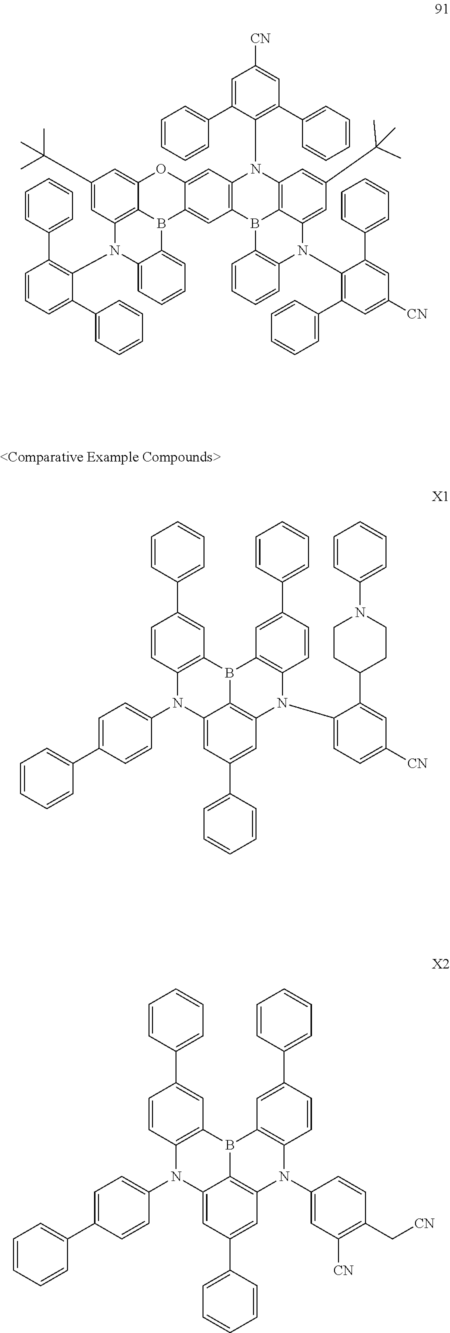 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccccc1N2c1c(-c2ccccc2)cc(C#N)cc1-c1ccccc1 ; N#Cc1ccc(N2c3ccc(-c4ccccc4)cc3B3c4cc(-c5ccccc5)ccc4N(c4ccc(-c5ccccc5)cc4)c4cc(-c5ccccc5)cc2c43)c(C2CCN(c3ccccc3)CC2)c1 ; N#CCc1ccc(N2c3ccc(-c4ccccc4)cc3B3c4cc(-c5ccccc5)ccc4N(c4ccc(-c5ccccc5)cc4)c4cc(-c5ccccc5)cc2c43)cc1C#N]

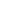

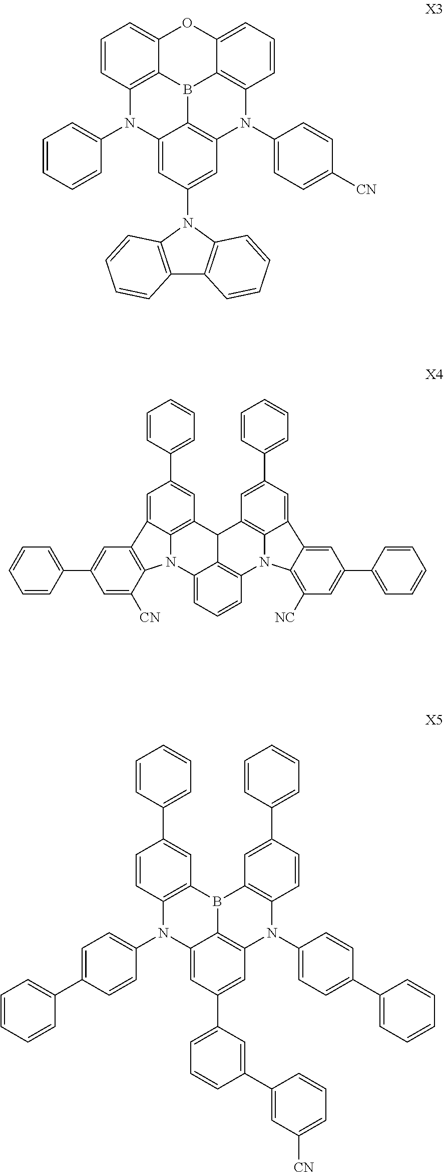 [SMILES: N#Cc1ccc(N2c3cccc4c3B3c5c(cccc5N(c5ccccc5)c5cc(-n6c7ccccc7c7ccccc76)cc2c53)O4)cc1 ; N#Cc1cc(-c2ccccc2)cc2c3cc(-c4ccccc4)cc4c3n(c12)-c1cccc2c1C4c1cc(-c3ccccc3)cc3c4cc(-c5ccccc5)cc(C#N)c4n-2c13 ; N#Cc1cccc(-c2cccc(-c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)c2)c1]

TABLE 1

| Compound | PLλₘₐₓ/nm | PLQY/% | FWHM/nm |
|---|---|---|---|
| Example Compound 31 | 463 | 87 | 23 |
| Example Compound 33 | 466 | 72 | 19 |
| Example Compound 35 | 462 | 69 | 20 |
| Example Compound 40 | 459 | 84 | 20 |
| Example Compound 46 | 464 | 91 | 25 |
| Example Compound 56 | 456 | 89 | 21 |
| Example Compound 91 | 457 | 93 | 16 |
| Comparative Example | 464 | 48 | 26 |
| Compound X1 | | | |
| Comparative Example | 465 | 56 | 25 |
| Compound X2 | | | |
| Comparative Example | 442 | 65 | 30 |
| Compound X3 | | | |
| Comparative Example | 512 | 82 | 28 |
| Compound X4 | | | |
| Comparative Example | 495 | 76 | 30 |
| Compound X5 | | | |

Referring to Table 1, it is confirmed that, since the Example Compounds emit light in a wavelength region in a range of about 460 nm to about 470 nm, have a measured value of photoluminescence quantum yield of 65% or more, and exhibit a narrow full width at half maximum less than or equal to about 25 nm of an emission wavelength spectrum, to thereby be suitable for using as a material for a blue light-emitting material.

Compared to the Example Compounds, Comparative Example Compounds X1 and X2 exhibit lower photoluminescence quantum yields than the Example Compounds. It can be seen that Comparative Example Compounds X3 and X5 have an expanded full width at half maximum, compared to the Example Compounds. Comparative Example Compound X4 is confirmed to emit light with a photoluminescence wavelength corresponding to green light.

### 3. Manufacture and Evaluation of Light-Emitting Element

The light-emitting element including a polycyclic compound according to an embodiment or a Comparative Example Compound in the emission layer was manufactured by the following method. The light-emitting elements according to Example 1 to Example 7 were manufactured using Compounds 31, 33, 35, 40, 46, 56, and 91, which are the polycyclic compounds according to an embodiment, as a dopant material of the emission layer. The light-emitting elements according to Comparative Example 1 to Comparative Example 5 were respectively manufactured using Comparative Example Compound X1 to Comparative Example Compound X5, as dopant materials in the emission layer.

### (1) Manufacture of Light-Emitting Element

A glass substrate, on which an ITO was patterned as a first electrode, was cleansed by ultrasonic waves using isopropyl alcohol and pure water for about five minutes each. After ultrasonic wave cleansing, the glass substrate was irradiated with ultraviolet rays for about 30 minutes and was subjected to an ozone treatment. HAT-CN at a thickness of about 10 nm, TrisPCz at a thickness of about 30 nm, and mCBP at a thickness of about 5 nm were deposited to form a hole transport region.

mCBP was co-deposited with an Example Compound or a Comparative Example compound to form an emission layer having a thickness of about 30 nm. The Example Compound and the Comparative Example Compound were co-deposited at a weight ratio of 2:98. In the manufacture of the light-emitting element, the Example Compound or the Comparative Example Compound was used as a dopant material.

SF3-TRZ at a thickness of about 10 nm, SF3-TRZ:Liq at a thickness of about 20 nm at a weight ratio of 50:50, and Liq at a thickness of about 2 nm were deposited to form an electron transport region.

Al was deposited at a thickness of about 100 nm to form a second electrode.

In an embodiment, the hole transport region, the emission layer, the electron transport region, and the second electrode were formed using a vacuum deposition apparatus.

The compounds used for the manufacture of the light-emitting element are as follows.

### (Materials Used for Manufacture of Light-Emitting Element)

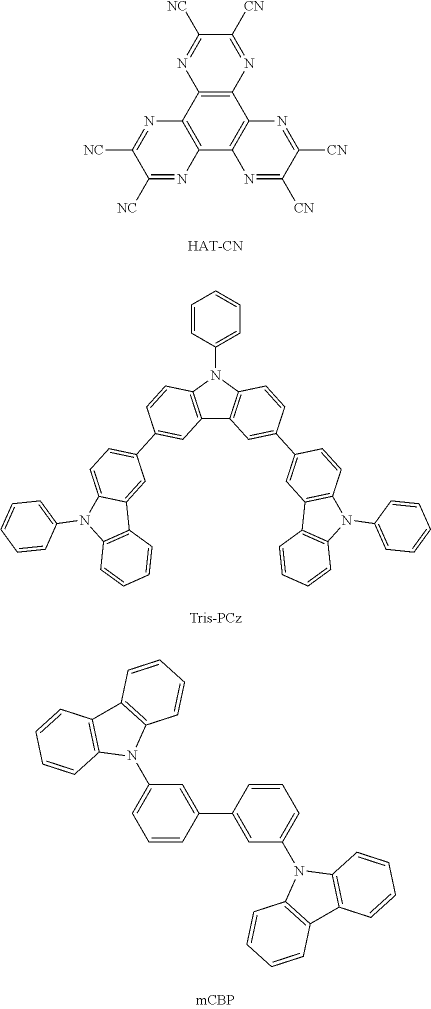 [SMILES: N#Cc1nc2c3nc(C#N)c(C#N)nc3c3nc(C#N)c(C#N)nc3c2nc1C#N ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1cc(-c2cccc(-n3c4ccccc4c4ccccc43)c2)cc(-n2c3ccccc3c3ccccc32)c1]

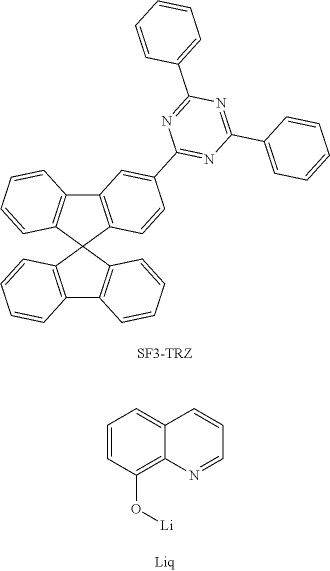

### (2) Evaluation of Characteristics of Light-Emitting Element

Characteristics of the light-emitting elements according to Example 1 to Example 7, and Comparative Example 1 to Comparative Example 5 were evaluated and the evaluation results were listed in Table 2. In Table 2, a maximum photoluminescence wavelength (λₘₐₓ), a maximum external quantum yield (EQEₘₐₓ), and a relative element lifespan were listed. Time taken for initial luminance to decrease from 100% to 50% was measured as a lifespan (LT50) at 1000 cd/m² during continuous operation, and the relative element lifespan of each light-emitting element was calculated with respect to a value of the light-emitting element according to Comparative Example 1.

TABLE 2

| Manufacture | | | | Relative |
|---|---|---|---|---|
| example of | Dopant | λₘₐₓ | EQEₘₐₓ | lifespan of |
| element | compound | (nm) | (%) | element (%) |
| Example 1 | 31 | 465 | 14 | 155 |
| Example 2 | 33 | 468 | 16 | 168 |
| Example 3 | 35 | 464 | 18 | 158 |
| Example 4 | 40 | 462 | 16 | 180 |
| Example 5 | 46 | 468 | 17 | 175 |
| Example 6 | 56 | 456 | 18 | 183 |
| Example 7 | 91 | 459 | 22 | 176 |
| Comparative | X1 | 466 | 12 | 100 |
| Example 1 | | | | |
| Comparative | X2 | 467 | 13 | 110 |
| Example 2 | | | | |
| Comparative | X3 | 446 | 8.0 | 82 |
| Example 3 | | | | |
| Comparative | X4 | 523 | 18 | 120 |
| Example 4 | | | | |
| Comparative | X5 | 498 | 17 | 135 |
| Example 5 | | | | |

Referring to Table 2, it can be confirmed that the light-emitting elements according to the examples emit blue light having a maximum photoluminescence wavelength less than or equal to about 470 nm. The light-emitting elements according to examples exhibit excellent results in maximum external quantum yield (EQEₘₐₓ) properties and relative element lifespan properties, compared to the light-emitting elements according to the Comparative Examples.

From the results listed in Table 2, it can be seen that, the polycyclic compounds used in the light-emitting elements according to the Examples have, compared to the Comparative Example Compounds, characteristics of excellent maximum external quantum yield, material stability and so on since having a structure in which a benzene ring is connected to a nitrogen atom constituting a core structure, and a cyano group and an aryl group are additionally connected to the benzene ring. Therefore, the light-emitting element using the polycyclic compound according to an embodiment as an emission material exhibit characteristics of excellent efficiency and long lifespan.

In Comparative Example Compounds X1 and X2 used in Comparative Examples 1 and 2, one cyano group is connected to the benzene group connected to the nitrogen atom constituting the core structure, but an aliphatic substituent is included, compared to the polycyclic compound according to examples. In Comparative Example Compound X1, a substituted piperidine group is connected to the first benzene ring, and in Comparative Example Compound X2, a substituted methyl group is connected to the first benzene ring. Even in the evaluation of the polycyclic compound physical properties in Table 1, Comparative Example Compounds X1 and X2 exhibit low photoluminescence quantum yield, and Comparative Example Compound X1 exhibits the expanded full width at half maximum of the emission spectrum, compared to the Example Compounds. Therefore, the light-emitting elements according to Comparative Examples 1 and 2 exhibit characteristics of a lower external quantum yield and a shorter element lifespan than the light-emitting elements according to examples.

In Comparative Example Compound X3 used in Comparative Example 3, an aryl group is not additionally connected to the first benzene ring, and R₄ and R₅ in Formula 1 are connected to each other, and thus the core structure contributing to emission characteristics differs from those of the example compounds. Comparative Example Compound X3 has no association suppression effect due to a structural characteristic in which an aryl group is not additionally connected to the first benzene ring and planarity is high caused by the core structure, the expanded full width at half maximum is confirmed, and significantly low efficiency and lifespan are observed when driving the device.

Comparative Example Compound X4 used in Comparative Example 4 has a structure in which a cyano group is directly bonded to a core structure and emits light with a wavelength in a green light region, as shown in Table 1. These results are caused by the cyano group involving in the conjugation of a compound skeleton, and it can be seen that a similar level to the example compounds are exhibited in terms of a photoluminescence quantum yield (PLQY) and element efficiency for maximum external quantum efficiency (EQE max), but Comparative Example Compound X4 is unsuitable for being used as a blue light-emitting material.

Comparative Example Compound X4 has a structure with high planarity, and thus an association state may not be effectively suppressed even if an aryl group is additionally connected to the benzene ring to which the cyano group is connected, thereby exhibiting poor results in the full width at half maximum and element lifespan, compared to the example compounds.

Comparative Example Compound X5 used in Comparative Examples 5 has a structure in which a cyano group is bonded to a core structure via a divalent biphenylarylene group. Comparative Example Compound X5 is assumed to have reduced effect of the cyano group on the core structure by a spatial distance caused by the divalent biphenyl group. As a result, it can be seen that Comparative Example Compound X5 had a significantly different wavelength from a suitable blue light wavelength as observed in the example compounds and no significant effect on the element lifespan was obtained.

In the light-emitting element according to an embodiment, the emission layer may include the polycyclic compound according to an embodiment. The polycyclic compound according to an embodiment may include, as a core structure, a five-membered fused ring including one hetero atom, one nitrogen (N) atom, and one boron (B) atom as a ring-forming atom, or may include, as a core structure, a seven-membered fused ring or a nine-membered fused ring, respectively, in which a two-membered ring including two hetero atoms as ring-forming atoms, or four-membered ring including four hetero atoms as ring-forming atoms is additionally fused to the five-membered fused ring. In the polycyclic compound according to an embodiment, a first benzene ring is connected to the nitrogen atom constituting a core structure, at least one cyano group and at least one aryl group is connected to the first benzene group, thereby protecting five-membered, seven-membered or nine-membered fused ring core and capable of having a structure with relaxed molecular planarity. In the polycyclic compound according to an embodiment, solvation and association with a solvent or host material may be suppressed through the cyano group and the aryl group connected to the core structure via the first benzene ring. Therefore, the light-emitting element including the polycyclic compound according to an embodiment in the emission layer may exhibit characteristics of high efficiency and long lifespan.

The light-emitting element includes the polycyclic compound according to an embodiment in the emission layer, and thus may exhibit characteristics of high efficiency and long lifespan.

The polycyclic compound according to an embodiment may contribute to improvements in light efficiency and long lifespan of the light-emitting element.

The display element according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode facing the first electrode; and
an emission layer disposed between the first electrode and the second electrode and including a first compound represented by Formula 1: 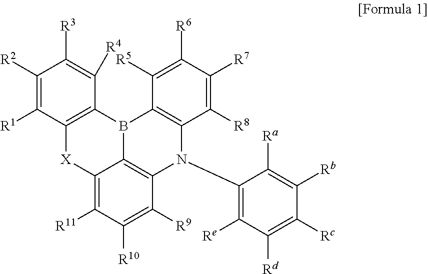
wherein in Formula 1,
X is O, S, or N(R¹²),
R¹ to R¹² are each independently a hydrogen atom, a deuterium atom, a halogen atom, a cyano group, a substituted or unsubstituted amine group, a substituted or unsubstituted oxy group, a substituted or unsubstituted sulfinyl group, a substituted or unsubstituted boron group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or R¹ to R₄ is bonded to an adjacent group to form a ring only between R¹ to R₄, or R⁵ to R⁸ is bonded to an adjacent group to form a ring only between R⁵ to R⁸,
R^{a} to R^{e} are each independently a hydrogen atom, a deuterium atom, a halogen atom, a cyano group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
at least one of R^{a} to R^{e} is a cyano group, and
at least one of the remainder of R^{a} to R^{e} is each independently a substituted or unsubstituted aryl group having a ring-forming carbon number of 6 to 30.

2. The light-emitting element of claim 1, wherein the emission layer further comprises at least one of a second compound represented by Formula HT-1 and a third compound represented by Formula ET-1: 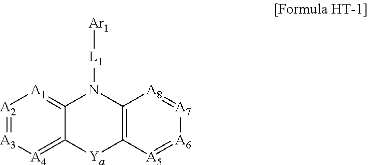
wherein in Formula HT-1,
A₁ to A₈ are each independently N or C(R₅₁),
L₁ is a direct linkage, a substituted or unsubstituted arylene group having a ring-forming carbon number of 6 to 30 or a substituted or unsubstituted heteroarylene group having a ring-forming carbon number of 2 to 30,
Yₐ is a direct linkage, C(R₅₂)(R₅₃), or Si(R₅₄)(R₅₅),
Ar₁ is a substituted or unsubstituted aryl group having a ring-forming carbon number of 6 to 30 or a substituted or unsubstituted heteroaryl group having a ring-forming carbon number of 2 to 30, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 30, or a substituted or unsubstituted heteroaryl group having a ring-forming carbon number of 2 to 60, or bonded to an adjacent group to form a ring; 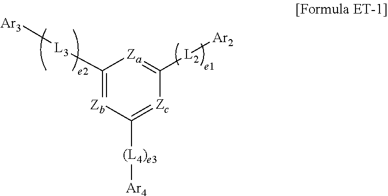
wherein in Formula ET-1,
at least one of Zₐ to Z_{c} is N,
the remainder of Zₐ to Z_{c} are each independently C(R₅₆),
R₅₆ is a hydrogen atom, a deuterium atom, a substituted or unsubstituted alkyl group having a carbon number of 1 to 20, a substituted or unsubstituted aryl group having a ring-forming carbon number of 6 to 60, or a substituted or unsubstituted heteroaryl group having a ring-forming carbon number of 2 to 60,
e1 to e3 are each independently an integer from 0 to 10,
Ar₂ to Ar₄ are each independently a hydrogen atom, a deuterium atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
L₂ to L₄ are each independently a direct linkage, a substituted or unsubstituted arylene group having a ring-forming carbon number of 6 to 30, or a substituted or unsubstituted heteroarylene group having a ring-forming carbon number of 2 to 30.

3. The light-emitting element of claim 2, wherein the emission layer further comprises a fourth compound represented by Formula D-1: 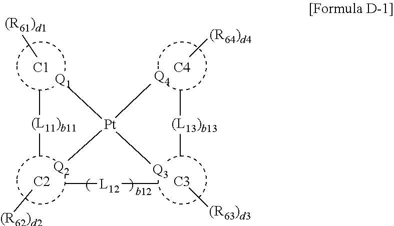
wherein in Formula D-1,
Q₁ to Q₄ are each independently C or N,
C1 to C4 are each independently a substituted or unsubstituted hydrocarbon ring having a ring-forming carbon number of 5 to 30, or a substituted or unsubstituted heterocycle having a ring-forming carbon number of 2 to 30,
L₁₁ to L₁₃ are each independently a direct linkage, 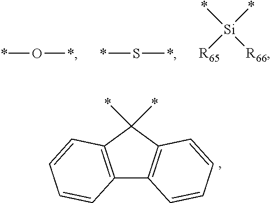
a substituted or unsubstituted alkylene group having a carbon number of 1 to 20, a substituted or unsubstituted arylene group having a ring-forming carbon number of 6 to 30, or a substituted or unsubstituted heteroarylene group having a ring-forming carbon number of 2 to 30,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 60, or a substituted or unsubstituted heteroaryl group having a ring-forming carbon number of 2 to 60, and
d1 to d4 are each independently an integer from 0 to 4.

4. The light-emitting element of claim 1, wherein
among two selected from R^{a} to R^{e}, one thereof is a cyano group, and the other thereof is a substituted or unsubstituted phenyl group, and
the remainder of R^{a} to R^{e} that are not the cyano group or the substituted or unsubstituted phenyl group, are each independently a hydrogen atom, a deuterium atom, or a substituted or unsubstituted aryl group having a ring-forming carbon number of 6 to 30.

5. The light-emitting element of claim 1, wherein the first compound is represented by one of Formula 2-1 to Formula 2-3: 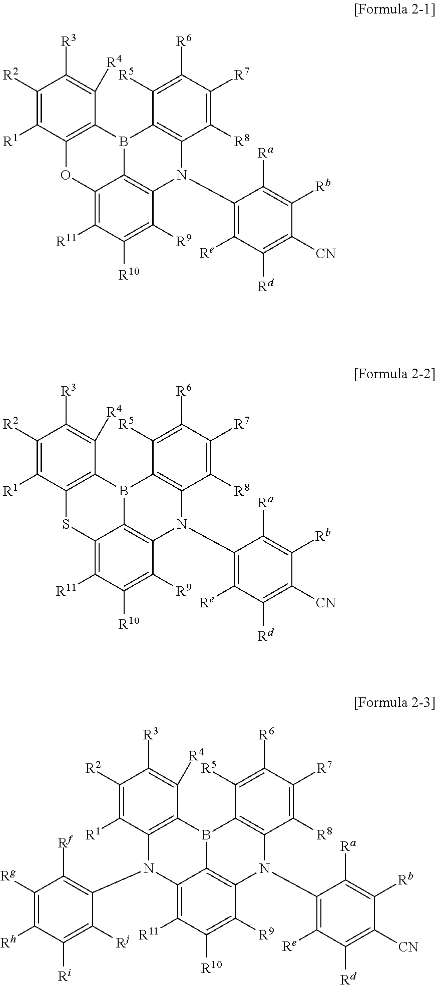
wherein in Formula 2-1 to Formula 2-3,
one or two of R^{a}, R^{b}, R^{d} and R^{e} are each independently a substituted or unsubstituted phenyl group,
the remainder of R^{a}, R^{b}, R^{d} and R^{e} are each independently a hydrogen atom or a deuterium atom, and
R¹ to R¹¹ are each the same as defined in Formula 1, and
wherein in Formula 2-3,
R^{f}, R^{g}, R^{h}, Rⁱ, and R^{j} are each independently a hydrogen atom, a deuterium atom, a cyano group, an unsubstituted alkyl group having a carbon number of 1 to 20, or a substituted or unsubstituted aryl group having a ring-forming carbon number of 6 to 30.

6. The light-emitting element of claim 1, wherein the first compound is represented by one of Formula 3-1 to Formula 3-5: 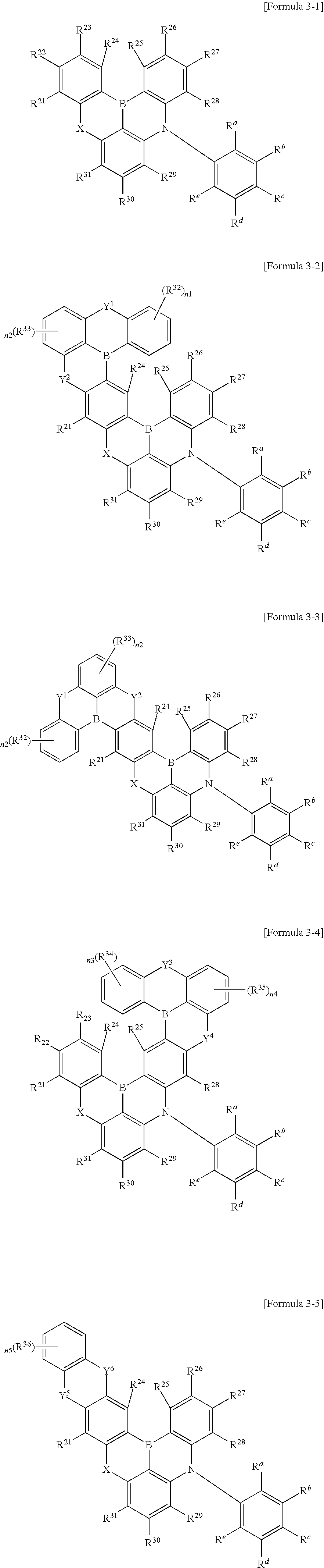
wherein in Formula 3-1 to Formula 3-5,
R²¹ to R³⁶ are each independently a hydrogen atom, a deuterium atom, a substituted or unsubstituted amine group, a substituted or unsubstituted oxy group, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
X, R^{a}, R^{b}, R^{c}, R^{d}, and R^{e} are each the same as defined in Formula 1, and
wherein in Formula 3-2 to Formula 3-5,
n1, n3, and n5 are each independently an integer from 0 to 4,
n2 and n4 are each independently an integer from 0 to 3,
Y¹ to Y⁴ are each independently O, S, or N(R³⁷),
Y⁵ and Y⁶ are each independently O, S, N(R³⁸), or B(R³⁹), and
R³⁷ to R³⁹ are each independently a substituted or unsubstituted aryl group having a ring-forming carbon number of 6 to 30.

7. The light-emitting element of claim 1, wherein at least one hydrogen atom in the first compound is substituted with a deuterium atom.

8. The light-emitting element of claim 1, wherein the emission layer emits delayed fluorescence.

9. The light-emitting element of claim 1, wherein the emission layer emits blue light.

10. The light-emitting element of claim 1, wherein the first compound is selected from Compound Group 1: 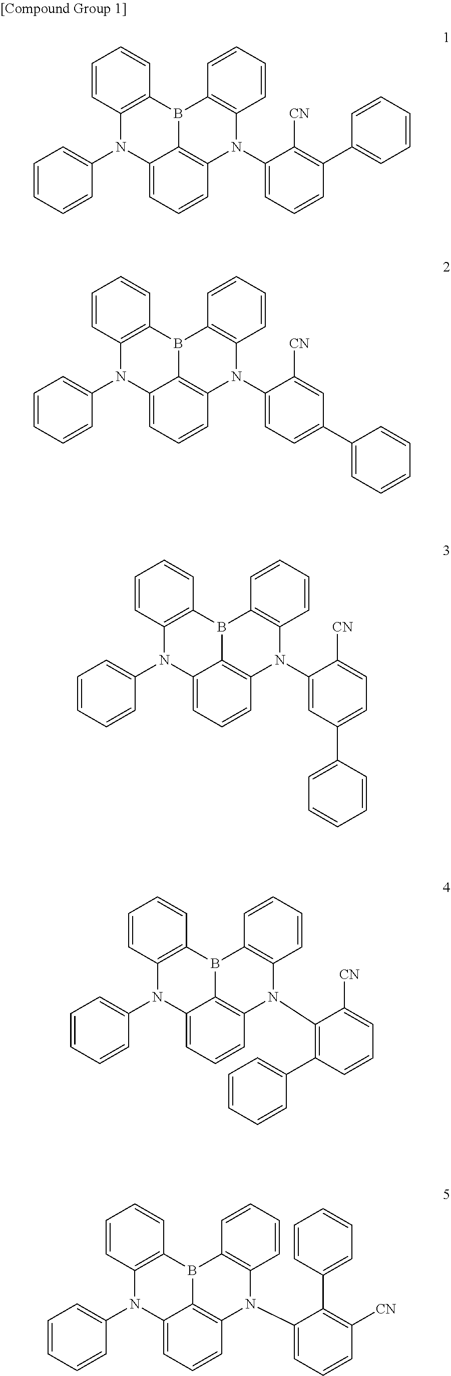 [SMILES: N#Cc1c(-c2ccccc2)cccc1N1c2ccccc2B2c3ccccc3N(c3ccccc3)c3cccc1c32 ; N#Cc1cc(-c2ccccc2)ccc1N1c2ccccc2B2c3ccccc3N(c3ccccc3)c3cccc1c32 ; N#Cc1ccc(-c2ccccc2)cc1N1c2ccccc2B2c3ccccc3N(c3ccccc3)c3cccc1c32 ; N#Cc1cccc(-c2ccccc2)c1N1c2ccccc2B2c3ccccc3N(c3ccccc3)c3cccc1c32 ; N#Cc1cccc(N2c3ccccc3B3c4ccccc4N(c4ccccc4)c4cccc2c43)c1-c1ccccc1] 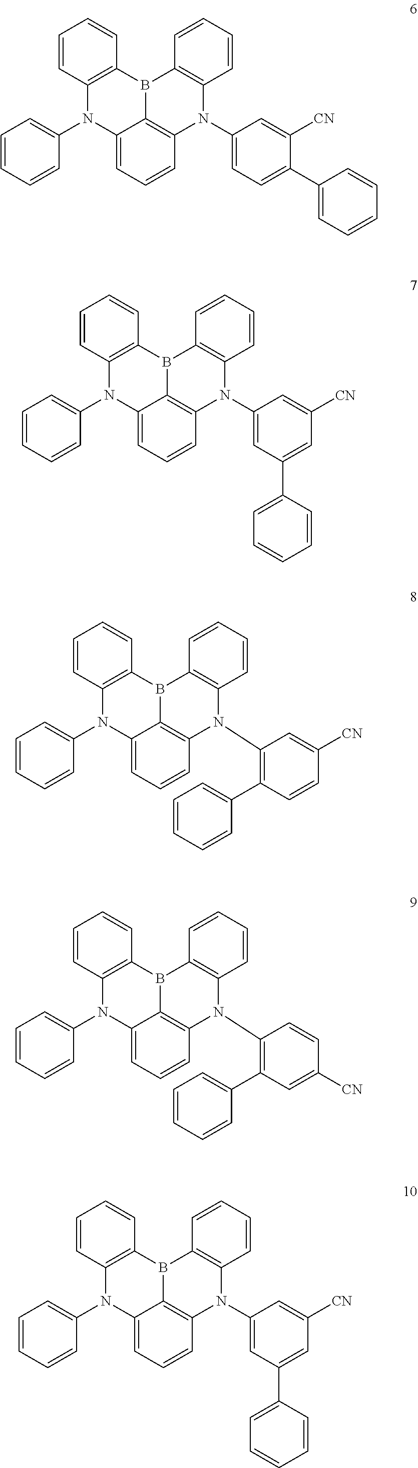 [SMILES: N#Cc1cc(N2c3ccccc3B3c4ccccc4N(c4ccccc4)c4cccc2c43)ccc1-c1ccccc1 ; N#Cc1cc(-c2ccccc2)cc(N2c3ccccc3B3c4ccccc4N(c4ccccc4)c4cccc2c43)c1 ; N#Cc1ccc(-c2ccccc2)c(N2c3ccccc3B3c4ccccc4N(c4ccccc4)c4cccc2c43)c1 ; N#Cc1ccc(N2c3ccccc3B3c4ccccc4N(c4ccccc4)c4cccc2c43)c(-c2ccccc2)c1 ; N#Cc1cc(-c2ccccc2)cc(N2c3ccccc3B3c4ccccc4N(c4ccccc4)c4cccc2c43)c1] 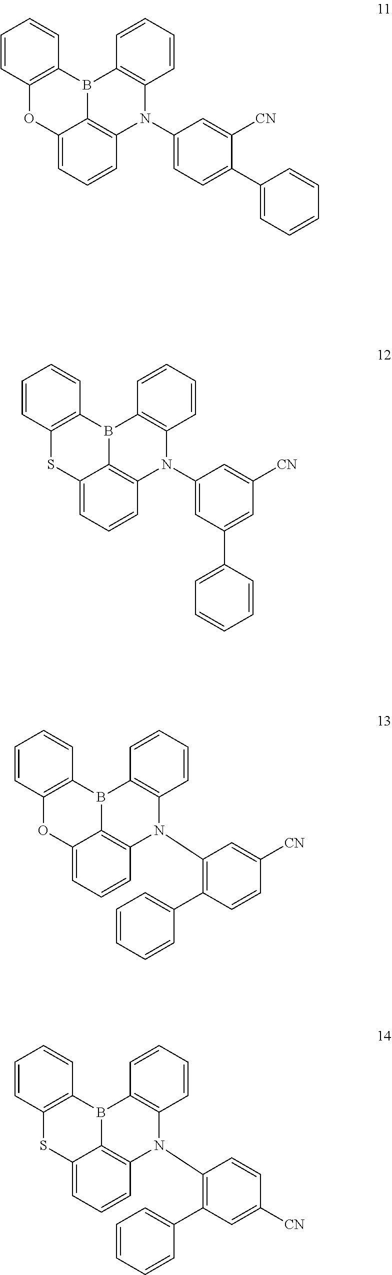 [SMILES: N#Cc1cc(N2c3ccccc3B3c4ccccc4Oc4cccc2c43)ccc1-c1ccccc1 ; N#Cc1cc(-c2ccccc2)cc(N2c3ccccc3B3c4ccccc4Sc4cccc2c43)c1 ; N#Cc1ccc(-c2ccccc2)c(N2c3ccccc3B3c4ccccc4Oc4cccc2c43)c1 ; N#Cc1ccc(N2c3ccccc3B3c4ccccc4Sc4cccc2c43)c(-c2ccccc2)c1] 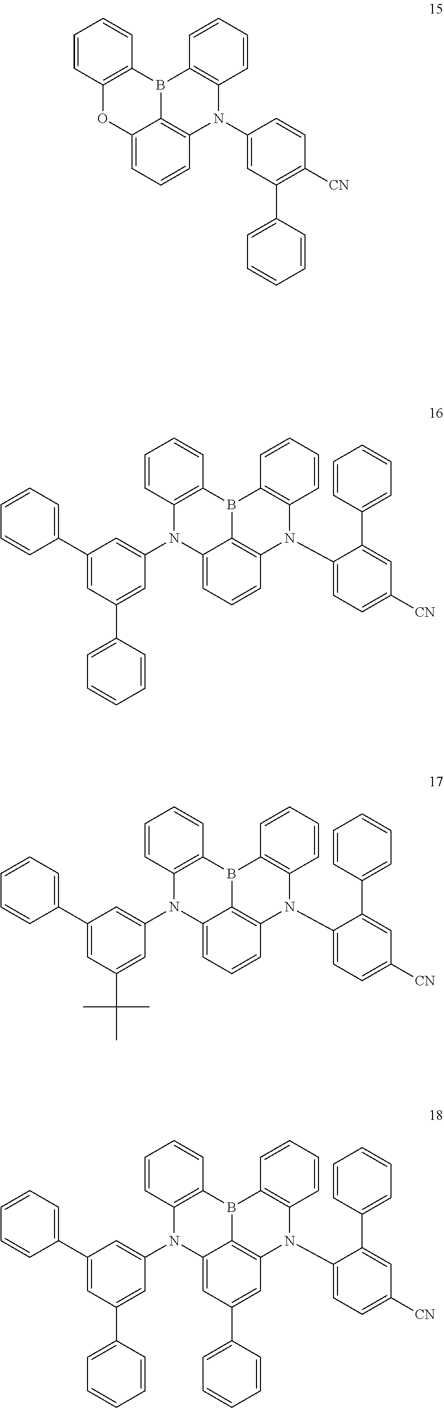 [SMILES: N#Cc1ccc(N2c3ccccc3B3c4ccccc4Oc4cccc2c43)cc1-c1ccccc1 ; N#Cc1ccc(N2c3ccccc3B3c4ccccc4N(c4cc(-c5ccccc5)cc(-c5ccccc5)c4)c4cccc2c43)c(-c2ccccc2)c1 ; CC(C)(C)c1cc(-c2ccccc2)cc(N2c3ccccc3B3c4ccccc4N(c4ccc(C#N)cc4-c4ccccc4)c4cccc2c43)c1 ; N#Cc1ccc(N2c3ccccc3B3c4ccccc4N(c4cc(-c5ccccc5)cc(-c5ccccc5)c4)c4cc(-c5ccccc5)cc2c43)c(-c2ccccc2)c1] 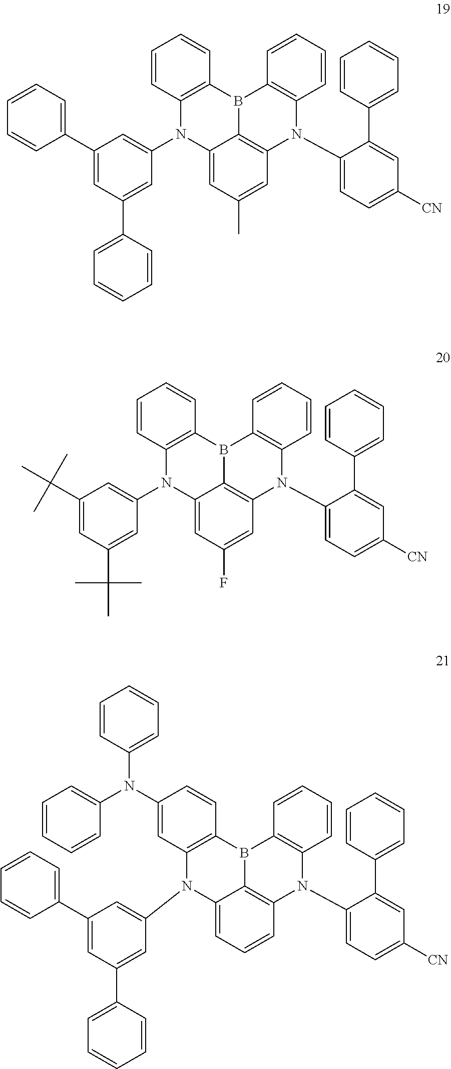 [SMILES: Cc1cc2c3c(c1)N(c1ccc(C#N)cc1-c1ccccc1)c1ccccc1B3c1ccccc1N2c1cc(-c2ccccc2)cc(-c2ccccc2)c1 ; CC(C)(C)c1cc(N2c3ccccc3B3c4ccccc4N(c4ccc(C#N)cc4-c4ccccc4)c4cc(F)cc2c43)cc(C(C)(C)C)c1 ; N#Cc1ccc(N2c3ccccc3B3c4ccc(N(c5ccccc5)c5ccccc5)cc4N(c4cc(-c5ccccc5)cc(-c5ccccc5)c4)c4cccc2c43)c(-c2ccccc2)c1] 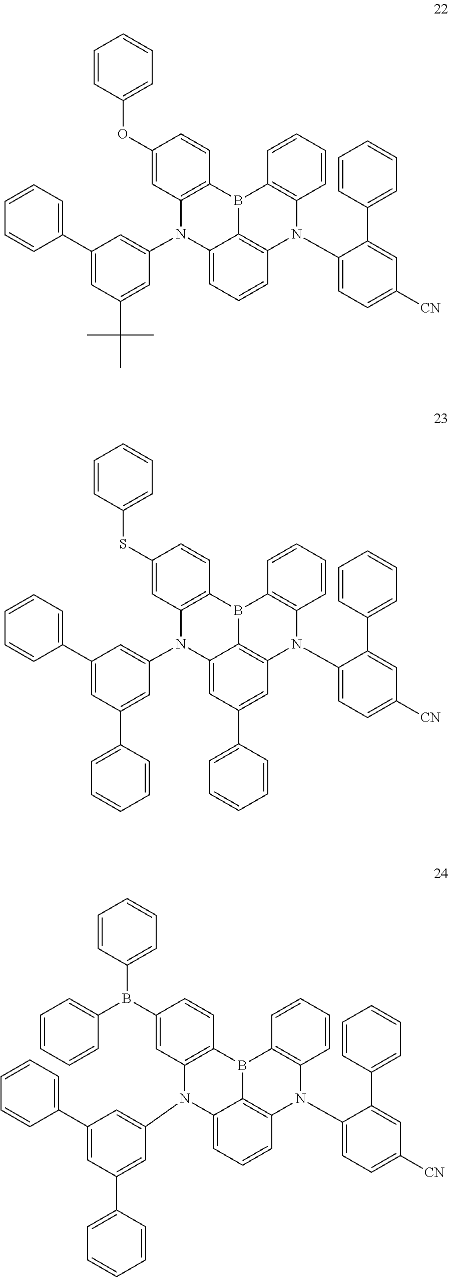 [SMILES: CC(C)(C)c1cc(-c2ccccc2)cc(N2c3cc(Oc4ccccc4)ccc3B3c4ccccc4N(c4ccc(C#N)cc4-c4ccccc4)c4cccc2c43)c1 ; N#Cc1ccc(N2c3ccccc3B3c4ccc(Sc5ccccc5)cc4N(c4cc(-c5ccccc5)cc(-c5ccccc5)c4)c4cc(-c5ccccc5)cc2c43)c(-c2ccccc2)c1 ; N#Cc1ccc(N2c3ccccc3B3c4ccc(B(c5ccccc5)c5ccccc5)cc4N(c4cc(-c5ccccc5)cc(-c5ccccc5)c4)c4cccc2c43)c(-c2ccccc2)c1] 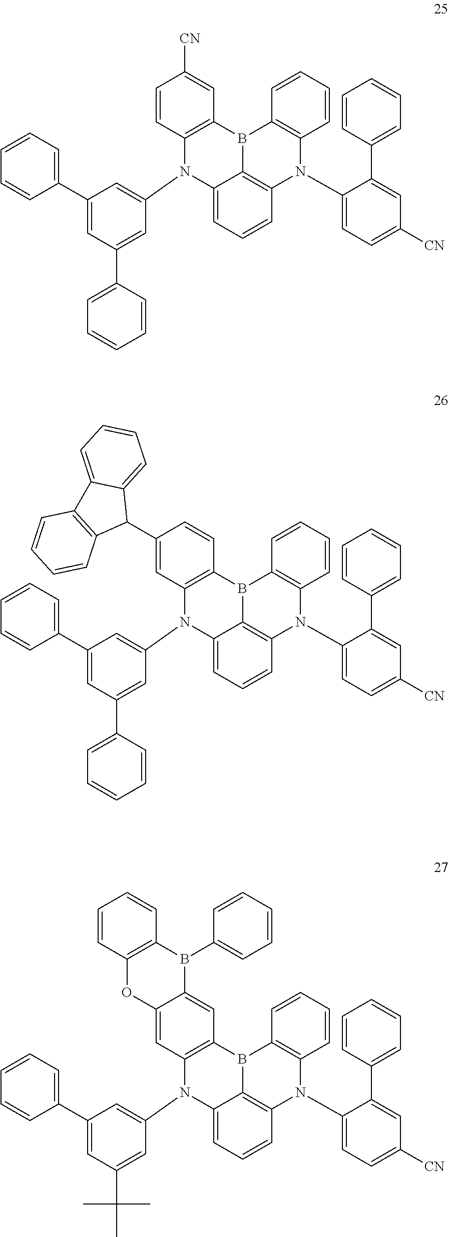 [SMILES: N#Cc1ccc2c(c1)B1c3ccccc3N(c3ccc(C#N)cc3-c3ccccc3)c3cccc(c31)N2c1cc(-c2ccccc2)cc(-c2ccccc2)c1 ; N#Cc1ccc(N2c3ccccc3B3c4ccc(C5c6ccccc6-c6ccccc65)cc4N(c4cc(-c5ccccc5)cc(-c5ccccc5)c4)c4cccc2c43)c(-c2ccccc2)c1 ; CC(C)(C)c1cc(-c2ccccc2)cc(N2c3cc4c(cc3B3c5ccccc5N(c5ccc(C#N)cc5-c5ccccc5)c5cccc2c53)B(c2ccccc2)c2ccccc2O4)c1] 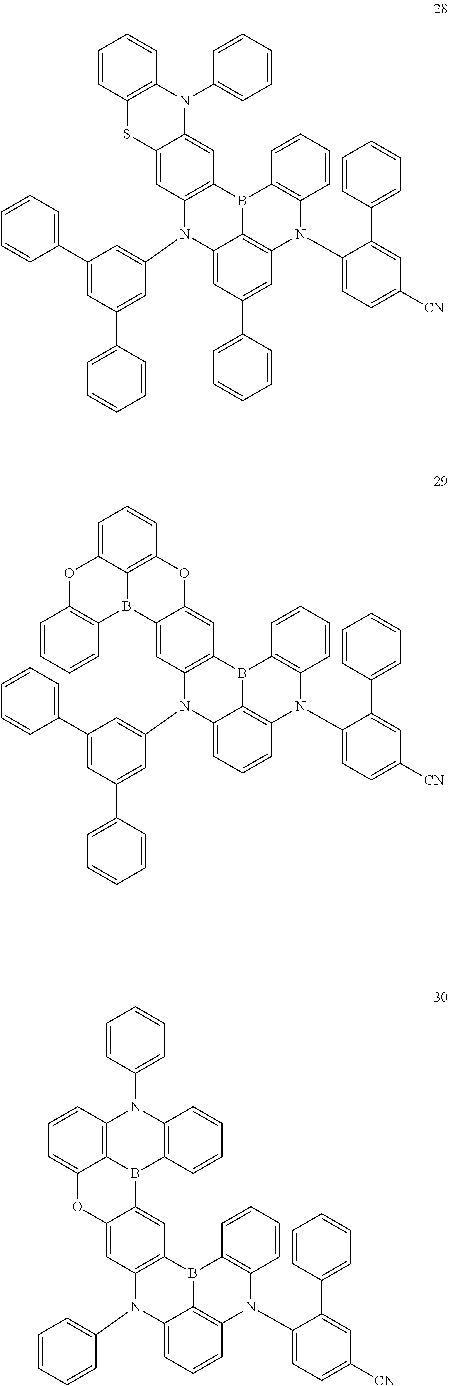 [SMILES: N#Cc1ccc(N2c3ccccc3B3c4cc5c(cc4N(c4cc(-c6ccccc6)cc(-c6ccccc6)c4)c4cc(-c6ccccc6)cc2c43)Sc2ccccc2N5c2ccccc2)c(-c2ccccc2)c1 ; N#Cc1ccc(N2c3ccccc3B3c4cc5c(cc4N(c4cc(-c6ccccc6)cc(-c6ccccc6)c4)c4cccc2c43)B2c3ccccc3Oc3cccc(c32)O5)c(-c2ccccc2)c1 ; N#Cc1ccc(N2c3ccccc3B3c4cc5c(cc4N(c4ccccc4)c4cccc2c43)Oc2cccc3c2B5c2ccccc2N3c2ccccc2)c(-c2ccccc2)c1] 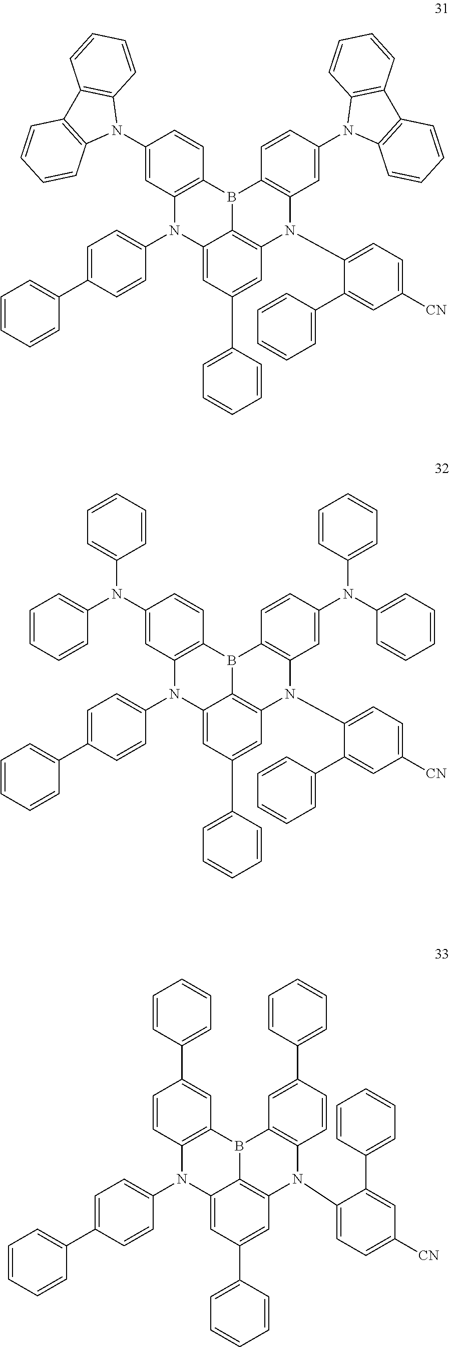 [SMILES: N#Cc1ccc(N2c3cc(-n4c5ccccc5c5ccccc54)ccc3B3c4ccc(-n5c6ccccc6c6ccccc65)cc4N(c4ccc(-c5ccccc5)cc4)c4cc(-c5ccccc5)cc2c43)c(-c2ccccc2)c1 ; N#Cc1ccc(N2c3cc(N(c4ccccc4)c4ccccc4)ccc3B3c4ccc(N(c5ccccc5)c5ccccc5)cc4N(c4ccc(-c5ccccc5)cc4)c4cc(-c5ccccc5)cc2c43)c(-c2ccccc2)c1 ; N#Cc1ccc(N2c3ccc(-c4ccccc4)cc3B3c4cc(-c5ccccc5)ccc4N(c4ccc(-c5ccccc5)cc4)c4cc(-c5ccccc5)cc2c43)c(-c2ccccc2)c1] 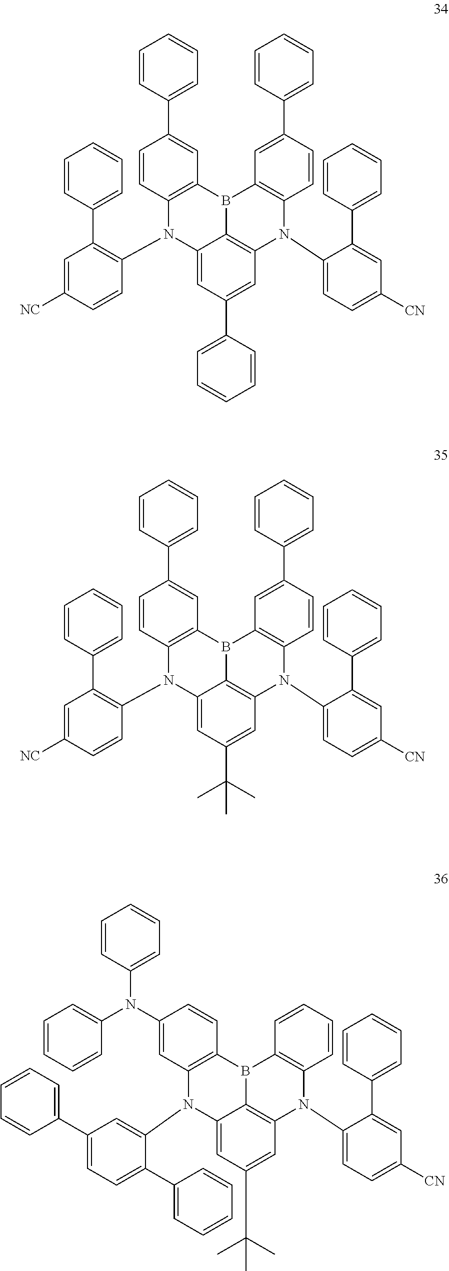 [SMILES: N#Cc1ccc(N2c3ccc(-c4ccccc4)cc3B3c4cc(-c5ccccc5)ccc4N(c4ccc(C#N)cc4-c4ccccc4)c4cc(-c5ccccc5)cc2c43)c(-c2ccccc2)c1 ; CC(C)(C)c1cc2c3c(c1)N(c1ccc(C#N)cc1-c1ccccc1)c1ccc(-c4ccccc4)cc1B3c1cc(-c3ccccc3)ccc1N2c1ccc(C#N)cc1-c1ccccc1 ; CC(C)(C)c1cc2c3c(c1)N(c1cc(-c4ccccc4)ccc1-c1ccccc1)c1cc(N(c4ccccc4)c4ccccc4)ccc1B3c1ccccc1N2c1ccc(C#N)cc1-c1ccccc1] 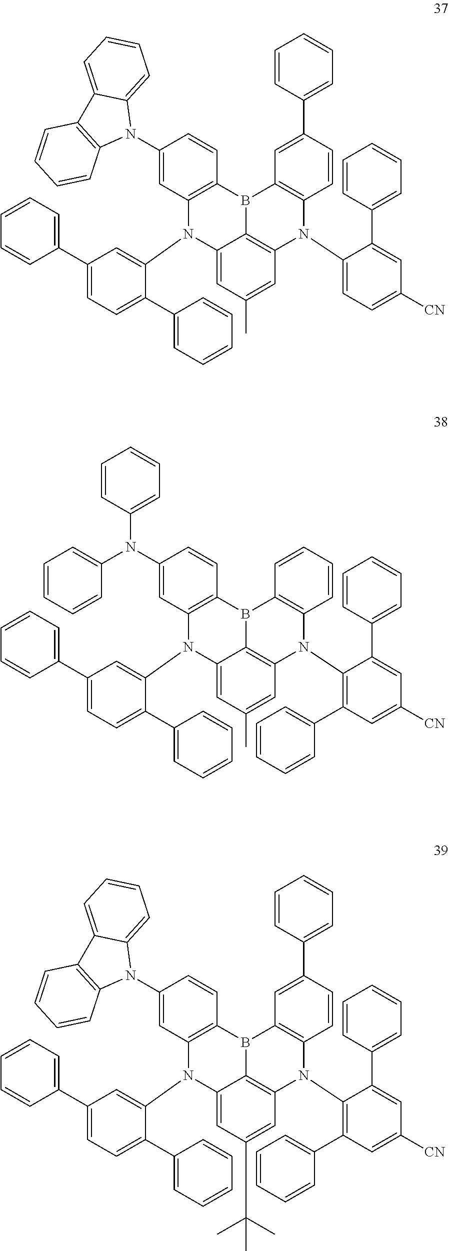 [SMILES: Cc1cc2c3c(c1)N(c1cc(-c4ccccc4)ccc1-c1ccccc1)c1cc(-n4c5ccccc5c5ccccc54)ccc1B3c1cc(-c3ccccc3)ccc1N2c1ccc(C#N)cc1-c1ccccc1 ; Cc1cc2c3c(c1)N(c1c(-c4ccccc4)cc(C#N)cc1-c1ccccc1)c1ccccc1B3c1ccc(N(c3ccccc3)c3ccccc3)cc1N2c1cc(-c2ccccc2)ccc1-c1ccccc1 ; CC(C)(C)c1cc2c3c(c1)N(c1c(-c4ccccc4)cc(C#N)cc1-c1ccccc1)c1ccc(-c4ccccc4)cc1B3c1ccc(-n3c4ccccc4c4ccccc43)cc1N2c1cc(-c2ccccc2)ccc1-c1ccccc1] 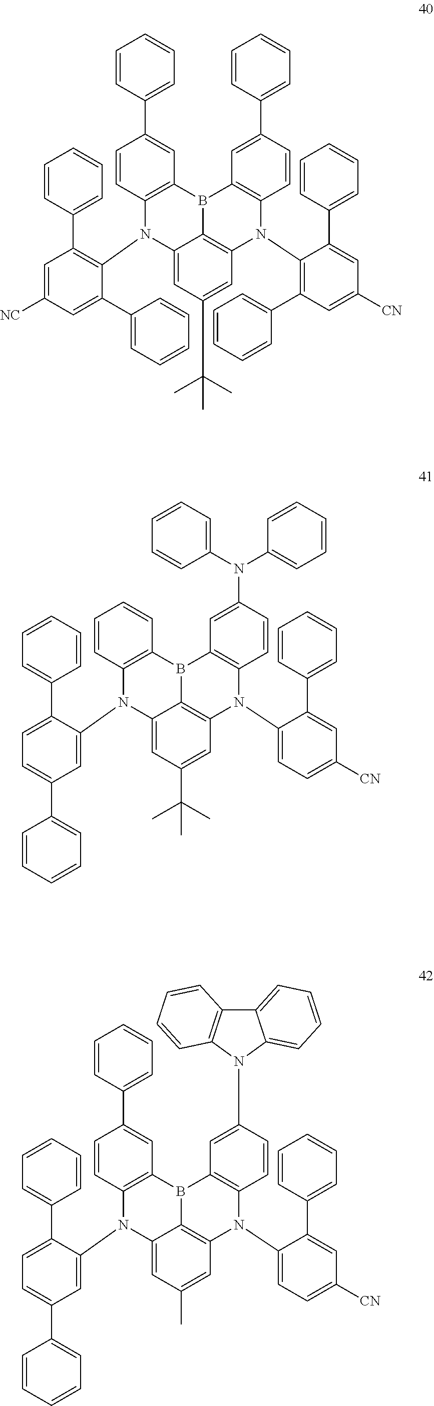 [SMILES: CC(C)(C)c1cc2c3c(c1)N(c1c(-c4ccccc4)cc(C#N)cc1-c1ccccc1)c1ccc(-c4ccccc4)cc1B3c1cc(-c3ccccc3)ccc1N2c1c(-c2ccccc2)cc(C#N)cc1-c1ccccc1 ; CC(C)(C)c1cc2c3c(c1)N(c1cc(-c4ccccc4)ccc1-c1ccccc1)c1ccccc1B3c1cc(N(c3ccccc3)c3ccccc3)ccc1N2c1ccc(C#N)cc1-c1ccccc1 ; Cc1cc2c3c(c1)N(c1cc(-c4ccccc4)ccc1-c1ccccc1)c1ccc(-c4ccccc4)cc1B3c1cc(-n3c4ccccc4c4ccccc43)ccc1N2c1ccc(C#N)cc1-c1ccccc1] 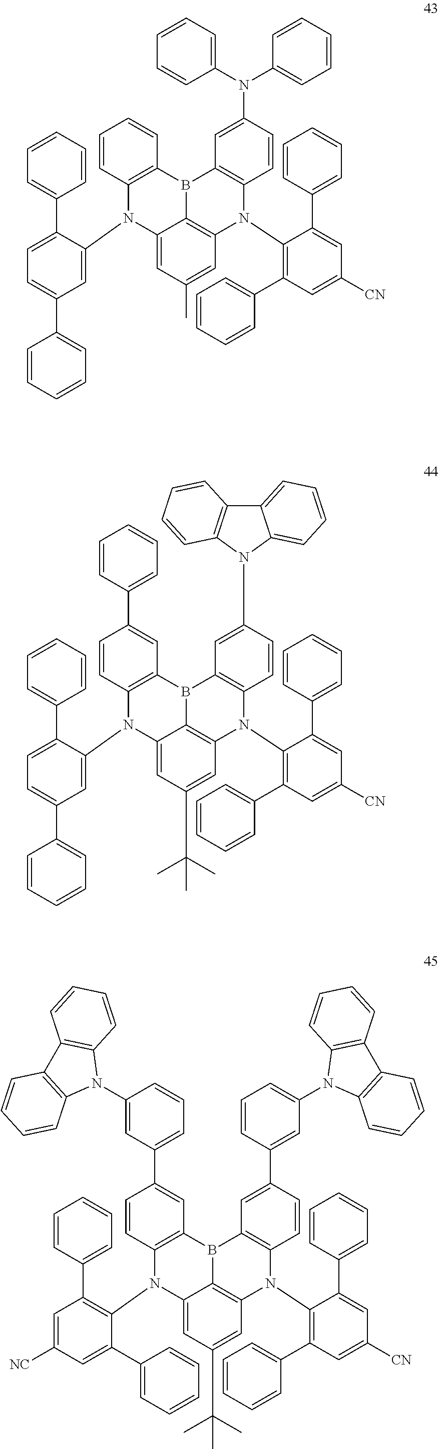 [SMILES: Cc1cc2c3c(c1)N(c1c(-c4ccccc4)cc(C#N)cc1-c1ccccc1)c1ccc(N(c4ccccc4)c4ccccc4)cc1B3c1ccccc1N2c1cc(-c2ccccc2)ccc1-c1ccccc1 ; CC(C)(C)c1cc2c3c(c1)N(c1c(-c4ccccc4)cc(C#N)cc1-c1ccccc1)c1ccc(-n4c5ccccc5c5ccccc54)cc1B3c1cc(-c3ccccc3)ccc1N2c1cc(-c2ccccc2)ccc1-c1ccccc1 ; CC(C)(C)c1cc2c3c(c1)N(c1c(-c4ccccc4)cc(C#N)cc1-c1ccccc1)c1ccc(-c4cccc(-n5c6ccccc6c6ccccc65)c4)cc1B3c1cc(-c3cccc(-n4c5ccccc5c5ccccc54)c3)ccc1N2c1c(-c2ccccc2)cc(C#N)cc1-c1ccccc1] 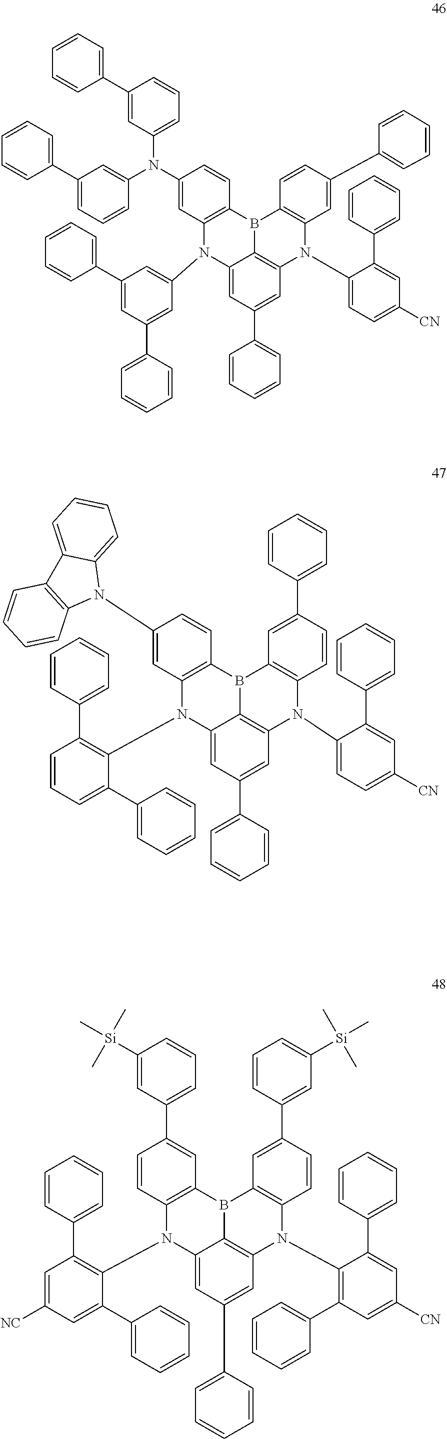 [SMILES: N#Cc1ccc(N2c3cc(-c4ccccc4)ccc3B3c4ccc(N(c5cccc(-c6ccccc6)c5)c5cccc(-c6ccccc6)c5)cc4N(c4cc(-c5ccccc5)cc(-c5ccccc5)c4)c4cc(-c5ccccc5)cc2c43)c(-c2ccccc2)c1 ; N#Cc1ccc(N2c3ccc(-c4ccccc4)cc3B3c4ccc(-n5c6ccccc6c6ccccc65)cc4N(c4c(-c5ccccc5)cccc4-c4ccccc4)c4cc(-c5ccccc5)cc2c43)c(-c2ccccc2)c1 ; C[Si](C)(C)c1cccc(-c2ccc3c(c2)B2c4cc(-c5cccc([Si](C)(C)C)c5)ccc4N(c4c(-c5ccccc5)cc(C#N)cc4-c4ccccc4)c4cc(-c5ccccc5)cc(c42)N3c2c(-c3ccccc3)cc(C#N)cc2-c2ccccc2)c1] 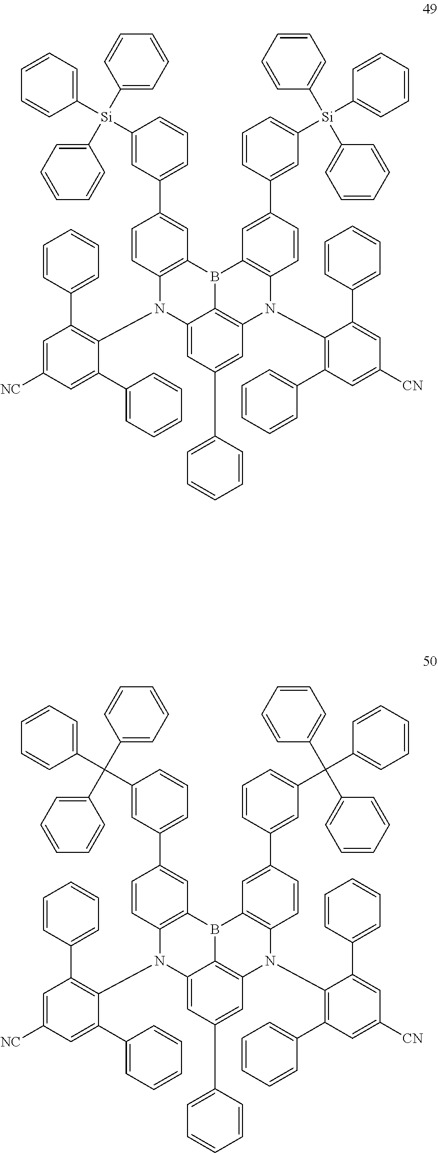 [SMILES: N#Cc1cc(-c2ccccc2)c(N2c3ccc(-c4cccc([Si](c5ccccc5)(c5ccccc5)c5ccccc5)c4)cc3B3c4cc(-c5cccc([Si](c6ccccc6)(c6ccccc6)c6ccccc6)c5)ccc4N(c4c(-c5ccccc5)cc(C#N)cc4-c4ccccc4)c4cc(-c5ccccc5)cc2c43)c(-c2ccccc2)c1 ; N#Cc1cc(-c2ccccc2)c(N2c3ccc(-c4cccc(C(c5ccccc5)(c5ccccc5)c5ccccc5)c4)cc3B3c4cc(-c5cccc(C(c6ccccc6)(c6ccccc6)c6ccccc6)c5)ccc4N(c4c(-c5ccccc5)cc(C#N)cc4-c4ccccc4)c4cc(-c5ccccc5)cc2c43)c(-c2ccccc2)c1] 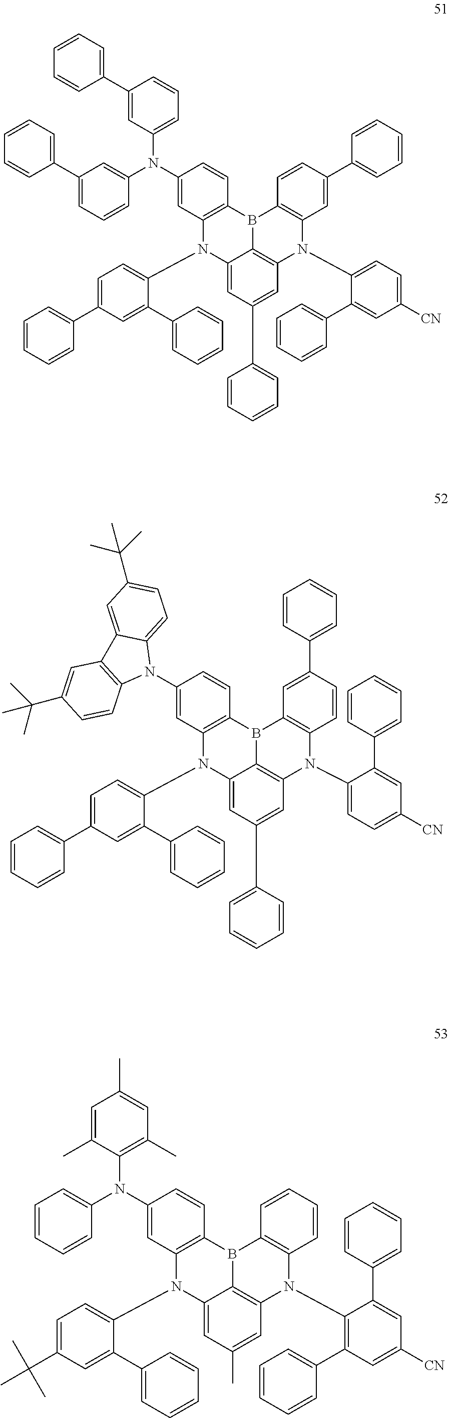 [SMILES: N#Cc1ccc(N2c3cc(-c4ccccc4)ccc3B3c4ccc(N(c5cccc(-c6ccccc6)c5)c5cccc(-c6ccccc6)c5)cc4N(c4ccc(-c5ccccc5)cc4-c4ccccc4)c4cc(-c5ccccc5)cc2c43)c(-c2ccccc2)c1 ; CC(C)(C)c1ccc2c(c1)c1cc(C(C)(C)C)ccc1n2-c1ccc2c(c1)N(c1ccc(-c3ccccc3)cc1-c1ccccc1)c1cc(-c3ccccc3)cc3c1B2c1cc(-c2ccccc2)ccc1N3c1ccc(C#N)cc1-c1ccccc1 ; Cc1cc(C)c(N(c2ccccc2)c2ccc3c(c2)N(c2ccc(C(C)(C)C)cc2-c2ccccc2)c2cc(C)cc4c2B3c2ccccc2N4c2c(-c3ccccc3)cc(C#N)cc2-c2ccccc2)c(C)c1] 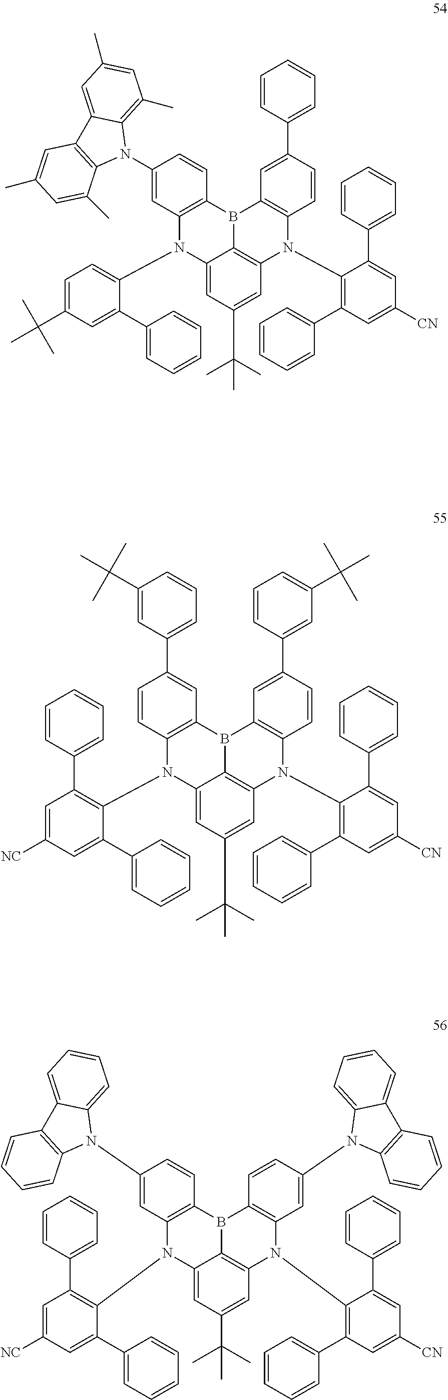 [SMILES: Cc1cc(C)c2c(c1)c1cc(C)cc(C)c1n2-c1ccc2c(c1)N(c1ccc(C(C)(C)C)cc1-c1ccccc1)c1cc(C(C)(C)C)cc3c1B2c1cc(-c2ccccc2)ccc1N3c1c(-c2ccccc2)cc(C#N)cc1-c1ccccc1 ; CC(C)(C)c1cccc(-c2ccc3c(c2)B2c4cc(-c5cccc(C(C)(C)C)c5)ccc4N(c4c(-c5ccccc5)cc(C#N)cc4-c4ccccc4)c4cc(C(C)(C)C)cc(c42)N3c2c(-c3ccccc3)cc(C#N)cc2-c2ccccc2)c1 ; CC(C)(C)c1cc2c3c(c1)N(c1c(-c4ccccc4)cc(C#N)cc1-c1ccccc1)c1cc(-n4c5ccccc5c5ccccc54)ccc1B3c1ccc(-n3c4ccccc4c4ccccc43)cc1N2c1c(-c2ccccc2)cc(C#N)cc1-c1ccccc1] 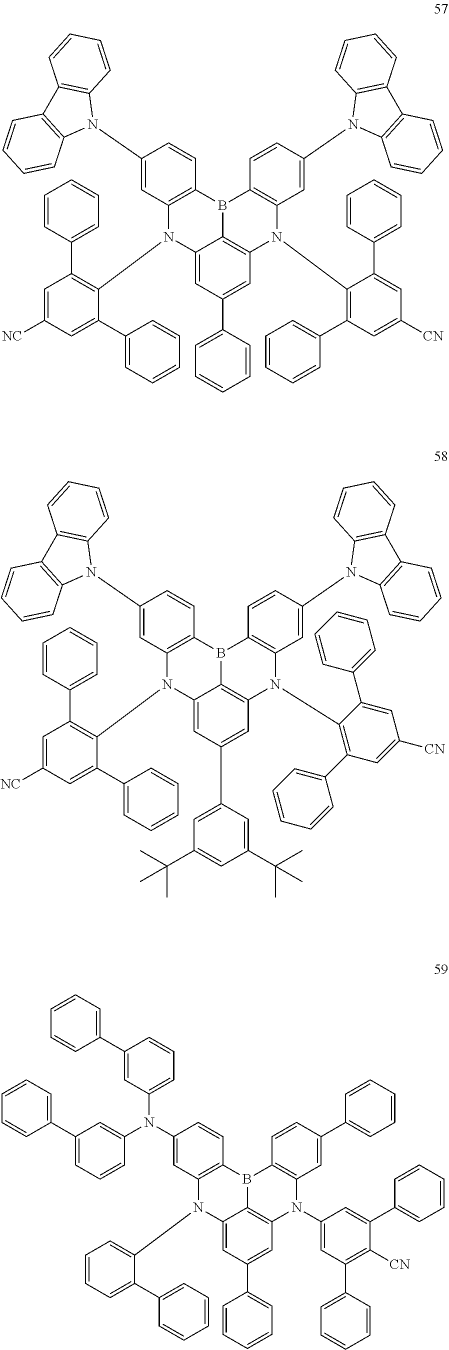 [SMILES: N#Cc1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C#N)cc4-c4ccccc4)c4cc(-c5ccccc5)cc2c43)c(-c2ccccc2)c1 ; CC(C)(C)c1cc(-c2cc3c4c(c2)N(c2c(-c5ccccc5)cc(C#N)cc2-c2ccccc2)c2cc(-n5c6ccccc6c6ccccc65)ccc2B4c2ccc(-n4c5ccccc5c5ccccc54)cc2N3c2c(-c3ccccc3)cc(C#N)cc2-c2ccccc2)cc(C(C)(C)C)c1 ; N#Cc1c(-c2ccccc2)cc(N2c3cc(-c4ccccc4)ccc3B3c4ccc(N(c5cccc(-c6ccccc6)c5)c5cccc(-c6ccccc6)c5)cc4N(c4ccccc4-c4ccccc4)c4cc(-c5ccccc5)cc2c43)cc1-c1ccccc1] 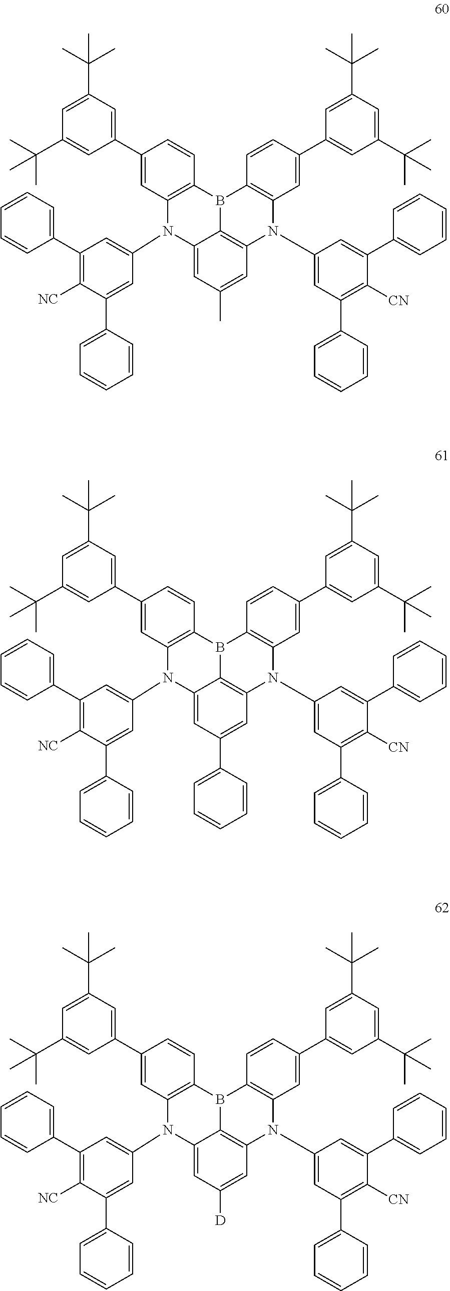 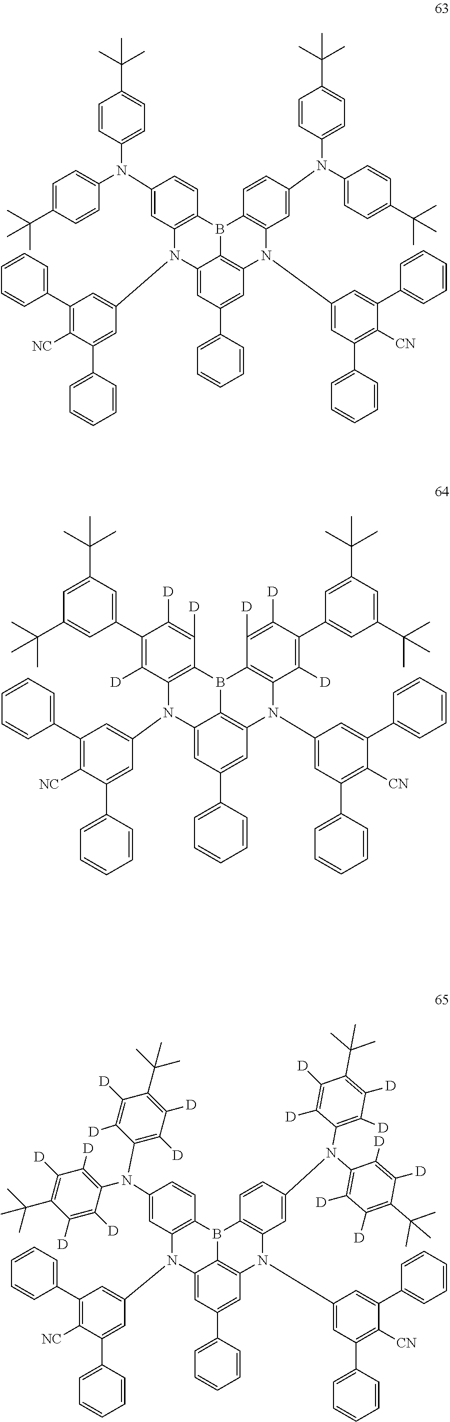 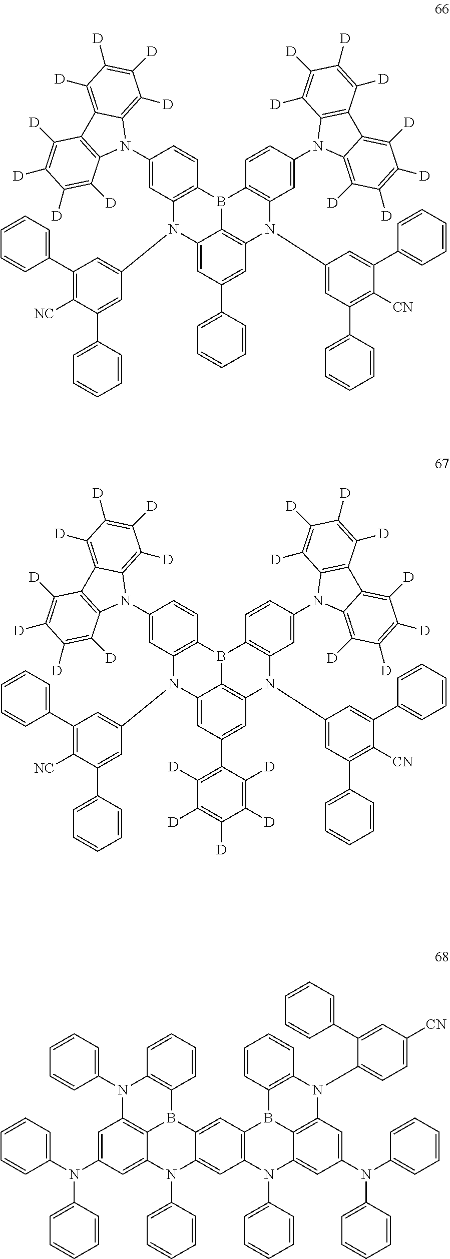 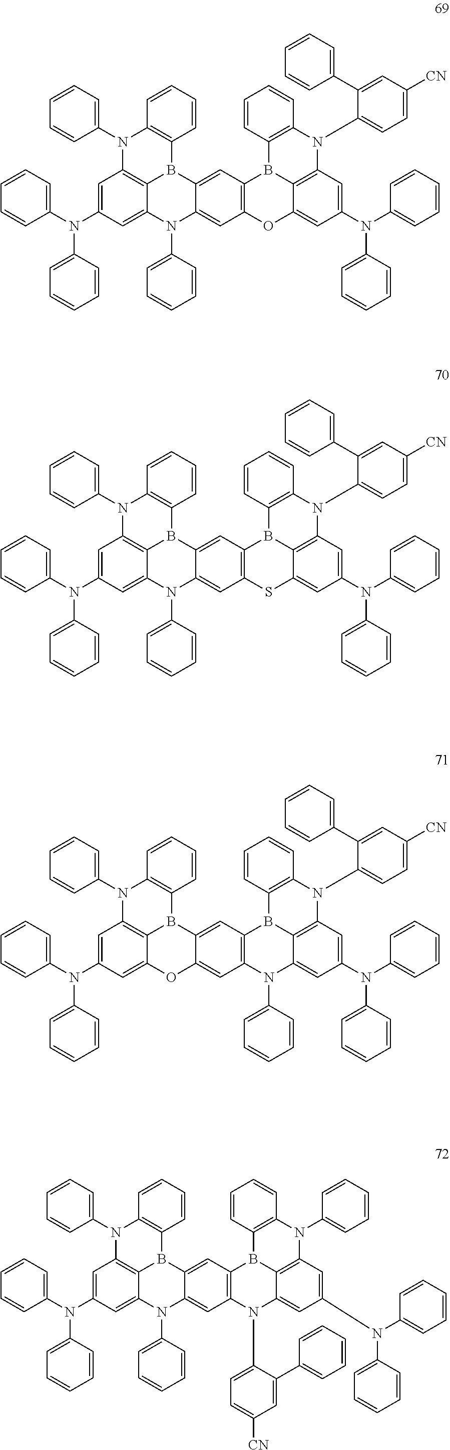 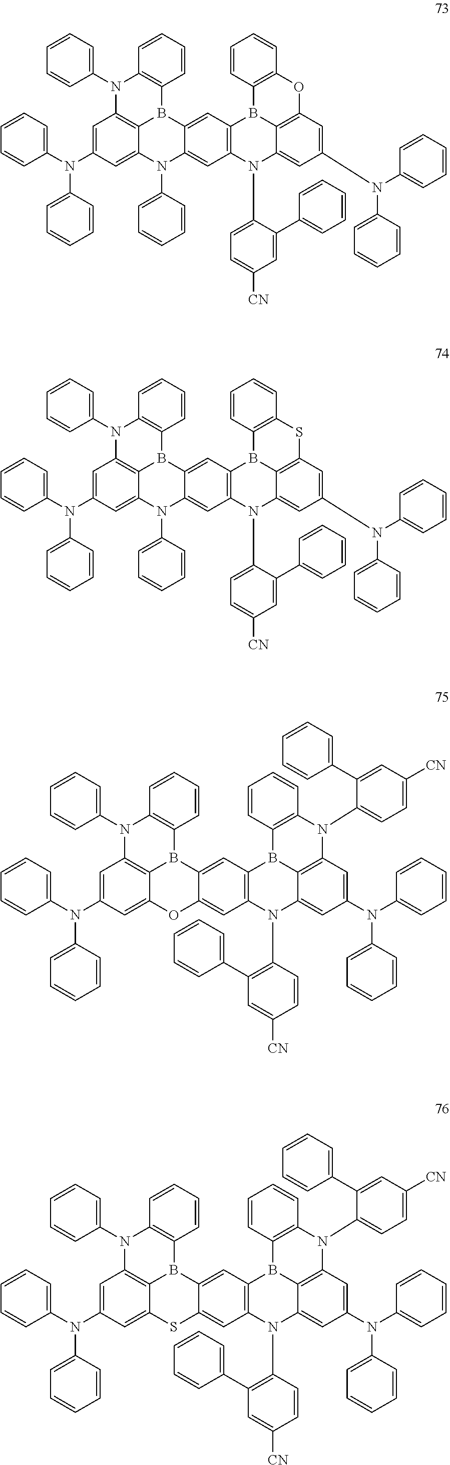 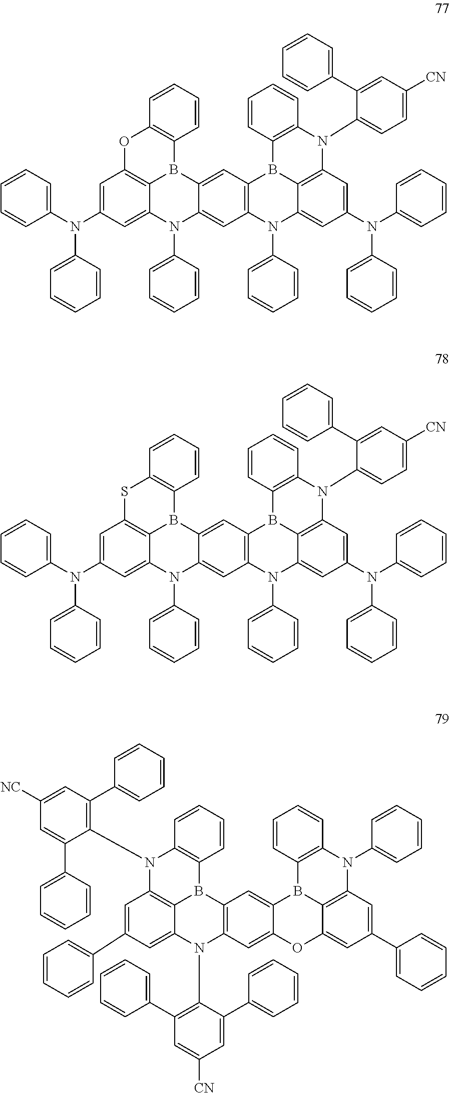 [SMILES: N#Cc1ccc(N2c3ccccc3B3c4cc5c(cc4N(c4ccccc4)c4cc(N(c6ccccc6)c6ccccc6)cc2c43)N(c2ccccc2)c2cc(N(c3ccccc3)c3ccccc3)cc3c2B5c2ccccc2O3)c(-c2ccccc2)c1 ; N#Cc1ccc(N2c3ccccc3B3c4cc5c(cc4N(c4ccccc4)c4cc(N(c6ccccc6)c6ccccc6)cc2c43)N(c2ccccc2)c2cc(N(c3ccccc3)c3ccccc3)cc3c2B5c2ccccc2S3)c(-c2ccccc2)c1 ; N#Cc1cc(-c2ccccc2)c(N2c3ccccc3B3c4cc5c(cc4N(c4c(-c6ccccc6)cc(C#N)cc4-c4ccccc4)c4cc(-c6ccccc6)cc2c43)Oc2cc(-c3ccccc3)cc3c2B5c2ccccc2N3c2ccccc2)c(-c2ccccc2)c1] 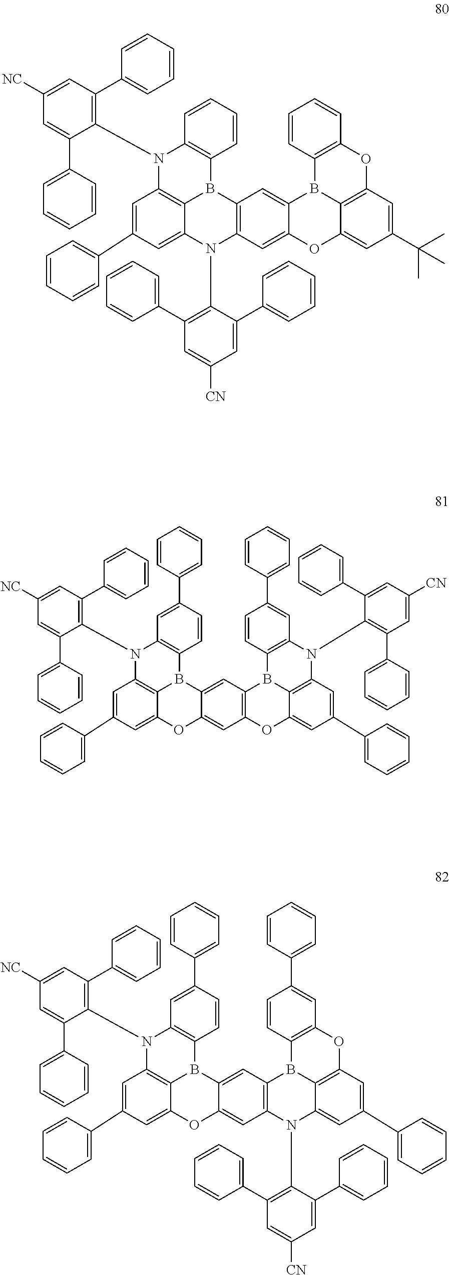 [SMILES: CC(C)(C)c1cc2c3c(c1)Oc1cc4c(cc1B3c1ccccc1O2)B1c2ccccc2N(c2c(-c3ccccc3)cc(C#N)cc2-c2ccccc2)c2cc(-c3ccccc3)cc(c21)N4c1c(-c2ccccc2)cc(C#N)cc1-c1ccccc1 ; N#Cc1cc(-c2ccccc2)c(N2c3cc(-c4ccccc4)ccc3B3c4cc5c(cc4Oc4cc(-c6ccccc6)cc2c43)Oc2cc(-c3ccccc3)cc3c2B5c2ccc(-c4ccccc4)cc2N3c2c(-c3ccccc3)cc(C#N)cc2-c2ccccc2)c(-c2ccccc2)c1 ; N#Cc1cc(-c2ccccc2)c(N2c3cc(-c4ccccc4)ccc3B3c4cc5c(cc4Oc4cc(-c6ccccc6)cc2c43)N(c2c(-c3ccccc3)cc(C#N)cc2-c2ccccc2)c2cc(-c3ccccc3)cc3c2B5c2ccc(-c4ccccc4)cc2O3)c(-c2ccccc2)c1] 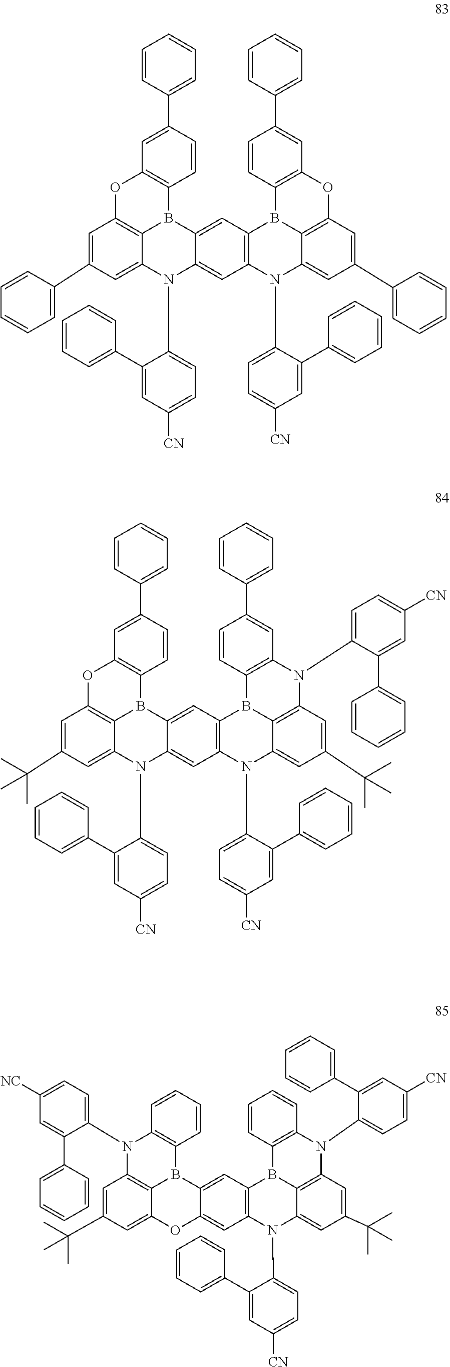 [SMILES: N#Cc1ccc(N2c3cc4c(cc3B3c5ccc(-c6ccccc6)cc5Oc5cc(-c6ccccc6)cc2c53)B2c3ccc(-c5ccccc5)cc3Oc3cc(-c5ccccc5)cc(c32)N4c2ccc(C#N)cc2-c2ccccc2)c(-c2ccccc2)c1 ; CC(C)(C)c1cc2c3c(c1)N(c1ccc(C#N)cc1-c1ccccc1)c1cc4c(cc1B3c1ccc(-c3ccccc3)cc1O2)B1c2ccc(-c3ccccc3)cc2N(c2ccc(C#N)cc2-c2ccccc2)c2cc(C(C)(C)C)cc(c21)N4c1ccc(C#N)cc1-c1ccccc1 ; CC(C)(C)c1cc2c3c(c1)N(c1ccc(C#N)cc1-c1ccccc1)c1ccccc1B3c1cc3c(cc1O2)N(c1ccc(C#N)cc1-c1ccccc1)c1cc(C(C)(C)C)cc2c1B3c1ccccc1N2c1ccc(C#N)cc1-c1ccccc1] 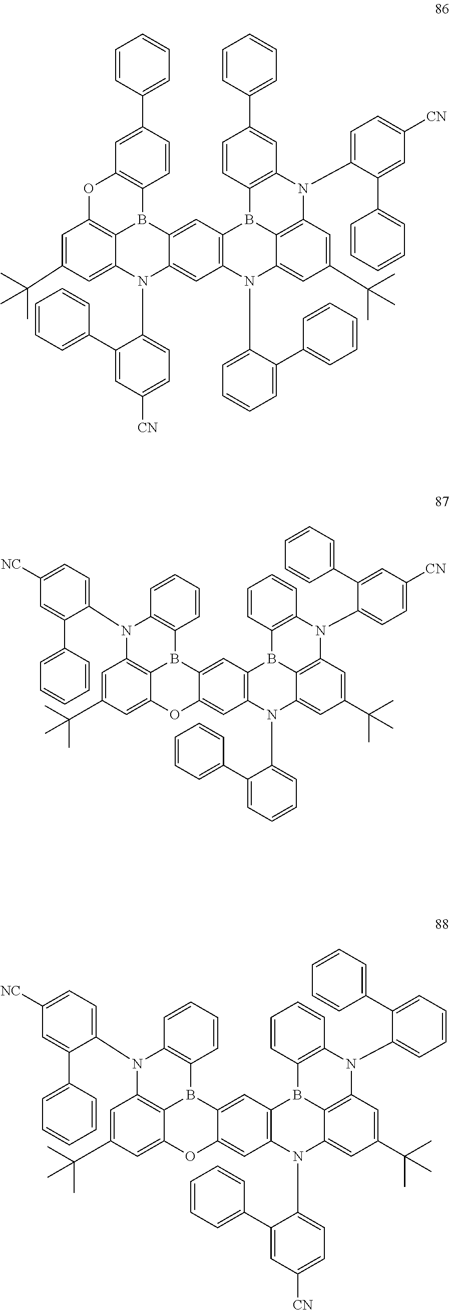 [SMILES: CC(C)(C)c1cc2c3c(c1)N(c1ccc(C#N)cc1-c1ccccc1)c1cc4c(cc1B3c1ccc(-c3ccccc3)cc1O2)B1c2ccc(-c3ccccc3)cc2N(c2ccc(C#N)cc2-c2ccccc2)c2cc(C(C)(C)C)cc(c21)N4c1ccccc1-c1ccccc1 ; CC(C)(C)c1cc2c3c(c1)N(c1ccc(C#N)cc1-c1ccccc1)c1ccccc1B3c1cc3c(cc1O2)N(c1ccccc1-c1ccccc1)c1cc(C(C)(C)C)cc2c1B3c1ccccc1N2c1ccc(C#N)cc1-c1ccccc1 ; CC(C)(C)c1cc2c3c(c1)N(c1ccc(C#N)cc1-c1ccccc1)c1ccccc1B3c1cc3c(cc1O2)N(c1ccc(C#N)cc1-c1ccccc1)c1cc(C(C)(C)C)cc2c1B3c1ccccc1N2c1ccccc1-c1ccccc1] 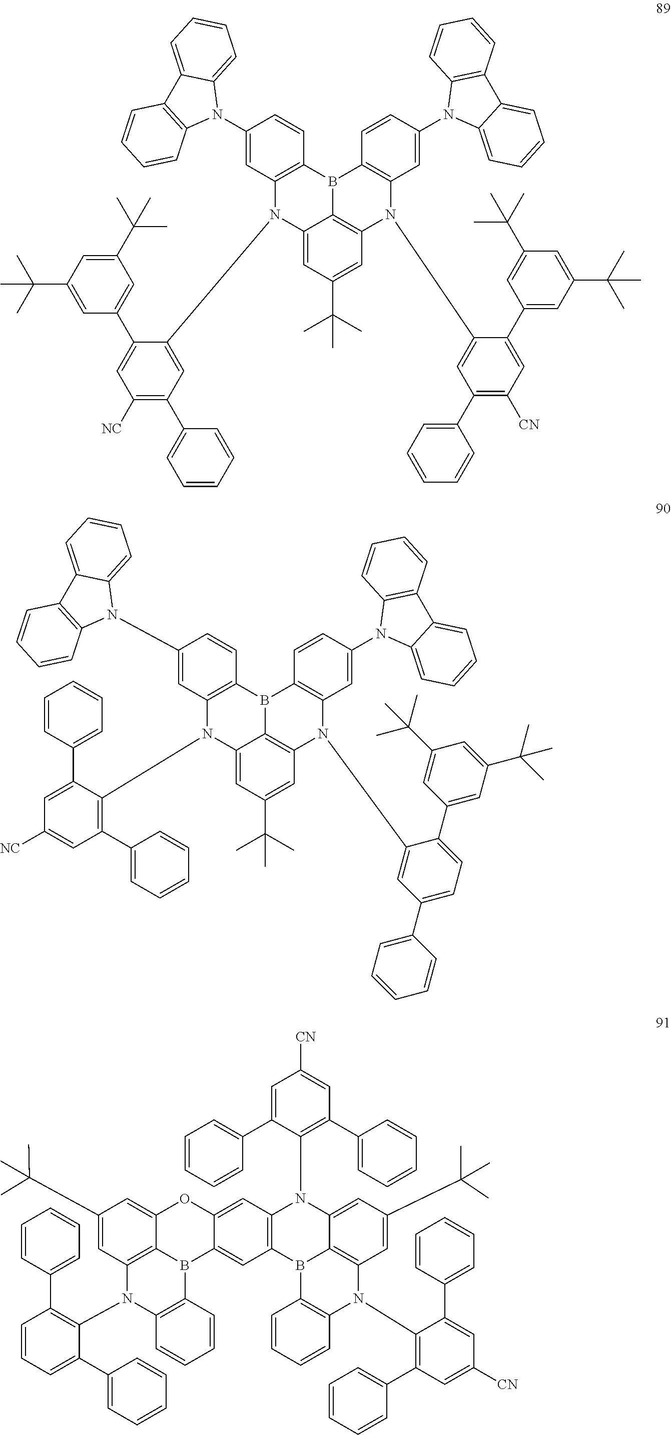 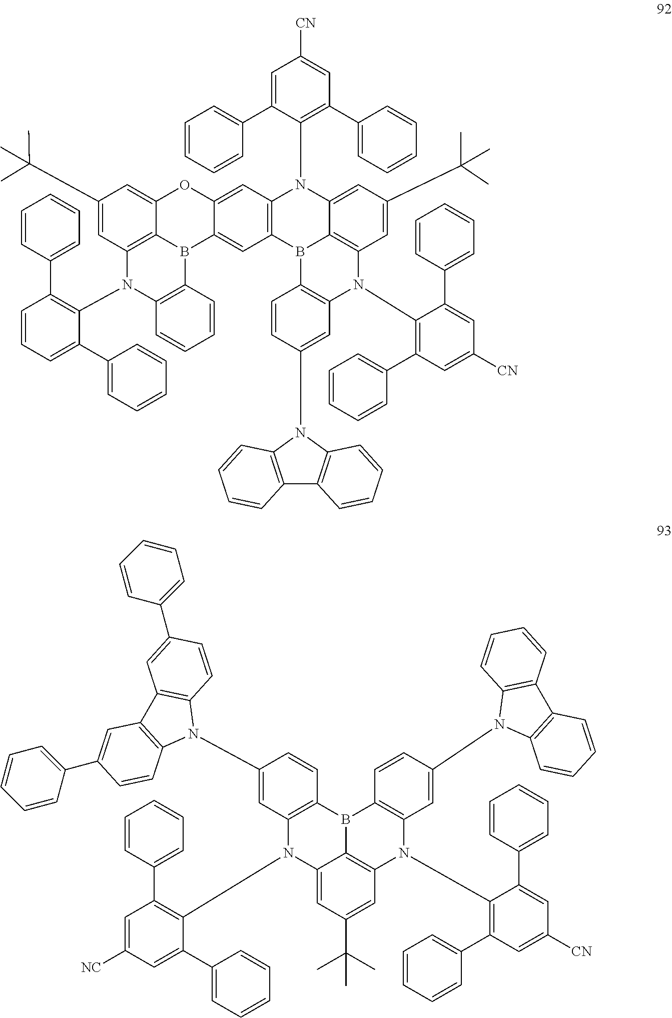 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccc(-n3c4ccccc4c4ccccc43)cc1N2c1c(-c2ccccc2)cc(C#N)cc1-c1ccccc1 ; CC(C)(C)c1cc2c3c(c1)N(c1c(-c4ccccc4)cc(C#N)cc1-c1ccccc1)c1cc(-n4c5ccc(-c6ccccc6)cc5c5cc(-c6ccccc6)ccc54)ccc1B3c1ccc(-n3c4ccccc4c4ccccc43)cc1N2c1c(-c2ccccc2)cc(C#N)cc1-c1ccccc1] 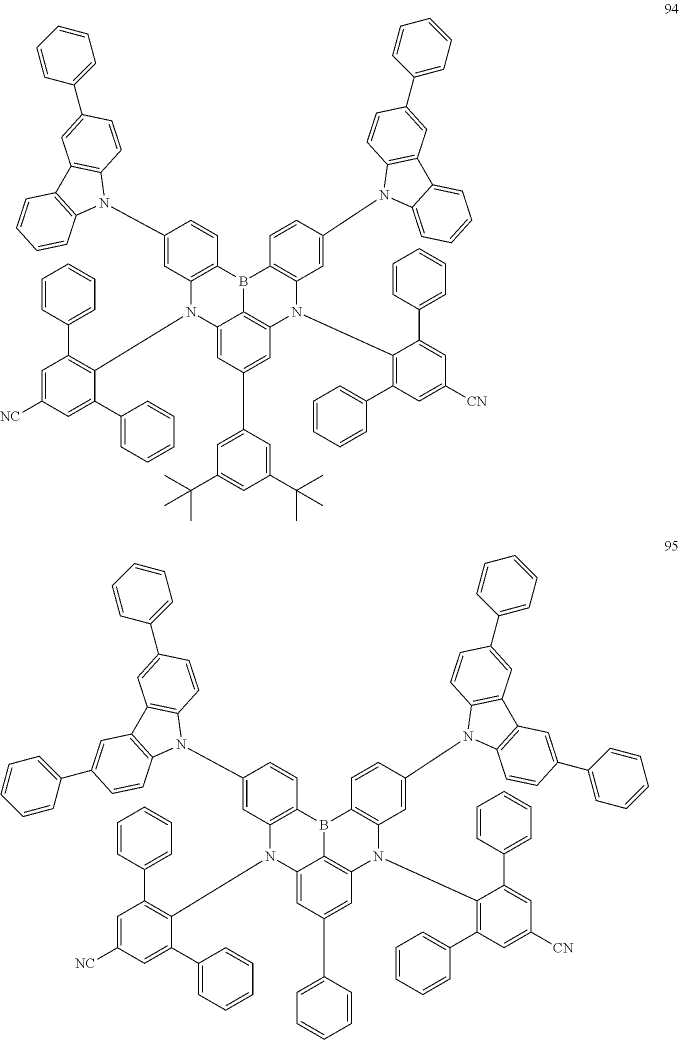 [SMILES: CC(C)(C)c1cc(-c2cc3c4c(c2)N(c2c(-c5ccccc5)cc(C#N)cc2-c2ccccc2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cc(C#N)cc2-c2ccccc2)cc(C(C)(C)C)c1 ; N#Cc1cc(-c2ccccc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4N(c4c(-c5ccccc5)cc(C#N)cc4-c4ccccc4)c4cc(-c5ccccc5)cc2c43)c(-c2ccccc2)c1]
wherein in Compound Group 1,
D is a deuterium atom.

11. A polycyclic compound represented by Formula 1: 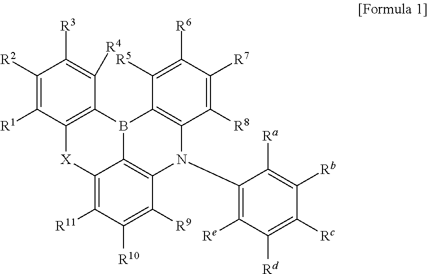
wherein in Formula 1,
X is O, S, or N(R¹²),
R¹ to R¹² are each independently a hydrogen atom, a deuterium atom, a halogen atom, a cyano group, a substituted or unsubstituted amine group, a substituted or unsubstituted oxy group, a substituted or unsubstituted sulfinyl group, a substituted or unsubstituted boron group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or R¹ to R₄ is bonded to an adjacent group to form a ring only between R¹ to R₄, or R⁵ to R⁸ is bonded to an adjacent group to form a ring only between R⁵ to R⁸,
R^{a} to R^{e} are each independently a hydrogen atom, a deuterium atom, a halogen atom, a cyano group, an unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30,
at least one of R^{a} to R^{e} is a cyano group,
at least one of the remainder of R^{a} to R^{e} is each independently a substituted or unsubstituted aryl group having a ring-forming carbon number of 6 to 30.

12. The polycyclic compound of claim 11, wherein
among two selected from R^{a} to R^{e}, one thereof is a cyano group, and the other thereof is a substituted or unsubstituted phenyl group, and
the remainder of R^{a} to R^{e} that are not the cyano group or the substituted or unsubstituted phenyl group are each independently a hydrogen atom, a deuterium atom, or a substituted or unsubstituted aryl group having a ring-forming carbon number of 6 to 30.

13. The polycyclic compound of claim 11, wherein
X is N(R¹²), and
R¹² is a substituted or unsubstituted aryl group having a ring-forming carbon number of 6 to 30.

14. The polycyclic compound of claim 11, wherein the polycyclic compound is represented by one of Formula 2-1 to Formula 2-3: 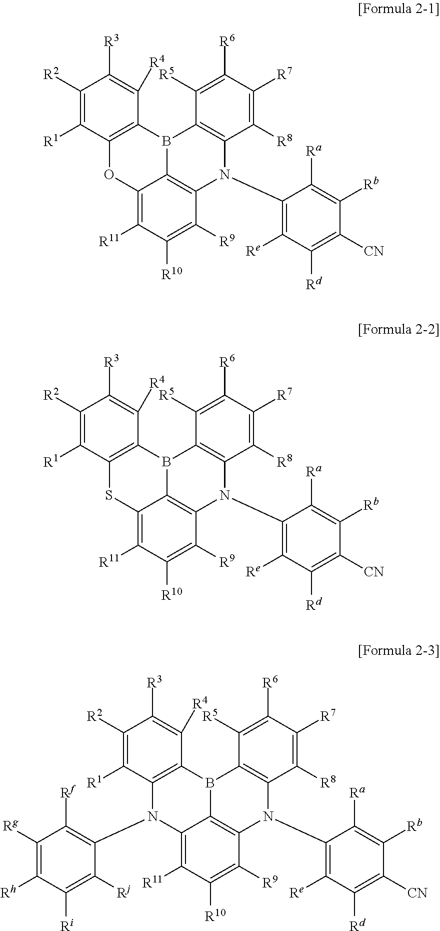
wherein in Formula 2-1 to Formula 2-3,
one or two of R^{a}, R^{b}, R^{d}, and R^{e} are each independently a substituted or unsubstituted phenyl group,
the remainder of R^{a}, R^{b}, R^{d} and R^{e} are each independently a hydrogen atom or a deuterium atom, and
R¹ to R¹¹ are each the same as defined in Formula 1, and
wherein in Formula 2-3,
R^{f}, R^{g}, R^{h}, Rⁱ, and Rⱼ are each independently a hydrogen atom, a deuterium atom, a cyano group, an unsubstituted alkyl group having a carbon number of 1 to 20, or a substituted or unsubstituted aryl group having a ring-forming carbon number of 6 to 30.

15. The polycyclic compound of claim 14, wherein the polycyclic compound represented by Formula 2-3 is represented by Formula 2-3-1: 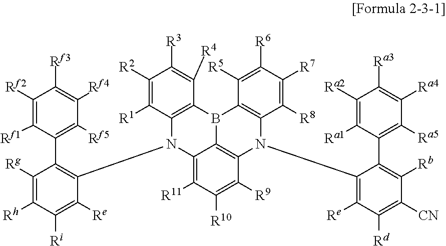
wherein in Formula 2-3-1,
R^{a1} to R^{a5} and R^{f1} to R^{f5} are each independently a hydrogen atom, a deuterium atom, or a substituted or unsubstituted alkyl group having a carbon number of 1 to 10,
one of R^{b}, R^{d}, and R^{e} is a substituted or unsubstituted phenyl group,
the remainder of R^{b}, R^{d}, and R^{e} are each independently a hydrogen atom, or a deuterium atom,
R^{g}, Rⁱ, and Rⱼ are each independently a hydrogen atom, a deuterium atom, an unsubstituted alkyl group having a carbon number 1 to 20, or a substituted or unsubstituted aryl group having a ring-forming carbon number of 6 to 30,
R^{h} is a hydrogen atom, a deuterium atom, or a cyano group, and
R¹ to R¹¹ are each the same as defined in Formula 1.

16. The polycyclic compound of claim 15, wherein the polycyclic compound is represented by one of Formula 3-1 to Formula 3-5: 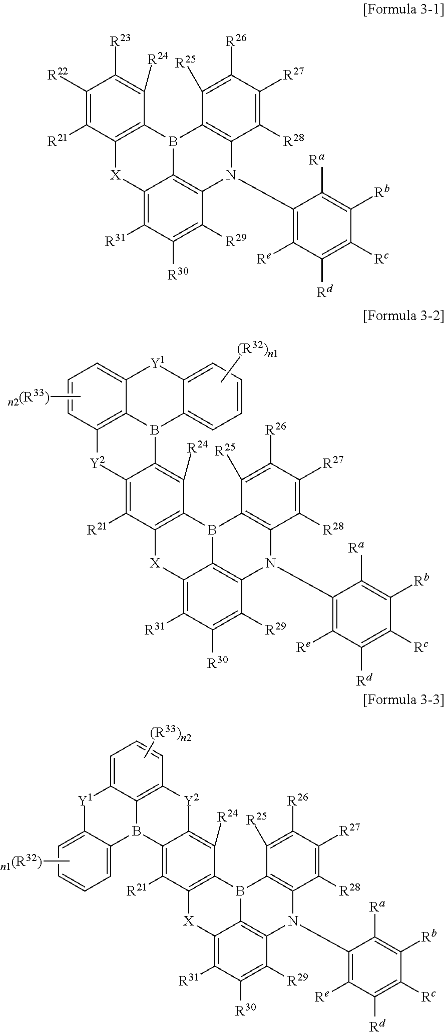 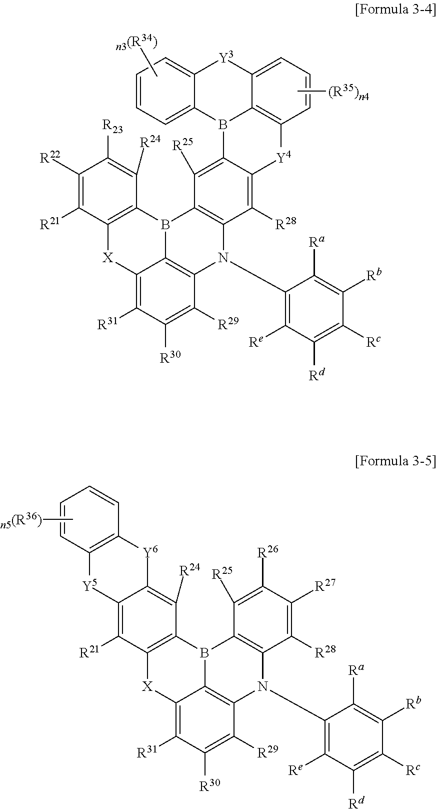
wherein in Formula 3-1 to Formula 3-5,
R²¹ to R³⁶ are each independently a hydrogen atom, a deuterium atom, a substituted or unsubstituted amine group, a substituted or unsubstituted oxy group, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
X, R^{a}, R^{b}, R^{c}, R^{d}, and R^{e} are each the same as defined in Formula 1, and
wherein in Formula 3-2 to 3-5,
n1, n3, and n5 are each independently an integer from 0 to 4,
n2 and n4 are each independently an integer from 0 to 3,
Y¹ to Y⁴ are each independently O, S, or N(R³⁷),
Y⁵ and Y⁶ are each independently O, S, N(R³⁸), or B(R³⁹), and
R³⁷ to R³⁹ are each independently a substituted or unsubstituted aryl group having a ring-forming carbon number of 6 to 30.

17. The polycyclic compound of claim 11, wherein the polycyclic compound is a compound selected from Compound Group 1: 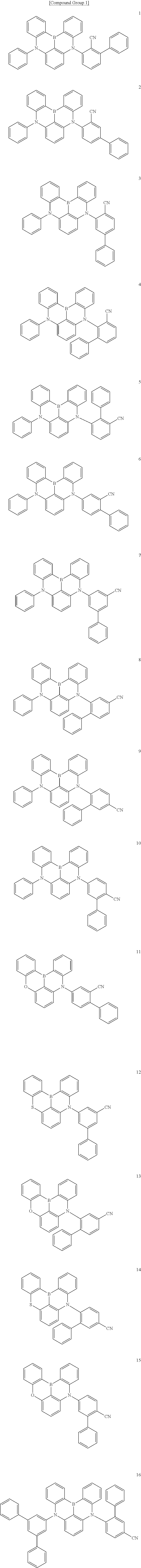 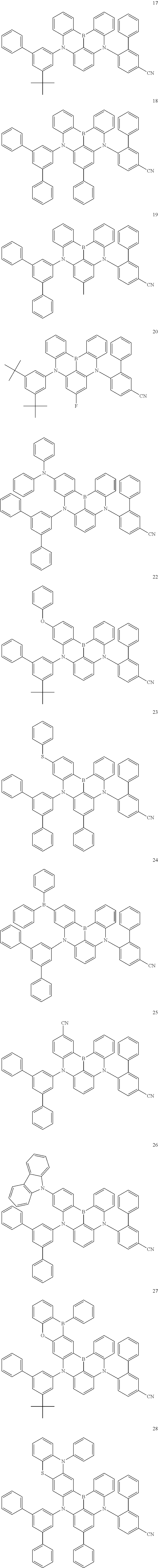 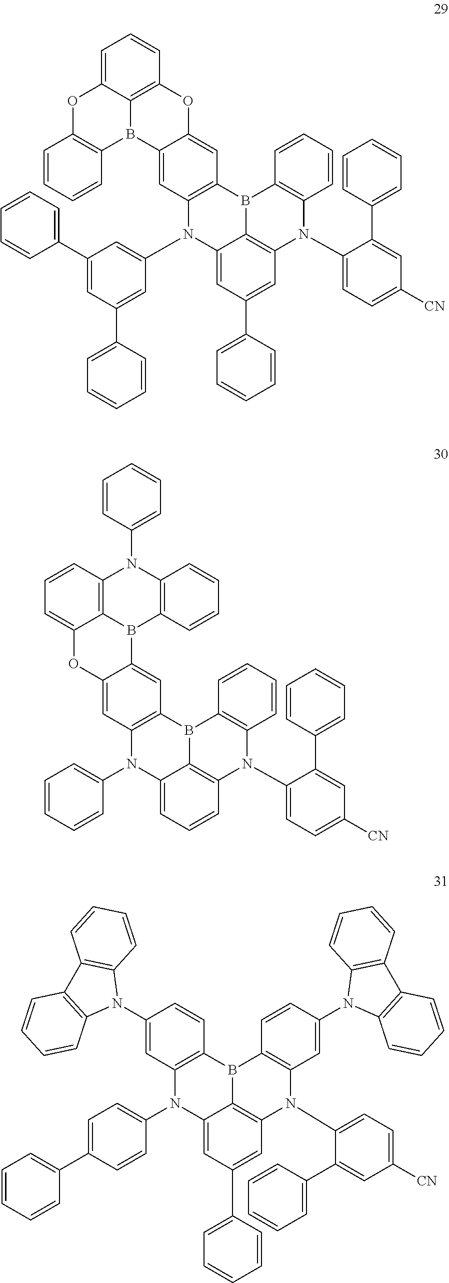 [SMILES: N#Cc1ccc(N2c3ccccc3B3c4cc5c(cc4N(c4cc(-c6ccccc6)cc(-c6ccccc6)c4)c4cc(-c6ccccc6)cc2c43)B2c3ccccc3Oc3cccc(c32)O5)c(-c2ccccc2)c1 ; N#Cc1ccc(N2c3ccccc3B3c4cc5c(cc4N(c4ccccc4)c4cccc2c43)Oc2cccc3c2B5c2ccccc2N3c2ccccc2)c(-c2ccccc2)c1 ; N#Cc1ccc(N2c3cc(-n4c5ccccc5c5ccccc54)ccc3B3c4ccc(-n5c6ccccc6c6ccccc65)cc4N(c4ccc(-c5ccccc5)cc4)c4cc(-c5ccccc5)cc2c43)c(-c2ccccc2)c1] 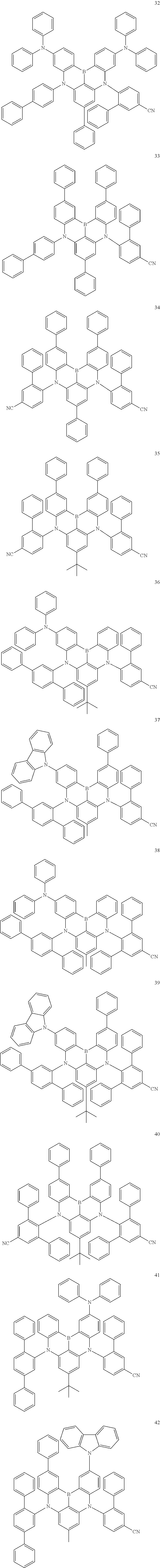 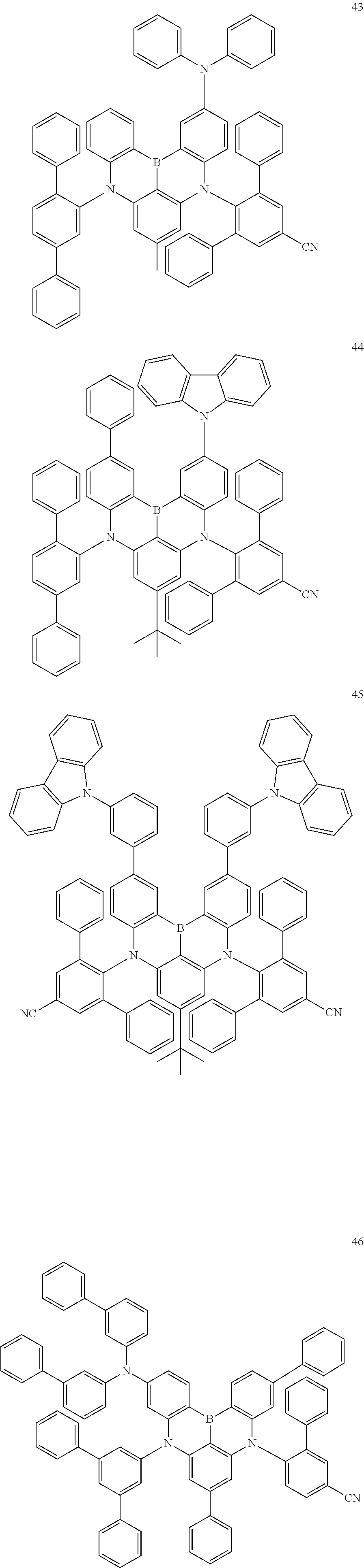 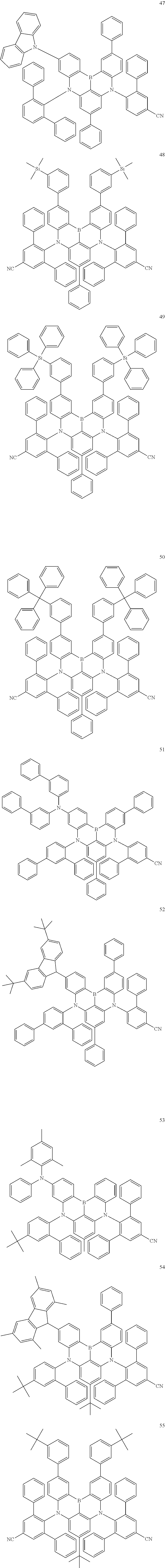 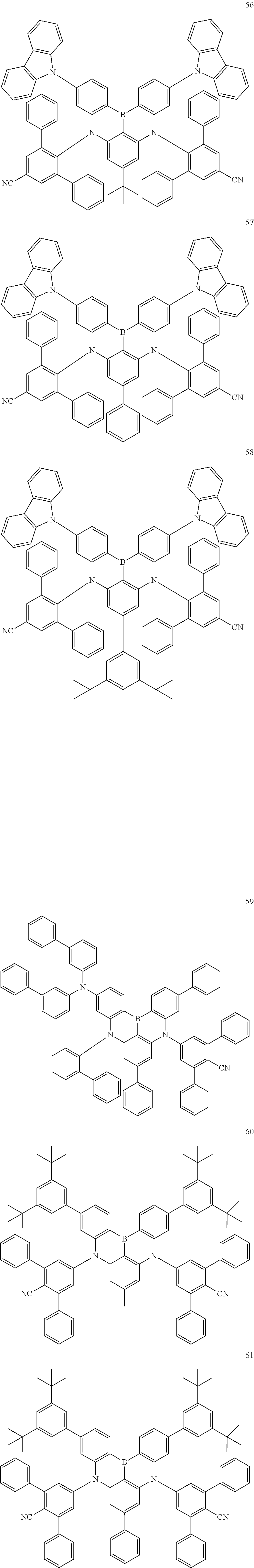 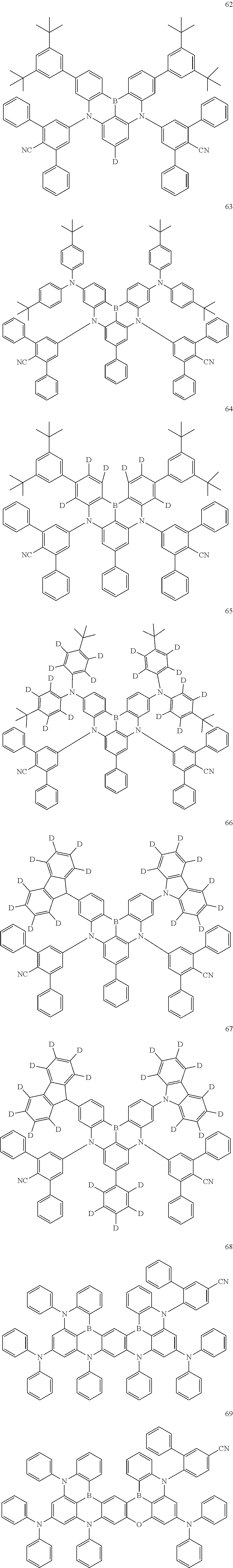 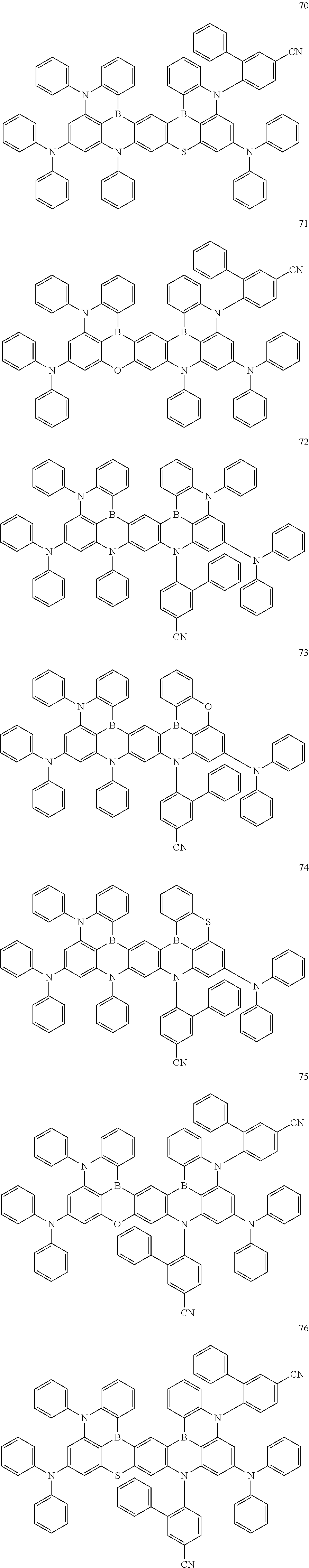 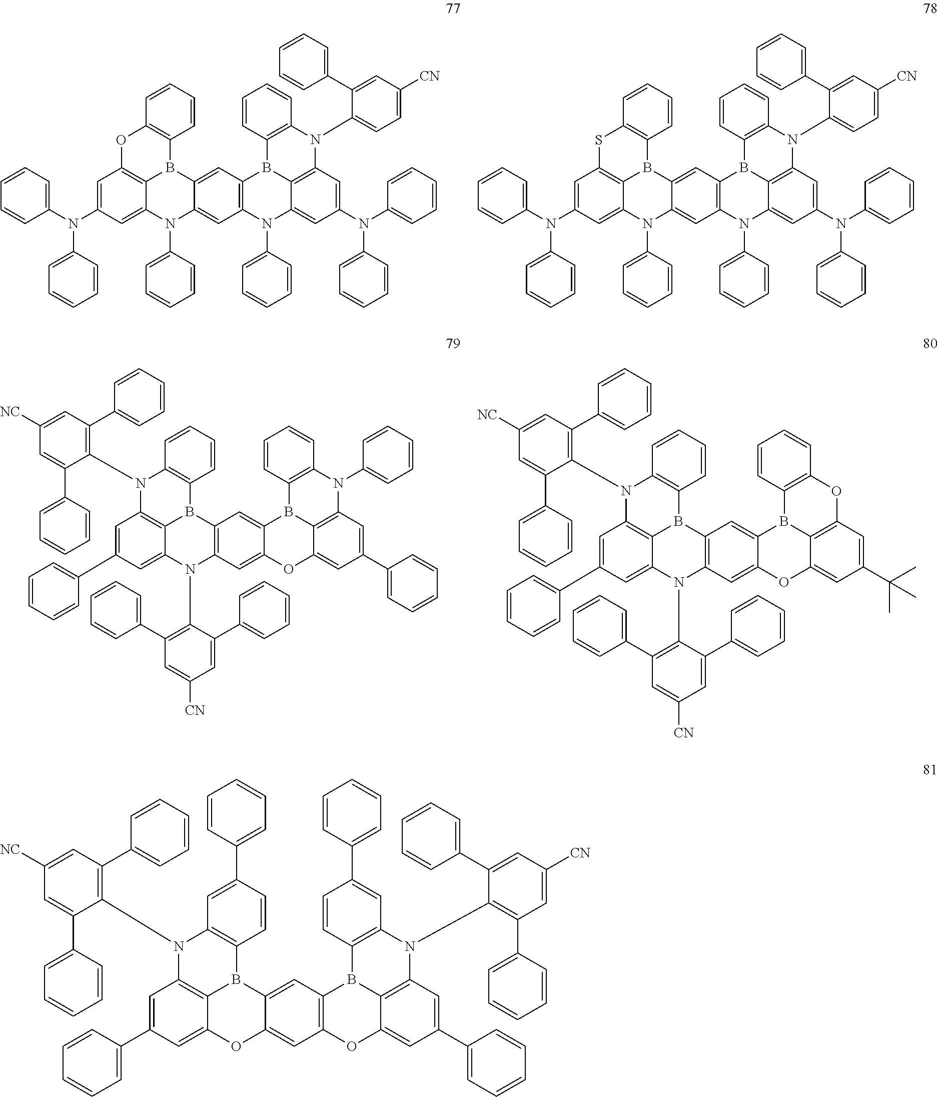 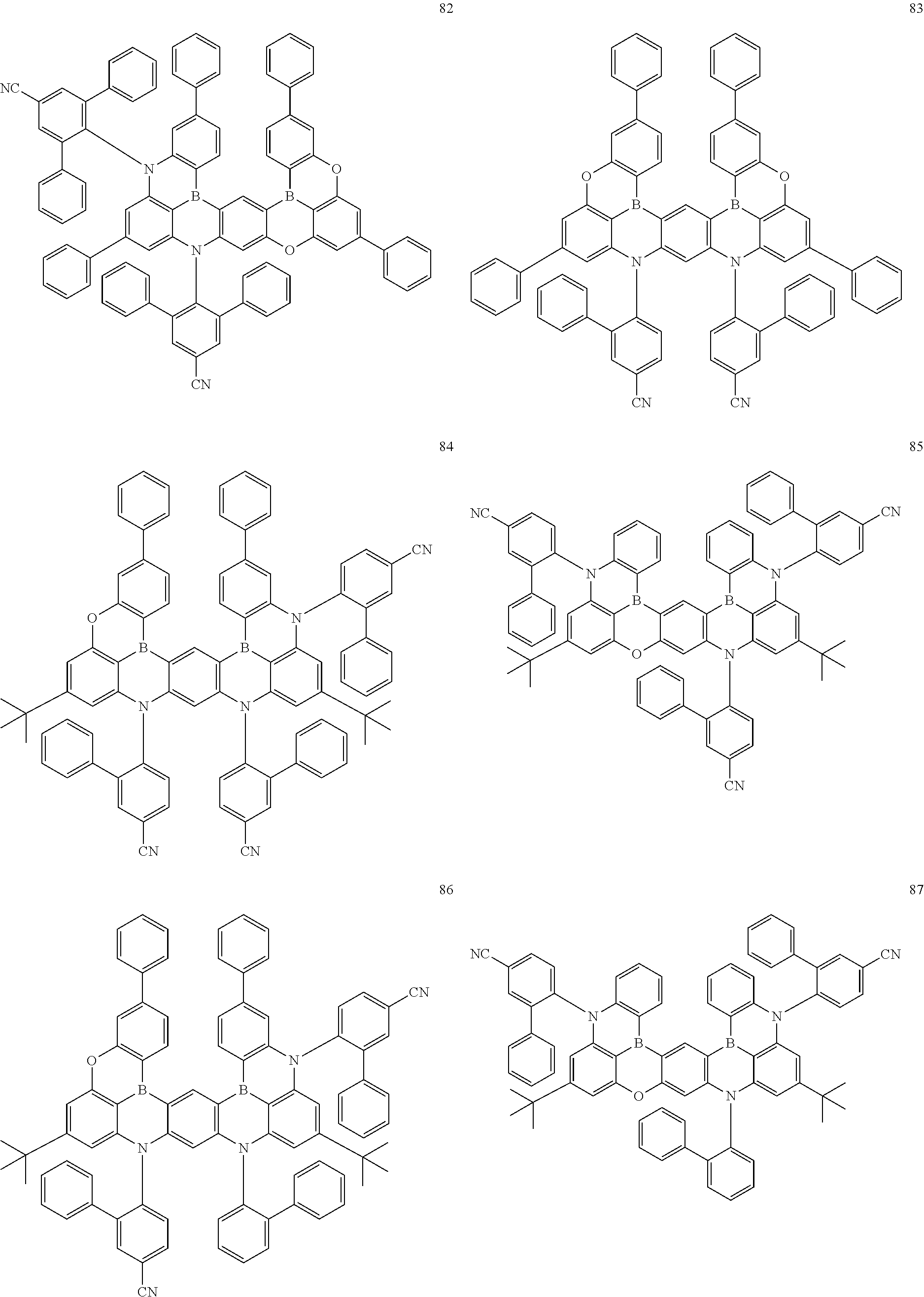 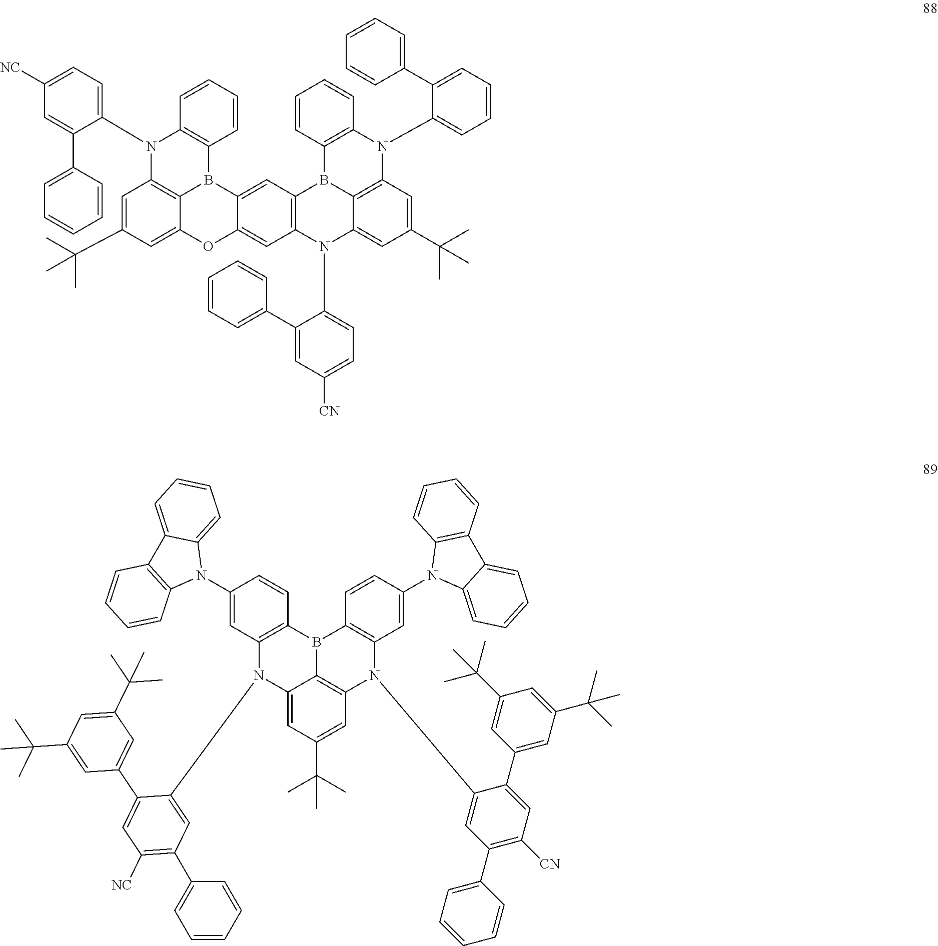 [SMILES: CC(C)(C)c1cc2c3c(c1)N(c1ccc(C#N)cc1-c1ccccc1)c1ccccc1B3c1cc3c(cc1O2)N(c1ccc(C#N)cc1-c1ccccc1)c1cc(C(C)(C)C)cc2c1B3c1ccccc1N2c1ccccc1-c1ccccc1 ; CC(C)(C)c1cc(-c2cc(C#N)c(-c3ccccc3)cc2N2c3cc(-n4c5ccccc5c5ccccc54)ccc3B3c4ccc(-n5c6ccccc6c6ccccc65)cc4N(c4cc(-c5ccccc5)c(C#N)cc4-c4cc(C(C)(C)C)cc(C(C)(C)C)c4)c4cc(C(C)(C)C)cc2c43)cc(C(C)(C)C)c1] 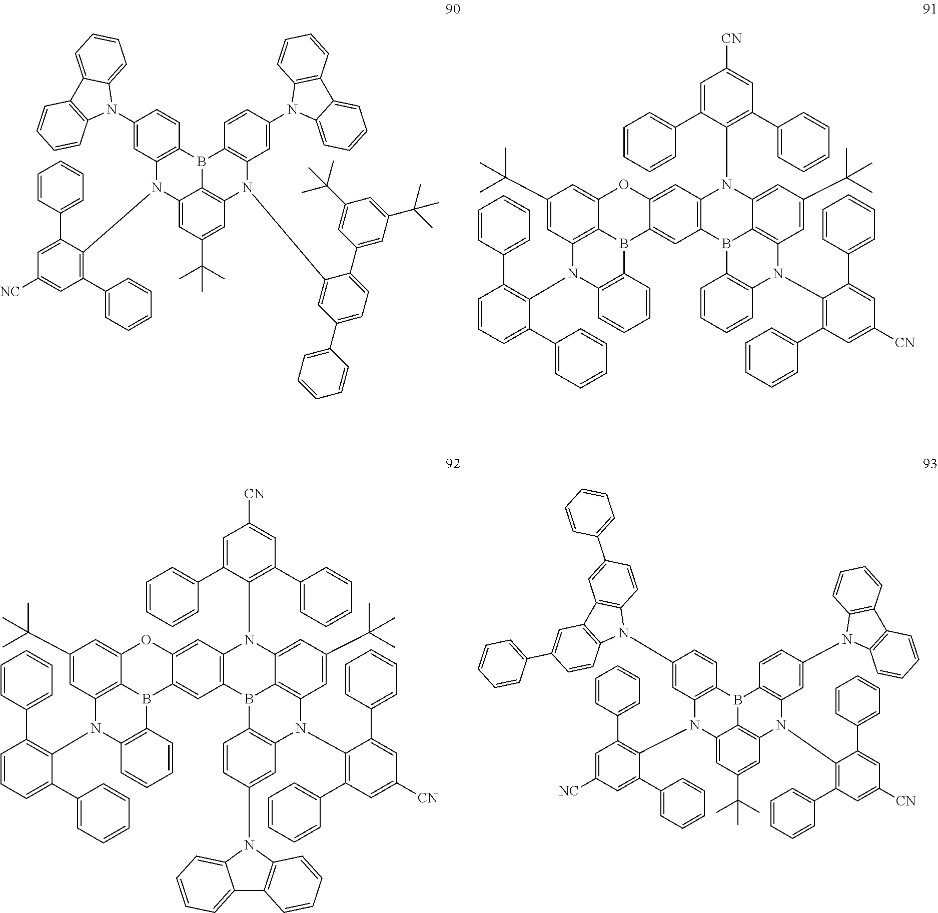 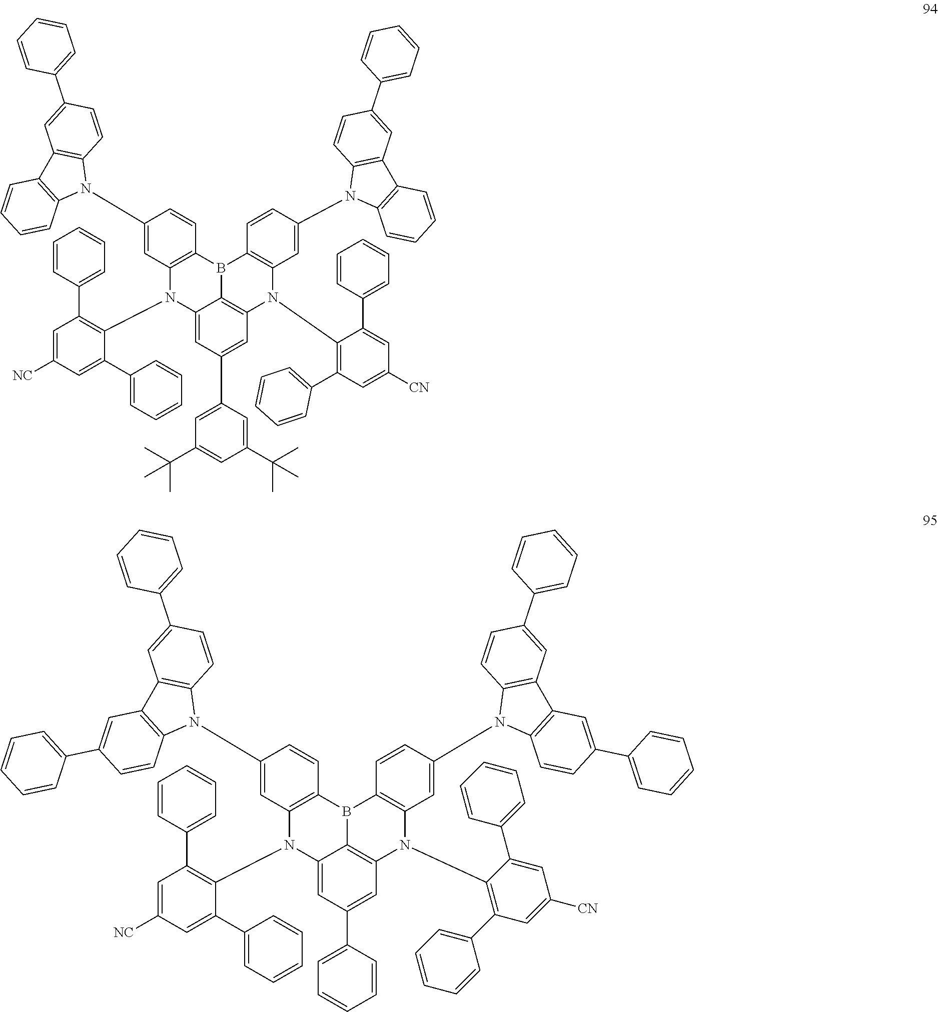
wherein in Compound Group 1,
D is a deuterium atom.

18. An electronic device comprising a display device, the display device comprising:
a circuit layer disposed on a base layer; and
a display element layer disposed on the circuit layer and including a light-emitting element, wherein
the light-emitting element includes:
a first electrode;
a second electrode facing the first electrode; and
an emission layer disposed between the first electrode and the second electrode and including a polycyclic compound represented by Formula 1: 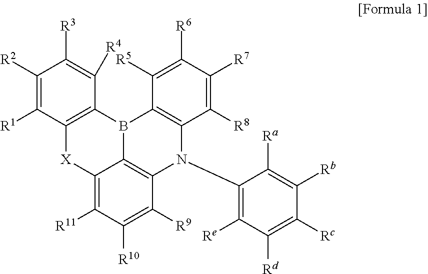
wherein in Formula 1,
X is O, S, or N(R¹²),
R¹ to R¹² are each independently a hydrogen atom, a deuterium atom, a halogen atom, a cyano group, a substituted or unsubstituted amine group, a substituted or unsubstituted oxy group, a substituted or unsubstituted sulfinyl group, a substituted or unsubstituted boron group, a unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or R¹ to R⁴ is bonded to an adjacent group to form a ring only between R¹ to R⁴, or R⁵ to R⁸ is bonded to an adjacent group to form a ring only between R⁵ to R⁸,
R^{a} to R^{e} are each independently a hydrogen atom, a deuterium atom, a halogen atom, a cyano group, an unsubstituted alkyl group having a carbon number of 1 to 20, a substituted or unsubstituted aryl group having a ring-forming carbon atom of 6 to 30, or a substituted or unsubstituted heteroaryl group having a ring-forming carbon number of 2 to 30,
at least one of R^{a} to R^{e} is a cyano group, and
at least one of the remainder of R^{a} to R₁ is each independently a substituted or unsubstituted aryl group having a ring-forming carbon number of 6 to 30.

19. The electronic device of claim 18, wherein the light-emitting element emits blue light.

20. The electronic device of claim 18, wherein the display device further comprises:
a light control layer including a quantum dot.
